(19) United States
(12) Patent Application Publication
(10) Pub. No.: US 2011/0101503 A1
(43) Pub. Date: May 5, 2011

(54) HYPERBRANCHED POLYMER SYNTHESIZING METHOD, HYPERBRANCHED POLYMER, RESIST COMPOSITION, SEMICONDUCTOR INTEGRATED CIRCUIT, AND SEMICONDUCTOR INTEGRATED CIRCUIT FABRICATION METHOD

(75) Inventors: Akinori Uno, Tokyo (JP); Yoshiyasu Kubo, Tokyo (JP); Yusuke Sasaki, Tokyo (JP); Mineko Horibe, Tokyo (JP); Yukihiro Kaneko, Tokyo (JP); Minoru Tamura, Tokyo (JP); Shinichiro Kabashima, Tokyo (JP); Yuko Tanaka, Tokyo (JP); Kaoru Suzuki, Tokyo (JP)

(73) Assignee: LION CORPORATION, TOKYO (JP)

(21) Appl. No.: 12/521,438

(22) PCT Filed: Dec. 20, 2007
(86) PCT No.: PCT/JP2007/074580

§ 371 Date: Jun. 26, 2009

(30) Foreign Application Priority Data
Dec. 28, 2006 (JP) 2006-355873

(51) Int. Cl. H01L 29/06; C08F 8/00; C08F 2/04; H01L 21/30

(52) U.S. Cl. 257/618; 525/192; 438/795; 257/E29.005; 257/E21.211

(57) ABSTRACT

A hyperbranched polymer synthesizing method employs living radical polymerization of a monomer in the presence of a metal catalyst. The method includes forming a shell portion by introducing an acid-decomposable group to a core portion formed of a hyperbranched polymer synthesized by living radical polymerization; forming an acid group by partially decomposing the acid-decomposable group by an acid catalyst; precipitating a core-shell hyperbranched polymer contained in a first solution and having the acid group, by mixing the first solution with ultrapure water; and extracting, from a mixed solution into an organic solvent by liquid-liquid extraction, the core-shell hyperbranched polymer having the acid group, wherein the mixed solution contains a second solution containing the core-shell hyperbranched polymer precipitated at the precipitating and dissolved into the organic solvent, and the ultrapure water of an amount yielding a prescribed ratio of the ultrapure water relative to the organic solvent in the second solution.

### TECHNICAL FIELD

The present invention relates to a hyperbranched polymer synthesizing method, a hyperbranched polymer, a resist composition, a semiconductor integrated circuit, and a semiconductor integrated circuit fabrication method.

### BACKGROUND ART

### Description of the First Background Art

In recent years, in photo lithography expected as a promising future microfabrication technology, design rules with an emphasis on miniaturization have been progressing by a shift to a shorter wavelength in a light source, and thereby realizing a high integration of a semi-conductor integrated circuit such as a very-large-scale integrated circuit. For design rules of 32 nm or less, EUV lithography draws a high degree of expectation.

In a resist composition, a base polymer having a chemical structure transparent to light sources has been developed. Resist compositions containing the following polymers have been proposed, for example, a polymer having a base skeleton of a novolak type polyphenol in a KrF excimer laser beam (248 nm wavelength) (see, for example, Patent Document 1), a poly(meth)acrylate ester in an ArF excimer laser beam (193 nm wavelength) (see, for example, Patent Document 2), and a polymer containing fluorine atoms (perfluoro structure) in an F2 excimer laser beam (157 nm wavelength) (see, for example, Patent Document 3). These polymers are based on a linear structure.

However, when these linear polymers are applied to form an ultrafine miniaturized pattern of 32 nm or less, the concavity and convexity of the pattern wall, which is a barometer of a line edge roughness, became a problem. It is pointed out that, to form an ultrafine pattern by irradiating an electron beam or an extreme ultraviolet beam (EUV: 13.5 nm) to conventional resists composed of mainly, for example, PMMA (poly(methyl methacrylate)) and PHS (poly-hydroxystyrene), control of a surface smoothness at a nanometer level will become a problem (see, for example, Nonpatent Literature 1).

On the other hand, attempts to use a hyperbranched polymer as a resist material have been made in recent years. A hyperbranched polymer having a highly branching structure in a core portion, and an acid group (for example, a carboxylic acid) and an acid-decomposable group (for example, a carboxylate ester) in a molecular terminal has less intermolecular entanglement, which is seen in a linear polymer. In addition, it swells less by an organic solvent as compared with a molecular structure of a crosslinked main chain. It is reported that, when a resist material containing a hyperbranched polymer such as this is used, formation of a large molecular aggregate body causing surface roughness on a pattern wall is suppressed (see, for example, Patent Document 4).

There exists a core-shell hyperbranched polymer having a core portion formed of a hyperbranched polymer and a shell portion formed by introducing an acid-decomposable group to the core portion. The core-shell hyperbranched polymer such as this may be synthesized, for example, by the ATRP method (atom transfer radical polymerization).

When the ATRP method is used, the core portion is firstly formed by polymerizing monomers, polymerizable by a living radical polymerization, in the presence of a metal catalyst, then an acid-decomposable group is introduced to the core portion thus formed to form the shell portion, and thereafter an acid group is formed by partially decomposing the acid-decomposable group in the shell portion by an acid catalyst (hereinafter, “deprotection”). The ATRP method has a high potential as a practical method of synthesizing the core-shell hyperbranched polymer in view of availability of raw materials and ease of the up-scaling.

In the synthesis of the core-shell hyperbranched polymer by the ATRP method as described above, there is a technology in which a substance after the deprotection is dissolved in a small amount of an organic solvent, then a large excess of water relative to the organic solvent (about 10 times) is added to the solution containing the substance after the deprotection to obtain the core-shell hyperbranched polymer precipitated in the solution.

### Description of the Second Background Art

In recent years, in photo lithography expected as a promising future microfabrication technology, design rules with an emphasis on miniaturization have been progressing by a shift to a shorter wavelength in a light source, thereby realizing a high integration of a semi-conductor integrated circuit such as a very-large-scale integrated circuit. For design rules of 32 nm or less, EUV lithography draws a high degree of expectation.

In a resist composition, a base polymer having a chemical structure transparent to light sources has been developed. Resist compositions containing the following polymers have been proposed, for example, a polymer having a base skeleton of a novolak type polyphenol in a KrF excimer laser beam (248 nm wavelength) (see, for example, Patent Document 4), a poly(meth)acrylate ester in an ArF excimer laser beam (193 nm wavelength) (see, for example, Patent Document 5), and a polymer containing fluorine atoms (perfluoro structure) in an F2 excimer laser beam (157 nm wavelength) (see, for example, Patent Document 6). These polymers are based on a linear structure.

However, when these linear polymers are applied to form an ultrafine miniaturized pattern of 32 nm or less, the concavity and convexity of the pattern wall, which is a barometer of a line edge roughness, became a problem. It is pointed out that, to form an ultrafine pattern by irradiating an electron beam or an extreme ultraviolet beam (EUV: 13.5 nm) to conventional resists composed of mainly, for example, PMMA (poly(methyl methacrylate)) and PHS (poly-hydroxystyrene), control of surface smoothness at a nanometer level will become a problem (see, for example, Nonpatent Literature 2).

It is assumed that the concavity and convexity of the pattern wall is caused by a cluster formation of polymers composing the resist (see, for example, Nonpatent Literature 3). Although it is said that a decrease of the line edge roughness due to clustering may be reduced by using a low molecular weight mono-dispersion polymer (see, for example, Patent Document 7), it lacks practicability because, when a low molecular weight polymer is used, the glass transition temperature (Tg) of the polymer is lowered, making thermal baking difficult.

On the other hand, a branched polymer is known as an example to improve the line edge roughness as compared to a linear polymer (see, for example, Nonpatent Literature 4). However, requirements in substrate adhesiveness and sensitivity accompanying the progress of design rules in terms of miniaturization have yet to be satisfied.

In view of the above, attempts to use a hyperbranched polymer as a resist material has been made in recent years. A hyperbranched polymer having a highly branching structure in a core portion, and an acid group (for example, a carboxylic acid) and an acid-decomposable group (for example, a carboxylate ester) in a molecular terminal has less intermolecular entanglement, which is seen in a linear polymer, and swells less by an organic solvent as compared with a molecular structure of a crosslinked main chain. It is reported that, when a resist material containing a hyperbranched polymer such as this is used, formation of a large molecular aggregate body causing surface roughness on a pattern wall is suppressed (see, for example, Patent Document 8).

A hyperbranched polymer usually takes a spherical morphology. In photo lithography, when an acid-decomposable group is present on a surface of a spherical hyperbranched polymer, a decomposition reaction takes place in a light-exposed part by the action of acid generated from a photo-inductive acid-generating material, thereby forming a hydrophilic group. It is reported that it became clear that this enabled a spherical micellar structure having a large number of hydrophilic groups at the periphery of the hyperbranched polymer.

A hyperbranched polymer with a spherical micellar structure having a large number of hydrophilic groups at its periphery is dissolved efficiently in an aqueous basic solution, and thus is removed along with the basic solution. It is reported that it became clear that a resist material containing a hyperbranched polymer like this enabled the formation of a fine pattern, thereby allowing it to be used suitably as a base resin in a resist material. In addition, it became clear that solubility in a basic solution after a light exposure, namely sensitivity, can be improved when the core portion and the shell portion exist at a specific value, and also the acid-decomposable carboxylate ester group and the carboxylic acid group coexist at a specific ratio in the shell portion.

Generally, when a hyperbranched polymer having a core portion with a highly branched structure and containing in its molecular terminal an acid-decomposable group and an acid group, for example, a carboxylic acid group and a carboxylate ester group, at a specific ratio is synthesized by the ATRP method (atom transfer radical polymerization), the synthesis can be performed via the following steps (a) and (b).

(a) A step of synthesizing a core portion in the presence of a metal catalyst, thereby introducing an acid-decomposable group (a carboxylate ester group) (hereinafter, “shell portion”) to the core portion.
(b) A step of obtaining a carboxylic acid group (hereinafter, “acid group”) by partially decomposing the carboxylate ester group (hereinafter, “de-esterification” or “deprotection”) in such a manner as to obtain an optimum base-solubility when exposed to light.

When a hyperbranched polymer is synthesized by the ATRP method, which enables the step (a) and the step (b) and has a high practicality because of the availability of raw materials and an ease of up-scaling, a metal catalyst such as a copper is used in the synthesis. Because of this, when a hyperbranched polymer is synthesized by the ATRP method, the removal of metal is indispensable to prevent adverse effects on subsequent processes. A metal catalyst is also used in the step of introducing the acid-decomposable group into the core portion. If a large amount of metals derived from the metal catalyst remain in the core portion after the core portion synthesis, there is a risk of adverse effects such as particularly large change in the reactivity and insolubilization of a resist composition containing the hyperbranched polymer after exposure to light. Accordingly, it is necessary to remove the metal to a level not causing significant effects.

In the past, a method such as a column fractionation (see, for example, Patent Document 6), an alumina adsorption (see, for example, Patent Document 8), has been known for removal of the metal catalyst.

When the hyperbranched polymer is contaminated by monomer and by-product oligomer, there is also a risk of adverse effects such as insolubilization of a resist composition containing the hyperbranched polymer after exposure to light. Accordingly, it is desirable that impurities such as monomer used for polymerization to the hyperbranched polymer and by-product oligomer be removed appropriately. In the past, as a method of removing monomer and oligomer, a method of washing by a solvent mixture of a good solvent and a poor solvent has been known; however, a conventional method like this has problems in that the number of the washing operations needs to be increased and a large amount of solvent is used to achieve high removal efficiency.

### Description of the Third Background Art

In recent years, in photo lithography expected as a promising future microfabrication technology, design rules with an emphasis on miniaturization have been progressing by a shift to a shorter wavelength in a light source, thereby realizing a high integration of a very-large-scale integrated circuit. For design rules of 32 nm or less, UV lithography draws a high degree of expectation.

In a resist composition, a base polymer having a chemical structure transparent to light sources has been developed. Resist compositions containing the following polymers have been proposed, for example, a polymer having a base skeleton of a novolak type polyphenol in a KrF excimer laser beam (248 nm wavelength) (Patent Document 1), a poly(meth)acrylate ester in an ArF excimer laser beam (193 nm wavelength) (Patent Document 2), and a polymer containing fluorine atoms (perfluoro structure) in an F2 excimer laser beam (157 nm wavelength) (Patent Document 3). These polymers are based on a linear structure.

However, when these linear polymers are applied to form an ultrafine miniaturized pattern of 32 nm or less, the concavity and convexity of the pattern wall, which is a barometer of a line edge roughness, became a problem. In Nonpatent Literature 1, it is pointed out that, to form an ultrafine pattern by irradiating an electron beam or an extreme ultraviolet beam (EUV: 13.5 nm) to conventional resists composed of mainly PMMA (poly(methyl methacrylate)) and PHS (poly-hydroxystyrene), control of surface smoothness at a nanometer level will become a problem.

According to Nonpatent Literature 3, it is assumed that the concavity and convexity of the pattern wall is caused by a cluster formation of polymers composing the resist. Although it is said that a decrease of the line edge roughness due to clustering may be reduced by using a low molecular weight mono-dispersion polymer (Patent Document 9), it lacks practicability because, when a low molecular weight polymer is used, the glass transition temperature (Tg) of the polymer is lowered, making thermal baking difficult.

On the other hand, a branched polymer is known as an example to improve the line edge roughness as compared to a linear polymer (Nonpatent Literature 4). However, requirements in substrate adhesiveness and sensitivity accompanying the progress of the design rules in terms of miniaturization have yet to be satisfied.

In view of the above, in recent years, attempts to use a hyperbranched polymer as a resist material have been made. According to Patent Document 4, it is reported that a hyperbranched polymer having a highly branching structure in a core portion, and an acid group (for example, a carboxylic acid) and an acid-decomposable group (for example, a carboxylate ester) in a molecular terminal has less intermolecular entanglement, which is seen in a linear polymer, and swells less by an organic solvent as compared with a molecular structure of a crosslinked main chain, thereby suppressing formation of a large molecular aggregate body which causes surface roughness on a pattern wall.

Further, it is reported that it became clear that, although a hyperbranched polymer usually takes a spherical morphology, in photo lithography, when an acid-decomposable group is present on a surface of a spherical hyperbranched polymer, a decomposition reaction takes place in the exposed part by the action of acid generated from a photo-inductive acid-generating material, thereby forming a hydrophilic group and thus enabling a spherical micellar structure having a large number of hydrophilic groups at the periphery of the hyperbranched polymer.

It is reported that it became clear that, because of this, the polymer can be dissolved efficiently in an aqueous basic solution and removed along with the basic solution, thereby enabling formation of a fine pattern and thus, is advantageously usable as a base resin in a resist material. In addition, it has become clear that an improvement of solubility in a basic solution after optical exposure, namely an improvement of the sensitivity, can be achieved when the acid-decomposable carboxylate ester group and the carboxylic acid group coexist at a specific ratio.

Generally, a hyperbranched polymer having a core portion with a highly branched structure and containing an acid-decomposable group and an acid group, for example, a carboxylic acid group and a carboxylate ester group, at a specific ratio in its molecular terminal may be synthesized by the ATRP method (atom transfer radical polymerization) via the following steps.

(a) A step of synthesizing a core portion in the presence of a metal catalyst, thereby introducing an acid-decomposable group (a carboxylate ester group) to the core portion; and
(b) A step of obtaining a carboxylic acid group (acid group) by partially decomposing the carboxylate ester group (de-esterification or deprotection) in such a manner as to obtain an optimum base-solubility when exposed to light.

The ATRP method, which enables the above steps, has a high practicality because of the availability of raw materials and ease of up-scaling. However, because a metal catalyst such as copper is used, metal removal is indispensable. In a high performance photo resist polymer, the amount of metal impurities needs to be reduced markedly to avoid pollution in plasma treatment and prevent any adverse effects on electrical properties of a semi-conductor due to metal impurities remaining in a pattern.

The methods for removing metals after a photo resist polymer is synthesized by the ATRP method, namely, for example, the column fractionation after step (b) (Patent Document 6) and the alumina adsorption after step (a) (Patent Document 4), are known; however, both are costly and thus, not suitable for industrialization.

On the other hand, as a method to remove a small amount of metals, methods using an ion-exchange resin and an acidic water wash are known (Patent Documents 7 and 8). However, these methods have problems in that removal of the large amount of metals used in such a method as the ATRP method is difficult, and in addition, particularly in the polymer of the present invention containing a carboxylic acid group and an acid-decomposable group in its terminal, the carboxylic acid group forms a chelate with metal, and further the acid-decomposable group is decomposed by protons generated from the ion-exchange resin, thereby causing a change in the ratio of the carboxylate ester group to the carboxylic acid group.

### Description of the Fourth Background Art

“Hyperbranched polymer” is a general term for a multi-branched polymer having a branching structure in its repeating units. The hyperbranched polymer has a specific structure having intentionally introduced branches, while a conventional linear polymer is generally in the form of a string. The polymer is in the size of nanometers and can have many functional groups on its surface. Because of these characteristics, the polymer is expected to have various applications.

In the past, there is a technology in which, for example, the core portion is firstly formed by polymerizing monomers by a living radical polymerization in the presence of a metal catalyst, then the acid-decomposable group is introduced to the core portion formed therein to form the shell portion, and subsequently the acid group is formed by partially decomposing the acid-decomposable group in the shell portion by using an acid catalyst to synthesize the core-shell hyperbranched polymer.

A hyperbranched polymer like this is applied, for example, to a resist composition in a photo-resist. It is known that in a resist composition, when impurities such as unreacted monomers and the hyperbranched polymer are concomitantly present, polymerization of the hyperbranched polymer progresses with time, resulting in an increase in molecular weight and thereby, leading to a decrease in the degree of resolution in the photo resist process.

Accordingly, to obtain a high degree of resolution in the photo resist process regardless of the elapse of time, resist compositions, using the core-shell hyperbranched polymer with a suppressed formation of the photopolymer assembly and an excellent dissolving contrast (see, for example, Patent Document 4) and the hyperbranched polymer from which surface-active sub-micron particles that accelerate polymerization are removed by filtration (see, for example, Nonpatent Literature 4), or the like, are known.

### Description of the Fifth Background Art

“Hyperbranched polymer” is a general term for a multi-branched polymer having a branching structure in its repeating units. The hyperbranched polymer has a specific structure having intentionally introduced branches, while a conventional linear polymer is generally in the form of a string. The polymer is in the size of nanometers and can have many functional groups on its surface. Because of these characteristics, the polymer is expected to have various applications. The hyperbranched polymer may be synthesized by polymerizing monomers by a living radical polymerization in the presence of a metal catalyst.

In the past, it was reported that a hyperbranched polystyrene could be obtained as a hyperbranched polymer, for example, by polymerizing 4-chlorostyrene in the presence of copper (I) chloride and 2,2′-bipyridine in benzene, chlorobenzene, or without a solvent (see, for example, Nonpatent Literature 2). In addition, there is a technology designing the core-shell hyperbranched polymer having the hyperbranched polymer as the core portion by a graft polymerization of the hyperbranched polymer chain at its terminal with a monomer (see, for example, Patent Document 9).
Patent Document 1: Japanese Patent Application Laid-Open Publication No. 2004-231858
Patent Document 2: Japanese Patent Application Laid-Open Publication No. 2004-359929
Patent Document 3: Japanese Patent Application Laid-Open Publication No. 2005-91428
Patent Document 4: International Publication Pamphlet No. WO 2005/061566
Patent Document 5: Japanese Patent Application Laid-Open Publication No. 2003-268057
Patent Document 6: Published Patent Application No. H07-504762
Patent Document 7: Japanese Patent Application Laid-Open Publication No. H05-019463
Patent Document 8: Published Patent Application No. 2000-514479
Patent Document 9: Japanese Patent Application Laid-Open Publication No. H6-266099
Nonpatent Literature 1: Franco Cerrina, Vac. Sci. Tech. B, 19, 2890 (2001)
Nonpatent Literature 2: Jean M. J. Frechet, J. Poly. Sci., 36, 955 (1998)
Nonpatent Literature 3: Toru Yamaguti, Jpn. J. Appl. Phys., 38, 7114 (1999)
Nonpatent Literature 4: Alexander R. Trimble, Proceedings of SPIE, 3999, 1198, (2000)

### DISCLOSURE OF INVENTION

### Problem to be Solved by the Invention

### Problem to be Solved by First Aspect of the Present Invention

However, conventional technologies as described above have a problem in that a large excess of water (about 10 times) relative to an organic solvent which dissolves substances obtained after the deprotection is added, thereby increasing the amount of waste effluent accompanying an increase in the scale of synthesis, and thus it is not suitable for practice at an industrial scale.

To solve the above problems in conventional technologies, objects of the present invention include providing a process for synthesizing a core-shell hyperbranched polymer, in which the core-shell hyperbranched polymer can be synthesized stably and in large quantities with aiming to reduce an amount of waste effluent discharged from the synthesis, the core-shell hyperbranched polymer, a resist composition, a semi-conductor integrated circuit, and a process for producing the semi-conductor integrated circuit.

### Problem to be Solved by Second Aspect of the Present Invention

Further, the conventional technology above has a problem in that the each method is costly and inappropriate for industrialization. If an absorbent such as alumina is used, the conventional technology of removing metal catalyst has a problem in that metal is inevitably mixed in the hyperbranched polymer due to elution of metal, for example, aluminum derived from absorbent.

To solve the above problem of the conventional technology, an object of the present invention is to provide a hyperbranched polymer synthesizing method capable of simple and stable mass synthesis of a hyperbranched polymer, a hyperbranched polymer, a resist composition, a semiconductor integrated circuit, and a semiconductor integrated circuit producing method.

### Problem to be Solved by Third Aspect of the Present Invention

Therefore, an object of the present invention is to provide a simple method of synthesizing a core-shell hyperbranched polymer containing an acid-degradable group and an acid group in a shell portion and having a reduced metal content.

### Problem to be Solved by Fourth Aspect of the Present Invention

The above conventional technology further has a problem that increase in molecular weight due to progress over time in polymerization of the hyper branch polymer cannot be prevented sufficiently.

To solve the above problem of the conventional technology, an object of the present invention is to provide a hyperbranched polymer synthesizing method capable of improving the long-term stability of the resolution performance of a hyperbranched polymer utilizable in a resist composition.

### Problem to be Solved by Fifth Aspect of the Present Invention

Further, the hyperbranched polymer easily forms gel depending on temperature at the time of distilling off solvent or drying after the distilling-off of solvent even in the absence of solvent due to a complicated branching structure unlike linear polymers, the conventional technology problematically requires cumbersome temperature control and is troublesome.

To solve the above problem of the conventional technology, an object of the present invention is to provide a hyperbranched polymer synthesizing method capable of stably acquiring the hyperbranched polymer having a desired molecular weight without considerably increasing a molecular weight due to progression of the cross-linking reaction between hyperbranched polymer molecules, a hyperbranched polymer, a resist composition, a semiconductor integrated circuit, and a semiconductor integrated circuit producing method.

### Means for Solving Problem

### Means for Solving the First Problem

To solve the problems and achieve objects as described above, according to the present invention, a core-shell hyperbranched polymer synthesizing method employing living radical polymerization of a monomer in the presence of a metal catalyst, includes forming a shell portion by introducing an acid-decomposable group to a core portion formed of a hyperbranched polymer synthesized by living radical polymerization; forming an acid group by partially decomposing the acid-decomposable group in the shell portion by the acid catalyst; precipitating a core-shell hyperbranched polymer contained in a first solution and having the acid group, by mixing the first solution with ultrapure water; removing the acid catalyst from a solution containing the core-shell hyperbranched polymer having the acid group, by washing a second solution containing the precipitated core-shell hyperbranched polymer dissolved into an organic solvent, the washing being with ultrapure water of an amount giving a prescribed ratio of the ultrapure water relative to the organic solvent in the second solution; and extracting, by a liquid-liquid extraction, the core-shell hyperbranched polymer in the organic solvent and having the acid group, from a mixed solution of the second solution and the ultrapure water of the amount giving a prescribed ratio of the ultrapure water relative to the organic solvent in the second solution, the core-shell polymer being extracted into the organic solvent.

According to the present invention, the amount of the ultrapure water relative to the organic solvent dissolving the core-shell hyperbranched polymer resulting after the acid group is formed can be controlled, and thus, accompanying increases in the scale of the synthesis, increases in the amount of the water layer (waste effluent) containing the acid catalyst as an impurity dissolved therein by the liquid-liquid extraction, can be suppressed without causing difficulty in dissolving impurities into the water layer by the liquid-liquid extraction at the step of removing the acid catalyst. Accordingly, the core-shell hyperbranched polymer can be synthesized stably and in large quantities with an aim to reduce the waste effluent accompanying an increase in the scale of the synthesis.

Further, the step of removing the acid catalyst by the liquid-liquid extraction in the synthesis of the core-shell hyperbranched polymer of the present invention includes mixing the second solution with the ultrapure water at a prescribed volume ratio of the ultrapure water to the organic solvent (hereinafter, “ultrapure water/organic solvent”), namely, ultrapure water/organic solvent=0.1/1 to 1/0.1 in the volume ratio. Here, the term “volume ratio” in the present invention means a volume ratio of each of the above-mentioned liquids at 25° C. unless otherwise specifically mentioned.

According to the present invention, when the liquid-liquid extraction for removal of the acid catalyst is carried out by controlling the volume ratio of the ultrapure water to the organic solvent from 0.1/1 to 1/0.1, an increase in the amount of the water layer (waste effluent), containing the impurities dissolved therein by the liquid-liquid extraction, accompanying an increase in the scale of the synthesis may be suppressed without causing a difficulty in the dissolution of impurities into the water layer by the liquid-liquid extraction at the step of removing the acid catalyst. Accordingly, the core-shell hyperbranched polymer can be synthesized stably and in large quantities with an aim to reduce increases in the waste effluent accompanying an increase in the scale of the synthesis.

Further, the step of removing the acid catalyst by the liquid-liquid extraction in the synthesis of the core-shell hyperbranched polymer of the present invention includes mixing the second solution with the ultrapure water in a prescribed volume ratio of the ultrapure water to the organic solvent (hereinafter, “ultrapure water/organic solvent”), namely, ultrapure water/organic solvent=0.5/1 to 1/0.5 in the volume ratio.

According to the present invention, when the liquid-liquid extraction for removal of the acid catalyst is carried out by controlling the volume ratio of the ultrapure water to the organic solvent in the range of 0.5/1 to 1/0.5, an increase in the amount of the water layer (waste effluent), containing the impurities dissolved therein by the liquid-liquid extraction and accompanying an increase in the scale of the synthesis can be suppressed without causing difficulty in the dissolution of the impurities into the water layer at the liquid-liquid extraction. Accordingly, the core-shell hyperbranched polymer can be synthesized stably and in large quantities with an aim to ensure reduction of the waste effluent accompanying an increase in the scale of synthesis.

Further, the organic solvent in the method of synthesizing the core-shell hyperbranched polymer according to the present invention has properties of dissolving the core-shell hyperbranched polymer precipitated at the precipitation step and separating from water.

According to the present invention, the organic solvent, from which the core-shell hyperbranched polymer after formation of the acid group is extracted, can be easily separated from the water layer, and thus the core-shell hyperbranched polymer can be synthesized stably and in large quantities with an aim to ensure reduction of the waste effluent accompanying an increase in the scale of the synthesis.

In addition, the resist composition of the present invention contains the core-shell hyperbranched polymer as described above.

A semiconductor integrated circuit according to the present invention has a pattern formed with the resist composition through the electron-beam, deep-ultraviolet (DUV), or extreme-ultraviolet (EUV) lithography.

According to the present invention, a highly-integrated, high-capacity semiconductor integrated circuit having stable performance can be acquired.

A semiconductor integrated circuit manufacturing method according to the present invention includes a step of forming a pattern with the use of the resist composition through the electron-beam, deep-ultraviolet (DUV), or extreme-ultraviolet (EUV) lithography.

According to the present invention, a highly-integrated, high-capacity semiconductor integrated circuit having stable performance can be manufactured.

### Means for Solving the Second Problem

To solve the above problem and achieve an object, a hyperbranched polymer synthesizing method according to the present invention is a hyperbranched polymer synthesizing method of synthesizing a hyperbranched polymer by polymerizing a monomer capable of living radical polymerization in the presence of a metal catalyst, including a precipitation generating step of generating a precipitate by mixing two or more mixed solvents each having a solubility parameter of 10.5 or more in a reaction solution containing a hyperbranched polymer synthesized by the living radical polymerization.

According to the present invention, since impurities such as a metal catalyst, monomers, and by-product oligomers can be removed easily without using absorbent, the hyperbranched polymer can be synthesized easily and stably in large amounts.

At the precipitation generating step of the hyperbranched polymer synthesizing method according to the present invention, the precipitate is generated by mixing 0.2 to 10 parts by volume of a mixed solvent consisting of two or more solvents and having a solubility parameter of 10.5 or more (hereinafter, solvent A in some cases) based on the reaction solution.

According to the present invention, since impurities such as a metal catalyst, monomers, and by-product oligomers can be removed easily without using absorbent, the hyperbranched polymer may be further easily and stably synthesized in large amounts.

In the present invention, the precipitate generated by mixing the solvent A into the reaction solvent containing the hyperbranched polymer synthesized by the living radical polymerization is dissolved by adding a solvent having a solubility parameter of 7 to 10.5 (hereinafter, a solvent B in some cases), and a precipitate is generated again by further adding a solvent having a solubility parameter of 10.5 or more (hereinafter, a solvent C in some cases). The step of dissolving the precipitate with the solvent B and causing the reprecipitation with the solvent C may be repeated multiple times.

In the hyperbranched polymer synthesizing method according to the present invention, the hyperbranched polymer synthesizing method includes a step of using the precipitate generated at the precipitation generating step as a core portion to generate a core-shell hyperbranched polymer including a shell portion formed by introducing an acid-decomposable group into the core portion, and a step of forming an acid group by using an acid catalyst to decompose a portion of the acid-decomposable group constituting the shell portion of the core-shell hyperbranched polymer generated at the above step.

A hyperbranched polymer according to the present invention is synthesized according to the hyperbranched polymer synthesizing method.

According to the present invention, since impurities such as a metal catalyst, monomers, and by-product oligomers can be removed easily without using absorbent, a hyperbranched polymer having stable quality can be acquired in large amounts with impurities such as a metal catalyst, monomers, and by-product oligomers removed.

A resist composition according to the present invention includes the hyperbranched polymer.

According to the present invention, occurrence of adverse effects such as considerable changes in reactivity and insolubilization after exposure can be reduced.

A semiconductor integrated circuit according to the present invention has a pattern formed with the resist composition.

According to the present invention, a semiconductor integrated circuit having an ultrafine circuit pattern formed can be acquired.

A semiconductor integrated circuit manufacturing method according to the present invention includes a step of forming an ultrafine circuit pattern with the use of the resist composition.

According to the present invention, a semiconductor integrated circuit having an ultrafine circuit pattern formed can be produced.

### Means for Solving the Third Problem

To solve the above problem, as a result of keen examinations, the present inventors have found that removing metals in the middle of a synthesizing step can considerably reduce the metals and keep variations in the rate of the acid group and the acid-decomposable group in the shell portion at a lower level in the synthesis of the hyperbranched polymer containing a carboxylic acid and a carboxylic acid ester at terminals.

The present invention provides a hyperbranched polymer synthesizing method of a core-shell hyperbranched polymer having an acid group and an acid-decomposable group in a shell portion, including:

(A) a step of synthesizing a core portion by polymerizing a monomer capable of living radical polymerization in the presence of a metal catalyst to form the shell portion by introducing an acid-decomposable group into the acquired core portion;

(B) a step of washing a hyperbranched polymer having the acid-decomposable group in the shell portion with the use of pure water to acquire the hyperbranched polymer having a metal content not greater than 100 ppb; and

(C) a step of subsequently decomposing a portion of the acid-decomposable group constituting the shell portion with an acid catalyst to form the acid group.

The present invention provides a hyperbranched polymer synthesizing method for a core-shell hyperbranched polymer having an acid group and an acid-decomposable group in a shell portion, the method including:

(A) a step of synthesizing a core portion by polymerizing a monomer capable of living radical polymerization in the presence of a metal catalyst to form the shell portion by introducing an acid-decomposable group into the acquired core portion;

(B) a step of washing a hyperbranched polymer having the acid-decomposable group in the shell portion with the use of pure water and an aqueous solution of an organic compound having chelating ability and/or an aqueous solution of an inorganic solution to acquire the hyperbranched polymer having a metal content not greater than 100 ppb; and

(C) a step of subsequently decomposing a portion of the acid-decomposable group constituting the shell portion with an acid catalyst to form the acid group.

### Means for Solving the Fourth Problem

To solve the above problem and achieve an object, a hyperbranched polymer synthesizing method according to the present invention is a hyperbranched polymer synthesizing method including a polymerizing method of causing living radical polymerization of a monomer in the presence of a metal catalyst to polymerize a polymer; a refining step of using a reprecipitating method for a reaction solution containing the polymer polymerized at the polymerizing step to collect the polymer; and a filtrating step of filtrating the refined polymer with the use of a filter having a pore diameter of 0.1 μm or less.

The present invention provides a hyperbranched polymer synthesizing method capable of improving the temporal stability of the resolution performance of the hyperbranched polymer available for the resist composition by using a polar solvent to prevent the rapid increase in the molecular weight and acquire a hyperbranched polymer having a desired molecular weight and branching degree and to prevent the increase in the molecular weight due to temporal progress in the polymerization of the hyper branch polymer.

The hyperbranched polymer synthesizing method according to the present invention can include a shell portion generating step of using the polymer polymerized at the polymerizing step as a core portion to generate a shell portion by introducing an acid-decomposable group into the core portion and the polymer may be collected by a refining step using the reprecipitating method.

The present invention can provide a hyperbranched polymer synthesizing method capable of improving the temporal stability of the resolution performance of the hyperbranched polymer available for the resist composition by preventing the increase in the molecular weight due to temporal progress in the polymerization of the hyper branch polymer including the shell portion with the acid-decomposable group introduced.

A hyperbranched polymer according to the present invention is produced according to the hyperbranched polymer synthesizing method.

According to the present invention, the hyperbranched polymer having a desired molecular weight and branching degree can be acquired with the increase in the molecular weight due to temporal progress in the polymerization being prevented.

A resist composition according to the present invention contains the hyperbranched polymer.

According to the present invention, a resist composition containing the hyperbranched polymer having a desired molecular weight and branching degree can be acquired with the increase in the molecular weight due to temporal progress of the polymerization being prevented.

A semiconductor integrated circuit according to the present invention has a pattern formed with the resist composition.

According to the present invention, a fine semiconductor integrated circuit having stable performance and supporting electron beams, deep ultraviolet (DUV), and extreme ultraviolet (EUV) can be manufactured.

A semiconductor integrated circuit manufacturing method according to the present invention includes a step of forming a pattern with the use of the resist composition.

According to the present invention, a fine semiconductor integrated circuit having stable performance and supporting electron beams, deep ultraviolet (DUV), and extreme ultraviolet (EUV) can be manufactured.

### Means for Solving the Fifth Problem

To solve the above problem and achieve an object, a hyperbranched polymer synthesizing method according to the present invention is a hyperbranched polymer synthesizing method of synthesizing a hyperbranched polymer through living radical polymerization of a monomer in the presence of a metal catalyst, including a removing step of removing a metal catalyst in a reaction system where the hyperbranched polymer synthesized by the living radical polymerization exists after the living radical polymerization; and a drying step of drying a solvent existing in the reaction system after the removing step at 10 to 70 degrees C. to remove the solvent.

According to the present invention, since the considerable increase in the molecular weight due to progress in a bridging reaction between hyperbranched polymer molecules can be prevented by drying the solvent in the reaction system to prevent the adhesion and entwining of the hyperbranched polymer molecules, a hyperbranched polymer having a desired molecular weight can be acquired stably.

The hyperbranched polymer synthesizing method according to the present invention includes a catalyst removing step of removing the metal catalyst in the reaction system after the living radical polymerization and, at the drying step, the solvent is removed by drying the solvent existing in the reaction system after the metal catalyst is removed at the catalyst removing step.

According to the present invention, since the progress in the bridging reaction between hyperbranched polymer molecules can be prevented more effectively by drying the solvent in the reaction system after removing the metal catalyst activating the progress in the bridging reaction between hyperbranched polymer molecules, a hyperbranched polymer having a desired molecular weight can be acquired stably.

According to the present invention, since the progress in the bridging reaction between hyperbranched polymer molecules can be prevented in the middle of the drying by managing a temperature of the reaction system during the drying, the hyperbranched polymer having the desired molecular weight can be acquired stably.

At the drying step of the hyperbranched polymer synthesizing method according to the present invention, a pressure of the reaction system is reduced to a pressure lower than the atmosphere pressure to achieve a vacuum state.

According to the present invention, since the solvent in the reaction system can be dried easily, a hyperbranched polymer having a desired molecular weight can be acquired stably and easily.

At the drying step of the hyperbranched polymer synthesizing method according to the present invention, the solvent in the reaction system is dried for 1 to 20 hours.

According to the present invention, since the solvent in the reaction system can be dried with certainty, a hyperbranched polymer having a desired molecular weight can be acquired stably and with certainty.

A hyperbranched polymer according to the present invention is manufactured according to the hyperbranched polymer synthesizing method.

According to the present invention, the hyperbranched polymer can be acquired stably in large amounts without considerably increasing an amount of waste liquid associated with the scale-up of the synthesis.

A resist composition according to the present invention contains the hyperbranched polymer.

According to the present invention, the resist composition containing the hyperbranched polymer having a desired molecular weight and branching degree can be acquired stably.

A semiconductor integrated circuit according to the present invention has a pattern formed with the resist composition through the electron-beam, deep-ultraviolet (DUV), or extreme-ultraviolet (EUV) lithography.

According to the present invention, a highly-integrated, high-capacity semiconductor integrated circuit having stable performance can be acquired.

A semiconductor integrated circuit manufacturing method according to the present invention includes a step of forming a pattern with the use of the resist composition through the electron-beam, deep-ultraviolet (DUV), or extreme-ultraviolet (EUV) lithography.

According to the present invention, a highly-integrated, high-capacity semiconductor integrated circuit having stable performance can be manufactured.

### BRIEF DESCRIPTION OF DRAWINGS

FIG. 1 is a flowchart depicting steps for synthesizing a hyperbranched polymer.

### BEST MODE(S) FOR CARRYING OUT THE INVENTION

The best modes for carrying out the present invention will be explained in Chapters 1 to 5 hereinafter.

### <Chapter 1>

Exemplary embodiments of a method of synthesizing a core-shell hyperbranched polymer in the embodiments of the present invention according to Chapter 1 will be explained in detail with reference to the attached drawing.

### (Substances Used in Synthesis of Core-Shell Hyperbranched Polymer)

Substances used in the synthesis of a core-shell hyperbranched polymer in the embodiment will be explained. In the synthesis of the core-shell hyperbranched polymer, a monomer, a metal catalyst, and a solvent are used. The hyperbranched core polymer corresponding to the core portion of the core-shell hyperbranched polymer is synthesized by the atom transfer radical polymerization (ATRP) method, one kind of living radical polymerization method. Examples of the monomer used for synthesis of the hyperbranched core polymer include at least a monomer represented by the following formula (I).

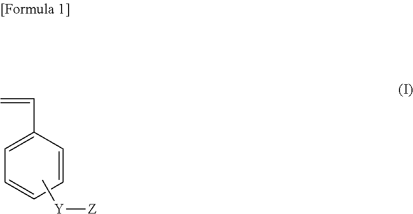

In formula (I), Y represents a linear, a branched, or a cyclic alkylene group having 1 to 10 carbon atoms. The number of carbons in Y is preferably 1 to 8. More preferable number of carbons in Y is 1 to 6. Y in formula (I) may contain a hydroxyl group or a carboxyl group.

Specific examples of Y in formula (I) include a methylene group, an ethylene group, a propylene group, an isopropylene group, a butylene group, an isobutylene group, an amylene group, a hexylene group, and a cyclohexylene group. Furthermore, Y in formula (I) includes a group in which the above-mentioned groups are bonded with each other directly or via —O—, —CO—, and —COO—.

Y in formula (I) is preferably an alkylene group having 1 to 8 carbon atoms among the groups mentioned above. Y in formula (I) is more preferably a linear alkylene group having 1 to 8 carbon atoms among the alkylene groups having 1 to 8 carbon atoms. examples of the alkylene group more preferable include a methylene group, an ethylene group, an —OCH₂— group, and an —OCH₂CH₂— group. Z in formula (I) represents a halogen atom (a halogen group) such as a fluorine atom, a chlorine atom, a bromine atom, and an iodine atom. Specific examples of preferable Z in formula (I) include a chlorine atom and a bromine atom among the halogen atoms mentioned above.

Specific examples of the monomer represented by formula (I) include chloromethyl styrene, bromomethyl styrene, p-(1-chloroethyl)styrene, bromo(4-vinylphenyl)phenylmethane, 1-bromo-1-(4-vinylphenyl)propane-2-one, and 3-bromo-3-(4-vinylphenyl)propanol. More specific examples of the preferable monomer represented by formula (I) among the monomers used for synthesis of the hyperbranched polymer include chloromethyl styrene, bromomethyl styrene, and p-(1-chloroethyl)styrene.

Monomers constituting the core portion of the hyperbranched polymer of the present invention may include, in addition to the monomers represented by formula (I), other monomers. There is no restriction with regard to other monomers provided the monomer can be subject to radical polymerization, and may be chosen appropriately according to purpose. Examples of other monomers capable of radical polymerization include compounds having a radical polymerizable unsaturated bond such as (meth)acrylic acid, (meth)acrylate esters, vinylbenzoic acid, vinylbenzoate esters, styrenes, an allyl compound, vinyl ethers, vinyl esters, and the like.

Specific examples of (meth)acrylate esters cited as other monomers capable of radical polymerization include tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1 ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1 ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate.

Specific examples of vinyl benzoate esters cited as other monomers capable of radical polymerization include vinyl benzoate, tert-butyl vinyl benzoate, 2-methylbutyl vinyl benzoate, 2-methylpentyl vinyl benzoate, 2-ethylbutyl vinyl benzoate, 3-methylpentyl vinyl benzoate, 2-methylhexyl vinyl benzoate, 3-methylhexyl vinyl benzoate, triethylcarbyl vinyl benzoate, 1-methyl-1-cyclopentyl vinyl benzoate, 1-ethyl-1-cyclopentyl vinyl benzoate, 1-methyl-1-cyclohexyl vinyl benzoate, 1-ethyl-1-cyclohexyl vinyl benzoate, 1-methylnorbornyl vinyl benzoate, 1-ethylnorbornyl vinyl benzoate, 2-methyl-2-adamantyl vinyl benzoate, 2-ethyl-2-adamantyl vinyl benzoate, 3-hydroxy-1-adamantyl vinyl benzoate, tetrahydrofuranyl vinyl benzoate, tetrahydropyranyl vinyl benzoate, 1-methoxyethyl vinyl benzoate, 1-ethoxyethyl vinyl benzoate, 1-n-propoxyethyl vinyl benzoate, 1-isopropoxyethyl vinyl benzoate, n-butoxyethyl vinyl benzoate, 1-isobutoxyethyl vinyl benzoate, 1-sec-butoxyethyl vinyl benzoate, 1-tert-butoxyethyl vinyl benzoate, 1-tert-amyloxyethyl vinyl benzoate, 1-ethoxy-n-propyl vinyl benzoate, 1-cyclohexyloxyethyl vinyl benzoate, methoxypropyl vinyl benzoate, ethoxypropyl vinyl benzoate, 1-methoxy-1-methyl-ethyl vinyl benzoate, 1-ethoxy-1-methyl-ethyl vinyl benzoate, trimethylsilyl vinyl benzoate, triethylsilyl vinyl benzoate, dimethyl-tert-butylsilyl vinyl benzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinyl benzoate, adamantyl vinyl benzoate, 2-(2-methyl)adamantyl vinyl benzoate, chloroethyl vinyl benzoate, 2-hydroxyethyl vinyl benzoate, 2,2-dimethylhydroxypropyl vinyl benzoate, 5-hydroxybenzyl vinyl benzoate, trimethylolpropane vinyl benzoate, glycidyl vinyl benzoate, benzyl vinyl benzoate, phenyl vinyl benzoate, and naphthyl vinyl benzoate.

Specific examples of styrenes cited as other monomers capable of radical polymerization include styrene, benzyl styrene, trifluoromethyl styrene, acetoxy styrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethyl styrene, 4-fluoro-3-trifluoromethyl styrene, and vinyl naphthalene.

Specific examples of allyl compounds cited as other monomers capable of radical polymerization include allyl acetate, allyl caproate, allyl caprylate, allyl laurate, allyl palmitate, allyl stearate, allyl benzoate, allyl acetoacetate, allyl lactate, and allyl oxyethanol.

Specific examples of vinyl ethers cited as other monomers capable of radical polymerization include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethyleneglycol vinyl ether, dimethylaminoethyl vinyl ether, diethylaminoethyl vinyl ether, butylaminoethyl vinyl ether, benzyl vinyl ether, tetrahydrofurfuryl vinyl ether, vinyl phenyl ether, vinyl tolyl ether, vinyl chlorophenyl ether, vinyl 2,4-dichlorophenyl ether, vinyl naphthyl ether, and vinyl anthranyl ether.

Specific examples of vinyl esters cited as other monomers capable of radical polymerization include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl buthoxyacetate, vinyl phenylacetate, vinyl acetoacetate, vinyl lactate, vinyl β-phenylbutyrate, and vinyl cyclohexylcarboxylate.

Specific examples of a preferable monomer constituting the hyperbranched core polymer include (meth)acrylic acid, tert-butyl(meth)acrylate, 4-vinyl benzoic acid, tert-butyl 4-vinylbenzoate, styrene, benzyl styrene, chlorostyrene, and vinyl naphthalene.

The amount of the monomer constituting the hyperbranched core polymer relative to total monomers used in the synthesis of the hyperbranched polymer is preferably 10 to 90% by mol, more preferably 10 to 80% by mol, and yet more preferably 10 to 60% by mol.

By controlling the amount of monomer constituting the hyperbranched core polymer at the above ranges, for example, when the core-shell hyperbranched polymer having the hyperbranched core polymer as the core portion is used in a resist composition, a hyperbranched polymer with a suitable hydrophobicity to a developing solution can be provided. Thus, for example, when a semi-conductor integrated circuit, a flat panel display, a printed wiring board, are produced by a microfabrication process using a resist composition containing the hyperbranched polymer, dissolution of an unexposed part may be suppressed, and thus, is preferable.

The amount of the monomer represented by formula (I) relative to total monomers used in the synthesis of the hyperbranched core polymer is preferably 5 to 100% by mol, more preferably 20 to 100% by mol, and yet more preferably 50 to 100% by mol. When the amount of the monomer represented by formula (I) in the hyperbranched core polymer is at the above ranges, the hyperbranched core polymer takes a spherical morphology, which is advantageous in suppressing the intermolecular entanglement, and thus, is preferable.

When the hyperbranched core polymer is a polymer of a monomer represented by formula (I) and other monomers, the amount of the monomer represented by formula (I) relative to total monomers constituting the hyperbranched core polymer is preferably 10 to 99% by mol, more preferably 20 to 99% by mol, and yet more preferably 30 to 99% by mol. When the amount of the monomer represented by formula (I) in the hyperbranched core polymer is at the above ranges, the hyperbranched core polymer takes a spherical morphology, thereby advantageously suppressing the intermolecular entanglement and improving functions such as the substrate adhesiveness and the glass transition temperature, and thus, is preferable. The amount of the monomer represented by formula (I) and the other monomers in the core portion may be controlled by the charging ratio at the time of polymerization according to the purpose.

In the synthesis of the hyperbranched core polymer, a metal catalyst is used. As the metal catalyst, for example, a metal catalyst composed of a ligand and a transition metal compound of, for example, copper, iron, ruthenium, and chromium. examples of the transition metal compound include copper (I) chloride, copper (I) bromide, copper (I) iodide, copper (I) cyanide, copper (I) oxide, copper (I) perchlorate, iron (I) chloride, iron (I) bromide, and iron (I) iodide.

Examples of the ligand include pyridines, bipyridines, polyamines, and phosphines, unsubstituted or substituted with an alkyl group, an aryl group, an amino group, a halogen group, an ester group, and the like. examples of the preferable metal catalyst include a copper (I) bipyridyl complex and a copper (I) pentamethyl diethylene triamine complex, which are composed of copper chloride and respective ligands, and an iron (II) triphenyl phosphine complex and an iron (II) tributyl amine complex, which are composed of iron chloride and respective ligands, or others.

The amount of the metal catalyst relative to that of total monomers used for synthesis of the hyperbranched core polymer is preferably 0.01 to 70% by mol, and more preferably 0.1 to 60% by mol. When the catalyst is used at this amount, reactivity can be improved, thereby enabling synthesis of a hyperbranched core polymer having a suitable degree of branching.

When the amount of the metal catalyst used is below the range, reactivity may be markedly reduced, thereby leading to a risk of the polymerization becoming sluggish. On the other hand, when the amount of the metal catalyst used is above the range, the polymerization reaction becomes excessively active and the coupling reaction among radicals at growing terminals tends to occur easily, thereby making control of the polymerization difficult. Further, when the amount of the metal catalyst used is above the range, the coupling reaction among radicals induces gelation of the reaction system.

The metal catalyst may be made into a coordination compound by mixing a transition metal compound and a ligand in an apparatus. The metal catalyst composed of a transition metal compound and a ligand may be added to the apparatus in the form of an active coordination compound. Making a coordination compound by mixing a transition metal compound and a ligand in the apparatus is preferable because of operations in the synthesis of the hyperbranched polymer can be simplified.

A method of adding the metal catalyst is not particularly restricted and the metal catalyst may be added, for example, all at once prior to the polymerization of the hyperbranched core polymer. Further, additional metal catalyst may be added after initiation of the polymerization depending on the level of inactivation of the catalyst. For example, when distribution of a coordination compound forming the metal catalyst in the reaction system is not uniform, the transition metal compound may be added to the apparatus in advance, followed by addition of only a ligand afterwards.

The polymerization reaction for synthesis of the hyperbranched core polymer in the presence of the metal catalyst is carried out preferably in a solvent, though the reaction can occur in the absence of a solvent. The solvent used in the polymerization of the hyperbranched core polymer in the presence of the metal catalyst is not particularly restricted. examples of the solvent include a hydrocarbon solvent such as benzene and toluene; an ether solvent such as diethyl ether, tetrahydrofuran, diphenyl ether, anisole, and dimethoxy benzene; a halogenated hydrocarbon solvent such as methylene chloride, chloroform, and chlorobenzene; a ketone solvent such as acetone, methyl ethyl ketone, and methyl isobutyl ketone; an alcohol solvent such as methanol, ethanol, propanol, and isopropanol; a nitrile solvent such as acetonitrile, propionitrile, and benzonitrile; an ester solvent such as ethyl acetate and butyl acetate; a carbonate solvent such as ethylene carbonate and propylene carbonate; and an amide solvent such as N,N-dimethylformamide and N,N-dimethylacetamide. These may be used independently or in a combination of two or more kinds.

In the synthesis of the hyperbranched core polymer (core polymerization), it is preferable that the core polymerization be carried out in the presence of nitrogen, an inert gas, or under the flow thereof, and in the absence of oxygen to prevent oxygen from affecting the radicals. The core polymerization may be carried out in a batch process or a continuous process. In the core polymerization, it is preferable that all substances to be used, including metal catalysts, solvents, and monomers, be fully deoxygenated (degassed) by evacuation or by blowing-in an inert gas such as nitrogen and argon to prevent oxidative deactivation of the metal catalyst from occurring.

The core polymerization may be carried out, for example, by adding a monomer dropwise into a reaction vessel. When the amount of the metal catalyst is small, a high degree of branching in a synthesized macro initiator can be maintained by controlling the speed of the dropwise addition of the monomer. In other words, the amount of the metal catalyst can be reduced while maintaining a high degree of branching in the synthesized hyperbranched core polymer (macro initiator) by controlling the rate of the dropwise addition of the monomer. To maintain a high degree of branching in the hyperbranched core polymer, the concentration of the monomer added dropwise is preferably 1 to 50% by mass and more preferably 2 to 20% by mass relative to the total reaction amount.

In the core polymerization, an additive is used. Among compounds represented by formula (1-1) and compounds represented by formula (1-2), at least one type may be added.

R₁-A Equation (1-1)

R₂—B—R₃ Equation (1-2)

R₁ in formula (1-1) represents hydrogen, an alkyl group having 1 to 10 carbon atoms, an aryl group having 6 to 10 carbon atoms, or an aralkyl group having 7 to 10 carbon atoms. More specifically, R₁ in the formula (1-1) represents a hydrogen, an alkyl group having 1 to 10 carbon atoms, an aryl group having 6 to 10 carbon atoms, or an aralkyl group having 7 to 10 carbon atoms. “A” in formula (1-1) represents a cyano group, a hydroxy group, and a nitro group. Examples of the compound represented by formula (1-1) include nitriles, alcohols, and a nitro compound.

Specific examples of nitriles included in compounds represented by formula (1-1) include acetonitrile, propionitrile, butyronitrile, and benzonitrile. Specific examples of alcohols included in compounds represented by formula (1-1) include methanol, ethanol, 1-propanol, 2-propanol, 1-butanol, cyclohexyl alcohol, and benzyl alcohol. Specific examples of nitro compounds included in compounds represented by formula (1-1) include nitromethane, nitroethane, nitropropane, and nitrobenzene. The compound represented by formula (1-1) is not restricted to the compounds mentioned above.

R₂ and R₃ in formula (1-2) represent hydrogen, an alkyl group having 1 to 10 carbon atoms, an aryl group having 6 to 10 carbon atoms, an aralkyl group having 7 to 10 carbon atoms, or a dialkyl amino group having 1 to 10 carbon atoms; B represents a carbonyl group and a sulfonyl group. More specifically, R₂ and R₃ in formula (1-2) represent hydrogen, an alkyl group having 1 to 10 carbon atoms, an aryl group having 6 to 10 carbon atoms, an aralkyl group having 7 to 10 carbon atoms, or a dialkyl amine group having 2 to 10 carbon atoms. R₂ and R₃ in formula (1-2) may be the same or different.

Examples of the compound represented by formula (1-2) include ketones, sulfoxides, and an alkyl formamide compound. Specific examples of the ketones include acetone, 2-butanone, 2-pentanone, 3-pentanone, 2-hexanone, cyclohexanone, 2-methyl cyclohexanone, acetophenone, and 2-methyl acetophenone.

Specific examples of the sulfoxides included in the compounds represented by formula (1-2) include dimethyl sulfoxide and diethyl sulfoxide. Specific examples of the alkyl formamide compound included in the compounds represented by formula (1-2) include N,N-dimethyl formamide, N,N-diethylformamide, and N,N-dibutyl formamide. The compounds represented by formula (1-2) are not restricted to the above-mentioned compounds. Among the compounds represented by formula (1-1) or formula (1-2), nitriles, nitro compounds, ketones, sulfoxides, and alkyl formamide compounds are preferable, while acetonitrile, propionitrile, benzonitrile, nitroethane, nitropropane, dimethyl sulfoxide, acetone, and N,N-dimethyl formamide are more preferable.

In the synthesis of the hyperbranched polymer, compounds represented by formula (1-1) or formula (1-2) may be used independently or in combination of two or more.

In the synthesis of the hyperbranched polymer, compounds represented by formula (1-1) or formula (1-2) may be used independently or in combination of two or more as a solvent.

The amount of the compounds represented by formula (1-1) or (1-2) to be added in the synthesis of the hyperbranched polymer is preferably 2 times to 10000 times by mol ratio relative to the amount of transition metal in the metal catalyst. The amount of the compound represented by formula (1-1) or the amount of the compound represented by (1-2) to be added relative to the amount of a transition metal in the metal catalyst is more preferably 3 times to 7000 times by mol ratio, and yet more preferably 4 times to 5000 times by mol ratio relative to the amount of transition metal in the metal catalyst.

When the added amount of the compound represented by formula (1-1) or of the compound represented by formula (1-2) is too small, the rapid increase in molecular weight may not be controlled sufficiently. On the other hand, when the added amount of the compound represented by formula (1-1) or of the compound represented by formula (1-2) is too large, the reaction rate is slowed, leading to the formation of a large amount of oligomers.

The polymerization time for the core polymerization is preferably 0.1 to 10 hours depending on the molecular weight of the polymer. Reaction temperature in the core polymerization is preferably 0 to 200° C. More preferable reaction temperature in the core polymerization is 50 to 150° C. When the polymerization is carried out at a temperature above the boiling point of the solvent used, for example, the pressure may be increased in an autoclave.

In the core polymerization, it is preferable for the reaction system to be distributed uniformly. The reaction system is distributed uniformly, for example, by agitating the reaction system. As a specific example of an agitation condition for core polymerization, preferably the power necessary for agitation per unit volume is set as 0.01 kW/m3 or more. In the core polymerization, additional catalyst or a reducing agent to regenerate the catalyst may be added according to the progress of the polymerization and degree of catalyst inactivation.

In the core polymerization, the polymerization reaction is stopped at the point when the set molecular weight is attained. A method of stopping the core polymerization is not particularly limited, and a method such as inactivating the catalyst, for example, by cooling or by adding an oxidizing agent, a chelating agent, etc. may be used.

The core-shell hyperbranched polymer according to an embodiment has a shell portion which constitutes the terminal of the hyperbranched core polymer molecule synthesized as described above. The shell portion of the hyperbranched polymer has at least a repeating unit represented by formula (II) or a repeating unit represented by formula (III).

The repeating unit represented by formula (II) and the repeating unit represented by formula (III) contains an acid-decomposable group which is decomposed by an organic acid such as acetic acid, maleic acid, and benzoic acid, and an inorganic acid such as hydrochloric acid, sulfuric acid, and nitric acid, or preferably by a photo-inductive acid-generating material which generates an acid by optical energy. An acid-decomposable group giving a hydrophilic group by decomposition is preferable.

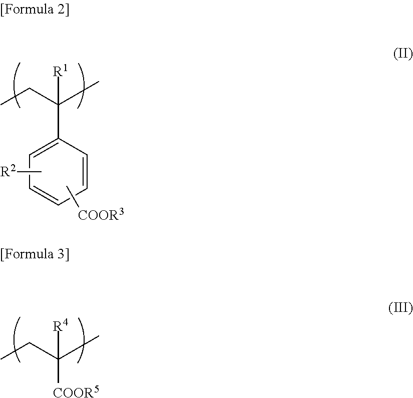

R¹ in formula (II) and R⁴ in formula (III) represent hydrogen or an alkyl group having 1 to 3 carbon atoms, among which, R¹ in formula (II) and R⁴ in formula (III) are preferably hydrogen and a methyl group. Hydrogen is more preferable as R¹ in formula (II) and R⁴ in formula (III).

R² in formula (II) represents hydrogen, an alkyl group, or an aryl group. The alkyl group in R² in formula (II) is preferably, for example, an alkyl group having 1 to 30 carbon atoms, more preferably an alkyl group having 1 to 20 carbon atoms, and yet more preferably an alkyl group having 1 to 10 carbon atoms. The alkyl group has a linear, a branched, or a cyclic structure. Specific examples of the alkyl group of R² in formula (II) include a methyl group, an ethyl group, a propyl group, an isopropyl group, a butyl group, an isobutyl group, a tert-butyl group, and a cyclohexyl group.

The aryl group of R² in formula (II) preferably has 6 to 30 carbon atoms, more preferably 6 to 20, and yet more preferably 6 to 10. Specific examples of the aryl group of R² in formula (II) include a phenyl group, a 4-methyl phenyl group, and a naphthyl group, among which, includes hydrogen, methyl groups, ethyl groups, phenyl groups, and the like. As one of the most preferable group of R² in formula (II), a hydrogen atom may be mentioned.

R³ in formula (II) and R⁵ in formula (III) represent hydrogen, an alkyl group, a trialkyl silyl group, an oxoalkyl group, or a group represented by the following formula (i). It is preferable that the alkyl group of R³ in formula (II) and R⁵ in formula (III) be an alkyl group having 1 to 40 carbon atoms. More preferably the number of carbons of the alkyl group of R³ in formula (II) and R⁵ in formula (III) is 1 to 30.

Yet more preferably the number of carbons of the alkyl group in R³ in formula (II) and R⁵ in formula (III) is 1 to 20. The alkyl group in R³ in formula (II) and R⁵ in formula (III) may be linear, branched, or cyclic. R³ in formula (II) and R⁵ in formula (III) are more preferably a branched alkyl group having 1 to 20 carbon atoms.

Preferably the number of carbons of each alkyl group in R³ in formula (II) and R⁵ in formula (III) is 1 to 6, and more preferably 1 to 4. Preferably the number of carbons of the alkyl group of the oxoalkyl group in R³ in formula (II) and R⁵ in formula (III) is 4 to 20, and more preferably 4 to 10.

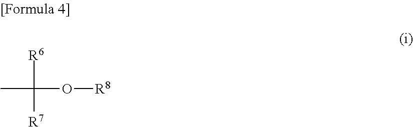

R⁶ in formula (i) represents hydrogen or an alkyl group. The alkyl group of R⁶ in formula (i) is linear, branched, or cyclic. It is preferable that the alkyl group of R⁶ in formula (i) be an alkyl group having 1 to 10 carbon atoms. More preferably the number of carbons of the alkyl group of R⁶ in formula (i) is 1 to 8, and yet more preferably the number is 1 to 6.

R⁷ and R⁸ in formula (i) represent hydrogen or an alkyl group. The hydrogen atom and the alkyl group in R⁷ and R⁸ in formula (i) may be independent of each other or form a ring. The alkyl group in R⁷ and R⁸ in formula (i) has a linear, branched, or cyclic structure. It is preferable that the alkyl group in R⁷ and R⁸ in formula (i) be an alkyl group having 1 to 10 carbon atoms. More preferably the number of carbons of the alkyl group in R⁷ and R⁸ in formula (i) is 1 to 8, and yet more preferably the number is 1 to 6. R⁷ and R⁸ in formula (i) are preferably a branched alkyl group having 1 to 20 carbon atoms.

Examples of the group represented by formula (i) include a linear or a branched acetal group such as a 1-methoxyethyl group, a 1-ethoxyethyl group, a 1-n-propoxyethyl group, a 1-isopropoxyethyl group, a 1-n-butoxyethyl group, a 1-isobutoxyethyl group, a 1-sec-butoxyethyl group, a 1-tert-butoxyethyl group, a 1-tert-amyloxyethyl group, a 1-ethoxy-n-propyl group, a 1-cyclohexyloxyethyl group, a methoxypropyl group, an ethoxypropyl group, a 1-methoxy-1-methyl-ethyl group, and 1-ethoxy-1-methyl-ethyl group; a cyclic acetal group such as a tetrahydrofuranyl group and a tetrahydropyranyl group. Among the above-mentioned groups represented by formula (i), an ethoxyethyl group, a butoxyethyl group, an ethoxypropyl group, and a tetrahydropyranyl group are particularly preferable.

Examples of a linear, a branched, or a cyclic alkyl group in R³ in formula (II) and R⁵ in formula (III) include an ethyl group, a propyl group, an isopropyl group, a butyl group, an isobutyl group, a tert-butyl group, a cyclopentyl group, a cyclohexyl group, a cycloheptyl group, a triethylcarbyl group, a 1-ethylnorbornyl group, 1-methylcyclohexyl group, an adamantyl group, a 2-(2-methyl)adamantyl group, and a tert-amyl group. Among them, a tert-butyl group is particularly preferable.

Examples of the trialkyl silyl group in R³ in formula (II) and R⁵ in formula (III) include a group having 1 to 6 carbon atoms in each alkyl group, such as a trim ethyl silyl group, a triethyl silyl group, and a dimethyl tert-butyl silyl group. Example of the oxoalkyl group includes a 3-oxocyclohexyl group.

Monomers giving repeating units represented by formula (II) include, for example, vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δvalerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate. Among these, a polymer of 4-vinylbenzoic acid and tert-butyl 4-vinylbenzoate is preferable.

Monomers giving repeating units represented by formula (III) include, for example, acrylate, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1-ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, methacrylic acid, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate. Among these, polymers of acrylate and tert-butyl acrylate are preferable.

As the monomer constituting the shell portion, a polymer composed of at least one among 4-vinyl benzoic acid and acrylic acid and at least one among tert-butyl 4-vinyl benzoate and tert-butyl acrylate is also preferable. As a monomer constituting the shell portion, monomer other than the monomers giving repeating units represented by formula (II) and repeating units represented by formula (III) may also be used provided the monomer has a structure containing a radical polymerizable unsaturated bond.

Examples of monomers usable for the polymerization include a compound containing a radical polymerizable unsaturated bond selected from styrenes other than the styrenes mentioned above, an allyl compound, vinyl ethers, vinyl esters, and crotonate esters.

Specific examples of styrenes other than the styrenes cited as monomers usable as the monomer constituting the shell portion include styrene, tert-buthoxy styrene, α-methyl-tert-buthoxy styrene, 4-(1-methoxyethoxy)styrene, 4-(1-ethoxyethoxy)styrene, tetrahydropyranyloxy styrene, adamantyloxy styrene, 4-(2-methyl-2-adamantyloxy)styrene, 4-(1-methylcyclohexyloxy)styrene, trimethylsilyloxy styrene, dimethyl-tert-butylsilyloxy styrene, tetrahydropyranyloxy styrene, benzyl styrene, trifluoromethyl styrene, acetoxy styrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethyl styrene, 4-fluoro-3-trifluoromethyl styrene, and vinyl naphthalene.

Specific examples of allyl compounds cited as monomers usable as monomers constituting the shell portion include allyl acetate, allyl caproate, allyl caprylate, allyl laurate, allyl palmitate, allyl stearate, allyl benzoate, allyl acetoacetate, allyl lactate, and allyl oxyethanol.

Specific examples of vinyl ethers cited as monomers usable as monomers constituting the shell portion include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethyleneglycol vinyl ether, dimethylaminoethyl vinyl ether, diethylaminoethyl vinyl ether, butylaminoethyl vinyl ether, benzyl vinyl ether, tetrahydrofurfuryl vinyl ether, vinyl phenyl ether, vinyl tolyl ether, vinyl chlorophenyl ether, vinyl 2,4-dichlorophenyl ether, vinyl naphthyl ether, and vinyl anthranyl ether.

Specific examples of vinyl esters cited as monomers usable as monomers constituting the shell portion include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl buthoxyacetate, vinyl phenylacetate, vinyl acetoacetate, vinyl lactate, vinyl β-phenylbutyrate, and vinyl cyclohexylcarboxylate.

Specific examples of the crotonate esters cited as monomers usable as the monomers constituting the shell portion include butyl crotonate, hexyl crotonate, glycerine monocrotonate, dimethyl itaconate, diethyl itaconate, dibutyl itaconate, dimethyl maleate, dibutyl fumarate, maleic anhydride, maleimide, acrylonitrile, methacrylonitrile, and maleironitrile.

Specific examples of monomers usable as monomers constituting the shell portion also include monomers represented by formula (IV) to formula (VIII).

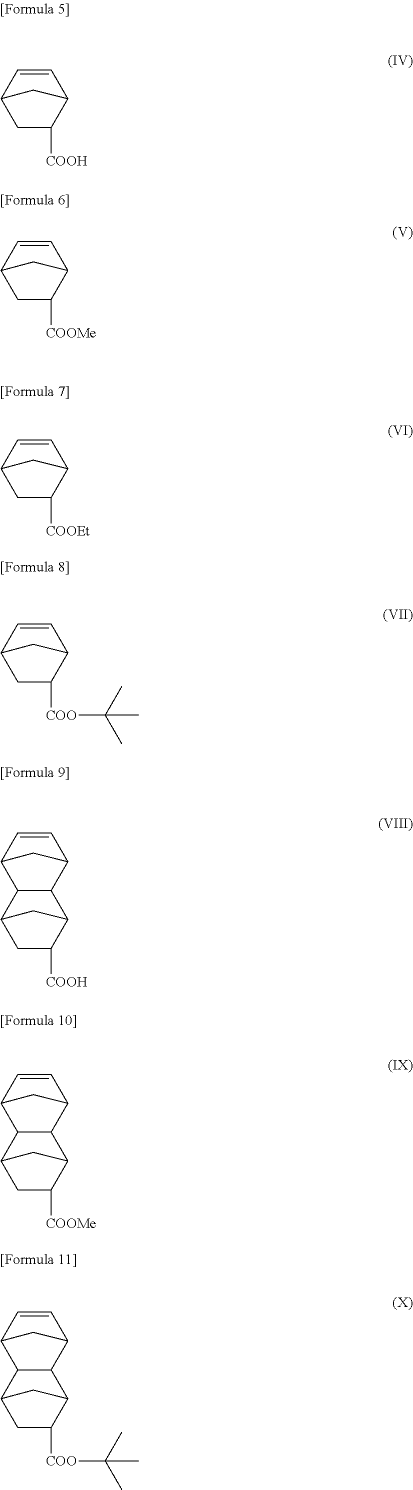

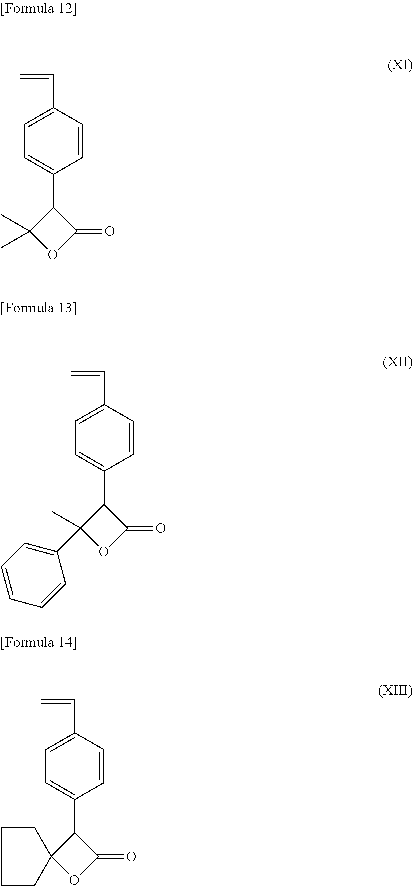

Among monomers usable as monomers constituting the shell portion, styrenes and crotonate esters are preferable. Among monomers usable as monomers constituting the shell portion, styrene, benzyl styrene, chlorostyrene, vinyl naphthalene, butyl crotonate, hexyl crotonate, and maleic anhydride are preferable.

In the hyperbranched polymer, at least monomer giving a repeating unit represented by formula (II) or monomer giving a repeating unit represented by formula (III) is included. The amount of monomer giving the repeating units above is preferably 10 to 90% by mol relative to the total charge amount of monomer used for synthesizing the hyperbranched polymer at the time of charge. The amount of monomer giving the repeating units as described above is more preferably 20 to 90% by mol relative to the total charge amount of monomer used for synthesizing the hyperbranched polymer at the time of charge.

The amount of monomer giving the repeating units as described above is yet more preferably 30 to 90% by mol relative to the total charge amount of monomer used for synthesizing the hyperbranched polymer at the time of charge. In particular, it is preferable that the repeating unit represented by formula (II) or the repeating unit represented by formula (III) be 50 to 100% by mol, and more preferably 80 to 100% by mol at the time of charge relative to the total charge amount of monomer used for synthesis of the hyperbranched polymer. When the charge amount of monomer giving the repeating unit as described above relative to the total charge amount of monomer used for synthesizing the hyperbranched polymer is at this range, a light-exposed part in the developing step in a lithography using a resist composition containing the hyperbranched polymer is efficiently removed by dissolution into a basic solution, and thus is preferable.

When the shell portion of the core-shell hyperbranched polymer is a polymer of monomer giving a repeating unit represented by formula (II) or monomer giving a repeating unit represented by formula (III) and other monomers, the amount of monomer giving the repeating unit represented by formula (II) and/or the amount of monomer giving the repeating unit represented by to formula (III) is preferably 30 to 90% by mol relative to the total monomer constituting the shell portion, and more preferably 50 to 70% by mol.

When monomer giving a repeating unit represented by formula (II) and/or monomer giving a repeating unit represented by formula (III) is at the above ranges relative to the total amount of monomer constituting the shell portion' functions such as etching resistance, wetting properties, and glass transition temperature are improved without hindering efficient dissolution of a light-exposed part in a basic solution, and thus, is preferable. Here, at least the amount of a repeating unit represented by formula (II) or the amount of the repeating unit represented by formula (III), and other repeating units in the shell portion may be controlled by the mol ratio at the time of introduction into the shell portion according to purpose.

It is preferable that a polymerization of the shell portion in the hyperbranched core polymer (shell polymerization) be carried out in the presence of nitrogen, an inert gas, or under the flow thereof, and in the absence of oxygen to prevent radicals from being affected by oxygen. The shell polymerization may be carried out in a batch process or a continuous process. The shell polymerization may be carried out consecutively following the core polymerization, or by adding a catalyst again after the metal catalyst and monomer are removed after the core polymerization. Further, the shell polymerization may be carried out after drying the hyperbranched core polymer synthesized by the core polymerization.

The shell polymerization is carried out in the presence of a metal catalyst. In the shell polymerization, a metal catalyst similar to those used in the core polymerization may be used. In the shell polymerization, for example, a metal catalyst is placed in a reaction system of the shell polymerization prior to initiation of the shell polymerization, and then the hyperbranched core polymer synthesized by the core polymerization (macro initiator, or core macromer) and a monomer constituting the shell portion are added dropwise. To be specific, for example, a metal catalyst is placed in advance inside a reaction vessel, into which the macro initiator and the monomer are added dropwise. Specifically, for example, a monomer constituting the shell portion as described above may be added dropwise into a reaction vessel containing the hyperbranched core polymer in advance. It is preferable that a monomer, a metal catalyst, and a solvent used in the shell polymerization be fully deoxygenated (degassed) in advance as in the case of the core polymerization.

In the polymerization of the shell, a metal catalyst is used. As the metal catalyst, for example, a metal catalyst composed of a ligand and a transition metal compound of, for example, copper, iron, ruthenium, and chromium. examples of the transition metal compound include copper (I) chloride, copper (I) bromide, copper (I) iodide, copper (I) cyanide, copper (I) oxide, copper (I) perchlorate, iron (I) chloride, iron (I) bromide, and iron (I) iodide.

Examples of the ligand include pyridines, bipyridines, polyamines, and phosphines, unsubstituted or substituted with an alkyl group, an aryl group, an amino group, a halogen group, an ester group, and the like. Examples of the preferable metal catalyst include a copper (I) bipyridyl complex and a copper (I) pentamethyl diethylene triamine complex, which are composed of copper chloride and respective ligands, and an iron (II) triphenyl phosphine complex and an iron (II) tributyl amine complex, which are composed of iron chloride and respective ligands, or others.

The amount of the metal catalyst relative to active reaction sites of the hyperbranched core polymer used in the polymerization of the shell is preferably 0.01 to 70% by mol, and more preferably 0.1 to 60% by mol. When the catalyst is used at this amount, reactivity can be improved, thereby enabling synthesis of a core-shell hyperbranched polymer having a suitable degree of branching.

When the amount of metal catalyst used is below the range, reactivity may be markedly reduced, thereby leading to a risk of the polymerization becoming sluggish. On the other hand, when the amount of metal catalyst used is above the range, the polymerization reaction becomes excessively active and the coupling reaction among radicals at growing terminals tends to occur easily, thereby making control of the polymerization difficult. Further, when the amount of metal catalyst used is above the range, the coupling reaction among radicals induces gelation of the reaction system.

The metal catalyst may be made into a coordination compound by mixing a transition metal compound and a ligand in an apparatus. The metal catalyst composed of a transition metal compound and a ligand may be added to the apparatus in the form of an active coordination compound. Making a coordination compound by mixing a transition metal compound and a ligand in the apparatus is preferable because of operations in the synthesis of the hyperbranched polymer can be simplified.

A method of adding the metal catalyst is not particularly restricted and the metal catalyst may be added, for example, all at once prior to the polymerization of the shell. Further, additional metal catalyst may be added after initiation of the polymerization depending on the level of inactivation of the catalyst. For example, when distribution of a coordination compound forming the metal catalyst in the reaction system is not uniform, the transition metal compound may be added to the apparatus in advance, followed by addition of only a ligand afterwards.

The shell polymerization reaction in the presence of the metal catalyst is carried out preferably in a solvent, though the reaction can occur in the absence of a solvent. The solvent used in the polymerization of the hyperbranched core polymer in the presence of the metal catalyst is not particularly restricted. examples of the solvent include a hydrocarbon solvent such as benzene and toluene; an ether solvent such as diethyl ether, tetrahydrofuran, diphenyl ether, anisole, and dimethoxy benzene; a halogenated hydrocarbon solvent such as methylene chloride, chloroform, and chlorobenzene; a ketone solvent such as acetone, methyl ethyl ketone, and methyl isobutyl ketone; an alcohol solvent such as methanol, ethanol, propanol, and isopropanol; a nitrile solvent such as acetonitrile, propionitrile, and benzonitrile; an ester solvent such as ethyl acetate and butyl acetate; a carbonate solvent such as ethylene carbonate and propylene F0199 carbonate; and an amide solvent such as N,N-dimethylformamide and N,N-dimethylacetamide. These may be used independently or in a combination of two or more kinds.

According to the shell polymerization described above, gelation can be efficiently prevented from occurring regardless of the concentration of the hyperbranched core polymer. The concentration of the hyperbranched core polymer in the shell polymerization is preferably 0.1 to 30% by mass and more preferably 1 to 20% by mass relative to the total reaction amount including the hyperbranched core polymer and monomer at the time of charging.

The concentration of the monomer in the shell polymerization is preferably 0.5 to 20 mol equivalents relative to the active site of the core macromer. More preferably, the concentration of the monomer in the shell polymerization is 1 to 15 mol equivalents relative to the active site of the core macromer. By appropriately controlling the amount of the monomer relative to the active site of the reaction, the core/shell ratio can be controlled.

The polymerization time for the shell polymerization is preferably 0.1 to 10 hours depending on a molecular weight of the polymer. Reaction temperature of the shell polymerization is preferably 0 to 200° C. More preferably, the reaction temperature of the shell polymerization is 50 to 150° C. When the polymerization is carried out at a temperature above a boiling point of the solvent used, for example, the pressure may be increased in an autoclave.

In the shell polymerization, the reaction system is distributed uniformly. For example, the reaction system is distributed uniformly by agitation. As a specific example of an agitation condition for shell polymerization, preferably the power necessary for agitation per unit volume is 0.01 kW/m³ or more.

In the shell polymerization, additional catalyst or a reducing agent to regenerate the catalyst may be added according to the progress of the polymerization and degree of catalyst inactivation. The shell polymerization is stopped when the molecular weight reaches the point prescribed for the shell polymerization. The method of stopping the shell polymerization is not particularly limited, and a method such as inactivating the catalyst, for example, by cooling or by adding an oxidizing agent, a chelating agent, or others may be used.

In the synthesis of the core-shell hyperbranched polymer, removal of the metal catalyst, removal of monomers, and removal of trace metal (derived from the metal catalyst) are performed after the shell polymerization. The metal catalyst is removed after the shell polymerization is complete. Removal of the metal catalyst may be done, for example, by the following (a) to (c) methods independently or in a combination thereof.

(a) Use various kinds of adsorbents, such as Kyoward manufactured by Kyowa Chemical Industry Co., Ltd.
(b) Remove insoluble matter by filtration and centrifugal separation.
(c) Extract by using a water solution containing an acid and/or a compound having a chelating effect.

Examples of a compound having a chelating effect and used in method (c) include organic acids such as formic acid, acetic acid, oxalic acid, citric acid, gluconic acid, tartaric acid, and malonic acid; an amino carbonate such as nitrilotriacetic acid, ethylenediaminetetraacetic acid, and diethylenetriamine pentaacetic acid; and a hydroxyamino carbonate. examples of a compound having a chelating effect and used in the method (c) include inorganic acids such as hydrochloric acid and sulfuric acid. Concentration of the aqueous solution containing a compound having a chelating capacity is preferably, for example, 0.05 to 10% by mass, and may differ depending on a chelating capacity of the substance.

Removal of the monomers may be performed after the metal catalyst is removed or after the metal catalyst and subsequently, trace metals are removed. In the removal of monomers, unreacted monomers among the monomers added dropwise at the core polymerization and the shell polymerization are removed. Unreacted monomers may be removed, for example, by the following (d) to (e) methods independently or in a combination thereof.

(d) Precipitate polymer by adding a poor solvent to a reaction substance dissolved in a good solvent.
(e) Wash polymer using a mixed solvent of a good solvent and a poor solvent.

In (d) to (e) above, examples of a good solvent include a halogenated hydrocarbon, a nitro compound, a nitrile, an ether, a ketone, an ester, a carbonate, and a mixture thereof. Specific examples include tetrahydrofuran, chlorobenzene, and chloroform. Examples of the poor solvent include methanol, ethanol, 1-propanol, 2-propanol, water, and a mixture thereof.

In the synthesis of the core-shell hyperbranched polymer, trace amounts of residual metal in the polymer are reduced after removal of the metal catalyst and removal of monomers as described above. Reduction of trace amounts of residual metal in the polymer may be performed, for example, by the following (f) to (g) methods independently or in a combination thereof.

(f) Extract by a liquid-liquid extraction using an aqueous solution containing an organic compound having a chelating capacity, an aqueous solution of an inorganic acid, and pure water.
(g) Use an adsorbent and an ion-exchange resin.

Examples of the organic solvent preferably used for the liquid-liquid extraction in method (f) include a halogenated hydrocarbon such as chlorobenzene and chloroform; acetate esters such as ethyl acetate, n-butyl acetate, and isoamyl acetate; ketones such as methyl ethyl ketone, methyl isobutyl ketone, cyclohexanone, 2-heptane, and 2-pentanone; glycol ether acetates such as ethyleneglycol monoethyl ether acetate, ethyleneglycol monobutyl ether acetate, ethyleneglycol monomethyl ether acetate; and aromatic hydrocarbons such as toluene and xylene.

Examples of the organic solvent more preferably used for the liquid-liquid extraction in method (f) include chloroform, methyl isobutyl ketone, and ethyl acetate. These solvents may be used independently or in a combination of two or more. In the liquid-liquid extraction method (f), the amount of the core-shell hyperbranched polymer after the monomers and the metal catalyst are removed is preferably approximately 1 to 30 by mass, and more preferably approximately 5 to 20% by mass relative to the organic solvent.

Examples of an organic compound having an chelating capacity used in the liquid-liquid extraction method (f) include an organic acid such as formic acid, acetic acid, oxalic acid, citric acid, gluconic acid, tartaric acid, and malonic acid; an amino carbonate such as nitrilotriacetic acid, ethylenediaminetetraacetic acid, and diethylenetriamine pentaacetic acid; and a hydroxyamino carbonate. Examples of the inorganic acid used in the liquid-liquid extraction method (f) include hydrochloric acid and sulfuric acid.

In the liquid-liquid extraction according to method (f), concentrations of the organic compound having a chelating capacity and the inorganic acid in the aqueous solution are preferably, for example, 0.05 to 10% by mass. Here, concentrations of the organic compound having a chelating capacity and the inorganic acid in the aqueous solution in the liquid-liquid extraction using method (f) differ depending on the chelating capacity of the compound.

In the method of removing trace metal, when an aqueous solution containing an organic compound having a chelating capacity and an aqueous solution containing an inorganic acid are used, a mixture of the aqueous solution containing the organic compound having a chelating capacity and the aqueous solution containing the inorganic acid may be used, or the aqueous solution containing the organic compound having a chelating capacity and the aqueous solution containing the inorganic acid may be used separately. When the aqueous solution containing the organic compound having a chelating capacity and the aqueous solution containing the inorganic acid are used separately, the aqueous solution containing the organic compound having a chelating capacity or the aqueous solution containing the inorganic acid may be used first.

In removing metals, when the aqueous solution containing the organic compound having a chelating capacity and the aqueous solution containing the inorganic acid are used separately, it is more preferable to use the aqueous solution containing the inorganic acid at later stage because the aqueous solution containing the organic compound having a chelating capacity is effective in removing copper catalyst and multivalent metal, and the aqueous solution containing the inorganic acid is effective in removing monovalent metal derived from experimental equipment and the like.

Accordingly, when the aqueous solution containing the organic compound having a chelating capacity and the aqueous solution containing the inorganic acid are used as a mixture, it is also preferable to wash the shell portion by an aqueous solution containing only the inorganic acid at a later stage. The number of extractions is not particularly restricted, but preferably is 2 to 5 times, for example. To avoid contamination by metals derived from experimental equipment and the like, it is preferable to use pre-washed experimental equipment particularly when used in a reduced copper ion state. The method of pre-washing is not particularly restricted, and for example, may be washing by an aqueous nitric acid.

The number of washings solely by the aqueous solution containing the inorganic acid is preferably 1 to 5 times. When the washing solely by the aqueous solution containing the inorganic acid is performed 1 to 5 times, monovalent metal can be removed sufficiently. Further, to remove residual acid components, it is preferable to perform the extraction treatment by pure water last to remove the acid completely. The number of washings by pure water is preferably 1 to 5 times. When the washing by pure water is performed 1 to 5 times, residual acid can be removed sufficiently.

In the removal of metals, respective ratios of the reaction solvent containing the purified core-shell hyperbranched polymer (hereinafter, “reaction solvent”) to the aqueous solution containing the organic compound having a chelating capacity, to the aqueous solution containing the inorganic acid, and to pure water are each preferably 1:0.1 to 1:10 by volume. More preferably the ratios are 1:0.5 to 1:5 by volume. When the washing is performed using the solvent at such ratios, metal can be easily removed by a moderate number of washings. Thus, operations can be simplified and easy, thereby leading to efficient synthesis of the core-shell hyperbranched polymer, and thus, is preferable. It is preferable that the concentration by mass of a resist polymer intermediate dissolved in the reaction solvent be usually approximately 1 to 30% by mass relative to the solvent.

The liquid-liquid extraction treatment in method (f) is performed, for example, by separating the mixed solvent composed of the reaction solvent and the aqueous solution containing the organic compound having a chelating capacity, the aqueous solution containing the inorganic acid, and pure water (hereinafter, simply “mixed solvent”) into two layers, and then removing a water layer containing migrated metal ions by decantation.

Separation of the mixed solvent into two layers may be performed, for example, by the following method; the aqueous solution containing the organic compound having a chelating capacity, the aqueous solution containing the inorganic acid, and pure water are added into the reaction solvent, are mixed thoroughly by agitation, and allowed to stand thereafter. Separation of the mixed solvent into two layers may be performed by centrifugal separation, for example. The liquid-liquid extraction treatment in method (f) is preferably performed, for example, at a temperature of 10 to 50° C. and more preferably at 20 to 40° C.

In the synthesis of the core-shell hyperbranched polymer, partial decomposition of an acid-decomposable group may be carried out, as needed, after trace metal are removed. In the partial decomposition of the acid-decomposable group, for example, a part of the acid-decomposable group is decomposed (the acid-decomposable group is directed) to an acid group by using the acid catalyst mentioned above.

In the decomposition of part of an acid-decomposable group by the acid catalyst (partial decomposition of the acid-decomposable group) to the acid group, usually acid catalyst of 0.001 to 100 equivalents to the acid-decomposable group in the hyperbranched polymer obtained after the removal of metal is used. The acid catalyst is not particularly restricted, and examples include hydrochloric acid, sulfuric acid, phosphoric acid, hydrobromic acid, p-toluene sulfonic acid, acetic acid, trifluoroacetic acid, trifluoromethane sulfonic acid, and formic acid.

The organic solvent used in the reaction of the partial decomposition of the acid-decomposable group by using the acid catalyst is preferably one that can dissolve the hyperbranched polymer obtained after metals are removed, and also is miscible with water. In view of availability and ease of handling, the organic solvent used in the reaction of the partial decomposition of the acid-decomposable group by using the acid catalyst is preferably selected from among 1,4-dioxane, tetrahydrofuran, acetone, methyl ethyl ketone, diethyl ketone, and a mixture thereof.

The amount of organic solvent used in the reaction of the partial decomposition of the acid-decomposable group by using the acid catalyst is not particularly restricted provided the core-shell hyperbranched polymer obtained after removal of the metals as described above and the acid catalyst dissolve. The amount is preferably, by mass, 5 to 500 times the core-shell hyperbranched polymer obtained after removal of the metals. More preferably the amount of the organic solvent used in the reaction of the partial decomposition of the acid-decomposable group by using the acid catalyst is 8 to 200 times by mass. The reaction to partially decompose the acid-decomposable group by using the acid catalyst may be done by heating at 50 to 150° C. for 10 minutes to 20 hours combined with agitation.

Concerning the ratio of the acid-decomposable group to the acid group in the core-shell hyperbranched polymer obtained after the partial decomposition of the acid-decomposable group, preferably 0.1 to 80% by mol of the monomer having the introduced acid-decomposable group is de-protected to the acid group. For example, when the core-shell hyperbranched polymer obtained after the partial decomposition of the acid-decomposable group is used for a resist composition of a photo resist, the optimum value of the ratio of the acid-decomposable group to the acid group in the core-shell hyperbranched polymer varies according to the composition of the resist composition containing the core-shell hyperbranched polymer.

When the ratio of the acid-decomposable group to the acid group in the core-shell hyperbranched polymer obtained after the partial decomposition of the acid-decomposable group is at the above range, an increase in the light-sensitivity and efficient base-dissolution after the light-exposure is realized, and thus, is preferable. The ratio of the acid-decomposable group to the acid group in the core-shell hyperbranched polymer obtained after the partial decomposition of the acid-decomposable group may be controlled by appropriately choosing the amount of acid catalyst, temperature, and reaction time.

For example, when the core-shell hyperbranched polymer obtained after the deprotection as described above is used for a resist composition of a photo resist, the optimum ratio of the acid-decomposable group to the acid group in the core-shell hyperbranched polymer varies according to the composition of the resist composition. The ratio of the acid-decomposable group to the acid group may be controlled by appropriately choosing the amount of acid catalyst, temperature, and reaction time.

After the partial decomposition reaction of the acid-decomposable group, a solution containing the core-shell hyperbranched polymer having a formed acid group obtained after the partial decomposition reaction of the acid-decomposable group (hereinafter, “reaction solution”) is mixed with ultrapure water to precipitate the core-shell hyperbranched polymer obtained after the partial decomposition reaction of the acid-decomposable group. Then, the solution containing the precipitated core-shell hyperbranched polymer is subjected to centrifugal separation, filtration, decantation, and the like to separate the core-shell hyperbranched polymer obtained after the partial decomposition reaction of the acid-decomposable group.

In the embodiment, the precipitation step is realized here. Thereafter, the precipitated core-shell hyperbranched polymer is re-dissolved in an organic solvent, and then the liquid-liquid extraction using the solution containing the dissolved core-shell hyperbranched polymer precipitated and ultrapure water is performed to remove residual acid catalyst. In the embodiment, the liquid-liquid extraction step is realized here.

An organic solvent used in the liquid-liquid extraction is preferably one that can dissolve the precipitated core-shell hyperbranched polymer, and in addition, is poorly miscible or not miscible with water. There is no particular restriction in the organic solvent used in the liquid-liquid extraction provided the organic solvent has the properties as described above. Examples of the solvent include a halogenated hydrocarbon such as chloroform, carbon tetrachloride, and chlorobenzene; alcohols such as 1-pentanol and 1-hexanol; phenols such as phenol and p-cresol; ethers such as dipropyl ether and anisole; ketones such as methyl ethyl ketone, methyl propyl ketone, methyl isobutyl ketone, and cyclohexanone; esters such as ethyl acetate, propyl acetate, and butyl acetate. These solvents may be used independently or as a mixture having an arbitrary mixing ratio. Among these solvents, ketones and esters, in particular methyl isobutyl ketone and ethyl acetate, are preferable.

The solubility of the precipitated core-shell hyperbranched polymer in the solvent used in the liquid-liquid extraction varies depending on the ratio of the acid-decomposable group to the acid group in the core-shell hyperbranched polymer. Accordingly, the concentration of the precipitated core-shell hyperbranched polymer in the organic solvent used in the liquid-liquid extraction is not particularly restricted; however, for first example to 40% by mass is preferable.

The amount of ultrapure water used in the liquid-liquid extraction relative to the organic solvent is preferably a ratio of ultrapure water/organic solvent=0.1/1 to 1/0.1 by volume. When a part of the acid-decomposable group is decomposed to the acid group by using the acid catalyst, it is preferable that the ultrapure water for the liquid-liquid extraction be used with a volume ratio of ultrapure water/organic solvent=0.5/1 to 1/0.5 because the amount of a waste effluent can be reduced.

It is preferable that the liquid-liquid extraction be repeated until pH of the water layer is neutral at 10 to 50° C. The number of extractions is determined based on the concentration of the acid used, but is preferably 1 to 10 times to suppress an increase in the amount of the waste effluent accompanying an increase in the scale of the synthesis of the core-shell hyperbranched polymer for industrialization.

After the extraction by the liquid-liquid extraction as described above, the organic solvent used in the liquid-liquid extraction is distilled out and then the residue is dried. The drying method is not particularly restricted and may include drying methods as such vacuum drying and spray drying. In the drying, the temperature of the environment of the core-shell hyperbranched polymer obtained after removal of monomers and the core-shell hyperbranched polymer (hereinafter, “drying temperature”) is preferably 10 to 70° C. In the drying process, the drying temperature is more preferably 15 to 40° C.

In the drying process, it is preferable to evacuate the environment of the core-shell hyperbranched polymer obtained after removal of monomers. The pressure the drying process is preferably equal to or less than 20 Pa. The drying time is preferably 1 to 20 hours. Here, the degree of vacuum and drying time are not restricted to the above-mentioned values, and are chosen in such a manner as to maintain the drying temperature appropriately. Thus, the core-shell hyperbranched polymer having a desired structure can be obtained.

### (Molecular Structure)

A molecular structure of the core-shell hyperbranched polymer will be explained. The degree of branching (Br) of the core portion of the core-shell hyperbranched polymer is preferably 0.3 to 0.5. More preferably the degree of branching (Br) is 0.4 to 0.5. When the degree of branching (Br) of the core portion of the core-shell hyperbranched polymer is at the above range, a resist composition containing the core-shell hyperbranched polymer synthesized by using the hyperbranched core polymer has a low intermolecular entanglement among the polymers and thereby suppresses surface roughness in the pattern wall, and thus, is preferable.

Here, the degree of branching (Br) of the core portion in the core-shell hyperbranched polymer may be obtained by measuring a ¹H-NMR of the product. Namely, the degree of branching can be calculated by computing equation (A) by using H1°, an integral ratio of protons in —CH₂Cl appearing at 4.6 ppm, and H2°, an integral ratio of the protons in —CHCl appearing at 4.8 ppm. When polymerization progresses at both —CH₂Cl and —CHCl, thereby enhancing the branching, the degree of branching (Br) approaches 0.5.

$$[ Equation 1 ]$$

$$Br = \frac{\frac{1}{2} H {1}^{∘}}{\frac{1}{2} H {1}^{∘} + H {2}^{∘}} \qquad ( A )$$

The weight-average molecular weight (Mw) of the core portion in the core-shell hyperbranched polymer is preferably 300 to 8,000, also preferably 500 to 6,000, and most preferably 1,000 to 4,000. When the molecular weight of the core portion is at such ranges, the core portion takes a spherical morphology, thereby, ensuring solubility into the reaction solvent in the reaction to introduce the acid-decomposable group, and thus, is preferable. In addition, performance of a film-formation is excellent, and dissolution of a light-unexposed part is prevented advantageously in the hyperbranched polymer whose core portion having the molecular weight at the above range is introduced by the acid-decomposable group, and thus, is preferable.

The degree of multi-dispersion (Mw/Mn) of the core portion in the core-shell hyperbranched polymer is preferably 1 to 3, and more preferably 1 to 2.5. At such ranges, there is no risk of adverse effects such as insolubilization after light exposure, and thus, is preferable.

The weight-average molecular weight (M) of the core-shell hyperbranched polymer is preferably 500 to 21,000, more preferably 2,000 to 21,000, and most preferably 3,000 to 21,000. When the weight-average molecular weight (M) of the core-shell hyperbranched polymer is at such ranges, a resist containing the hyperbranched polymer is excellent in a film formation and can maintain its form because the process pattern formed in a lithography step is strong. In addition, it is excellent in terms of dry-etching resistance and surface roughness.

The weight-average molecular weight (Mw) of the core portion in the core-shell hyperbranched polymer may be obtained, for example, by a GPC (Gel Permeation Chromatography) measurement using a tetrahydrofuran solution (0.5% by mass) at 40° C. In the measurement, tetrahydrofuran was used as a moving phase, styrene was used as a standard material, and two TSKgel HXL-M columns (manufactured by Tosoh Corporation) were connected in series by using a GPC HLC-8020 type instrument.

The weight-average molecular weight (M) of the core-shell hyperbranched polymer may be obtained as follows: an introduction ratio (composition ratio) of each repeating unit in the polymer into which the acid-decomposable group is introduced is obtained by ¹H-NMR, and then, based on the weight-average molecular weight (Mw) of the core portion in the core-shell hyperbranched polymer, M is obtained by a calculation by using the introduction ratio of each composition unit and the molecular weight of each composition unit. The morphology of the synthesized core-shell hyperbranched polymer is judged as a spherical form based on the primary and the secondary hydrogens measured by an NMR.

As described, according to the embodiment, the core-shell hyperbranched polymer can be synthesized stably and in large quantities with an aim of reducing the amount of waste effluent generated from the synthesis.

### (Application of the Core-Shell Hyperbranched Polymer)

Application of the Core-Shell polymer is not particularly restricted, and may be used for, for example, a polymer for a photo resist, a resin for ink-jet processing such as a color filter and a biochip, a crosslinking agent in a powder paint, a substrate for a solid electrolyte, and a pour-point depressant for a BDF.

For example, when the core-shell hyperbranched polymer is applied to a polymer of a photo resist, an excellent polymer for a photo resist having a small concavity and convexity of the pattern wall and a high solubility in a basic solution after a light-exposure, namely a high light-sensitivity, may be obtained by introducing the acid-decomposable group, as the shell portion, into the terminal of the hyperbranched polymer. In such an application, for example, tert-butyl acrylate may be polymerized to give the shell portion of the core-shell hyperbranched polymer by an Atom Transfer Radical Polymerization.

The resist composition may support an electron beam, a deep ultraviolet beam (DUV), and an extreme ultraviolet beam (EUV), which require a surface smoothness at a nanometer level, thereby enabling formation of a fine pattern for manufacturing a semi-conductor integrated circuit. Thus, a resist composition containing the core-shell hyperbranched polymer synthesized by the synthesis method of the present invention can be suitably used in various fields which use a semi-conductor integrated circuit produced by using a light source irradiating a short wavelength light.

Further, in a semi-conductor integrated circuit produced by using a resist composition containing the hyperbranched polymer of the embodiment, when the semi-conductor integrated circuit is exposed to light, is heated, dissolved in a basic developing solution, and then washed by water-washing and the like during fabrication, substantially no undissolved residues remain on exposed surfaces, thereby enabling formation of a nearly vertical edge. This, a fine semi-conductor integrated circuit having stable performance and supporting an electron beam, a deep ultraviolet beam (DUV), and an extreme ultraviolet beam (EUV) can be obtained.

### (Resist Composition)

A resist composition using the hyperbranched polymer will be explained. The blending amount of the core-shell hyperbranched polymer (resist polymer) in a resist composition using the hyperbranched polymer (hereinafter, simply “resist composition”) is preferably 4 to 40% by mass and more preferably 4 to 20% by mass relative to a total amount of the resist composition.

The resist composition contains the core-shell hyperbranched polymer above and a photo-inductive acid-generating material. The resist composition may further contain, as needed, an acid-diffusion suppressor (an acid scavenger), a surfactant, other components, a solvent, and the like.

There is no particular restriction in terms of photo-inductive acid-generating material contained in the resist composition provided acid is generated upon exposure to UV light, an X-ray beam, an electron beam, and the like, and may be selected appropriately from among commonly known photo-inductive acid-generating materials according to purpose. Specific examples of the photo-inductive acid-generating material include onium salt, sulfonium salt, a halogen-containing triazine compound, a sulfone compound, a sulfonate compound, an aromatic sulfonate compound, and an N-hydroxyimide sulfonate compound.

Examples of onium salt included in the photo-inductive acid-generating material include a diaryl iodonium salt, a triaryl selenonium salt, and a triaryl sulfonium salt. Examples of diaryl iodonium salt include diphenyl iodonium trifluoromethane sulfonate, 4-methoxyphenyl phenyl iodonium hexafluoroantimonate, 4-methoxyphenyl phenyl iodonium trifluoromethane sulfonate, bis(4-tert-butylphenyl)iodonium tetrafluoroborate, bis(4-tert-butylphenyl)iodonium hexafluorophosphate, bis(4-tert-butylphenyl)iodonium hexafluoroantimonate, and bis(4-tert-butylphenyl)iodonium trifluoromethane sulfonate.

Specific examples of triaryl selenonium salt included in onium salt include triphenyl selenonium hexafluorophosphoric salt, triphenyl selenonium tetrafluoroborate salt, and triphenyl selenonium hexafluoroantimonate salt. Examples of triaryl sulfonium salt included in onium salt include triphenyl sulfonium hexafluorophosphoric salt, triphenyl sulfonium hexafluoroantimonate salt, diphenyl-4-thiophenoxyphenyl sulfonium hexafluoroantimonate salt, and diphenyl-4-thiophenoxyphenyl sulfonium pentafluorohydroxy antimonate salt.

Examples of sulfonium salt included in the photo-inductive acid-generating material include triphenyl sulfonium hexafluorophosphate, triphenyl sulfonium hexafluoroantimonate, triphenyl sulfonium trifluoromethane sulfonate, 4-methoxyphenyl diphenyl sulfonium hexafluoroantimonate, 4-methoxyphenyl diphenyl sulfonium trifluoromethane sulfonate, p-tolyldiphenyl sulfonium trifluoromethane sulfonate, 2,4,6-trimethylphenyl diphenyl sulfonium trifluoromethane sulfonate, 4-tert-butylphenyl diphenyl sulfonium trifluoromethane sulfonate, 4-phenylthiophenyl diphenyl sulfonium hexafluorophosphate, 4 phenylthiophenyl diphenyl sulfonium hexafluoroantimonate, 1-(2-naphthoylmethyl)thioranium hexafluoroantimonate, 1-(2-naphthoylmethyl)thioranium trifluoroantimonate, 4-hydroxy-1-naphthyl dimethyl sulfonium hexafluoroantimonate, and 4-hydroxy-1-naphthyl dimethyl sulfonium trifluoromethane sulfonate.

Specific examples of a halogen-containing triazine compound included in the photo-inductive acid-generating material include 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2-(4-chlorophenyl)-4,6-bis(trichloromethyl)-1,3,5-triazine, 2-(4-methoxyphenyl)-4,6-bis(trichloromethyl)-1,3,5-triazine, 2-(4-methoxy-1-naphthyl)-4,6-bis(trichloromethyl)-1,3,5-triazine, 2-(benzo[d][1,3]dioxolane-5-yl)-4,6-bis(trichloromethyl)-1,3,5-triazine, 2-(4-methoxystyryl)-4,6-bis(trichloromethyl)-1,3,5-triazine, 2-(3,4,5-trimethoxystyryl)-4,6-bis(trichloromethyl)-1,3,5-triazine, 2-(3,4-dimethoxystyryl)-4,6-bis(trichloromethyl)-1,3,5-triazine, 2-(2,4-dimethoxystyryl)-4,6-bis(trichloromethyl)-1,3,5-triazine, 2-(2-methoxystyryl)-4,6-bis(trichloromethyl)-1,3,5-triazine, 2-(4-butoxystyryl)-4,6-bis(trichloromethyl)-1,3,5-triazine, and 2-(4-benzyloxystyryl)-4,6-bis(trichloromethyl)-1,3,5-triazine.

Specific examples of the sulfone compound included in the photo-inductive acid-generating material include diphenyl disulfone, di-p-tolyl disulfone, bis(phenylsulfonyl)diazomethane, bis(4-chlorophenylsulfonyl)diazomethane, bis(p-tolylsulfonyl)diazomethane, bis(4-tert-butylphenylsulfonyl)diazomethane, bis(2,4-xylylsulfonyl)diazomethane, bis(cyclohexylsulfonyl)diazomethane, (benzoyl)(phenylsulfonyl)diazomethane, and phenylsulfonyl acetophenone.

Specific examples of the aromatic sulfonate compound included in the photo-inductive acid-generating material include α-benzoylbenzyl p-toluene sulfonate (common name: benzoin tosylate), β-benzoyl-β-hydroxyphenethyl p-toluene sulfonate (common name: α-methylol benzoin tosylate), 1,2,3-benzenetriyl trismethane sulfonate, 2,6-dinitrobenzyl p-toluene sulfonate, 2-nitrobenzyl p-toluene sulfonate, and 4-nitrobenzyl p-toluene sulfonate.

Specific examples of the N-hydroxyimide sulfonate compound included in the photo-inductive acid-generating material include N-(phenylsulfonyloxy)succinimide, N-(trifluoromethylsulfonyloxy)succinimide, N-(p-chlorophenylsulfonyloxy)succinimide, N-(cyclohexylsulfonyloxy)succinimide, N-(1-naphthylsulfonyloxy)succinimide, N-(benzylsulfonyloxy)succinimide, N-(10-camphorsulfonyloxy)succinimide, N-(trifluoromethylsulfonyloxy)phthalimide, N-(trifluoromethylsulfonyloxy)-5-norbornene-2,3-dicarboxylmide, N-(trifluoromethylsulfonyloxy)naphthalimide, and N-(10-camphorsulfonyloxy)naphthalimide.

Among various kinds of the photo-inductive acid-generating material as described above, sulfonium salt is preferable, in particular, triphenyl sulfonium trifluoromethane sulfonate; and sulfone compounds, in particular, bis(4-tert-butylphenylsulfonyl)diazomethane and bis(cyclohexylsulfonyl)diazomethane.

The photo-inductive acid-generating material may be used independently or in a combination of two or more. There is no particular restriction in the blending ratio of the photo-inductive acid-generating material, and the blending ratio may be appropriately determined according to purpose, though it is preferably 1 to 30 parts by mass relative to 100 parts by mass of the hyperbranched polymer of the present invention. More preferably, the blending ratio of the photo-inductive acid-generating material is 0.1 to 10 parts by mass.

There is no particular restriction in the acid-diffusion suppressor contained in the resist composition provided the acid-diffusion suppressor is a component having functions to control the diffusion of acid generated from the photo-inductive acid-generating material in a resist film and to suppress undesired chemical reactions in non-exposed regions. The acid-diffusion suppressor contained in the resist composition may be appropriately selected from various kinds of commonly known acid-diffusion suppressors according to purpose.

Examples of acid-diffusion suppressors contained in the resist composition include a compound having one nitrogen atom in a single molecule, a compound having two nitrogen atoms in a single molecule, a polyamino compound and a polymer thereof having three nitrogen atoms or more in a single molecule, an amide-containing compound, an urea compound, and a nitrogen-containing heterocyclic compound.

Examples of compounds having one nitrogen atom in a single molecule cited as an acid-diffusion suppressor include a mono(cyclo)alkyl amine, a di(cyclo)alkyl amine, a tri(cyclo)alkyl amine, and an aromatic amine. Specific examples of mono(cyclo)alkyl amine include n-hexyl amine, n-heptyl amine, n-octyl amine, n-nonyl amine, n-decyl amine, and cyclohexyl amine.

Examples of di(cyclo)alkyl amine included in compounds having one nitrogen atom in a single molecule include di-n-butyl amine, di-n-pentyl amine, di-n-hexyl amine, di-n-heptyl amine, di-n-octyl amine, di-n-nonyl amine, di-n-decyl amine, and cyclohexyl methyl amine.

Examples of tri(cyclo)alkyl amine included in compounds having one nitrogen atom in a single molecule include triethyl amine, tri-n-propyl amine, tri-n-butyl amine, tri-n-pentyl amine, tri-n-hexyl amine, tri-n-heptyl amine, tri-n-octyl amine, tri-n-nonyl amine, tri-n-decyl amine, cyclohexyl dimethyl amine, methyl dicyclohexyl amine, and tricyclohexyl amine.

Examples of aromatic amine included in compounds having one nitrogen atom in a single molecule include aniline, N-methyl aniline, N,N-dimethyl aniline, 2-methyl aniline, 3-methyl aniline, 4-methyl aniline, 4-nitroaniline, diphenyl amine, triphenyl amine, and naphthyl amine.

Examples of compounds having two nitrogen atoms in a single molecule cited as an acid-diffusion suppressor include ethylenediamine, N,N,N′,N′-tetramethyl ethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, and bis(2-diethylaminoethyl)ether.

Examples of polyamino compounds and polymers thereof having three nitrogen atoms or more in a single molecule and cited as an acid-diffusion suppressor include poly(ethylene imine), poly(allyl amine), and a polymer of N-(2-dimethylaminoethyl)acrylamide.

Examples of amide-containing compounds cited as an acid-diffusion suppressor include N-tert-buthoxycarbonyl di-n-octylamine, N-tert-buthoxycarbonyl di-n-nonylamine, N-tert-buthoxycarbonyl di-n-decylamine, N-tert-buthoxycarbonyl dicyclohexylamine, N-tert-buthoxycarbonyl-1-adamantylamine, N-tert-buthoxycarbonyl-N-methyl-1-adamantylamine, N,N-di-tert-buthoxycarbonyl-1-adamantylamine, N,N-di-tert-buthoxycarbonyl-N-methyl-1-adamantylamine, N-tert-buthoxycarbonyl-4,4-diaminodiphenylmethane, N,N′-di-tert-buthoxycarbonyl hexamethylenediamine, N,N,N′,N′-tetra-tert-buthoxycarbonyl hexamethylenediamine, N,N′-di-tert-buthoxycarbonyl-1,7-diaminoheptane, N,N′-di-tert-buthoxycarbonyl-1,8-diaminooctane, N,N′-di-tert-buthoxycarbonyl-1,9-diaminononane, N,N-di-tert-buthoxycarbonyl-1,10-diaminodecane, N,N-di-tert-buthoxycarbonyl-1,12-diaminododecane, N,N-di-tert-buthoxycarbonyl-4,4′-diaminodiphenylmethane, N-tert-buthoxycarbonyl benzimidazole, N-tert-buthoxycarbonyl-2-methyl benzimidazole, N-tert-buthoxycarbonyl-2-phenyl benzimidazole, formamide, N-methyl formamide, N,N-dimethyl formamide, acetamide, N-methyl acetamide, N,N-dimethyl acetamide, propionamide, benzamide, pyrrolidone, and N-methylpyrrolidone.

Specific examples of urea compounds cited as an acid-diffusion suppressor include urea, methyl urea, 1,1-dimethyl urea, 1,3-dimethyl urea, 1,1,3,3-tetramethyl urea, 1,3-diphenyl urea, and tri-n-butyl thiourea.

Specific examples of nitrogen-containing heterocyclic compounds cited as an acid-diffusion suppressor include imidazole, 4-methyl imidazole, 4-methyl-2-phenyl imidazole, benzimidazole, 2-phenyl benzimidazole, pyridine, 2-methyl pyridine, 4-methylpyridine, 2-ethyl pyridine, 4-ethyl pyridine, 2-phenyl pyridine, 4-phenyl pyridine, 2-methyl-4-phenyl pyridine, nicotine, nicotinic acid, nicotinic acid amide, quinoline, 4-hydroxy quinoline, 8-oxy quinoline, acridine, piperadine, 1-(2-hydroxyethyl)piperadine, pyrazine, pyrazole, pyridazine, quinozalin, purine, pyrrolidine, piperidine, 3-piperidino-1,2-propanediol, morpholine, 4-methyl morpholine, 1,4-dimethyl piperadine, and 1,4-diazabicyclo[2.2.2]octane.

The acid-diffusion suppressor may be used independently or in a combination of two or more. The blending amount of the acid-diffusion suppressor is preferably 0.1 to 1000 parts by mass relative to 100 parts by mass of the photo-inductive acid-generating material. More preferable blending amount of the acid-diffusion suppressor is 0.5 to 10 parts by mass relative to 100 parts by mass of the photo-inductive acid-generating material. Here, there is no particular restriction in the blending amount of the acid-diffusion suppressor and the amount may be appropriately chosen according to purpose.

Examples of surfactant contained in the resist composition include a polyoxyethylene alkyl ether, a polyoxyethylene alkyl aryl ether, a sorbitan fatty acid ester, a nonionic surfactant of a polyoxyethylene sorbitan fatty acid ester, a fluoro-surfactant, and a silicon-surfactant. There is no particular restriction in the surfactant contained in the resist composition provided the surfactant is a component exhibiting improved functions in coating properties, striation, developing properties, and the like, and may be appropriately selected from commonly known surfactants according to purpose.

Specific examples of polyoxyethylene alkyl ethers cited as a surfactant contained in the resist composition include polyoxyethylene lauryl ether, polyoxyethylene stearyl ether, polyoxyethylene cetyl ether, and polyoxyethylene oleyl ether. Specific examples of polyoxyethylene alkyl aryl ethers cited as the surfactant contained in the resist composition include polyoxyethylene octylphenol ether and polyoxyethylene nonylphenol ether.

Specific examples of sorbitan fatty acid esters cited as the surfactant contained in the resist composition include sorbitan monolaurate, sorbitan monopalmitate, sorbitan monostearate, sorbitan monooleate, sorbitan trioleate, and sorbitan tristearate. Specific examples of the nonionic surfactant of the polyoxyethylene sorbitan fatty acid ester cited as the surfactant contained in the resist composition include polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate.

Specific examples of the fluoro-surfactant cited as the surfactant contained in the resist composition include EFTOP EF301, EF303, and EF352 (manufactured by Shin Akita Kasei Co., Ltd.), MEGAFAC F171, F173, F176, F189, and R08 (manufactured by DIC Corp.), Fluorade FC430 and FC431 (manufactured by Sumitomo 3M Ltd.), and Asahi Guard AG710. Surflon S-382, SC101, SX102, SC103, SC104, SC105, and SC106 (manufactured by Asahi Glass Co. Ltd.).

Specific examples of silicon-surfactants cited as the surfactant contained in the resist composition include organosiloxane polymer KP341 (manufactured by Shin-Etsu Chemical Co. Ltd.). Various kinds of the surfactant cited above may be used independently or in a combination of two or more. The blending amount of the various kinds of surfactant is preferably, for example, 0.0001 to 5 parts by mass relative to 100 parts by mass of the hyperbranched polymer formed by the synthesis method of the present invention.

More preferably, the blending amount of the various kinds of the surfactant is 0.0002 to 2 parts by mass relative to 100 parts by mass of the hyperbranched polymer formed by the synthesis method of the present invention. There is no particular restriction in the blending amount of the various kinds of surfactant and the amount may be appropriately chosen according to purpose.

Examples of other components contained in the resist composition include a sensitizer, a dissolution-control material, an additive having an acid-dissociating group, a resin that is dissolvable in a basic solution, a dye, a pigment, an adhesive adjuvant, a defoamer, a stabilizer, and an anti-halation agent. Specific examples of sensitizers cited as other components contained in the resist composition include acetophenones, benzophenones, naphthalenes, biacetyl, eosin, rose bengal, pyrenes, anthracenes, and phenothiazines.

There is no particular restriction in the sensitizer provided the sensitizer absorbs the energy of radioactive ray and transmits the energy to the photo-inductive acid-generating material, thereby increasing the amount of acid generated and effecting an apparent sensitivity of the resist composition. The sensitizers may be used independently or in a combination of two or more.

Specific examples of dissolution-control materials cited as other components contained in the resist composition include a polyketone and a polyspiroketal. There is no particular restriction in the dissolution-control material cited as other components contained in the resist composition provided the material appropriately controls the dissolution contrast and the dissolution rate when the resist is formed. The dissolution-control materials cited as other components contained in the resist composition may be used independently or in a combination of two or more.

Specific examples of additives having the acid-dissociation group cited and as other components contained in the resist composition include tert-butyl 1-adamantanecarboxylate, tert-buthoxycarbonylmethyl 1-adamantanecarboxylate, di-tert-butyl 1,3-adamantanedicarboxylate, tert-butyl 1-adamantaneacetate, tert-buthoxycarbonylmethyl 1-adamantaneacetate, di-tert-butyl 1,3-adamantanediacetate, tert-butyl deoxycholate, tert-buthoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, mevalonolactone deoxycholate, tert-butyl lithocholate, tert-buthoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate. The various kinds of additive having an acid-dissociating group as described above may be used independently or in a combination of two or more. There is no particular restriction in the various kinds of additive having an acid-dissociating group provided the additive further improves the dry-etching resistance, pattern formation, adhesion with a substrate, and the like.

Specific examples of resin dissolvable in a basic solution cited as other components contained in the resist composition include poly(4-hydroxystyrene), partially hydrogenated poly(4-hydroxystyrene), poly(3-hydroxystyrene), 4-hydroxystyrene/3-hydroxystyrene copolymer, 4-hydroxystyrene/styrene copolymer, novolak resin, poly(vinyl alcohol), and poly(acrylic acid).

The weight-average molecular weight (Mw) of the resin that is dissolvable in a basic solution is usually 1,000 to 1,000,000, and preferably 2,000 to 100,000. The resin dissolvable in a basic solution may be used independently or in a combination of two or more. There is no particular restriction in the resin dissolvable in a basic solution cited as other components contained in the resist composition provided the resin improves the solubility of the resin composition of the present invention into a basic solution.

The dye or the pigment cited as other components contained in the resist composition visualizes a latent image in the exposed part. By visualizing a latent image in the exposed part, the effect of a halation during exposure to a light may be reduced. The adhesive adjuvant cited as other components contained in the resist composition may improve adhesion between the resist composition and a substrate.

Specific examples of solvents cited as other components contained in the resist composition include a ketone, a cyclic ketone, a propyleneglycol monoalkyl ether acetate, an alkyl 2-hydroxypropionate, an alkyl 3-alkoxypropionate, and other solvents. There is no particular restriction in the solvent cited as other components contained in the resist composition provided the solvent can dissolve the other components and the like contained in the resist composition, and the solvent may be appropriately selected from solvents safely usable.

Specific examples of ketones cited as other components contained in the resist composition include methyl isobutyl ketone, methyl ethyl ketone, 2-butanone, 2-pentanone, 3-methyl-2-butanone, 2-hexanone, 4-methyl-2-pentanone, 3-methyl-2-pentanone, 3,3-dimethyl-2-butanone, 2-heptanone, and 2-octanone.

Specific examples of the cyclic ketone contained in the solvent cited as other components contained in the resist composition include cyclohexanone, cyclopentanone, 3-methyl cyclopentanone, 2-methyl cyclohexanone, 2,6-dimethyl cyclohexanone, and isophorone.

Specific examples of the propyleneglycol monoalkyl ether acetate included in the solvent cited as other components contained in the resist composition include propyleneglycol monomethyl ether acetate, propyleneglycol monoethyl ether acetate, propyleneglycol mono-n-propyl ether acetate, propyleneglycol mono-1-propyl ether acetate, propyleneglycol mono-n-butyl ether acetate, propyleneglycol mono-i-butyl ether acetate, propyleneglycol mono-sec-butyl ether acetate, and propyleneglycol mono-tert-butyl ether acetate.

Specific examples of the alkyl 2-hydroxypropionate included in the solvent cited as other components contained in the resist composition include methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate, and tert-butyl 2-hydroxypropionate.

Specific examples of the alkyl 3-alkoxypropionate included in the solvent cited as other components contained in the resist composition include methyl 3-methoxypropionate, ethyl 3-methoxypropionate, methyl 3-ethoxypropionate, and ethyl 3-ethoxypropionate.

Examples of the other solvents contained in the solvent cited as other components contained in the resist composition include n-propyl alcohol, i-propyl alcohol, n-butyl alcohol, tert-butyl alcohol, cyclohexanol, ethyleneglycol monomethyl ether, ethyleneglycol monoethyl ether, ethyleneglycol mono-n-propyl ether, ethyleneglycol mono-n-butyl ether, diethyleneglycol dimethyl ether, diethyleneglycol diethyl ether, diethyleneglycol di-n-propyl ether, diethyleneglycol di-n-butyl ether, ethyleneglycol monomethyl ether acetate, ethyleneglycol monoethyl ether acetate, ethyleneglycol mono-n-propyl ether acetate, propyleneglycol, propyleneglycol monomethyl ether, propyleneglycol monoethyl ether, propyleneglycol mono-n-propyl ether, ethyl 2-hydroxy-2-methylpropionate, ethyl ethoxyacetate, ethyl hydroxyacetate, methyl 2-hydroxy-3-methyl lactate, 3-methoxybutyl acetate, 3-methyl-3-methoxybutyl acetate, 3-methyl-3-methoxybutyl propionate, 3-methyl-3-methoxybutyl butyrate, ethyl acetate, n-propyl acetate, n-butyl acetate, methyl acetoacetate, ethyl acetoacetate, methyl pilvate, ethyl pilvate, N-methyl pyrrolidone, N,N-dimethyl formamide, N,N-dimethyl acetamide, benzyl ethyl ether, di-n-hexyl ether, ethyleneglycol monomethyl ether, diethyleneglycol monoethyl ether, γ-butyrolactone, toluene, xylene, caproic acid, caprylic acid, octane, decane, 1-octanol, 1-nonanol, benzyl alcohol, benzyl acetate, ethyl benzoate, diethyl oxalate, diethyl maleate, ethylene carbonate, and propylene carbonate. These solvents may be used singly or in a combination of equal to or more than two kinds.

As described above, according to the method of synthesizing the core-shell hyperbranched polymer of the embodiment, after the acid group is formed by deprotection, the liquid-liquid extraction is carried out by using an organic solvent containing the core-shell hyperbranched polymer dissolved after the acid group is formed and ultrapure water, the amount of which is to give a prescribed ratio of the ultrapure water to the organic solvent. Thus, the amount of the ultrapure water can be reduced relative to the organic solvent dissolving the core-shell hyperbranched polymer obtained after the acid group is formed.

Thus, an increase in the amount of the water layer (waste effluent) containing dissolved impure substances by the liquid-liquid extraction accompanying an increase in the scale of the synthesis can be suppressed without causing difficulty in dissolving impure substances into the water layer at the liquid-liquid extraction. Accordingly, the core-shell hyperbranched polymer can be synthesized stably and in large quantities with an aim to reduce the waste effluent associated with an increase in the scale of the synthesis.

According to the method of synthesizing the core-shell hyperbranched polymer of the embodiment, when the liquid-liquid extraction is carried out with the volume ratio of the ultrapure water to the organic solvent in the deprotection at such a range as ultrapure water/organic solvent=0.1/1 to 1/0.1, an increase in the amount of the water layer (waste effluent) containing dissolved impure substances by the liquid-liquid extraction accompanying an increase in the scale of the synthesis can be suppressed without causing difficulty in dissolving impure substances into the water layer at the liquid-liquid extraction. Accordingly, the core-shell hyperbranched polymer can be synthesized stably and in large quantities with an aim to reduce the waste effluent associated with an increase in the scale of the synthesis.

According to the method of synthesizing the core-shell hyperbranched polymer of the embodiment, when the liquid-liquid extraction is carried out with the volume ratio of the ultrapure water to the organic solvent in the deprotection at such a range as ultrapure water/organic solvent=0.5/1 to 1/0.5, an increase in the amount of the water layer (waste effluent) containing dissolved impure substances at the liquid-liquid extraction accompanying an increase in the scale of the synthesis can be suppressed without causing difficulty in dissolving impure substances into the water layer by the liquid-liquid extraction. Accordingly, the core-shell hyperbranched polymer can be synthesized stably and in large quantities with an aim to ensure reduction of the waste effluent associated with an increase in the scale of the synthesis.

According to the core-shell hyperbranched polymer of the embodiment, the core-shell hyperbranched polymer can be obtained stably and in large quantities without an increase in the waste effluent accompanying an increase in the scale of the synthesis, because the core-shell hyperbranched polymer is produced by the above-mentioned method of synthesizing the core-shell hyperbranched polymer.

According to the resist composition of the embodiment, when the core-shell hyperbranched polymer is included, the resist composition containing the core-shell hyperbranched polymer having a desired molecular weight and degree of branching can be stably obtained.

According to the semi-conductor integrated circuit of the embodiment, when a pattern is formed by using the resist composition above, a fine semi-conductor integrated circuit having stable performance and supporting an electron beam, a deep ultraviolet beam (DUV), and an extreme ultraviolet beam (EUV) can be obtained.

According to the semi-conductor integrated circuit of the embodiment, when a process for forming a pattern by using the resist composition above is included in fabrication, a fine semi-conductor integrated circuit having stable performance and supporting an electron beam, a deep ultraviolet beam (DUV), and an extreme ultraviolet beam (EUV) can be obtained.

The resist composition containing the core-shell hyperbranched polymer of the embodiment may be treated for the patterning treatment by development after exposure to a light in a patterned form. The resist composition may support an electron beam, a deep ultraviolet beam (DUV), and an extreme ultraviolet beam (EUV), which require a surface smoothness of a nanometer level, thereby enabling formation of a fine pattern for manufacturing a semi-conductor integrated circuit. Thus, the resist composition containing the core-shell hyperbranched polymer formed by the synthesis method of the present invention can be used suitably in various fields using a semi-conductor integrated circuit produced by using a light source irradiating a short wavelength light.

In the semi-conductor integrated circuit produced by using the resist composition containing the core-shell hyperbranched polymer of the embodiment, when the semi-conductor integrated circuit is exposed to light, is heated, dissolved in a basic developing solution, and then washed by water and the like during production, substantially no undissolved residues remained on an exposed part, and thus, a nearly vertical edge can be obtained.

### EXAMPLES

In the following, the embodiments of the present invention as described above will be clarified concretely by the following examples. However, the following examples shall in no way limit the interpretation of the present invention.

### (Weight-Average Molecular Weight (Mw))

The weight-average molecular weight (Mw) of the core portion in the core-shell hyperbranched polymer of an example will be explained. The weight-average molecular weight (Mw) of the core portion in the core-shell hyperbranched polymer of the example was obtained by a GPC (Gel Permeation Chromatography) measurement using a tetrahydrofuran solution (0.5% by mass) at 40° C., a GPC HLC-8020 type instrument and two TSKgel HXL-M columns (manufactured by Tosoh Corporation) connected in series. In the GPC measurement, tetrahydrofuran was used as a moving phase and styrene was used as a standard material.

### (Degree of Branching (Br))

The degree of branching (Br) of the core portion in the core-shell hyperbranched polymer in examples will be explained. The degree of branching (Br) was obtained by measuring ¹H-NMR of the product. Namely, the degree of branching (Br) of the core portion in the core-shell hyperbranched polymer in examples was calculated by computing equation (A) by using H1°, an integral ratio of protons in —CH₂Cl appearing at 4.6 ppm, and H2°, an integral ratio of the protons in —CHCl appearing at 4.8 ppm. Here, when the polymerization progresses at both —CH₂Cl and —CHCl thereby enhancing the branching, the degree of branching (Br) approaches 0.5.

### (Core/Shell Ratio)

The core/shell ratio of the core-shell hyperbranched polymer in examples will be explained. The core/shell ratio was obtained by measuring ¹H-NMR of the product. Namely, the core/shell ratio of the core-shell hyperbranched polymer in examples was calculated by using the integral ratio of protons appearing at 1.4 to 1.6 ppm assignable to the tert-butyl group and the integral ratio of the protons appearing at near 7.2 ppm assignable to the aromatic group.

### (Ultrapure Water)

Ultrapure water used to synthesize the core-shell hyperbranched polymer in examples will be explained. The ultrapure water, containing 1 ppb or less of metals at 25° C. and having a specific resistance of 18 MΩ·cm, used to synthesize the core-shell hyperbranched polymer in examples is made by using GSR-200 equipment (manufactured by Advantec Toyo Kaisha. Ltd.).

Synthesis of the hyperbranched core polymer in examples was carried out as follows (in a temperature-controlled room at 25° C.) with reference to the synthesis method described by Krzysztof Matyjaszewski. Macromolecules, 29, 1079 (1996) and by Jean M. J. Frecht, J. Poly. Sci., 36, 955 (1998).

### First Example

### Synthesis of Hyperbranched Core Polymer

Synthesis of the hyperbranched core polymer of a first example will be explained. Into a four-necked reaction vessel (1 liter volume) equipped with an agitator and a cooling column 46.0 g of weighed 2,2′-bipyridyl and 15.0 g of copper (I) chloride were added, and then the system was fully degassed an in a vacuum state. Under an argon gas atmosphere, 400 mL of chlorobenzene (reaction solvent) was added to the reaction vessel, followed by a drop-wise addition of 90.0 g of chloromethyl styrene for 5 minutes. The resulting mixture was heated at a constant internal temperature of 125° C. and agitated. The total reaction time including the drop-wise addition was 27 minutes.

After the reaction, undissolved matter was removed by filtration, and then 500 mL of an aqueous oxalic acid solution (3% by mass) prepared by using ultrapure water was added into the filtrate. The resulting solution was agitated for 20 minutes and then a water layer was removed. These operations were repeated four times to remove the copper reaction catalyst. To the solution resulting after removal of the copper, 700 mL of methanol was added to re-precipitate a polymer. The obtained polymer was washed by 500 mL of a mixed solvent of THF/methanol=2/8 (by volume), and then the solvent was removed by decantation. This washing operation was repeated two times, and 46.8 g of a purified hyperbranched core polymer was obtained after drying. The yield, the weight-average molecular weight (Mw), and the degree of branching (Br) were 72%, 2,000, and 0.5, respectively.

### (Synthesis of Core-Shell Hyperbranched Polymer)

The synthesis of the core-shell hyperbranched polymer of first example will be explained. Into a four-necked reaction vessel (1 liter volume) equipped with an agitator and a cooling column, 10 g of the hyperbranched core polymer, 5.1 g of 2,2′-bipyridyl, and 1.6 g of copper (I) chloride were added, and then the system was fully degassed under a vacuum. Under an argon gas atmosphere, 250 mL of chlorobenzene (reaction solvent) was added to the system, followed by an addition of 48 mL of tert-butyl acrylate by syringe. The resulting mixture was heated at 120° C. and agitated for 5 hours.

After the polymerization, undissolved matter was removed by filtration, and then 300 mL of an aqueous oxalic acid solution (3% by mass) prepared by using ultrapure water was added to the filtered solution. The resulting mixture was agitated for 20 minutes and then a water layer was removed. This operation was repeated four times to remove the copper reaction catalyst. The obtained pale-yellow solution was distilled to remove the solvent, and then 700 mL of methanol was added to re-precipitate a polymer. The obtained polymer was dissolved in 50 mL of THF, and then 500 mL of methanol was added to re-precipitate the polymer. This re-precipitation operation was repeated two times, and 17.1 g of a purified core-shell hyperbranched polymer with a pale-yellow color was obtained after drying. The yield was 76%. The core/shell ratio of the copolymer calculated by the 1H-NMR was 4/6 by mol.

### (Removal of Trace Metal)

Removal of trace metal in the first example will be explained. A solution acquired by dissolving 6 g of the core-shell hyperbranched polymer into 100 g of chloroform was mixed with 100 g of an aqueous oxalic acid solution (3% by mass) prepared using ultrapure water and agitated vigorously for 30 minutes. An organic layer was extracted and the organic layer was again mixed with 100 g of the aqueous oxalic acid solution (3% by mass) prepared using ultrapure water and agitated vigorously for 30 minutes. After these operations were repeated five times, the operations of agitating the solution vigorously for 30 minutes with 10 g of an aqueous hydrochloric acid solution (3% by mass), extracting the organic layer, subsequently adding 100 g of ultrapure water thereto and vigorously agitating for 30 minutes, and extracting the organic layer were repeated three times. The organic solvent in the finally obtained organic layer was removed by distillation, and the remaining substance was dried. Measurement of atomic absorption indicated copper, sodium, iron, and aluminum in amounts of 20 ppb or less.

### (Deprotection)

Deprotection in the first example will be explained. Into a reaction vessel equipped with a reflux condenser, 2.0 g of the core-shell hyperbranched polymer obtained after trace metal was removed, 98.0 g of dioxane, and 3.5 g of hydrochloric acid (30% by mass) were added, and then the resulting mixture was refluxed with agitation for 60 minutes at 90° C. Thereafter, a resulting crude product was poured into 980 mL of ultrapure water to obtain a re-precipitated solid component. The solid component was dissolved in 50 mL of methyl isobutyl ketone, 50 mL of the ultrapure water was added thereto, and the resulting solution was agitated vigorously at room temperature for 30 minutes. After the water layer was separated, 50 mL of the ultrapure water was added again, and then the resulting mixture was agitated vigorously at room temperature for 30 minutes, and then the water layer was separated. The methyl isobutyl ketone solution was evaporated under a reduced pressure and dried to obtain 1.3 g of a polymer. The yield was 71%. The ratio of the acid-decomposable group to the acid group was 70/30.

### Second Example of Synthesis of Hyperbranched Core Polymer

Synthesis of the hyperbranched core polymer of a second example will be explained. Into a four-necked reaction vessel (1 liter volume) equipped with an agitator and a cooling column, 54.6 g of weighed tributylamine and 18.7 g of iron (II) chloride were added, and then the entire reaction system including the reaction vessel was fully degassed under a vacuum. Then, under an argon gas atmosphere, 430 mL of chlorobenzene (reaction solvent) was added, followed by a drop-wise addition of 90.0 g of chloromethyl styrene for 5 minutes. After the drop-wise addition, the reaction system was heated at a constant internal temperature of 125° C. and agitated. The total reaction time including the drop-wise addition was 27 minutes.

After the reaction, 500 mL of an aqueous oxalic acid solution (3% by mass) prepared using ultrapure water was added and the resulting solution was agitated for 20 minutes. Subsequently, a water layer was removed. This operation was repeated four times to remove the iron reaction catalyst. To the solution resulting after removal of the iron, 700 mL of methanol was added to re-precipitate a polymer. The obtained polymer was washed by 1200 mL of a mixed solvent of THF/methanol=2/8 (by volume), and then the solvent was removed by decantation. Subsequently, 500 mL of a mixed solvent of THF:methanol=2:8 (volume ratio) was added, the polymer was washed and after the solvent was removed by decantation, the polymer was dried to obtain 72 g of the hyperbranched core polymer of second example. The yield was 80%. The weight-average molecular weight (Mw) and the degree of branching (Br) were 2000 and 0.5, respectively.

### (Synthesis of Core-Shell Hyperbranched Polymer)

The synthesis of the core-shell hyperbranched polymer of the second example will be explained. Into a four-necked reaction vessel (1 liter volume) equipped with an agitator and a cooling column, 10 g of the hyperbranched core polymer, 6.1 g of tributylamine and 2.1 g of iron (II) chloride were added, and then the system was fully degassed under a vacuum. Under an argon gas atmosphere, 260 mL of chlorobenzene (reaction solvent) was added to the system, followed by an addition of 48 mL of tert-butyl acrylate by syringe. The resulting mixture was heated at 120° C. and agitated for 5 hours.

After the polymerization, 300 mL of an aqueous oxalic acid solution (3% by mass) prepared using ultrapure water was added to the filtered solution. The resulting mixture was agitated for 20 minutes and then a water layer was removed. This operation was repeated four times to remove the iron reaction catalyst. To the solution, from which the iron catalyst has been removed, 700 mL of methanol was added to re-precipitate a polymer. The obtained polymer was dissolved in 50 mL of THF, and then 500 mL of methanol was added to re-precipitate the polymer. This re-precipitation operation was repeated two times. Subsequently, 22 g of a purified core-shell hyperbranched polymer according to the second example was obtained after drying. The yield was 74%. The core/shell ratio of the copolymer calculated by the 1H-NMR was 3/7 by mol.

### (Removal of Trace Metal)

Removal of trace metal in the second example will be explained. A solution acquired by dissolving 6 g of the core-shell hyperbranched polymer into 100 g of chloroform was mixed with 100 g of an aqueous oxalic acid solution (3% by mass) and 50 g of an aqueous hydrochloric acid solution (1% by mass) prepared using ultrapure water, and agitated vigorously for 30 minutes. An organic layer was extracted and the organic layer was again mixed with 50 g of the aqueous oxalic acid solution (3% by mass) and 50 g of an aqueous hydrochloric acid solution (1% by mass) prepared using ultrapure water, and agitated vigorously for 30 minutes. After these operations were repeated five times, operations of extracting the organic layer, subsequently adding 100 g of ultrapure water thereto and agitating the solution vigorously for 30 minutes, and extracting the organic layer thereafter were repeated three times. The organic solvent in the finally obtained organic layer was removed by distillation, and the remaining substance was dried. Measurement of atomic absorption indicated sodium, iron, and aluminum in amounts of 20 ppb or less.

### (Deprotection)

Deprotection in the second example will be explained. Into a reaction vessel equipped with a reflux condenser, 2.0 g of the core-shell hyperbranched polymer obtained after trace metals were removed, 98.0 g of dioxane, and 3.5 g of hydrochloric acid (30% by mass) were added, and then the resulting mixture was refluxed with agitation for 60 minutes at 90° C. Thereafter, a resulting crude product was poured into 980 mL of ultrapure water to obtain a re-precipitated solid component. The solid component was dissolved in 50 mL of ethyl acetate, 50 mL of the ultrapure water was added thereto, and the resulting solution was agitated vigorously at room temperature for 30 minutes. After the water layer was separated, ethyl acetate was added so that the total ethyl acetate was 50 mL, 50 mL of the ultrapure water was added, and then the resulting mixture was agitated vigorously at room temperature for 30 minutes, and then the water layer was separated. The ethyl acetate solution was evaporated under a reduced pressure and dried to obtain 1.2 g of a polymer. The yield was 66%. The ratio of the acid-decomposable group to the acid group was 70/30.

### First Reference Example

### Synthesis of 4-Vinylbenzoic Acid Tert-Butyl Ester

The synthesis was carried out with reference to Synthesis, 833-834 (1982). Into a reaction vessel (1 liter volume) equipped with a dropping funnel, under an argon atmosphere, 91 g of 4-vinyl benzoic acid, 99.5 g of 1,1′-carbodimidazole, 2.4 g of 4-tert-butyl pyrocathecol, and 500 g of dehydrated dimethyl formamide were added, and the resulting solution was agitated for one hour at a constant temperature of 30° C. Thereafter, 93 g of 1,8-diazabicyclo[5.4.0]-7-undecene and 91 g of dehydrated 2-methyl-2-propanol was added, and the resulting mixture was agitated for 4 hours. After the reaction, 300 mL of diethyl ether and an aqueous potassium carbonate solution (10%) were added thereto, and then an intended substance was extracted to an ether layer. Thereafter, the diethyl ether layer was dried under reduced pressure to obtain acrylic acid tert-butyl ester with a pale yellow color. It was confirmed by 1H-NMR that the intended substance was obtained. The yield was 88%.

### Third Example

### Synthesis of Hyperbranched Core Polymer

Synthesis of the hyperbranched core polymer of a third example will be explained. Into a four-necked reaction vessel (1 liter volume) equipped with an agitator and a cooling column 25.5 g of pentamethyl diethylene triamine and 15.0 g of copper (I) chloride were added, and then the system was fully degassed an in a vacuum state. Under an argon gas atmosphere, 460 mL of chlorobenzene (reaction solvent) was added to the reaction vessel, followed by a drop-wise addition of 90.0 g of chloromethyl styrene for 5 minutes. The resulting mixture was heated at a constant internal temperature of 125° C. and agitated. The total reaction time including the drop-wise addition was 27 minutes.

After the reaction, undissolved matter was removed by filtration, and then 500 mL of an aqueous oxalic acid solution (3% by mass) prepared by using ultrapure water was added into the filtrate. The resulting solution was agitated for 20 minutes and then a water layer was removed. These operations were repeated four times to remove the copper reaction catalyst. To the solution resulting after removal of the copper, 700 mL of methanol was added to re-precipitate a polymer. The obtained polymer was washed by 1200 mL of a mixed solvent of THF/methanol=2/8 (by volume), and then the solvent was removed by decantation. This washing operation was repeated two times, and 64.8 g of the hyperbranched core polymer according to the third example was obtained after drying. The yield, the weight-average molecular weight (Mw), and the degree of branching (Br) were 72%, 2,000, and 0.5, respectively.

### (Synthesis of Core-Shell Hyperbranched Polymer)

The synthesis of the core-shell hyperbranched polymer of the third example will be explained. Into a four-necked reaction vessel (1 liter volume) equipped with an agitator and a cooling column, 10 g of the hyperbranched core polymer, 2.8 g of pentamethyl diethylene triamine and 1.6 g of copper (I) chloride were added, and then the system was fully degassed under a vacuum. Under an argon gas atmosphere, 400 mL of chlorobenzene (reaction solvent) was added to the system, followed by an addition of 40 g of tert-butyl 4-vinylbenzoate by syringe. The resulting mixture was heated at 120° C. and agitated for 3 hours.

After the polymerization, undissolved matter was removed by filtration, and then an aqueous oxalic acid solution (3% by mass) prepared by using ultrapure water was added to the filtered solution. The resulting mixture was agitated for 20 minutes and then a water layer was removed. These operations were repeated four times to remove the copper reaction catalyst. To the solution, from which the copper catalyst has been removed, 700 mL of methanol was added to re-precipitate a polymer. The obtained polymer was dissolved in 50 mL of THF, and then 500 mL of methanol was added to re-precipitate the polymer. This re-precipitation operation was repeated two times, and 20 g of the core-shell hyperbranched polymer according to the third example was obtained after drying. The yield was 48%. The core/shell ratio of the copolymer calculated by the 1H-NMR was 7/3 by mol.

### (Removal of Trace Metal)

Removal of trace metal in the third example will be explained. A solution acquired by dissolving 6 g of the core-shell hyperbranched polymer into 100 g of chloroform was mixed with 100 g of an aqueous oxalic acid solution (3% by mass) and 50 g of an aqueous hydrochloric acid solution (1% by mass) prepared using ultrapure water, and agitated vigorously for 30 minutes. An organic layer was extracted and the organic layer was again mixed with 50 g of the aqueous oxalic acid solution (3% by mass) and 50 g of an aqueous hydrochloric acid solution (1% by mass) prepared using ultrapure water, and agitated vigorously for 30 minutes. After these operations were repeated five times, the organic layer was extracted, subsequently 100 g of ultrapure water was added thereto and the solution was agitated vigorously for 30 minutes. The operations of extracting the organic layer, subsequently adding 100 g of ultrapure water thereto and agitating the solution vigorously for 30 minutes, and extracting the organic layer thereafter were repeated three times. The organic solvent in the finally obtained organic layer was removed by distillation, and the remaining substance was dried. Measurement of atomic absorption indicated copper, sodium, iron, and aluminum in amounts of 20 ppb or less.

### (Deprotection)

Deprotection in the third example will be explained. Into a reaction vessel equipped with a reflux condenser, 2.0 g of the core-shell hyperbranched polymer obtained after trace metal was removed, 98.0 g of dioxane, and 3.5 g of hydrochloric acid (30% by mass) were added, and then the resulting mixture was refluxed with agitation for 60 minutes at 90° C. Thereafter, a resulting crude product was poured into 980 mL of ultrapure water to obtain a re-precipitated solid component. The solid component was dissolved in 50 mL of methyl isobutyl ketone, 50 mL of the ultrapure water was added thereto, and the resulting solution was agitated vigorously at room temperature for 30 minutes. After the water layer was separated, 50 mL of the ultrapure water was added again, and then the resulting mixture was agitated vigorously at room temperature for 30 minutes, and then the water layer was separated. The methyl isobutyl ketone solution was evaporated under a reduced pressure and dried to obtain 1.6 g of the core-shell hyperbranched polymer. The yield was 74%. The ratio of the acid-decomposable group to the acid group was 70/30.

### Fourth Example

### Synthesis of Hyperbranched Core Polymer

The hyperbranched core polymer of a fourth example will be explained. The hyperbranched core polymer of the fourth example was synthesized in the following way. Firstly, 11.8 g of 2,2′-bipyridyl, 3.5 g of copper (I) chloride, and 345 mL of benzonitrile were charged into a four-necked flask (1 liter volume), which was then assembled with a dropping funnel containing 54.2 g of weighed chloromethyl styrene, a cooling column, and an agitator. The inside of the entire reaction equipment thus assembled was degassed and replaced with an argon gas. After the argon-replacement, the resulting mixture was heated at 125° C., and then chloromethyl styrene was added drop-wise thereto for 30 minutes. The heating with agitation continued for 3.5 hours after the drop-wise addition. The reaction time including the drop-wise addition of chloromethyl styrene into the reaction vessel was 4 hours.

After the reaction, the reaction solution was filtered through filter paper having a retaining particle size of 1 μm. Then, the filtered solution was poured into a pre-mixed solution of 844 g of methanol and 211 g of the ultrapure water to re-precipitate poly(chloromethyl styrene).

After 29 g of the polymer obtained by the re-precipitation was dissolved in 100 g of benzonitrile, a mixed solution of 200 g of methanol and 50 g of the ultrapure water was added to the resulting solution. After centrifugal separation, the solvents were removed by decantation to recover the polymer. This recovery operation was repeated three times to obtain a deposited polymer.

After the decantation, the precipitated product was dried under a reduce pressure to obtain 14.0 g of poly(chloromethyl styrene). The yield was 26%. The weight-average molecular weight (Mw) of the polymer obtained by GPC measurement (polystyrene equivalent) was 1140, and the degree of branching (Br) obtained by the 1H-NMR measurement was 0.51.

### (Synthesis of Core-Shell Hyperbranched Polymer)

The core-shell hyperbranched polymer of the fourth example will be explained. The core-shell hyperbranched polymer of the fourth example was synthesized by using the hyperbranched core polymer above. Into a four-necked reaction vessel (volume of 500 mL) under an argon atmosphere and containing 1.6 g of copper (I) chloride, 5.1 g of 2,2′-bipyridyl, and 10.0 g of the hyperbranched core polymer, 248 mL of monochlorobenzene and 48 mL of tert-butyl acrylate were charged by syringe, respectively. Subsequently, the mixture in the reaction vessel was heated at 125° C. and agitated for 5 hours.

### (Removal of Trace Metal)

Removal of trace metal in the fourth example will be explained. After the termination of the polymerization reaction carried out by heating with agitation as described above, the reaction system resulting after the termination of the polymerization reaction was filtered to remove undissolved matter. Subsequently, to 308 g of the filtered solution obtained by the filtration, 615 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 62.5 g of a concentrated solution was obtained. To the resulting concentrated solution, 219 g of methanol and then 31 g of ultrapure water were added to precipitate a solid component. After the solid component obtained by precipitation was dissolved into 20 g of THF, 200 g of methanol and 29 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 23.8 g. The mol fraction of the copolymer (the core-shell hyperbranched polymer having the formed shell portion) was calculated from 1H-NMR. The core/shell mol ratio of the core-shell hyperbranched polymer having the formed shell portion was 30/70.

### (Deprotection)

The partial decomposition of the acid-decomposable group in the fourth example will be explained. In the partial decomposition of the acid-decomposable group in the fourth example, firstly 2.0 g of the copolymer (the core-shell hyperbranched polymer before the deprotection in fourth example) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 60 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.6 g of the polymer was obtained. The ratio of the acid-decomposable group to the acid group was 78/22.

### Fifth Example

### Synthesis of Core-Shell Hyperbranched Polymer

The core-shell hyperbranched polymer of a fifth example will be explained. The core-shell hyperbranched polymer of the fifth example was synthesized by using the hyperbranched core polymer of the fourth example. Into a four-necked reaction vessel (volume of 500 mL) under an argon atmosphere and containing 1.6 g of copper (I) chloride, 5.1 g of 2,2′-bipyridyl, and 10.0 g of the hyperbranched core polymer of the fourth example, 248 mL of monochlorobenzene and 81 mL of tert-butyl acrylate were charged by syringe, respectively. Subsequently, the mixture in the reaction vessel was heated at 125° C. and agitated for 5 hours.

### (Removal of Trace Metal)

Removal of trace metal in the fifth example will be explained. After the termination of the polymerization reaction carried out by heating with agitation as described above, the reaction system resulting after the termination of the polymerization reaction was filtered to remove undissolved matter. Subsequently, to 340 g of the filtered solution obtained by the filtration, 680 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 88.0 g of a concentrated solution was obtained. To the resulting concentrated solution, 308 g of methanol and then 44 g of ultrapure water were added to precipitate a solid component. After the solid component obtained by precipitation was dissolved into 44 g of THF, 440 g of methanol and 63 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 33.6 g. The mol fraction of the copolymer (the core-shell hyperbranched polymer having the formed shell portion) was calculated from 1H-NMR. The core/shell mol ratio of the core-shell hyperbranched polymer having the formed shell portion was 19/81.

### Deprotection

The partial decomposition of the acid-decomposable group in the fifth example will be explained. In the partial decomposition of the acid-decomposable group in the fifth example, firstly 2.0 g of the copolymer (the core-shell hyperbranched polymer before the deprotection in fifth example) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 30 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.6 g of the polymer was obtained. The ratio of the acid-decomposable group to the acid group was 92/8.

### Sixth Example

### Synthesis of Core-Shell Hyperbranched Polymer

The core-shell hyperbranched polymer of a sixth example will be explained. The core-shell hyperbranched polymer of the sixth example was synthesized by using the hyperbranched core polymer of the fourth example. Into a four-necked reaction vessel (volume of 1000 mL) under an argon atmosphere and containing 1.6 g of copper (I) chloride, 5.1 g of 2,2′-bipyridyl, and 10.0 g of the hyperbranched core polymer according to the fourth example, 248 mL of monochlorobenzene and 187 mL of tert-butyl acrylate were charged by syringe, respectively. Subsequently, the mixture in the reaction vessel was heated at 125° C. and agitated for 5 hours.

### (Removal of Trace Metal)

After the termination of the polymerization reaction carried out by heating with agitation as described above, the reaction system resulting after the termination of the polymerization reaction was filtered to remove undissolved matter. Subsequently, to 440 g of the filtered solution obtained by the filtration, 880 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 175 g of a concentrated solution was obtained. To the resulting concentrated solution, 613 g of methanol and then 88 g of ultrapure water were added to precipitate a solid component. After the solid component obtained by precipitation was dissolved into 85 g of THF, 850 g of methanol and 121 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 65.9 g. The mol fraction of the copolymer (the core-shell hyperbranched polymer having the formed shell portion) was calculated from 1H-NMR. The core/shell mol ratio of the core-shell hyperbranched polymer having the formed shell portion was 10/90.

### (Deprotection)

The partial decomposition of the acid-decomposable group in the sixth example will be explained. In the partial decomposition of the acid-decomposable group in the sixth example, firstly 2.0 g of the copolymer (the core-shell hyperbranched polymer before the deprotection in sixth example) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 15 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.7 g of the polymer was obtained. The ratio of the acid-decomposable group to the acid group was 95/5.

### Seventh Example

### Synthesis of Core-Shell Hyperbranched Polymer

The core-shell hyperbranched polymer of a seventh example will be explained. The core-shell hyperbranched polymer of the seventh example was synthesized by using the hyperbranched core polymer of the fourth example. Into a four-necked reaction vessel (volume of 500 mL) under an argon atmosphere and containing 1.6 g of copper (I) chloride, 5.1 g of 2,2′-bipyridyl, and 10.0 g of the hyperbranched core polymer of the fourth example, 248 mL of monochlorobenzene and 14 mL of tert-butyl acrylate were charged by syringe, respectively. Subsequently, the mixture in the reaction vessel was heated at 125° C. and agitated for 5 hours.

### (Removal of Trace Metal)

After the termination of the polymerization reaction carried out by heating with agitation as described above, the reaction system resulting after the termination of the polymerization reaction was filtered to remove undissolved matter. Subsequently, to 285 g of the filtered solution obtained by the filtration, 570 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 32 g of a concentrated solution was obtained. To the resulting concentrated solution, 112 g of methanol and then 16 g of ultrapure water were added to precipitate a solid component. After the solid component obtained by precipitation was dissolved into 16 g of THF, 160 g of methanol and 23 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 12.1 g. The mol fraction of the copolymer (the core-shell hyperbranched polymer having the formed shell portion) was calculated from 1H-NMR. The core/shell mol ratio of the core-shell hyperbranched polymer having the formed shell portion was 61/39.

### (Deprotection)

The partial decomposition of the acid-decomposable group in the seventh example will be explained. In the partial decomposition of the acid-decomposable group in the seventh example, firstly 2.0 g of the copolymer (the core-shell hyperbranched polymer before the deprotection in seventh example) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 150 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.4 g of the polymer was obtained. The ratio of the acid-decomposable group to the acid group was 49/51.

### Eighth Example

### Synthesis of Core-Shell Hyperbranched Polymer

The core-shell hyperbranched polymer of an eighth example will be explained. The core-shell hyperbranched polymer of the eighth example was synthesized by using the hyperbranched core polymer of the fourth example. Into a four-necked reaction vessel (volume of 1000 mL) under an argon atmosphere and containing 0.8 g of copper (I) chloride, 2.6 g of 2,2′-bipyridyl, and 5.0 g of the hyperbranched core polymer of the fourth example, 421 mL of monochlorobenzene and 46.8 g of tert-butyl 4-vinylbenzoate were charged by syringe, respectively. Subsequently, the mixture in the reaction vessel was heated at 125° C. and agitated for 3.5 hours.

### (Removal of Trace Metal)

After the termination of the polymerization reaction carried out by heating with agitation as described above, the reaction system resulting after the termination of the polymerization reaction was filtered to remove undissolved matter. Subsequently, to 490 g of the filtered solution obtained by the filtration, 980 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 41 g of a concentrated solution was obtained. To the resulting concentrated solution, 144 g of methanol and then 21 g of ultrapure water were added to precipitate a solid component. After the solid component obtained by precipitation was dissolved into 21 g of THF, 210 g of methanol and 30 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 15.9 g. The mol fraction of the copolymer (the core-shell hyperbranched polymer having the formed shell portion) was calculated from 1H-NMR. The core/shell mol ratio of the core-shell hyperbranched polymer having the formed shell portion (hereinafter, core-shell hyperbranched polymer) was 29/71.

### (Deprotection)

The partial decomposition of the acid-decomposable group in the eighth example will be explained. In the partial decomposition of the acid-decomposable group in the eighth example, firstly 2.0 g of the copolymer (the core-shell hyperbranched polymer before the deprotection in eighth example) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 180 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.7 g of the polymer was obtained. The ratio of the acid-decomposable group to the acid group was 38/62.

### Ninth Example

### Synthesis of Core-Shell Hyperbranched Polymer

The core-shell hyperbranched polymer of a ninth example will be explained. The core-shell hyperbranched polymer of the ninth example was synthesized by using the hyperbranched core polymer of the fourth example. Into a four-necked reaction vessel (volume of 1000 mL) under an argon atmosphere and containing 1.6 g of copper (I) chloride, 5.1 g of 2,2′-bipyridyl, and 5.0 g of the hyperbranched core polymer of the fourth example, 421 mL of monochlorobenzene and 46.8 g of tert-butyl 4-vinylbenzoate were charged by syringe, respectively. Subsequently, the mixture in the reaction vessel was heated at 125° C. and agitated for 3 hours.

### (Removal of Trace Metal)

After the termination of the polymerization reaction carried out by heating with agitation as described above, the reaction system resulting after the termination of the polymerization reaction was filtered to remove undissolved matter. Subsequently, to 490 g of the filtered solution obtained by the filtration, 980 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 64 g of a concentrated solution was obtained. To the resulting concentrated solution, 224 g of methanol and then 32 g of ultrapure water were added to precipitate a solid component. After the solid component obtained by precipitation was dissolved into 32 g of THF, 320 g of methanol and 46 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 24.5 g. The mol fraction of the copolymer (the core-shell hyperbranched polymer having the formed shell portion) was calculated from 1H-NMR. The core/shell mol ratio of the core-shell hyperbranched polymer having the formed shell portion (hereinafter, core-shell hyperbranched polymer) was 20/80.

### (Deprotection)

The partial decomposition of the acid-decomposable group in the ninth example will be explained. In the partial decomposition of the acid-decomposable group in the ninth example, firstly 2.0 g of the copolymer (the core-shell hyperbranched polymer before the deprotection in ninth example) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 90 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.7 g of the polymer was obtained. The ratio of the acid-decomposable group to the acid group was 71/29.

### Tenth Example

### Synthesis of Core-Shell Hyperbranched Polymer

The core-shell hyperbranched polymer of a tenth example will be explained. The core-shell hyperbranched polymer of the tenth example was synthesized by using the hyperbranched core polymer of the fourth example. Into a four-necked reaction vessel (volume of 1000 mL) under an argon atmosphere and containing 1.6 g of copper (I) chloride, 5.1 g of 2,2′-bipyridyl, and 5.0 g of the hyperbranched core polymer of the fourth example, 530 mL of monochlorobenzene and 60.2 g of tert-butyl 4-vinylbenzoate were charged by syringe, respectively. Subsequently, the mixture in the reaction vessel was heated at 125° C. and agitated for 4 hours.

### (Removal of Trace Metal)

After the termination of the polymerization reaction carried out by heating with agitation as described above, the reaction system resulting after the termination of the polymerization reaction was filtered to remove undissolved matter. Subsequently, to 620 g of the filtered solution obtained by the filtration, 1240 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 130 g of a concentrated solution was obtained. To the resulting concentrated solution, 455 g of methanol and then 65 g of ultrapure water were added to precipitate a solid component. After the solid component obtained by precipitation was dissolved into 65 g of THF, 650 g of methanol and 93 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 50.2 g. The mol fraction of the co-polymer (the core-shell hyperbranched polymer having the formed shell portion) was calculated from 1H-NMR. The core/shell mol ratio of the core-shell hyperbranched polymer having the formed shell portion (hereinafter, core-shell hyperbranched polymer) was 9/91.

### (Deprotection)

The partial decomposition of the acid-decomposable group in the tenth example will be explained. In the partial decomposition of the acid-decomposable group in the tenth example, firstly 2.0 g of the copolymer (the core-shell hyperbranched polymer before the deprotection in tenth example) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 30 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.7 g of the polymer was obtained. The ratio of the acid-decomposable group to the acid group was 92/8.

### Eleventh Example

### Synthesis of Core-Shell Hyperbranched Polymer

The core-shell hyperbranched polymer of an eleventh example will be explained. The core-shell hyperbranched polymer of the eleventh example was synthesized by using the hyperbranched core polymer of the fourth example. Into a four-necked reaction vessel (volume of 300 mL) under an argon atmosphere and containing 0.8 g of copper (I) chloride, 2.6 g of 2,2′-bipyridyl, and 5.0 g of the hyperbranched core polymer of the fourth example, 106 mL of monochlorobenzene and 8.0 g of tert-butyl 4-vinylbenzoate were charged by syringe, respectively. Subsequently, the mixture in the reaction vessel was heated at 125° C. and agitated for 1 hour.

### (Removal of Trace Metal)

After the termination of the polymerization reaction carried out by heating with agitation as described above, the reaction system resulting after the termination of the polymerization reaction was filtered to remove undissolved matter. Subsequently, to 127 g of the filtered solution obtained by the filtration, 254 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 19 g of a concentrated solution was obtained. To the resulting concentrated solution, 67 g of methanol and then 10 g of ultrapure water were added to precipitate a solid component. After the solid component obtained by precipitation was dissolved into 10 g of THF, 100 g of methanol and 14 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 7.3 g. The mol fraction of the co-polymer (the core-shell hyperbranched polymer having the formed shell portion) was calculated from 1H-NMR. The core/shell mol ratio of the core-shell hyperbranched copolymer having the formed shell portion (hereinafter, core-shell hyperbranched polymer) was 60/40.

### (Deprotection)

The partial decomposition of the acid-decomposable group in the eleventh example will be explained. In the partial decomposition of the acid-decomposable group in the eleventh example, firstly 2.0 g of the copolymer (the core-shell hyperbranched polymer before the deprotection in eleventh example) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 240 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.4 g of the polymer was obtained. The ratio of the acid-decomposable group to the acid group was 22/78.

### First Comparative Example

The core-shell hyperbranched polymer before the deprotection, which was synthesized in a similar manner to that of the first example, was collected (2 g), and 98 g of dioxane and 3.5 g of hydrochloric acid (30% by mass) were added thereto. After the resulting mixture was refluxed with agitation at 95° C. for 60 minutes, the obtained crude product was poured into 980 mL of the ultrapure water to obtain a re-precipitated solid component. The solid component was dissolved into 80 mL of dioxane, and 800 mL of ultrapure water was added thereto to re-precipitate the solid component again. The solid component was recovered and dried to obtain 1.2 g of the core-shell hyperbranched polymer of the first comparative example. The yield was 66%. The mol ratio of the acid-decomposable group to the acid group was 70/30.

As indicated by the first to the third examples and in the first comparative example, the amount of waste effluent per unit weight of the polymer in the treatment after the deprotection according to the method of the first comparative example is about two times that in the first to the third examples of the present invention. Also, as indicated by the fourth to the eleventh examples and in the first comparative example, the amount of the waste effluent per unit weight of the polymer in the treatment after the deprotection according to the method of the first comparative example is about 10 times that in the fourth to the eleventh examples of the present invention.

### (Preparation of a Resist Composition)

Solutions of propyleneglycol monomethyl acetate (PEGMEA) containing 4.0% by mass of the respective polymers obtained in the first to the eleventh examples and 0.16% by mass of triphenylsulfonium trifluoromethane sulfonate as the photo-inductive acid-generating material were prepared and filtered through a filter having a pore diameter of 0.45 μm to obtain resist compositions. Each of the resist compositions thus obtained was spin-coated on a silicon wafer, and then heated at 90° C. for one minute to remove the solvent and thus, obtain a thin film having a 100-nanometer thickness.

### (Measurement of Sensitivity to the Ultraviolet Beam Exposure)

As a light source, an ultraviolet beam emitting instrument of an electric discharge tube type DNA-FIX DF-245 (manufactured by ATTO Corp.) was used. A 245 nm wavelength UV beam of was emitted, at varying energies from 0 mJ/cm2 to 50 mJ/cm2, to expose a 10 mm×3 mm rectangular portion of a thin film sample of a 100-nanometer thickness formed on a silicon wafer. After heat-treatment at 110° C. for 4 minutes, the silicon wafer was developed in an aqueous solution of tetramethyl ammonium hydroxide (TMAH, 2.4% by mass) at 25° C. for 2 minutes. After the silicon wafer was washed by water and dried, the film thickness was measured by a thin film measurement instrument F20 (manufactured by Filmetrics Japan. Inc.), and the emission energy at which the film thickness after the development became zero (sensitivity) was measured. The results are indicated in table 1.

TABLE 1

| | Sensitivity |
|---|---|
| | (mJ/cm²) |
| first example | 2 |
| second example | 1 |
| third example | 2 |
| fourth example | 1 |
| fifth example | 1 |
| sixth example | 1 |
| seventh example | 1 |
| eighth example | 3 |
| ninth example | 1 |
| tenth example | 1 |
| eleventh example | 1 |

### <Chapter 2>

In the following, exemplary embodiments of a method of synthesizing a hyperbranched polymer, the hyperbranched polymer, a resist composition, a semi-conductor integrated circuit, and a method of manufacturing the semi-conductor integrated circuit in the present invention will be explained in detail in with reference to the attached drawing.

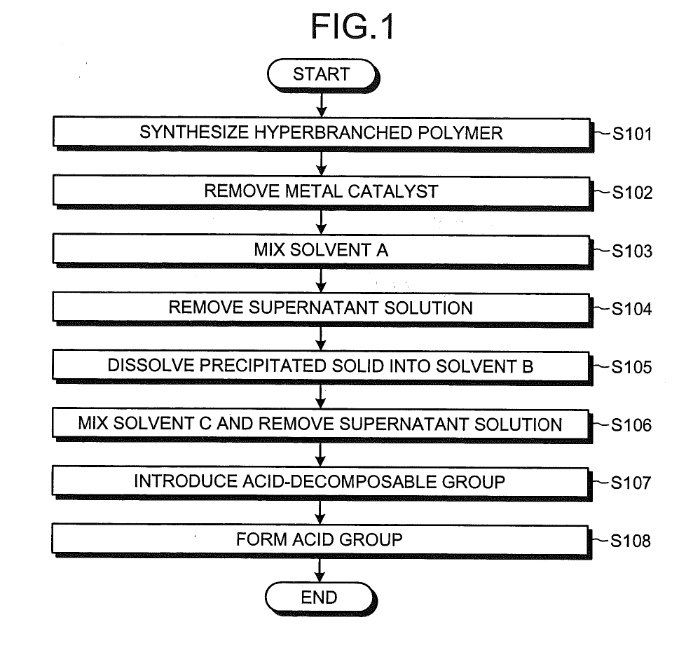

Firstly, a process for synthesizing a hyperbranched polymer of the embodiment of Chapter 2 will be explained. FIG. 1 is a flowchart of the synthesis the hyperbranched polymer of the embodiment. FIG. 1 depicts sequentially steps of synthesizing the hyperbranched polymer according to the method of synthesizing the hyperbranched polymer of the embodiment (hereinafter, hyperbranched polymer).

As depicted in FIG. 1, in the synthesis of the hyperbranched polymer, the hyperbranched polymer is synthesized from a raw material monomers and using a metal catalyst (step S101). The hyperbranched polymer synthesized at step S101 realizes a core portion of a core-shell hyperbranched polymer.

The metal catalyst is removed from the reaction solvent containing the hyperbranched polymer synthesized at step S101 (step S102). Thereafter, solvent A is mixed with the reaction solution resulting after the metal catalyst is removed to precipitate a polymer as a precipitated product (step S103). Thus, a step of forming the precipitated product is realized at step S103.

A supernatant solution of the solution containing the polymer precipitated at step S103 is removed to obtain the hyperbranched polymer (step S104). Depending on circumstances, the precipitated product obtained after the removal of the supernatant solution is dissolved further into solvent B to form a solution containing the dissolved polymer (step S105). Further, thereafter, the hyperbranched polymer may be precipitated by mixing the solution containing the dissolved polymer with solvent C (step S106).

An acid-decomposable group is introduced (step S107) into a core portion of the hyperbranched polymer obtained at step S104 (or step S106), and then a core-shell hyperbranched polymer having the shell portion and the hyperbranched polymer as a core portion is purified.

Thereafter, the acid-decomposable group constituting the shell portion of the purified core-shell hyperbranched polymer is partially decomposed by an acid catalyst to form an acid group (step S108) to synthesize the core-shell hyperbranched polymer having the acid-decomposable group and the acid group in the shell portion, thereby completing a series of treatments.

Each step in the synthesis of the core-shell hyperbranched polymer formed according to the series of steps depicted in FIG. 1 will be explained in detail.

### Synthesis of the Hyperbranched Polymer

Step S101 in FIG. 1 will be explained first. In the synthesis of the hyperbranched polymer at step S101 of FIG. 1, the hyperbranched polymer (the core portion of the core-shell hyperbranched polymer) is synthesized, for example, by a living radical polymerization reaction of raw material monomers in the presence of a metal catalyst in a solvent such as chlorobenzene at 0 to 200° C. and for 0.1 to 30 hours.

The hyperbranched polymer may be synthesized, for example, by a living radical polymerization reaction of raw material monomers in the presence of a metal catalyst in a solvent such as chlorobenzene at 0 to 200° C. and for 0.1 to 30 hours. At step 101, the reaction is stopped, for example, by adding into the reaction system, a solvent having a hydroxy group such as ultrapure water or methanol.

Step S102 in FIG. 3 will be explained next. at step S102 in FIG. 1, the metal catalyst is removed from the solution containing the hyperbranched polymer synthesized at step S101. Specifically, at step S102, for example, the insolubilized metal catalyst is removed by filtering the solution containing the hyperbranched polymer formed at step S101.

At step S102 of FIG. 1, the metal catalyst may also be removed by a liquid-liquid extraction using water-organic solvents. Preferable examples of the organic solvent to be used at step S102 include a halogenated hydrocarbon such as chlorobenzene and chloroform used in the radical living polymerization reaction at step S101. The organic solvent used at step S102 may also be solvent B which will be described later.

### (Precipitation of the Polymer)

Step S103 of FIG. 1 will be explained next. In operation of the polymer precipitation at step S103 of FIG. 1, preferably, a mixed solvent (solvent A) having a solubility parameter 10.5 or more and composed two or more kinds of solvents is used. Examples of solvent independently having a solubility parameter of 10.5 or more include methanol, ethanol, 1-propanol, 2-propanol, glycerin, and water. Solvent A contains these solvents. Specific examples of solvent A include ethyl acetate/methanol, ethyl acetate/ethanol, ethyl acetate/1-propanol, ethyl acetate/2-propanol, ethyl acetate/glycerin, tetrahydrofuran/methanol, tetrahydrofuran/ethanol, tetrahydrofuran/1-propanol, tetrahydrofuran/2-propanol, tetrahydrofuran/glycerin, acetone/methanol, acetone/ethanol, acetone/1-propanol, acetone/2-propanol, acetone/glycerin, methyl ethyl ketone/methanol, methyl ethyl ketone/ethanol, methyl ethyl ketone/1-propanol, methyl ethyl ketone/2-propanol, methyl ethyl ketone/glycerin, methanol/ethanol, methanol/1-propanol, methanol/2-propanol, methanol/glycerin, methanol/water, ethanol/1-propanol, ethanol/2-propanol, ethanol/glycerin, ethanol/water, 1-propanol/2-propanol, 1-propanol/glycerin, 1-propanol/water, 2-propanol/glycerin, 2-propanol/water, and glycerin/water.

Among these, methanol/water, methanol/ethanol, ethanol/water, 1-propanol/water, 2-propanol/water, and glycerin/water are preferable. Water is particularly preferable, the amount of which relative to the total amount of solvent A is preferably 1 to 50% by mass, and more preferably 3 to 40% by mass.

Here, the term “solubility parameter” is an index expressing the polarity of a substance, a value indicating the affinity between a solvent and a resin. When a resin is dissolved in a solvent, the closer the solubility parameters of the solvent and the polymer are, the better the solubility of the polymer in the solvent is. The polarity is higher with a higher SP value indicating the solubility parameter. The SP value is expressed by a square root of CED (Cohesive Energy Density), namely the attraction power between a polymer molecule and a solvent molecule. CED is defined as the energy necessary to evaporate 1 cc of a substance. In the case of a mixed solvent, it can be calculated similarly.

At step S103 of FIG. 1, an excess amount of solvent A relative to the reaction solution is added. Specifically, the amount of solvent A added is preferably 0.2 to 10 parts by volume relative to the reaction solution at step 103. When solvent A is added to the reaction solvent, a viscous polymer with a brown color is deposited in the reaction vessel. Subsequently, a supernatant solution is removed at step S104.

### (Re-Dissolution of the Polymer)

Step S105 of FIG. 1 will be explained next. In the re-dissolution of the polymer at step S105, a solvent having a solubility parameter of 7 to 10.5 is preferably used for solvent B to dissolve the precipitated product resulting after removal of the supernatant solution at step S104.

Specific examples of solvent B include halogenated hydrocarbons, nitro compounds, nitriles, ethers, ketones, esters, carbonates, or a mixture thereof. Specific examples include halogenated hydrocarbons such as chlorobenzene and chloroform; nitro compounds such as nitromethane and nitroethane; nitrile compounds such as acetonitrile and benzonitrile; ethers such as tetrahydrofuran and 1,4-dioxane; ketones such as methyl ethyl ketone, methyl isobutyl ketone, cyclohexanone, 2-heptanone, and 2-pentanone; esters such as ethyl acetate, n-butyl acetate, and isoamyl acetate; ethyleneglycol monoethyl ether acetate, ethyleneglycol monobutyl ether acetate, and ethyleneglycol monomethyl ether acetate.

Solvent B is preferably an ether, in particular tetrahydrofuran may be cited as one of the most preferable. Solvent B is used preferably in a quantity of 0.1 to 10 mL relative to 1 g of the polymer.

### (Removal of Impurities)

At step S104 (or S106) of FIG. 1, impurities such as residual monomer and by-product oligomer are removed. More specifically, a substance having one-fourth of the weight-average molecular weight (Mw) of the hyperbranched polymer and the metal catalyst are removed by a series of operations including step S102 to step S104 (or S106). At step S106, preferably, a solvent having a solubility parameter of 10.5 or more is used for solvent C. Examples of solvent C include methanol, ethanol, 1-propanol, 2-propanol, glycerin, water, or a mixture thereof. Among the various solvents cited above as solvent C, methanol, ethanol, and their mixture with water are preferable. Methanol containing 1 to 50% by mass of water is more preferable, and 3 to 40% by mass is yet more preferable. Same is true for the ethanol-water mixture. When solvent C is a mixed solvent, solvent A and solvent C may be the same or different. Solvent C is preferably 1 to 20 parts by volume relative to solvent B.

### (Decomposition of the Acid-Decomposable Group)

At step S108 of FIG. 1, examples of the acid catalyst partially decomposing the acid-decomposable group to the acid group include hydrochloric acid, sulfuric acid, phosphoric acid, hydrobromic acid, p-toluenesulfonic acid, acetic acid, trifluoroacetic acid, trifluoromethane sulfonic acid, and formic acid. The partial decomposition of the acid-decomposable group to the acid group may be performed as follows: a resist polymer intermediate in the solid state formed at step S107 is added to an appropriate organic solvent such as 1,4-dioxane containing the acid catalyst, and then the resulting mixture is heated at 50 to 150° C. and agitated for 10 minutes to 20 hours.

The optimum ratio of the acid-decomposable group to the acid group in the obtained resist polymer varies depending on the resist composition, though it is preferable to de-protect 5 to 80% by mol of the monomer having the introduced acid-decomposable group. The ratio of the acid-decomposable group to the acid group at this range is preferable because high sensitivity and efficient dissolution into a basic solution after the light exposure can be attained. The obtained solid resist polymer may also be used as a solid resist polymer after separation from the reaction solvent and drying to remove the solvent by such operation as, for example, distillation under reduced pressure.

### (Molecular Structure of the Core Portion of the Core-Shell Hyperbranched Polymer)

The molecular structure of the hyperbranched polymer (core portion of the core-shell hyperbranched polymer) will be explained. Here, the weight-average molecular weight (Mw), the number-average molecular weight (Mn), and the degree of branching (Br) of the core portion of the core-shell hyperbranched polymer synthesized as described above will be explained as the molecular structure of the hyperbranched polymer.

The weight-average molecular weight (Mw) and the number-average molecular weight (Mn) of the core portion of the core-shell hyperbranched polymer may be obtained by a GPC (Gel Permeation Chromatography) measurement using a tetrahydrofuran solution (0.5% by mass) at 40° C. Tetrahydrofuran may be used as a moving phase and polystyrene may be used as a standard material.

The degree of branching (Br) of the core portion of the core-shell hyperbranched polymer may be obtained by measuring ¹H-NMR of the product. Namely, the degree of branching can be calculated by computing equation (A) depicted in Chapter 1 by using H1°, an integral ratio of protons in —CH₂Cl appearing at 4.6 ppm, and H2°, an integral ratio of the protons in —CHCl appearing at 4.8 ppm. When the polymerization progresses at both —CH₂Cl and —CHCl, thereby enhancing the branching, the degree of branching (Br) approaches 0.5.

The weight-average molecular weight (Mw) of the core portion of the core-shell hyperbranched polymer of the present invention is preferably 300 to 8,000. More preferably, the weight-average molecular weight (Mw) is 500 to 8,000. Most preferably, the weight-average molecular weight (Mw) is 1,000 to 8,000.

When the weight-average molecular weight (Mw) of the core portion of the core-shell hyperbranched polymer is at such ranges, the core portion takes a spherical morphology and its solubility into the reaction solvent in the reaction for introducing the acid-decomposable group is ensured, and thus, is preferable. In addition, in the case where the core-shell hyperbranched polymer is used in a resist composition, when the weight-average molecular weight (Mw) of the core portion of the core-shell hyperbranched polymer is at such ranges, film-formation is excellent, and dissolution of an unexposed part of the hyperbranched polymer whose core portion has the introduced (induced) acid-decomposable group is prevented advantageously, and thus, is preferable.

The molecular weight distribution (Mw/Mn) of the core portion of the core-shell hyperbranched polymer is preferably 1 to 5. More preferably, the molecular weight distribution (Mw/Mn) of the core portion of the core-shell hyperbranched polymer is 1 to 3. Yet more preferably, the molecular weight distribution (Mw/Mn) of the core portion of the core-shell hyperbranched polymer is 1 to 2.5. In a case where the core-shell hyperbranched polymer is used in a resist composition, when the molecular weight distribution (Mw/Mn) of the core portion of the core-shell hyperbranched polymer is at this range, there is no risk of adverse effects such as insolubilization of the resist composition after light exposure, and thus, is preferable.

Additionally, in a case where the core-shell hyperbranched polymer is used in a resist composition, when the molecular weight distribution (Mw/Mn) of the core portion of the core-shell hyperbranched polymer is made at this range, a resist composition having excellent line edge roughness and high resistance to thermal baking can be obtained, and thus, is preferable.

The degree of branching (Br) of the core portion of the core-shell hyperbranched polymer is preferably 0.3 or higher. More preferably, the degree of branching (Br) is 0.4 to 0.5. Yet more preferably, the degree of branching (Br) is 0.5. When the degree of branching (Br) of the core-shell hyperbranched polymer is at the above ranges, intermolecular entanglement among the hyperbranched polymers is small, thereby suppressing surface roughness in the pattern wall when the hyperbranched polymer is used for a resist composition, and thus, is preferable.

### (Molecular Structure of the Core-Shell Hyperbranched Polymer)

The molecular structure of the core-shell hyperbranched polymer will be explained. The weight-average molecular weight (M) of the core-shell hyperbranched polymer synthesized as described above will be explained as the molecular structure of the core-shell hyperbranched polymer.

The weight-average molecular weight (M) of the core-shell hyperbranched polymer in the present invention may be obtained as follows: an introduction ratio (composition ratio) of each repeating unit in the polymer having the introduced acid-decomposable group is obtained by ¹H-NMR, and based on the weight-average molecular weight (Mw) of the hyperbranched polymer as described above, a calculation is made using the introduction ratio of each composition unit and the molecular weight of each composition unit.

The weight-average molecular weight (M) of the core-shell hyperbranched polymer of the present invention is preferably 500 to 21,000. More preferably, the weight-average molecular weight (M) is 2,000 to 21,000. Most preferably, the weight-average molecular weight (M) is 3,000 to 21,000.

A resist composition containing the core-shell hyperbranched polymer having the weight-average molecular weight (M) at such ranges is excellent in film formation and can maintain a form of each pattern due to increased strength in the process pattern formed at a lithography step. In addition, a resist composition containing the core-shell hyperbranched polymer having the weight-average molecular weight (M) at such ranges is excellent in dry-etching resistance and can provide excellent surface roughness.

### (Substances Used in the Synthesis of the Core-Shell Hyperbranched Polymer)

The substances used in the synthesis of the core-shell hyperbranched polymer will be explained. In the synthesis of the core-shell hyperbranched polymer, monomer, metal catalyst, and solvent are used.

### (Monomer Used in the Synthesis of the Core Portion of the Core-Shell Hyperbranched Polymer)

A monomer used in the synthesis of the core portion of the core-shell hyperbranched polymer will be explained. Examples of the monomer used in the synthesis of the core portion of the core-shell hyperbranched polymer include the monomer represented by formula (I) depicted in Chapter 1.

In formula (I), Y represents a linear, a branched, or a cyclic alkylene group having 1 to 10 carbon atoms. The number of carbons in Y is preferably 1 to 8. More preferable number of carbons in Y is 1 to 6. Y in formula (I) may contain a hydroxyl group or a carboxyl group.

Specific examples of Y in formula (I) include a methylene group, an ethylene group, a propylene group, an isopropylene group, a butylene group, an isobutylene group, an amylene group, a hexylene group, and a cyclohexylene group. Furthermore, Y in formula (I) includes a group in which the above-mentioned groups are bonded with each other directly or via —O—, —CO—, and —COO—.

Y in formula (I) is preferably an alkylene group having 1 to 8 carbon atoms among the groups mentioned above. Y in formula (I) is more preferably a linear alkylene group having 1 to 8 carbon atoms among the alkylene groups having 1 to 8 carbon atoms. examples of the alkylene group more preferable include a methylene group, an ethylene group, an —OCH₂— group, and an —OCH₂CH₂— group. Z in formula (I) represents a halogen atom (a halogen group) such as a fluorine atom, a chlorine atom, a bromine atom, and an iodine atom. Specific examples of preferable Z in formula (I) include a chlorine atom and a bromine atom among the halogen atoms mentioned above.

Among monomer used in synthesizing the core portion of the core-shell hyperbranched polymer, specific examples of monomer represented by formula (I) include chloromethyl styrene, bromomethyl styrene, p-(1-chloroethyl) styrene, bromo(4-vinylphenyl)phenylmethane, 1-bromo-1-(4-vinylphenyl)propane-2-one, and 3-bromo-3-(4-vinylphenyl)propanol. More specific examples of preferable monomers represented by formula (I) among the monomers used for synthesis of the hyperbranched polymer include chloromethyl styrene, bromomethyl styrene, and p-(1-chloroethyl)styrene.

Monomers used in the synthesis of the core portion of the hyperbranched polymer may include, in addition to the monomers represented by formula (I), other monomers. There is no restriction with regard to other monomers provided the monomer can be subject to radical polymerization, and may be chosen appropriately according to purpose. Examples of other monomers capable of radical polymerization include compounds having a radical polymerizable unsaturated bond such as (meth)acrylic acid, (meth)acrylate esters, vinylbenzoic acid, vinylbenzoate esters, styrenes, an allyl compound, vinyl ethers, vinyl esters, and the like.

Specific examples of (meth)acrylate esters cited as other monomers capable of radical polymerization include tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1 ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1 ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate.

Specific examples of vinyl benzoate esters cited as other monomers capable of radical polymerization include vinyl benzoate, tert-butyl vinyl benzoate, 2-methylbutyl vinyl benzoate, 2-methylpentyl vinyl benzoate, 2-ethylbutyl vinyl benzoate, 3-methylpentyl vinyl benzoate, 2-methylhexyl vinyl benzoate, 3-methylhexyl vinyl benzoate, triethylcarbyl vinyl benzoate, 1-methyl-1-cyclopentyl vinyl benzoate, 1-ethyl-1-cyclopentyl vinyl benzoate, 1-methyl-1-cyclohexyl vinyl benzoate, 1-ethyl-1-cyclohexyl vinyl benzoate, 1-methylnorbornyl vinyl benzoate, 1-ethylnorbornyl vinyl benzoate, 2-methyl-2-adamantyl vinyl benzoate, 2-ethyl-2-adamantyl vinyl benzoate, 3-hydroxy-1-adamantyl vinyl benzoate, tetrahydrofuranyl vinyl benzoate, tetrahydropyranyl vinyl benzoate, 1-methoxyethyl vinyl benzoate, 1-ethoxyethyl vinyl benzoate, 1-n-propoxyethyl vinyl benzoate, 1-isopropoxyethyl vinyl benzoate, n-butoxyethyl vinyl benzoate, 1-isobutoxyethyl vinyl benzoate, 1-sec-butoxyethyl vinyl benzoate, 1-tert-butoxyethyl vinyl benzoate, 1-tert-amyloxyethyl vinyl benzoate, 1-ethoxy-n-propyl vinyl benzoate, 1-cyclohexyloxyethyl vinyl benzoate, methoxypropyl vinyl benzoate, ethoxypropyl vinyl benzoate, 1-methoxy-1-methyl-ethyl vinyl benzoate, 1-ethoxy-1-methyl-ethyl vinyl benzoate, trimethylsilyl vinyl benzoate, triethylsilyl vinyl benzoate, dimethyl-tert-butylsilyl vinyl benzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinyl benzoate, adamantyl vinyl benzoate, 2-(2-methyl)adamantyl vinyl benzoate, chloroethyl vinyl benzoate, 2-hydroxyethyl vinyl benzoate, 2,2-dimethylhydroxypropyl vinyl benzoate, 5-hydroxybenzyl vinyl benzoate, trimethylolpropane vinyl benzoate, glycidyl vinyl benzoate, benzyl vinyl benzoate, phenyl vinyl benzoate, and naphthyl vinyl benzoate.

Specific examples of styrenes cited as other monomers capable of radical polymerization include styrene, m-methyl styrene, o-methyl styrene, p-methyl styrene, m-ethyl styrene, o-ethyl styrene, p-ethyl styrene, benzyl styrene, trifluoromethyl styrene, acetoxy styrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethyl styrene, 4-fluoro-3-trifluoromethyl styrene, vinyl naphthalene, and divinylbenzene.

Specific examples of allyl compounds cited as other monomers capable of radical polymerization include allyl acetate, allyl caproate, allyl caprylate, allyl laurate, allyl palmitate, allyl stearate, allyl benzoate, allyl acetoacetate, allyl lactate, and allyl oxyethanol.

Specific examples of vinyl ethers cited as other monomers capable of radical polymerization include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethyleneglycol vinyl ether, dimethylaminoethyl vinyl ether, diethylaminoethyl vinyl ether, butylaminoethyl vinyl ether, benzyl vinyl ether, tetrahydrofurfuryl vinyl ether, vinyl phenyl ether, vinyl tolyl ether, vinyl chlorophenyl ether, vinyl 2,4-dichlorophenyl ether, vinyl naphthyl ether, and vinyl anthranyl ether.

Specific examples of vinyl esters cited as other monomers capable of radical polymerization include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl buthoxyacetate, vinyl phenylacetate, vinyl acetoacetate, vinyl lactate, vinyl β-phenylbutyrate, and vinyl cyclohexylcarboxylate.

As the monomer used in the synthesis of the hyperbranched polymer of the present invention, (meth)acrylic acid, (meth)acrylate esters, 4-vinylbenzoic acid, 4-vinylbenzoate esters, and styrenes are preferable, among the various kinds of monomers used in the synthesis of the core portion of the core-shell hyperbranched polymer described above. Specifically, (meth)acrylic acid, tert-butyl(meth)acrylate, 4-vinylbenzoic acid, tert-butyl 4-vinylbenzoate, styrene, benzyl styrene, chlorostyrene, and vinylnaphthalene are preferable as the monomer corresponding to the core portion of the core-shell hyperbranched polymer among the various kinds of monomers described above.

The amount of the monomer forming the core portion of the core-shell hyperbranched polymer at the time of charge is preferably 10 to 90% by mol relative to the total monomer forming the core-shell hyperbranched polymer. More preferably, the amount of monomer forming the core portion at the time of charge is 10 to 80% by mol relative to the total monomer forming the core-shell hyperbranched polymer. Yet more preferably, the amount of monomer forming the core portion at the time of charge is 10 to 60% by mol relative to the total monomer forming the core-shell hyperbranched polymer.

When the amount of monomer constituting the core portion of the core-shell hyperbranched polymer is at the above ranges, a resist composition using the hyperbranched polymer has an appropriate hydrophobicity to a developing solution, thereby suppressing the dissolution of the unexposed part, and thus, is preferable.

Monomer represented by formula (I) is included preferably in the amount of 5 to 100% by mol relative to the total monomer forming the core portion of the core-shell hyperbranched polymer. More preferably, the amount of monomer represented by formula (I) is 20 to 100% by mol relative to the total monomer forming the core portion of the core-shell hyperbranched polymer.

Yet more preferably, the amount of monomer represented by formula (I) is 50 to 100% by mol relative to the total monomer forming the core portion of the core-shell hyperbranched polymer. When the amount of monomer represented by formula (I) relative to the total monomer forming the core portion of the core-shell hyperbranched polymer is at the above ranges, the core portion takes a spherical morphology, thereby suppressing the intermolecular entanglement, and thus, is preferable.

In a case where the core portion of the core-shell hyperbranched polymer is a polymer of monomer represented by formula (I) and other monomers, the amount of monomer represented by formula (I) relative to the total monomer constituting the core portion at the time of charge is preferably 10 to 99% by mol. In this case, more preferably, the amount of monomer represented by formula (I) relative to the total monomer constituting the core portion at the time of charge is 20 to 99% by mol. In this case, yet more preferably, the amount of the monomer represented by formula (I) relative to the total monomer constituting the core portion at the time of charge is 30 to 99% by mol.

In a case where the core portion of the core-shell hyperbranched polymer is a polymer of monomer represented by formula (I) and other monomers, when the amount of monomer represented by formula (I) relative to the total monomer constituting the core portion is at the above ranges, the core portion takes a spherical morphology, thereby suppressing the intermolecular entanglement, and thus, is preferable.

Further, when the amount of monomer represented by formula (I) relative to the total monomer constituting the core portion is at the above-mentioned range, functions such as substrate adhesiveness and the glass transition temperature may be improved while maintaining a spherical morphology in the core portion, and thus, is preferable. The amounts of monomer represented by formula (I) and of other monomer relative to the total monomer constituting the core portion may be controlled by the charging ratio according to purpose.

### (Catalyst Used in the Synthesis of the Core Portion of the Core-Shell Hyperbranched Polymer)

The catalyst used in the synthesis of the core portion of the core-shell hyperbranched polymer will be explained. Examples of the catalyst used in the synthesis of the core portion of the core-shell hyperbranched polymer include a catalyst formed of a transition metal such as copper, iron, ruthenium, and chromium combined with a ligand such as pyridines, bipyridines, aliphatic polyamines, and aliphatic amines, which are unsubstituted or substituted with a group such as an alkyl group, an aryl group, an amino group, a halogen group, and an ester group, or alkyl- or aryl-phosphines. Examples include catalysts such as a copper bipyridyl complex, a copper pentamethyl diethylenetriamine complex, and a copper tetramethylenediamine complex, which are formed of copper (I) chloride or copper (I) bromide combined with a ligand, and further include an iron tributyl phosphine complex, an iron triphenyl phosphine complex, and an iron tributylamine complex, which are formed of iron (II) chloride combined with a ligand.

Among the catalysts mentioned above, a copper bipyridyl complex, a copper pentamethyl diethylenetriamine complex, an iron tributylphosphine complex, and an iron tributylamine complex are particularly preferable as the catalyst for the synthesis of the core portion of the core-shell hyperbranched polymer of the present invention.

The amount of metal catalyst used for synthesis of the core portion of the core-shell hyperbranched polymer according to the synthesis method described above is preferably 0.1 to 70% by mol, and more preferably 1 to 60% by mol, relative to the total monomer at the time of charging. By using the catalyst at these amounts, the core portion of the hyperbranched polymer having suitable degree of branching can be obtained.

When the amount of metal catalyst used is below these ranges, reactivity may be markedly reduced making polymerization sluggish. On the other hand, when the amount of metal catalyst used is above these ranges, the polymerization reaction becomes excessively active causing the coupling reaction among radicals at growing terminals to take place easily, thereby making control of the polymerization difficult. Further, when the amount of metal catalyst used is above these ranges, the coupling reaction among radicals induces gelation of the reaction system.

The metal catalyst may be made into a coordination compound by mixing the transition metal compound and the ligand by an apparatus. A metal catalyst composed of a transition metal and ligand may also be added to the apparatus in the form of an active coordination compound. Preparation of the coordination compound by mixing the transition metal compound and the ligand in an apparatus is preferable in view of simplifying operations in the synthesis of the hyperbranched polymer.

The method of adding the metal catalyst is not particularly restricted and the metal catalyst may be added, for example, all at once prior to the polymerization to the hyperbranched polymer. Further, additional metal catalyst may be added after initiation of the polymerization depending on the level of inactivation. For example, when the state of dispersion of the coordination compound forming the metal catalyst is inhomogeneous in the reaction system, the transition metal compound may be added to the apparatus in advance, followed by the addition of only the ligand.

Preferably, the polymerization reaction for the synthesis of the hyperbranched polymer is carried out in the presence of the metal catalyst described above and in a solvent though the reaction can occur without a solvent. The solvent used in the polymerization of the hyperbranched core polymer in the presence of the metal catalyst described above is not particularly restricted. Examples include hydrocarbon solvents such as benzene and toluene; ether solvents such as diethyl ether, tetrahydrofuran, diphenyl ether, anisole, and dimethoxy benzene; halogenated hydrocarbon solvents such as methylene chloride, chloroform, and chlorobenzene; ketone solvents such as acetone, methyl ethyl ketone, and methyl isobutyl ketone; alcohol solvents such as methanol, ethanol, propanol, and isopropanol; nitrile solvents such as acetonitrile, propionitrile, and benzonitrile; ester solvents such as ethyl acetate and butyl acetate; carbonate solvents such as ethylene carbonate and propylene carbonate; and amide solvents such as N,N-dimethylformamide and N,N-dimethylacetamide. The solvents may be used independently or in a combination of than two or more.

Preferably, synthesis of the hyperbranched polymer (core polymerization) is carried out in the presence of nitrogen, an inert gas, or under the gas flow thereof, and in the absence of oxygen, to prevent radicals from being affected by oxygen. The core polymerization may be carried out in a batch process or a continuous process. In the core polymerization, to prevent deactivation of the metal catalyst by oxidation, it is preferable that all substances to be used for the core polymerization, namely metal catalysts, solvents, monomers, and the like be fully deoxygenated (degassed) by blowing-in an inert gas such as nitrogen and argon.

The core polymerization may be carried out, for example, by adding the monomer dropwise into a reaction vessel. By controlling the rate of the dropwise addition of monomer, a high degree of branching in the synthesized hyperbranched core polymer (macro initiator) can be maintained and a rapid increase of the molecular weight can be suppressed. In other words, by controlling the rate of the dropwise addition of the monomer, the molecular weight of the polymer can be precisely controlled while maintaining a high degree of branching in the synthesized hyperbranched core polymer. To suppress a rapid increase of the molecular weight of the hyperbranched core polymer, the concentration of the monomer added dropwise is preferably 1 to 50% by mass and more preferably 2 to 20% by mass relative to the total reaction mass.

In the core polymerization, the reaction may be carried out by adding a monomer (charging monomer) afterwards to the reaction vessel in which the polymerization reaction is performed. Here, the amount of monomer to be mixed (adding amount) into the reaction vessel (reaction system) at one charge is less than the total amount of the monomer to be mixed in the reaction system. To maintain a high degree of branching in the hyperbranched core polymer and to suppress a rapid increase of the molecular weight, the amount of monomer to be mixed in the reaction system per one charge is preferably 50% or less relative to the total amount of the monomer, and more preferably 30% or less.

For example, the monomer is added by such methods as a continuous method in which the monomer is mixed into the reaction system by a dropwise addition during a prescribed period, or a portion-wise method in which the total amount of the monomer to be mixed into the reaction system is divided into plural portions where the portions of a given amount are added at given intervals. Thus, the amount of the monomer to be mixed (adding amount) per one charge relative to the reaction vessel (reaction system) is less than the total amount of the monomer to be added to the reaction system.

The monomer also may be mixed into the reaction system, for example, by continuously charging the monomer during a prescribed period. In this case, the amount of the monomer to be mixed into the reaction system per unit time (adding amount) is less than the total amount of the monomer to be mixed into the reaction system.

When the monomer is mixed into the reaction system according to the continuous method, the time for the dropwise addition of the monomer is preferably, for example, 5 to 300 minutes. More preferably, the time for the dropwise addition of the monomer is 15 to 240 minutes, and yet more preferably, 30 to 180 minutes.

When the monomer is mixed into the reaction system according to the portion-wise method, one portion of the monomer is mixed, and the next portion of the monomer is mixed after a prescribed interval. The interval may be at least the time required for the mixed monomer to perform a polymerization of the added monomer, the time required for the mixed monomer to be homogeneously dispersed in the entire reaction system, or the time required for the fluctuated temperature of the reaction system caused by the addition of the monomer to be stabilized.

If the time of the dropwise addition of the monomer into the reaction system is too short, a rapid increase of the molecular weight may not be sufficiently controlled. If the time of the dropwise addition of the monomer into the reaction system is too long, the total polymerization time from the start of the synthesis of the hyperbranched polymer to the end becomes long, thereby increasing the cost for synthesizing the hyperbranched polymer, and thus, is not preferable.

In the core polymerization, an additive may be used. In the core polymerization, among compounds represented by formula (1-1) and compounds represented by formula (1-2) depicted in Chapter 1, at least one type may be added.

R₁ in formula (1-1) represents an alkyl group having 1 to 10 carbon atoms, an aryl group having 1 to 10 carbon atoms, or an aralkyl group having 1 to 10 carbon atoms. More specifically, R₁ in the formula (1-1) represents a hydrogen, an alkyl group having 1 to 10 carbon atoms, an aryl group having 6 to 10 carbon atoms, or an aralkyl group having 7 to 10 carbon atoms. “A” in formula (1-1) represents a cyano group, a hydroxy group, and a nitro group. examples of the compound represented by formula (1-1) include nitriles, alcohols, and a nitro compound.

Specific examples of nitriles included in compounds represented by formula (1-1) include acetonitrile, propionitrile, butyronitrile, and benzonitrile. Specific examples of alcohols included in compounds represented by formula (1-1) include methanol, ethanol, 1-propanol, 2-propanol, 1-butanol, cyclohexyl alcohol, and benzyl alcohol. Specific examples of nitro compounds included in compounds represented by formula (1-1) include nitromethane, nitroethane, nitropropane, and nitrobenzene. The compound represented by formula (1-1) is not restricted to the compounds mentioned above.

R₂ and R₃ in formula (1-2) represent an alkyl group having 1 to 10 carbon atoms, an aryl group having 1 to 10 carbon atoms, an aralkyl group having 1 to 10 carbon atoms, or a or a dialkylamide group having 1 to 10 carbon atoms; B represents a carbonyl group and a sulfonyl group. More specifically, R₂ and R₃ in formula (1-2) represent hydrogen, an alkyl group having 1 to 10 carbon atoms, an aryl group having 6 to 10 carbon atoms, an aralkyl group having 7 to 10 carbon atoms, or a dialkyl amine group having 2 to 10 carbon atoms. R₂ and R₃ in formula (1-2) may be the same or different.

Examples of the compound represented by formula (1-2) include ketones, sulfoxides, and an alkyl formamide compound. Specific examples of the ketones include acetone, 2-butanone, 2-pentanone, 3-pentanone, 2-hexanone, cyclohexanone, 2-methyl cyclohexanone, acetophenone, and 2-methyl acetophenone.

Specific examples of the sulfoxides included in the compounds represented by formula (1-2) include dimethyl sulfoxide and diethyl sulfoxide. Specific examples of the alkyl formamide compound included in the compounds represented by formula (1-2) include N,N-dimethyl formamide, N,N-diethylformamide, and N,N-dibutyl formamide. The compounds represented by formula (1-2) are not restricted to the above-mentioned compounds. Among the compounds represented by formula (1-1) or formula (1-2), nitriles, nitro compounds, ketones, sulfoxides, and alkyl formamide compounds are preferable, while acetonitrile, propionitrile, benzonitrile, nitroethane, nitropropane, dimethyl sulfoxide, acetone, and N,N-dimethyl formamide are more preferable.

In the synthesis of the hyperbranched polymer, compounds represented by formula (1-1) or formula (1-2) may be used independently or in combination of two or more.

In the synthesis of the hyperbranched polymer, compounds represented by formula (1-1) or formula (1-2) may be used independently or in combination of two or more as a solvent.

The amount of the compounds represented by formula (1-1) or (1-2) to be added in the synthesis of the hyperbranched polymer is preferably 2 times to 10000 times by mol ratio relative to the amount of transition metal in the metal catalyst. The amount of the compound represented by formula (1-1) or the amount of the compound represented by (1-2) to be added relative to the amount of a transition metal in the metal catalyst is more preferably 3 times to 7000 times by mol ratio, and yet more preferably 4 times to 5000 times by mol ratio relative to the amount of transition metal in the metal catalyst.

When the added amount of the compound represented by formula (1-1) or of the compound represented by formula (1-2) is too small, the rapid increase in molecular weight may not be controlled sufficiently. On the other hand, when the added amount of the compound represented by formula (1-1) or of the compound represented by formula (1-2) is too large, the reaction rate is slowed, leading to the formation of a large amount of oligomers.

Polymerization time for the core polymerization is preferably 0.1 to 30 hours, more preferably 0.1 to 10 hours, and yet more preferably 1 to 10 hours depending on the molecular weight of the polymer. Reaction temperature in the core polymerization is preferably 0 to 200° C. More preferable reaction temperature in the core polymerization is 50 to 150° C. When the polymerization is carried out at a temperature above the boiling point of the solvent used, for example, the pressure may be increased in an autoclave.

In the core polymerization, it is preferable for the reaction system to be distributed uniformly. The reaction system is distributed uniformly, for example, by agitating the reaction system. As a specific example of an agitation condition for core polymerization, preferably the power necessary for agitation per unit volume is set as 0.01 kW/m³ or more. In the core polymerization, additional catalyst or a reducing agent to regenerate the catalyst may be added according to the progress of the polymerization and degree of catalyst inactivation.

In the core polymerization, the polymerization reaction is stopped at the point when the set molecular weight is attained. A method of stopping the core polymerization is not particularly limited, and a method such as inactivating the catalyst, for example, by cooling or by adding an oxidizing agent, a chelating agent, etc. may be used.

According to the method of synthesizing the hyperbranched polymer described above, for example, when among compounds represented by R₁-A and compounds represented by R₂—B—R₃, at least one type is added in the core polymerization, gelation of the hyperbranched core polymers can be prevented, and thus, is preferable.

In addition, according to the method of synthesizing the hyperbranched polymer described above, for example, as compared with a case where the total amount of monomer is mixed into the reaction system all at once, when the amount of monomer mixed into the reaction system per one charge is made less than the total amount of monomer to be mixed into the reaction system in the core polymerization, the amount of metal catalyst used can be reduced and a rapid increase of the molecular weight can be suppressed and thus, is preferable.

Thus, according to the method of synthesizing the hyperbranched polymer described above, the amount of metal catalyst used can be reduced in a simple way while suppressing a rapid increase of the molecular weight, thereby enabling stable production the hyperbranched polymer of a desired molecular weight and desired degree of branching, and thus, is preferable.

### (Monomers Used for the Synthesis of the Shell Portion of the Core-Shell Hyperbranched Polymer)

Monomer used for the synthesis of the shell portion of the core-shell hyperbranched polymer will be explained. The shell portion of the core-shell hyperbranched polymer constitutes the terminal of the polymer molecule. Monomer used to synthesize the shell portion of the core-shell hyperbranched polymer may be selected, for example, from a group including monomer giving the repeating unit represented by formula (II) depicted in Chapter 1, the monomer giving the repeating unit represented by formula (III) depicted in Chapter 1, and a mixture thereof.

Monomers giving the repeating unit represented by formula (II) depicted in Chapter 1 and the repeating unit represented by formula (III) depicted in Chapter 1 contain an acid-decomposable group which is decomposable, for example, by an organic acid such as acetic acid, maleic acid, and benzoic acid or an inorganic acid such as hydrochloric acid, sulfuric acid, and nitric acid. Preferably, the repeating units represented by formula (II) and the repeating units represented by formula (III) contain an acid-decomposable group which is decomposable by the action of a photo-inductive acid-generating material that generates acid by photo energy. An acid-decomposable group giving a hydrophilic group by decomposition is preferable.

R¹ in formula (II) and R⁴ in formula (III) represent hydrogen or an alkyl group having 1 to 3 carbon atoms, among which, R¹ in formula (II) and R⁴ in formula (III) are preferably hydrogen and a methyl group. Hydrogen is more preferable as R¹ in formula (II) and R⁴ in formula (III).

R² in formula (II) represents hydrogen, an alkyl group, or an aryl group. The alkyl group in R² in formula (II) is preferably, for example, an alkyl group having 1 to 30 carbon atoms, more preferably an alkyl group having 1 to 20 carbon atoms, and yet more preferably an alkyl group having 1 to 10 carbon atoms. The alkyl group has a linear, a branched, or a cyclic structure. Specific examples of the alkyl group of R² in formula (II) include a methyl group, an ethyl group, a propyl group, an isopropyl group, a butyl group, an isobutyl group, a tert-butyl group, and a cyclohexyl group.

The aryl group of R² in formula (II) preferably has 6 to 30 carbon atoms, more preferably 6 to 20, and yet more preferably 6 to 10. Specific examples of the aryl group of R² in formula (II) include a phenyl group, a 4-methyl phenyl group, and a naphthyl group, among which, includes hydrogen, methyl groups, ethyl groups, phenyl groups, and the like. As one of the most preferable group of R² in formula (II), a hydrogen atom may be mentioned.

R³ in formula (II) and R⁵ in formula (III) represent hydrogen, an alkyl group, a trialkyl silyl group, an oxoalkyl group, or a group represented by formula (i) of Chapter 1. It is preferable that the alkyl group of R³ in formula (II) and R⁵ in formula (III) be an alkyl group having 1 to 40 carbon atoms. More preferably the number of carbons of the alkyl group of R³ in formula (II) and R⁵ in formula (III) is 1 to 30. Yet more preferably the number of carbons of the alkyl group in R³ in formula (II) and R⁵ in formula (III) is 1 to 20. The alkyl group in R³ in formula (II) and R⁵ in formula (III) may be linear, branched, or cyclic.

Preferably the number of carbons of each alkyl group in R³ in formula (II) and R⁵ in formula (III) is 1 to 6, and more preferably 1 to 4. Preferably the number of carbons of the alkyl group of the oxoalkyl group in R³ in formula (II) and R⁵ in formula (III) is 4 to 20, and more preferably 4 to 10.

R⁶ in formula (i) of Chapter 1 represents hydrogen or an alkyl group. The alkyl group of R⁶ in formula (i) is linear, branched, or cyclic. It is preferable that the alkyl group of R⁶ in formula (i) be an alkyl group having 1 to 10 carbon atoms. More preferably the number of carbons of the alkyl group of R⁶ in formula (i) is 1 to 8, and yet more preferably the number is 1 to 6.

R⁷ and R⁸ in formula (i) represent hydrogen or an alkyl group. The hydrogen atom and the alkyl group in R⁷ and R⁸ in formula (i) may be independent of each other or form a ring. The alkyl group in R⁷ and R⁸ in formula (i) has a linear, branched, or cyclic structure. It is preferable that the alkyl group in R⁷ and R⁸ in formula (i) be an alkyl group having 1 to 10 carbon atoms. More preferably the number of carbons of the alkyl group in R⁷ and R⁸ in formula (i) is 1 to 8, and yet more preferably the number is 1 to 6. R⁷ and R⁸ in formula (i) are preferably a branched alkyl group having 1 to 20 carbon atoms.

Examples of the group represented by formula (i) include a linear or a branched acetal group such as a 1-methoxyethyl group, a 1-ethoxyethyl group, a 1-n-propoxyethyl group, a 1-isopropoxyethyl group, a 1-n-butoxyethyl group, a 1-isobutoxyethyl group, a 1-sec-butoxyethyl group, a 1-tert-butoxyethyl group, a 1-tert-amyloxyethyl group, a 1-ethoxy-n-propyl group, a 1-cyclohexyloxyethyl group, a methoxypropyl group, an ethoxypropyl group, a 1-methoxy-1-methyl-ethyl group, and 1-ethoxy-1-methyl-ethyl group; a cyclic acetal group such as a tetrahydrofuranyl group and a tetrahydropyranyl group. Among the above-mentioned groups represented by formula (i), an ethoxyethyl group, a butoxyethyl group, an ethoxypropyl group, and a tetrahydropyranyl group are particularly preferable.

R³ in formula (II) and R⁵ in formula (III) are a linear, a branched, or a cyclic alkyl group having 1 to 40 carbon atoms, preferably 1 to 30 carbon atoms, and more preferably 1 to 20 carbon atoms. More preferable R³ in formula (II) and R⁵ in formula (III) are a branched alkyl group having 1 to 20 carbon atoms.

Examples of a linear, a branched, or a cyclic alkyl group in R³ in formula (II) and R⁵ in formula (III) include an ethyl group, a propyl group, an isopropyl group, a butyl group, an isobutyl group, a tert-butyl group, a cyclopentyl group, a cyclohexyl group, a cycloheptyl group, a triethylcarbyl group, a 1-ethylnorbornyl group, 1-methylcyclohexyl group, an adamantyl group, a 2-(2-methyl)adamantyl group, and a tert-amyl group. Among them, a tert-butyl group is particularly preferable.

Examples of the trialkyl silyl group in R³ in formula (II) and R⁵ in formula (III) include a group having 1 to 6 carbon atoms in each alkyl group, such as a trimethyl silyl group, a triethyl silyl group, and a dimethyl tert-butyl silyl group. Example of the oxoalkyl group includes a 3-oxocyclohexyl group.

Monomers giving repeating units represented by formula (II) include, for example, vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate. Among these, a polymer of 4-vinylbenzoic acid and tert-butyl 4-vinylbenzoate is preferable.

Monomers giving repeating units represented by formula (III) include, for example, acrylate, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1-ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, methacrylic acid, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate. Among these, polymers of acrylate and tert-butyl acrylate are preferable.

As the monomer corresponding to the shell portion, a polymer composed of at least one among 4-vinyl benzoic acid and acrylic acid and at least one among tert-butyl 4-vinyl benzoate and tert-butyl acrylate is also preferable. As a monomer corresponding to the shell portion, monomer other than the monomers giving repeating units represented by formula (II) and repeating units represented by formula (III) may also be used provided the monomer has a structure containing a radical polymerizable unsaturated bond.

Examples of monomers usable for the polymerization include a compound containing a radical polymerizable unsaturated bond selected from styrenes other than the styrenes mentioned above, an allyl compound, vinyl ethers, vinyl esters, and crotonate esters.

Specific examples of styrenes cited as monomers usable as the monomer constituting the shell portion include styrene, tert-buthoxy styrene, α-methyl-tert-buthoxy styrene, 4-(1-methoxyethoxy)styrene, 4-(1-ethoxyethoxy)styrene, tetrahydropyranyloxy styrene, adamantyloxy styrene, 4-(2-methyl-2-adamantyloxy)styrene, 4-(1-methylcyclohexyloxy)styrene, trimethylsilyloxy styrene, dimethyl-tert-butylsilyloxy styrene, tetrahydropyranyloxy styrene, benzyl styrene, trifluoromethyl styrene, acetoxy styrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethyl styrene, 4-fluoro-3-trifluoromethyl styrene, and vinyl naphthalene.

Specific examples of allyl compounds cited as monomers usable as monomers constituting the shell portion include allyl acetate, allyl caproate, allyl caprylate, allyl laurate, allyl palmitate, allyl stearate, allyl benzoate, allyl acetoacetate, allyl lactate, and allyl oxyethanol.

Specific examples of vinyl ethers cited as monomers usable as monomers constituting the shell portion include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethyleneglycol vinyl ether, dimethylaminoethyl vinyl ether, diethylaminoethyl vinyl ether, butylaminoethyl vinyl ether, benzyl vinyl ether, tetrahydrofurfuryl vinyl ether, vinyl phenyl ether, vinyl tolyl ether, vinyl chlorophenyl ether, vinyl 2,4-dichlorophenyl ether, vinyl naphthyl ether, and vinyl anthranyl ether.

Specific examples of vinyl esters cited as monomers usable as monomers constituting the shell portion include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl buthoxyacetate, vinyl phenylacetate, vinyl acetoacetate, vinyl lactate, vinyl β-phenylbutyrate, and vinyl cyclohexylcarboxylate.

Specific examples of the crotonate esters cited as monomers usable as the monomers constituting the shell portion include butyl crotonate, hexyl crotonate, glycerine monocrotonate, dimethyl itaconate, diethyl itaconate, dibutyl itaconate, dimethyl maleate, dibutyl fumarate, maleic anhydride, maleimide, acrylonitrile, methacrylonitrile, and maleironitrile.

Specific examples of monomers usable as monomers constituting the shell portion also include monomers represented by formula (IV) to formula (VIII) in Chapter 1.

Among monomers usable as monomers constituting the shell portion, styrenes and crotonate esters are preferable. Among monomers usable as monomers constituting the shell portion, styrene, benzyl styrene, chlorostyrene, vinyl naphthalene, butyl crotonate, hexyl crotonate, and maleic anhydride are preferable.

The shell portion of the core-shell hyperbranched polymer may be introduced at the terminal of the hyperbranched polymer synthesized as described above by reacting the core portion of the synthesized hyperbranched polymer with a monomer containing the acid-decomposable group. Examples of the monomer containing the acid-decomposable group which reacts with the core portion of the hyperbranched polymer include monomers giving at least a repeating unit represented by formula (II) or a repeating unit represented by formula (III). Thus, the acid-decomposable group giving at least a repeating unit represented by formula (II) or a repeating unit represented by formula (III) may be introduced at the shell portion of the core-shell hyperbranched polymer.

In the core-shell hyperbranched polymer of the present invention, at least monomer giving a repeating unit represented by formula (II) or monomer giving a repeating unit represented by formula (III) (alternatively both) is included. Monomer giving the repeating units above is included preferably at a range of 10 to 90% by mol relative to the core-shell hyperbranched polymer. More preferably, the range is 20 to 90% by mol, and yet more preferably the range is 30 to 90% by mol. In particular, the repeating unit represented by formula (II) and/or the repeating unit represented by formula (III) in the shell portion is included preferably at the range of 50 to 100% by mol relative to the core-shell hyperbranched polymer, and more preferably at the range of 80 to 100% by mol.

When the amount of at least the repeating unit represented formula (II) or the repeating unit represented by formula (III) in the shell portion is at the above range relative to the core-shell hyperbranched polymer, the light-exposed part of a resist composition using the core-shell hyperbranched polymer is removed efficiently by dissolution into a basic solution in a lithography developing process, and thus, is preferable.

When the shell portion of the core-shell hyperbranched polymer is a polymer of at least monomer giving a repeating unit represented by formula (II) and/or monomer giving a repeating unit represented by formula (III) and other monomers, the amount of monomer giving a repeating unit represented by formula (II) and/or the amount of monomer giving a repeating unit represented by formula (III) relative to the total amount of monomer constituting the shell portion at the time of charge is preferably 30 to 90% by mol, and more preferably 50 to 70% by mol. When the amount is at this range, functions such as etching resistance, wetting properties, and glass transition temperature can be improved without hindering efficient dissolution of the light-exposed part into a basic solution, and thus, is preferable.

The amount of at least the repeating unit represented by formula (II) or the repeating unit represented by formula (III) and the amount of other repeating units in the shell portion of the core-shell hyperbranched polymer may be controlled, according to purpose, by charging mol ratios at the time of the introduction of the shell portion.

### (Catalysts Used for the Synthesis of the Shell Portion of the Core-Shell Hyperbranched Polymer)

The catalysts used for the synthesis of the shell portion of the core-shell hyperbranched polymer will be explained. Examples of the catalyst used for the synthesis of the shell portion of the core-shell hyperbranched polymer include a transition metal complex catalyst similar to those used in the synthesis of the core portion of the core-shell hyperbranched polymer. Specific example of the catalyst used for the synthesis of the shell portion of the core-shell hyperbranched polymer include a copper (I) bipyridyl complex.

The catalyst used for the synthesis of the shell portion of the core-shell hyperbranched polymer is a catalyst which performs an addition polymerization giving a linear shell portion by living radical polymerization of a double bond of 1 or more compounds including at least monomer giving a repeating unit represented by formula (II) or monomer giving a repeating unit represented by formula (III) by utilizing the numerous halogenated carbons present at the core terminal of the core-shell hyperbranched polymer as the initiating points.

Specifically, for example, the core-shell hyperbranched polymer of the present invention may be synthesized by reacting the core portion of the core-hell type hyperbranched polymer with 1 or more compounds including at least monomer giving a repeating unit represented by formula (II) or monomer giving a repeating unit represented by formula (III) in a solvent such as chlorobenzene at 0 to 200° C. and for 0.1 to 30 hours.

The partial decomposition of the acid-decomposable group to the acid group by the acid catalyst such as hydrochloric acid, sulfuric acid, phosphoric acid, hydrobromic acid, p-toluenesulfonic acid, acetic acid, trifluoroacetic acid, trifluoromethane sulfonic acid, and formic acid may be performed by adding a solid resist polymer intermediate into an appropriate organic solvent such as 1,4-dioxane which contains the acid catalyst and then heating the resulting mixture usually at 50 to 150° C. and agitating for 10 minutes to 20 hours.

The optimum ratio of the acid-decomposable group to the acid group in the obtained resist polymer is different depending on the resist composition, though it is preferable that 0.1 to 80% by mol of the monomer having the introduced acid-decomposable group de-protected. The ratio of the acid-decomposable group to the acid group at this range is preferable because high sensitivity and efficient dissolution into a basic solution after the light-exposure can be attained. The solid resist polymer may also be used after separation from the reaction solvent and drying.

As described above, according to the method of synthesizing the hyperbranched polymer including the core-shell hyperbranched polymer, metals and oligomers can be removed simultaneously without using an adsorbent. Thus, according to the method of synthesizing the hyperbranched polymer including the core-shell hyperbranched polymer described above, impurities such as the metal catalyst and by-product oligomers can be removed in a simple manner without using an adsorbent, and thus, the hyperbranched polymer can be synthesized simply and stably in large quantities.

According to the method of synthesizing the hyperbranched polymer including the core-shell hyperbranched polymer described, the metal can be removed to a degree that does not affect the introduction of the acid-decomposable group into the core portion. Here, the oligomers removed in the method of synthesizing the hyperbranched polymer including the core-shell hyperbranched polymer mean substances whose molecular weights are equal to or less than one-fourth of the weight-average molecular weight of the hyperbranched polymer forming the core portion of the core-shell hyperbranched polymer.

In the method of synthesizing the hyperbranched polymer including the core-shell hyperbranched polymer, by controlling the solubility parameter of solvent A to solvent C and the amount thereof, metals and oligomers can be simultaneously removed without using an adsorbent. Thus, according to the method of synthesizing the hyperbranched polymer including the core-shell hyperbranched polymer, impurities such as the metal catalyst and by-product oligomers can be removed in a simple manner without using an adsorbent, and thus, the hyperbranched polymer can be synthesized simply and stably in large quantities.

As described, by synthesizing the core-shell hyperbranched polymer by using the hyperbranched polymer from which impurities such as the metal catalyst and by-product oligomers are removed in a simple manner, a core-shell hyperbranched polymer having a stable quality can be synthesized simply in large quantities. By using the synthesis method described, impurities such as the metal catalyst and by-product oligomers are removed, and thus, the hyperbranched polymer including the core-shell hyperbranched polymer having a stable quality can be obtained in large quantities.

According to the resist composition containing the core-shell hyperbranched polymer synthesized as described, the possibility of adverse effects such as a large change in reactivity and insolubilization after exposure of light can be reduced.

By using a resist composition containing the core-shell hyperbranched polymer synthesized as described, a semi-conductor integrated circuit with an ultrafine circuit pattern formed thereon can be obtained.

By fabricating a semi-conductor integrated circuit by using the resist composition containing the hyperbranched polymer including the core-shell hyperbranched polymer synthesized as described, a semi-conductor integrated circuit with an ultrafine circuit pattern formed thereon can be easily fabricated.

In the following, examples of the embodiments in Chapter 2 as described above will be explained. The embodiments in Chapter 2 are not restricted to the following specific examples, nor is interpretation of the embodiments to be limited by the following specific examples.

In examples, core-shell hyperbranched polymers are synthesized as indicated below, and the weight-average molecular weight (Mw), the number-average molecular weight (Mn), the degree of branching (Br), the metal content, the reduction rate of a monomer component (%), and the reduction rate of a dimer component (%) of the synthesized core-shell hyperbranched polymer are measured.

### (Weight-Average Molecular Weight (Mw) and Number-Average Molecular Weight (Mn))

The weight-average molecular weight (Mw) and the number-average molecular weight (Mn) of the core-shell hyperbranched polymer (core portion) in examples will be explained. The weight-average molecular weight (Mw) and the number-average molecular weight (Mn) of the core-shell hyperbranched polymer (core portion) in examples are values obtained by a GPC (Gel Permeation Chromatography) measurement using tetrahydrofuran solution (0.5% by mass) at 40° C. with a GPC HLC-8020 type instrument (manufactured by Tosoh Corporation) and two TSKgel HXL-M columns (manufactured by Tosoh Corporation) connected in series. In the measurement, tetrahydrofuran was used as a moving phase. In the measurement, polystyrene was used as a standard material.

### (Degree of Branching (Br))

The degree of branching (Br) of the core-shell hyperbranched polymer in the examples will be explained. The degree of branching (Br) of the core-shell hyperbranched polymer in the examples was obtained by measuring ¹H-NMR of the product. Specifically, the degree of branching was calculated by computing equation (B) by using H1°, an integral ratio of protons in —CH₂Cl appearing at 4.6 ppm, and H2°, an integral ratio of the protons in —CHCl appearing at 4.8 ppm. Here, when the polymerization progresses at both —CH₂Cl and —CHCl, thereby enhancing the branching, the degree of branching (Br) approaches 0.5.

### (Metal Content)

Metal content in the core-shell hyperbranched polymer in the examples will be explained. Metal content in the core-shell hyperbranched polymer in the examples were obtained as follows. The copper content derived from the catalyst and the aluminum content derived from the adsorbent were quantitatively analyzed at the wavelengths of λ(Cu)=324.752 nm and λ(Al)=308.215 nm in a xylene (atomic absorbance grade) solution containing 1% of the polymer by using an ICP (Inductively Coupled Plasma) instrument Optima 5300DV (manufactured by PerkinElmer Inc.). S-21 (manufactured by CONOSTAN) was used as the standard solution. Detection limits of the metal concentration under the measuring conditions in the examples were 1 ppm for copper and 10 ppm for aluminum (both relative to the polymer).

$$[ Equation 2 ]$$

$$reduction rate = ( 100 - \frac{\begin{matrix}contents of monomer component and \\ dimer component after fractionation\end{matrix}}{\begin{matrix}contents of monomer component and \\ dimer component before fractionation\end{matrix}} ) \times 100 \qquad Equation ( B )$$

In the examples, ultrapure water prepared by using a GSR-200 instrument (manufactured by Advantec Toyo Kaisha. Ltd.) was used. The ultrapure water contains 1 ppb or less of metal with the specific resistance of 18MΩ·cm at 25° C. In the examples, following syntheses were carried with reference to the synthesis method described by Krzysztof Matyjaszewski. Macromolecules, 29, 1079 (1996) and by Jean M. J. Frecht in J. Poly. Sci., 36, 955 (1998).

### First Example

### Synthesis of Hyperbranched Polymer

### Core Portion A

Synthesis of the hyperbranched polymer (core portion A) of the embodiment in a first example in Chapter 2 as described above will be explained. In the synthesis of the hyperbranched polymer (core portion A) in the first example, under an argon gas atmosphere, 6.65 g of 2,2′-bipyridyl and 2.1 g of copper (I) chloride were weighed into a four-necked reaction vessel (300 mL volume) equipped with an agitator and a cooling column, to which 150 mL of chlorobenzene and 10 mL of acetonitrile (reaction solvent) were added, and then 32.5 g of chloromethyl styrene was added dropwise for 60 minutes. The resulting mixture was agitated and heated to maintain the temperature inside the four-necked reaction vessel constantly at 115° C. The total reaction time including the dropwise addition was 240 minutes.

After the reaction, the reaction solution was filtered through a filter paper having a retaining particle size of 1 μm. Then, a mixed solution of 144 mL of methanol and 16 mL of water (solvent A: equivolume to the reaction solvent) was added to the filtered solution for re-precipitation. The yield was 80%.

The weight-average molecular weight (Mw) and the degree of branching (Br) of the hyperbranched polymer (core portion A) obtained as described were measured. The metal content (copper and aluminum) in the hyperbranched polymer (core portion A) were measured and the ratios relative to the polymer were calculated. The results of core portion A are indicated in table 2. In Table 2, the copper and aluminum content are expressed by “P ppm” and “Q ppm”, respectively.

The ratio of the substance whose molecular weight is equal to or less than one-fourth of the weight-average molecular weight (Mw) of the hyperbranched polymer (core portion A) relative to the purified hyperbranched polymer (core portion A) was calculated. The results of core portion A are indicated in table 2 and are expressed by “R %”. In the text or in Table 2. MeOH, IPA, and THF represent methanol, 2-propanol, and tetrahydrofuran, respectively.

TABLE 2

| | | | volume ratio | volume ratio | | | | | | | |
|---|---|---|---|---|---|---|---|---|---|---|---|
| | | | of solvent A | of solvent B | solvent C | | molecular | branching | | | |
| | core | | (to reaction | (to 1 g of | (volume | yield | weight | degree | P | Q | R |
| | portion | operation | solvent) | polymer) | ratio) | (%) | (Mw) | (Br) | (ppm) | (ppm) | (%) |
| first | A | repre- | MeOH/water | — | — | 80 | 1850 | 0.49 | 2 | <1 | 7 |
| example | | cipitated | 0.9/0.1 | | | | | | | | |
| | | 1 time | | | | | | | | | |
| second | B | repre- | MeOH/water | — | — | 85 | 2300 | 0.49 | 2 | <1 | 7 |
| example | | cipitated | 1.8/0.2 | | | | | | | | |
| | | 1 time | | | | | | | | | |
| third | C | repre- | IPA/water | — | — | 71 | 4000 | 0.47 | 5 | <1 | 5 |
| example | | cipitated | 0.9/0.1 | | | | | | | | |
| | | 1 time | | | | | | | | | |
| fourth | D | repre- | THF/MeOH | — | — | 70 | 3000 | 0.49 | 2 | <1 | 6 |
| example | | cipitated | 0.2/1.8 | | | | | | | | |
| | | 1 time | | | | | | | | | |
| fifth | E | repre- | MeOH/water | benzo- | MeOH/water | 26 | 1100 | 0.51 | <1 | <1 | 3 |
| example | | cipitated | 3.1/0.6 | nitrile | (5.1/1) | | | | | | |
| | | 4 time | | 3.4 mL | | | | | | | |
| first | F | repre- | hexane | — | — | 45 | 2800 | 0.48 | 980 | <1 | 10 |
| comparative | | cipitated | 1 | | | | | | | | |
| example | | 1 time | | | | | | | | | |
| second | G | repre- | toluene | — | — | 0 | — | — | — | — | — |
| comparative | | cipitated | 1 | | | | | | | | |
| example | | 1 time | | | | | | | | | |
| third | H | repre- | MeOH | — | MeOH/THF | 48 | 6000 | 0.48 | 3 | 50 | 5 |
| comparative | | cipitated + | 2 | | (4/1) | | | | | | |
| example | | washed | | | | | | | | | |

### Second Example

### Synthesis of Hyperbranched Polymer

### Core Portion B

Synthesis of the hyperbranched polymer (core portion B) in a second example will be explained. In the synthesis of the hyperbranched polymer (core portion B) in the second example, the polymerization reaction was carried out for 300 minutes as the reaction time in a similar manner to that in the synthesis of core portion A of the hyperbranched polymer as explained in the first example.

In the synthesis of the hyperbranched polymer (core portion B) in the second example, core portion B of the hyperbranched polymer was synthesized in a similar manner to that in the synthesis of core portion A of the hyperbranched polymer as explained in first example, except that solvent A used in the purification was a mixture of 288 mL of methanol and 32 mL of water (solvent A: twice as much as the reaction solvent by volume). The yield was 85%.

The ratio of substances whose molecular weight is equal to or less than one-fourth of the weight-average molecular weight (Mw) was calculated by measuring the weight-average molecular weight (Mw), the degree of branching (Br), and the metal content of the hyperbranched polymer (core portion B) in the second example in a similar manner to that in the first example. The results of core portion B are indicated in table 2.

### Third Example

### Synthesis of Hyperbranched Polymer

### Core Portion C

Synthesis of the hyperbranched polymer (core portion C) in a third example will be explained. In the synthesis of the hyperbranched polymer (core portion C) in the third example, the polymerization reaction was carried out for 300 minutes as the reaction time in a similar manner to that in the synthesis of core portion A of the hyperbranched polymer as explained in first example.

In the synthesis of the hyperbranched polymer (core portion C) in the third example, core portion C of the hyperbranched polymer was synthesized in a similar manner to that in the synthesis of core portion A of the hyperbranched polymer explained in the first example, except that methanol in solvent A used in the purification was replaced by 2-propanol. The yield was 71%.

The ratio of substances whose molecular weight is equal to or less than one-fourth of the weight-average molecular weight (Mw) was calculated by measuring the weight-average molecular weight (Mw), the degree of branching (Br), and the metal content of the hyperbranched polymer (core portion C) in the third example in a similar manner to that in the first example. The results of core portion C are indicated in table 2.

### Fourth Example

### Synthesis of Hyperbranched Polymer

### Core Portion D

Synthesis of the hyperbranched polymer (core portion D) in a fourth example will be explained. In the synthesis of the hyperbranched polymer (core portion D) in the fourth example, the polymerization reaction was carried out for 300 minutes as the reaction time in a similar manner to that in the synthesis of core portion A of the hyperbranched polymer as explained in the first example.

In the synthesis of the hyperbranched polymer (core portion D) in the fourth example, core portion D of the hyperbranched polymer was synthesized in a similar manner to that in the synthesis of core portion A of the hyperbranched polymer explained in the first example, except that solvent A used in the purification was changed to a mixture of 32 mL of tetrahydrofuran and 288 mL of methanol (solvent A: twice as much as the reaction solvent by volume). The yield was 70%.

The ratio of substances whose molecular weight is equal to or less than one-fourth of the weight-average molecular weight (Mw) was calculated by measuring the weight-average molecular weight (Mw), the degree of branching (Br), and the metal content of the hyperbranched polymer (core portion D) in the fourth example in a similar manner to that in the first example. The results of core portion D are indicated in table 2.

### Fifth Example

### Synthesis of Hyperbranched Polymer

### Core Portion E

Synthesis of the hyperbranched polymer (core portion E) of a fifth example will be explained. The hyperbranched polymer (core portion E) of the fifth example was synthesized in the following manner. Firstly, 11.8 g of 2,2′-bipyridyl, 3.5 g of copper (I) chloride, and 345 mL of benzonitrile were charged into a four-necked flask (300 mL volume), which was then assembled with a cooling column, an agitator, and a dropping funnel containing 54.2 g of weighed chloromethyl styrene. The inside the reaction equipment thus assembled was entirely degassed and replaced with an argon gas. After the argon-replacement, the mixture was heated at 125° C., and then chloromethyl styrene was added dropwise for 30 minutes. After the dropwise addition, the heating and agitation was continued for 3.5 hours. The reaction time including the dropwise addition of chloromethyl styrene into the reaction vessel was 4 hours.

After the reaction, the reaction solution was filtered through a filter paper having a retaining particle size of 1 μm. The filtered solution was poured into a pre-mixed solution of 844 g of methanol and 211 g of the ultrapure water to re-precipitate poly(chloromethyl styrene).

After 29 g of the polymer obtained by re-precipitation was dissolved into 100 g of benzonitrile (solvent B: 2 mL per 1 g of polymer), to the resulting solution a mixed solution of 200 g of methanol and 50 g of the ultrapure water (solvent C: four times as much as solvent B by volume) were added. After centrifugal separation, the solvents were removed by decantation to recover the polymer. This recovery operation was repeated three times to obtain a deposited polymer.

After the decantation, the precipitated product was dried under reduce pressure and 14.0 g of poly(chloromethyl styrene) was obtained. The yield was 26%.

The ratio of the substances having a molecular weight equal to or less than one-fourth of the weight-average molecular weight (Mw) was calculated by measuring the weight-average molecular weight (Mw), the degree of branching (Br), and the metal content of the hyperbranched polymer (Core Portion E) in the fifth example in a similar manner to that in the first example. The results of core portion E are indicated in table 2.

### First Comparative Example

### Synthesis of Hyperbranched Polymer

### Core Portion F

Synthesis of the hyperbranched polymer (core portion F) in a first comparative example will be explained. In the synthesis of the hyperbranched polymer (core portion F) in the first comparative example, the polymerization reaction was carried out for 300 minutes as the reaction time in a similar manner to that in the synthesis of core portion A of the hyperbranched polymer as explained in the first example.

In the synthesis of the hyperbranched polymer (core portion F) in the first comparative example, core portion F of the hyperbranched polymer was synthesized in a similar manner to that in the synthesis of core portion A of the hyperbranched polymer explained in the first example, except that solvent A used in the purification was changed to a mixture of 160 mL of hexane (solvent A: equivolume to the reaction solvent). The yield was 70%.

The ratio of substances whose molecular weight is equal to or less than one-fourth of the weight-average molecular weight (Mw) was calculated by measuring the weight-average molecular weight (Mw), the degree of branching (Br), and the metal content of the hyperbranched polymer (core portion F) in the first comparative example in a similar manner to that in the first example. The results of core portion F are indicated in table 2.

### Second Comparative Example

### Synthesis of Hyperbranched Polymer

### Core Portion G

Synthesis of the hyperbranched polymer (core portion G) in a second comparative example will be explained. In the synthesis of the hyperbranched polymer (core portion G) in the second comparative example, the polymerization reaction was carried out for 300 minutes as the reaction time in a similar manner to that in the synthesis of core portion A of the hyperbranched polymer as explained in the second example.

In the synthesis of the hyperbranched polymer (core portion G) in the second comparative example, core portion G of the hyperbranched polymer was synthesized in a similar manner to that in the synthesis of core portion A of the hyperbranched polymer explained in the first example, except that solvent A used in the purification was changed to a mixture of 160 mL of toluene (solvent A: equivolume to the reaction solvent). The yield was 0%.

The ratio of substances whose molecular weight is equal to or less than one-fourth of the weight-average molecular weight (Mw) was calculated by measuring the weight-average molecular weight (Mw), the degree of branching (Br), and the metal content of the hyperbranched polymer (core portion G) in the second comparative example in a similar manner to that in the first example. The results of core portion G are indicated in table 2.

### Third Comparative Example

### Synthesis of Hyperbranched Polymer

### Core Portion F

Synthesis of the hyperbranched polymer (core portion F) in a third comparative example will be explained. In the synthesis of the hyperbranched polymer (core portion F) in the third comparative example, the polymerization reaction was carried out for 360 minutes as the reaction time in a similar manner to that in the synthesis of core portion A of the hyperbranched polymer as explained in the first example.

After the reaction, to the reaction mixture, 1000 mL of tetrahydrofuran and 200 g of an active alumina was added, and then the resulting mixture was agitated for one hour. The active alumina was separated by suction filtration, and tetrahydrofuran in the filtered solution was removed by a rotary evaporator. Thereafter, 320 mL of methanol (solvent A: twice as much as the reaction solvent by volume) was added to the residual material for re-precipitation, and then the supernatant solution was removed by decantation after the mixture was allowed to stand overnight.

After the decantation, the precipitated substance was dried under reduced pressure, and to 20 g of the polymer obtained by re-precipitation, a mixed solvent of 40 mL tetrahydrofuran and 160 mL of methanol was added. The resulting mixture was agitated for 30 minutes, and then the solvent was removed by decantation and a hyperbranched polymer (Core Portion H) was obtained as a purified substance. The yield was 48%.

The ratio of the substances having a molecular weight equal to or less than one-fourth of the weight-average molecular weight (Mw) was calculated by measuring the weight-average molecular weight (Mw), the degree of branching (Br), and the metal content of the hyperbranched polymer (Core Portion H). The results of Core Portion H are indicated in table 2.

### Sixth Example)

### Synthesis of the Core-Shell Hyperbranched Polymer

Synthesis of the core-shell hyperbranched polymer of a sixth example will be explained. In the synthesis of the core-shell hyperbranched polymer of the sixth example, into a four-necked reaction vessel containing 2.7 g of copper (I) chloride, 8.3 g of 2,2′-bipyridyl, and 16.2 g of the core polymer A synthesized in the first example, 144 mL of monochlorobenzene and 76 mL of tert-butyl acrylate were charged by syringe under an argon atmosphere, and then the resulting mixture was agitated and heated at 120° C. for 5 hours.

To the reaction mixture after agitation and heating, 200 mL of the ultrapure water was added, and the resulting mixture was agitated for 20 minutes. After the agitation, a water layer was removed from the reaction mixture. A series of the operations to add the ultrapure water, agitate the mixture, and remove the water layer from the reaction mixture obtained after the agitation was repeated four times to remove the copper reaction catalyst, and a solution with a pale yellow color was obtained.

The obtained solution with a pale yellow color was distilled away under a vacuum to obtain a crude polymer product. After the crude polymer product was dissolved in 50 mL of tetrahydrofuran, 500 mL of methanol was added for re-precipitation, and then the solution was centrifuged to separate a solid component. The precipitated substance in the re-precipitated solution obtained by centrifugal separation was washed by methanol to obtain a purified solid substance with a pale yellow color. The yield was 18.7 g. The mol fraction of the polymer was calculated by ¹H-NMR.

### (Deprotection Step)

After 0.6 gram of the polymer was weighed into a reaction vessel equipped with a reflux column, 30 mL of dioxane and 0.6 milliliter of 30% hydrochloric acid were added, and the resulting mixture was agitated and heated at 90° C. for 60 minutes. The crude reaction product after the agitation and heating was poured into 300 mL of the ultrapure water and re-precipitated. After the re-precipitated solid component was dissolved into 30 mL of dioxane, the solid component was re-precipitated again. The solid component re-precipitated again was recovered and dried to obtain Polymer-1. The yield was 0.4 gram (66%). The structure of Polymer-1 is depicted by formula (XIV).

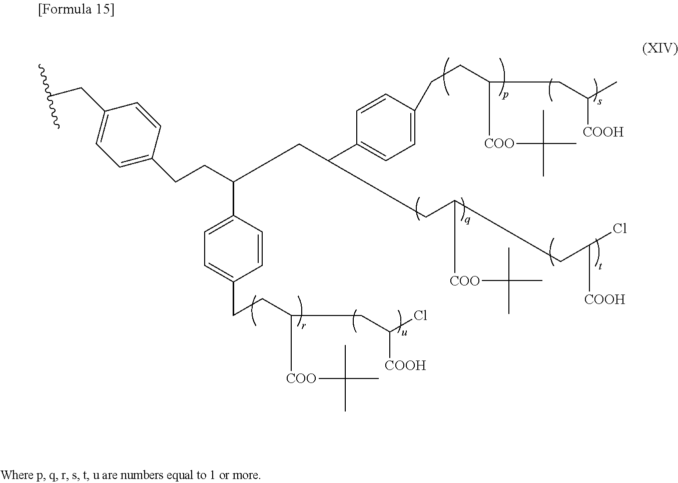

The introduction ratio (composition ratio) of each composition unit of Polymer-1 represented by formula (XIV) was obtained by ¹H-NMR. The weight-average molecular weight (M) of Polymer-1 was calculated by using the introduction ratio and the molecular weight of each composition unit based on the weight-average molecular weight (Mw) of the core portion A obtained in the first example. The weight-average molecular weight (M) of Polymer-1 was calculated specifically by equation (C) and equation (D). The results are indicated in Table 3.

$$[ Equation 3 ]$$

$$\begin{matrix}A = \frac{Mw}{b} \\ [ Equation 4 ] & Equation ( C ) \\ M = Mw + \frac{A \times C \times c + A \times D \times d}{B} & Equation ( D )\end{matrix}$$

In equation (C) and equation (D), A to D, b to d. Mw, and M are as follows:

A: Mol number of the core portion obtained

B: Mol ratio of the chloromethyl styrene part obtained from NMR

C: Mol ratio of the tert-butyl acrylate part obtained from NMR

D: Mol ratio of the acrylic acid part obtained from NMR

b: Molecular weight of the chloromethyl styrene part

c: Molecular weight of the tert-butyl acrylate part

d: Molecular weight of the acrylic acid part

Mw: Weight-average molecular weight of the core portion

M: Weight-average molecular weight of the hyperbranched polymer

The introduction ratio (introduction rate) and the weight-average molecular weight (M) of each composition unit of the core-shell hyperbranched polymers Polymer-2 to Polymer-6 in the seventh to the eleventh examples were obtained in a similar manner to that in the sixth example. The results of Polymer-2 to Polymer-6 are indicated in Table 3.

### Seventh Example

### Synthesis of Core-Shell Hyperbranched Polymer

The core-shell hyperbranched polymer of a seventh example will be explained. The core-shell hyperbranched polymer of the seventh example was synthesized by using the core portion polymer E of the fifth example. Into a four-necked reaction vessel (volume of 500 mL) under an argon atmosphere and containing 1.6 g of copper (I) chloride, 5.1 g of 2,2′-bipyridyl, and 10.0 g of the hyperbranched polymer of the tenth example, 248 mL of monochlorobenzene and 48 mL of acrylic acid tert-butyl ester were charged by syringe, respectively. Subsequently, the mixture in the reaction vessel was heated at 125° C. and agitated for 5 hours.

### (Removal of Trace Metal)

After the termination of the polymerization reaction carried out by heating with agitation as described above, the reaction system resulting after the termination of the polymerization reaction was filtered to remove undissolved matter. Subsequently, to 308 g of the filtered solution obtained by the filtration, 615 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 62.5 g of a concentrated solution was obtained. To the resulting concentrated solution, 219 g of methanol and then 31 g of ultrapure water were added to precipitate a solid component. After the solid component obtained by precipitation was dissolved into 20 g of THF, 200 g of methanol and 29 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 23.8 g. The mol fraction of the co-polymer (the core-shell hyperbranched polymer having the formed shell portion) was calculated from 1H-NMR. The core/shell mol ratio of the core-shell hyperbranched polymer having the formed shell portion was 30/70.

### Eighth Example

### Synthesis of the Core-Shell Hyperbranched Polymer

The core-shell hyperbranched polymer of an eighth example will be explained. The core-shell hyperbranched polymer of the eighth example was synthesized by partially decomposing (deprotection process) the acid-decomposable group of the core-shell hyperbranched polymer of the seventh example above.

### (Deprotection)

The partial decomposition of the acid-decomposable group in the eighth example will be explained. In the partial decomposition of the acid-decomposable group in the eighth example, firstly 2.0 g of the copolymer (the core-shell hyperbranched polymer above) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 60 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.6 g of the polymer was obtained. The ratio of the acid-decomposable group to the acid group was 78/22.

### Ninth Example

### Synthesis of Core-Shell Hyperbranched Polymer

The core-shell hyperbranched polymer of a ninth example will be explained. The core-shell hyperbranched polymer of the ninth example was synthesized by using the core portion polymer E of the fifth example. Into a four-necked reaction vessel (volume of 500 mL) under an argon atmosphere and containing 1.6 g of copper (I) chloride, 5.1 g of 2,2′-bipyridyl, and 10.0 g of the hyperbranched polymer of the tenth example, 248 mL of monochlorobenzene and 81 mL of acrylic acid tert-butyl ester were charged by syringe, respectively. Subsequently, the mixture in the reaction vessel was heated at 125° C. and agitated for 5 hours.

### (Removal of Trace Metal)

After the termination of the polymerization reaction carried out by heating with agitation as described above, the reaction system resulting after the termination of the polymerization reaction was filtered to remove undissolved matter. Subsequently, to 340 g of the filtered solution obtained by the filtration, 680 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 88.0 g of a concentrated solution was obtained. To the resulting concentrated solution, 308 g of methanol and then 44 g of ultrapure water were added to precipitate a solid component. After the solid component obtained by precipitation was dissolved into 44 g of THF, 440 g of methanol and 63 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 33.6 g. The mol fraction of the co-polymer (the core-shell hyperbranched polymer having the formed shell portion) was calculated from 1H-NMR. The core/shell mol ratio of the core-shell hyperbranched polymer having the formed shell portion (hereinafter, core-shell hyperbranched polymer) was 19/81.

### (Deprotection)

The partial decomposition of the acid-decomposable group in the ninth example will be explained. In the partial decomposition of the acid-decomposable group in the ninth example, firstly 2.0 g of the copolymer (the core-shell hyperbranched polymer above) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 30 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.6 g of the polymer was obtained. The ratio of the acid-decomposable group to the acid group was 92/8.

### Tenth Example

### Synthesis of Core-Shell Hyperbranched Polymer

The core-shell hyperbranched polymer of a tenth example will be explained. The core-shell hyperbranched polymer of the tenth example was synthesized by using the core portion polymer E of the fifth example. Into a four-necked reaction vessel (volume of 1000 mL) under an argon atmosphere and containing 1.6 g of copper (I) chloride, 5.1 g of 2,2′-bipyridyl, and 10.0 g of the hyperbranched polymer of the tenth example, 248 mL of monochlorobenzene and 187 mL of acrylic acid tert-butyl ester were charged by syringe, respectively. Subsequently, the mixture in the reaction vessel was heated at 125° C. and agitated for 5 hours.

### (Removal of Trace Metal)

After the termination of the polymerization reaction carried out by heating with agitation as described above, the reaction system resulting after the termination of the polymerization reaction was filtered to remove undissolved matter. Subsequently, to 440 g of the filtered solution obtained by the filtration, 880 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 175 g of a concentrated solution was obtained. To the resulting concentrated solution, 613 g of methanol and then 88 g of ultrapure water were added to precipitate a solid component. After the solid component obtained by precipitation was dissolved into 85 g of THF, 850 g of methanol and 121 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 65.9 g. The mol fraction of the co-polymer (the core-shell hyperbranched polymer having the formed shell portion) was calculated from 1H-NMR. The core/shell mol ratio of the core-shell hyperbranched polymer having the formed shell portion (hereinafter, core-shell hyperbranched polymer) was 10/90.

### (Deprotection)

The partial decomposition of the acid-decomposable group in the tenth example will be explained. In the partial decomposition of the acid-decomposable group in the tenth example, firstly 2.0 g of the copolymer (the core-shell hyperbranched polymer above) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 15 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.7 g of the polymer was obtained. The ratio of the acid-decomposable group to the acid group was 95/5.

### Eleventh Example

### Synthesis of Core-Shell Hyperbranched Polymer

The core-shell hyperbranched polymer of an eleventh example will be explained. The core-shell hyperbranched polymer of the eleventh example was synthesized by using the core portion polymer E of the fifth example. Into a four-necked reaction vessel (volume of 1000 mL) under an argon atmosphere and containing 1.6 g of copper (I) chloride, 5.1 g of 2,2′-bipyridyl, and 10.0 g of the hyperbranched polymer of the tenth example, 248 mL of monochlorobenzene and 14 mL of acrylic acid tert-butyl ester were charged by syringe, respectively. Subsequently, the mixture in the reaction vessel was heated at 125° C. and agitated for 5 hours.

### (Removal of Trace Metal)

After the termination of the polymerization reaction carried out by heating with agitation as described above, the reaction system resulting after the termination of the polymerization reaction was filtered to remove undissolved matter. Subsequently, to 285 g of the filtered solution obtained by the filtration, 570 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 32 g of a concentrated solution was obtained. To the resulting concentrated solution, 112 g of methanol and then 16 g of ultrapure water were added to precipitate a solid component. After the solid component obtained by precipitation was dissolved into 16 g of THF, 160 g of methanol and 23 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 12.1 g. The mol fraction of the co-polymer (the core-shell hyperbranched polymer having the formed shell portion) was calculated from 1H-NMR. The core/shell mol ratio of the core-shell hyperbranched polymer having the formed shell portion (hereinafter, core-shell hyperbranched polymer) was 61/39.

### (Deprotection)

The partial decomposition of the acid-decomposable group in the eleventh example will be explained. In the partial decomposition of the acid-decomposable group in the eleventh example, firstly 2.0 g of the copolymer (the core-shell hyperbranched polymer above) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 150 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.4 g of the polymer was obtained. The ratio of the acid-decomposable group to the acid group was 49/51.

### First Reference Example

### Synthesis of Tert-Butyl 4-Vinylbenzoate

The synthesis was carried out with reference to Synthesis, 833-834 (1982). Into a reaction vessel (1 liter volume) equipped with a dropping funnel, under an argon atmosphere, 91 g of 4-vinyl benzoic acid, 99.5 g of 1,1′-carbodimidazole, 2.4 g of 4-tert-butyl pyrocathecol, and 500 g of dehydrated dimethyl formamide were added, and the resulting solution was agitated for one hour at a constant temperature of 30° C. Thereafter, 93 g of 1,8-diazabicyclo[5.4.0]-7-undecene and 91 g of dehydrated 2-methyl-2-propanol was added, and the resulting mixture was agitated for 4 hours. After the reaction, 300 mL of diethyl ether and an aqueous potassium carbonate solution (10%) were added thereto, and then an intended substance was extracted to an ether layer. Thereafter, the diethyl ether layer was dried under reduced pressure to obtain tert-butyl 4-vinylbenzoate with a pale yellow color. It was confirmed by 1H-NMR that the intended substance was obtained. The yield was 88%.

The introduction ratio (introduction rate) and the weight-average molecular weight (M) of each composition unit of the core-shell hyperbranched polymers Polymer-7 to Polymer-10 in the twelfth to the fifteenth examples were obtained in a similar manner to that in the sixth example, except that tert-butyl 4-vinylbenzoate instead of tert-butyl acrylate and 4-vinylbenzoic acid instead of acrylic acid were used in equation (C) and equation (D). The results of Polymer-7 to Polymer-10 are indicated in Table 3.

### Twelfth Example

### Synthesis of Core-Shell Hyperbranched Polymer

The core-shell hyperbranched polymer of a twelfth example will be explained. The core-shell hyperbranched polymer of the twelfth example was synthesized by using the core portion polymer E of the fifth example. Into a four-necked reaction vessel (volume of 1000 mL) under an argon atmosphere and containing 0.8 g of copper (I) chloride, 2.6 g of 2,2′-bipyridyl, and 5.0 g of the hyperbranched polymer of the tenth example, 421 mL of monochlorobenzene and 46.8 g of tert-butyl 4-vinylbenzoate were charged by syringe, respectively. Subsequently, the mixture in the reaction vessel was heated at 125° C. and agitated for 3.5 hours.

After the termination of the polymerization reaction carried out by heating with agitation as described above, the reaction system resulting after the termination of the polymerization reaction was filtered to remove undissolved matter. Subsequently, to 490 g of the filtered solution obtained by the filtration, 980 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 41 g of a concentrated solution was obtained. To the resulting concentrated solution, 144 g of methanol and then 21 g of ultrapure water were added to precipitate a solid component. After the solid component obtained by precipitation was dissolved into 21 g of THF, 210 g of methanol and 30 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 15.9 g. The mol fraction of the co-polymer (the core-shell hyperbranched polymer having the formed shell portion) was calculated from 1H-NMR. The core/shell mol ratio of the core-shell hyperbranched polymer having the formed shell portion (hereinafter, core-shell hyperbranched polymer) was 29/71.

### (Deprotection)

The partial decomposition of the acid-decomposable group in the twelfth example will be explained. In the partial decomposition of the acid-decomposable group in the twelfth example, firstly 2.0 g of the copolymer (the core-shell hyperbranched polymer above) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 180 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.7 g of the polymer was obtained. The ratio of the acid-decomposable group to the acid group was 38/62.

### Thirteenth Example

### Synthesis of Core-Shell Hyperbranched Polymer

The core-shell hyperbranched polymer of a thirteenth example will be explained. The core-shell hyperbranched polymer of the thirteenth example was synthesized by using the core portion polymer E of the fifth example. Into a four-necked reaction vessel (volume of 1000 mL) under an argon atmosphere and containing 0.8 g of copper (I) chloride, 2.6 g of 2,2′-bipyridyl, and 5.0 g of the hyperbranched polymer of the tenth example, 421 mL of monochlorobenzene and 46.8 g of tert-butyl 4-vinylbenzoate were charged by syringe, respectively. Subsequently, the mixture in the reaction vessel was heated at 125° C. and agitated for 3 hours.

After the termination of the polymerization reaction carried out by heating with agitation as described above, the reaction system resulting after the termination of the polymerization reaction was filtered to remove undissolved matter. Subsequently, to 490 g of the filtered solution obtained by the filtration, 980 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 32 g of a concentrated solution was obtained. To the resulting concentrated solution, 244 g of methanol and then 32 g of ultrapure water were added to precipitate a solid component. After the solid component obtained by precipitation was dissolved into 32 g of THF, 320 g of methanol and 46 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 24.5 g. The mol fraction of the co-polymer (the core-shell hyperbranched polymer having the formed shell portion) was calculated from 1H-NMR. The core/shell mol ratio of the core-shell hyperbranched polymer having the formed shell portion (hereinafter, core-shell hyperbranched polymer) was 20/80.

### (Deprotection)

The partial decomposition of the acid-decomposable group in the thirteenth example will be explained. In the partial decomposition of the acid-decomposable group in the thirteenth example, firstly 2.0 g of the copolymer (the core-shell hyperbranched polymer above) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 90 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.7 g of the polymer was obtained. The ratio of the acid-decomposable group to the acid group was 71/29.

### Fourteenth Example

### Synthesis of Core-Shell Hyperbranched Polymer

The core-shell hyperbranched polymer of a fourteenth example will be explained. The core-shell hyperbranched polymer of the fourteenth example was synthesized by using the core portion polymer E of the fifth example. Into a four-necked reaction vessel (volume of 1000 mL) under an argon atmosphere and containing 0.8 g of copper (I) chloride, 2.6 g of 2,2′-bipyridyl, and 5.0 g of the hyperbranched polymer of the tenth example, 530 mL of monochlorobenzene and 60.2 g of tert-butyl 4-vinylbenzoate were charged by syringe, respectively. Subsequently, the mixture in the reaction vessel was heated at 125° C. and agitated for 4 hours.

After the termination of the polymerization reaction carried out by heating with agitation as described above, the reaction system resulting after the termination of the polymerization reaction was filtered to remove undissolved matter. Subsequently, to 620 g of the filtered solution obtained by the filtration, 1240 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 130 g of a concentrated solution was obtained. To the resulting concentrated solution, 455 g of methanol and then 65 g of ultrapure water were added to precipitate a solid component. After the solid component obtained by precipitation was dissolved into 65 g of THF, 650 g of methanol and 93 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 50.2 g. The mol fraction of the co-polymer (the core-shell hyperbranched polymer having the formed shell portion) was calculated from 1H-NMR. The core/shell mol ratio of the core-shell hyperbranched polymer having the formed shell portion (hereinafter, core-shell hyperbranched polymer) was 9/91.

### (Deprotection)

The partial decomposition of the acid-decomposable group in the fourteenth example will be explained. In the partial decomposition of the acid-decomposable group in the fourteenth example, firstly 2.0 g of the copolymer (the core-shell hyperbranched polymer above) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 30 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.7 g of the polymer was obtained. The ratio of the acid-decomposable group to the acid group was 92/8.

### Fifteenth Example

### Synthesis of Core-Shell Hyperbranched Polymer

The core-shell hyperbranched polymer of a fifteenth example will be explained. The core-shell hyperbranched polymer of the fifteenth example was synthesized by using the core portion polymer E of the fifth example. Into a four-necked reaction vessel (volume of 1000 mL) under an argon atmosphere and containing 0.8 g of copper (I) chloride, 2.6 g of 2,2′-bipyridyl, and 5.0 g of the hyperbranched polymer of the tenth example, 106 mL of monochlorobenzene and 8.0 g of tert-butyl 4-vinylbenzoate were charged by syringe, respectively. Subsequently, the mixture in the reaction vessel was heated at 125° C. and agitated for 1 hour.

After the termination of the polymerization reaction carried out by heating with agitation as described above, the reaction system resulting after the termination of the polymerization reaction was filtered to remove undissolved matter. Subsequently, to 127 g of the filtered solution obtained by the filtration, 254 g of an aqueous acids mixture solution containing 3% by mass of oxalic acid and 1% by mass of hydrochloric acid, prepared using ultrapure water was added. After the resulting solution was agitated for 20 minutes, the water layer was removed from the reaction system obtained after the agitation. Then, the above-mentioned aqueous mixture solution of acids containing oxalic acid and hydrochloric acid was added to the polymer solution obtained after removal of the water layer, the resulting solution was agitated, and then the water layer was removed from the solution obtained after the agitation. These operations were repeated four times to remove the copper reaction catalyst.

A pale yellow color solution obtained after the removal of copper was concentrated under a reduced pressure of 15 mmHg at 40° C. and 19 g of a concentrated solution was obtained. To the resulting concentrated solution, 67 g of methanol and then 10 g of ultrapure water were added to precipitate a solid component. After the solid component obtained by precipitation was dissolved into 10 g of THF, 100 g of methanol and 14 g of ultrapure water were added sequentially to the resulting solution to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 7.3 g. The mol fraction of the co-polymer (the core-shell hyperbranched polymer having the formed shell portion) was calculated from 1H-NMR. The core/shell mol ratio of the core-shell hyperbranched polymer having the formed shell portion (hereinafter, core-shell hyperbranched polymer) was 60/40.

### (Deprotection)

The partial decomposition of the acid-decomposable group in the fifteenth example will be explained. In the partial decomposition of the acid-decomposable group in the fifteenth example, firstly 2.0 g of the copolymer (the core-shell hyperbranched polymer above) was collected into a reaction vessel equipped with a reflux condenser, and then 18.0 g of 1,4-dioxane and 0.2 g of sulfuric acid (50% by mass) were added. Thereafter, the entire reaction system including the reaction vessel equipped with the reflux condenser was heated at the reflux temperature, under which condition the reaction system was refluxed with agitation for 240 minutes. Thereafter, a crude product obtained after the reflux with agitation was poured into 180 mL of ultrapure water to precipitate a solid component.

After the solid component obtained by re-precipitation was dissolved into 50 g of methyl isobutyl ketone, 50 g of ultrapure water was added to the resulting solution, and then the resulting mixture was agitated vigorously at room temperature for 30 minutes. After the water layer was separated, 50 g of ultrapure water was again added and the mixture was agitated vigorously at room temperature for 30 minutes, and then the water layer was separated. A series of the operations involving the addition of 50 g of ultrapure water, the vigorous agitation of the mixture at room temperature for 30 minutes, and then the separation of the water layer was repeated an additional two times. The methyl isobutyl ketone solution was evaporated under a reduced pressure to remove the solvent, and then the residue was dried at 40° C. under a reduced pressure and 1.4 g of the polymer was obtained. The ratio of the acid-decomposable group to the acid group was 22/78.

### (Preparation of Resist Composition)

Preparation of a resist composition of the sixth to the fifteenth examples will be explained. In preparation of a resist composition in the sixth to the fifteenth examples, a resist composition is prepared by filtering a propyleneglycol monomethyl acetate (PEGMEA) solution containing 4.0% by mass of each of Polymer-1 to Polymer-10 and 0.16% by mass of triphenyl sulfonium trifluoromethane sulfonate (photo-inductive acid-generating material) through a filter with 0.45 μm pore diameter. The prepared resist composition was spin-coated on a silicon wafer, and then the solvent was evaporated by a heat-treatment at 90° C. for one minute to obtain a thin film having a 100-nanometer thickness.

### (Measurement of Sensitivity to UV Beam Exposure)

Measurement of sensitivity to UV beam exposure will be explained. In measuring the sensitivity to the UV beam exposure, an ultraviolet beam emitting instrument of an electric discharge tube type DNA-FIX DF-245 (manufactured by ATTO Corp.) was used as the light source. A 245 nm wavelength UV beam having a varying energy of 0 mJ/cm² to 50 mJ/cm² was irradiated on a 10 mm×3 mm rectangular portion of a thin film sample of about 100 nm in thickness formed on a silicon wafer described above.

The silicon wafer, after the UV irradiation, was heat-treated at 100° C. for 4 minutes, and then the silicon wafer, after the heat-treatment, was developed by immersion in an aqueous solution of tetramethyl ammonium hydroxide (TMAH, 2.4% by mass) at 25° C. for 2 minutes. The silicon wafer was then washed with water and dried. The film thickness after drying was measured by a thin film measurement instrument F20 (manufactured by Filmetrics Japan. Inc.), and the range of the irradiation energy at which the film thickness after the development became zero was measured. The results of the sixth to the fifteenth examples are indicated in Table 3.

TABLE 3

| | | | mol. of constituent elements of core-shell | | | | | | |
|---|---|---|---|---|---|---|---|---|---|
| | | | hyperbranched polymer | | | | | weight- | range of |
| | | | | | | 4-vinyl- | | average | sensitivity |
| | | core-shell | chloro- | acrylic acid | | benzoic acid | | molecular | (mJ/cm²) to |
| | core | hyperbranched | methyl | tert-butyl | acrylic | tert-butyl | 4-vinyl- | weight | ultraviolet |
| | portion | polymer No. | styrene | ester | acid | ester | benzoic acid | (M) | (254 nm) |
| sixth | A | polymer 1 | 32 | 46 | 22 | — | — | 4680 | 2 to 50 |
| example | | | | | | | | | |
| seventh | E | polymer 2 | 30 | 70 | 0 | — | — | 3260 | 7 to 50 |
| example | | | | | | | | | |
| eighth | E | polymer 3 | 30 | 55 | 15 | — | — | 3050 | 3 to 50 |
| example | | | | | | | | | |
| ninth | E | polymer 4 | 19 | 75 | 6 | — | — | 4910 | 2 to 50 |
| example | | | | | | | | | |
| tenth | E | polymer 5 | 10 | 86 | 4 | — | — | 9250 | 2 to 50 |
| example | | | | | | | | | |
| eleventh | E | polymer 6 | 61 | 19 | 20 | — | — | 1560 | 3 to 50 |
| example | | | | | | | | | |
| twelfth | E | polymer 7 | 29 | — | — | 27 | 44 | 4090 | 3 to 50 |
| example | | | | | | | | | |
| thirteenth | E | polymer 8 | 20 | — | — | 57 | 23 | 6520 | 2 to 50 |
| example | | | | | | | | | |
| fourteenth | E | polymer 9 | 9 | — | — | 84 | 7 | 15670 | 2 to 50 |
| example | | | | | | | | | |
| fifteenth | E | polymer 10 | 60 | — | — | 9 | 31 | 1870 | 3 to 50 |
| example | | | | | | | | | |

As indicated in table 2, the first to the fifth examples are superior to the first to the third comparative examples in terms of metal and oligomer removal, and thus, are clearly preferable as the hyperbranched polymer. In addition, it is clear that metal catalysts, monomers, and oligomers can be further removed by repeating the re-precipitation operation. In addition, it is clear that, as indicated in Table 3, the first to the fifth examples are preferable for the resist composition when the core-shell hyperbranched polymer is formed.

### <Chapter 3>

### (Step (A))

In Step (A), the core-shell hyperbranched polymer having the acid-decomposable group in the shell portion (hereinafter, sometimes referred to as “resist polymer intermediate”) is synthesized by the ATRP (Atom Transfer Radical Polymerization) method using a metal catalyst.

### (Core Portion)

The core portion of the hyperbranched polymer of the present invention constitutes a nucleus of the polymer molecule, and is formed by polymerizing at least monomer represented by formula (I) depicted in Chapter 1.

In formula (I), Y represents a linear, a branched, or a cyclic alkylene group, which may contain a hydroxyl group or a carboxyl group, having 1 to 10 carbon atoms, preferably 1 to 8 carbon atoms, and more preferably 1 to 6 carbon atoms. Examples include a methylene group, an ethylene group, a propylene group, an isopropylene group, a butylene group, an isobutylene group, an amylene group, a hexylene group, and a cyclohexylene group; a group in which these groups are bonded; or a group in which —O—, —CO—, and —COO— are intervened in these groups. Among them, an alkylene group having 1 to 8 carbon atoms is preferable, a linear alkylene group having 1 to 8 carbon atoms is more preferable, and a methylene group, an ethylene group, a —OCH₂— group, and a —OCH₂CH₂— group are further more preferable. Z represents a halogen atom such as fluorine, chlorine, bromine, and iodine, among which, a chlorine atom and a bromine atom are preferable.

Specific examples of monomer used in the present invention and represented by formula (I) include chloromethyl styrene, bromomethyl styrene, p-(1-chloroethyl)styrene, bromo(4-vinylphenyl)phenylmethane, 1 bromo-1-(4-vinylphenyl)propane-2-one, and 3-bromo-3-(4-vinylphenyl)propanol, among which chloromethyl styrene, bromomethyl styrene, and p-(1-chloroethyl)styrene are preferable.

Monomers constituting the core portion of the hyperbranched polymer of the present invention may include, in addition to the monomers represented by formula (I), other monomers. There is no restriction with regard to other monomers provided the monomer can be subject to radical polymerization, and may be chosen appropriately according to purpose.

Examples of other monomers capable of radical polymerization include compounds having a radical polymerizable unsaturated bond such as (meth)acrylic acid, (meth)acrylate esters, vinylbenzoic acid, vinylbenzoate esters, styrenes, an allyl compound, vinyl ethers, vinyl esters, and the like.

Specific examples of (meth)acrylate esters include tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1 ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate.

Specific examples of vinyl benzoate esters include vinyl benzoate, tert-butyl vinyl benzoate, 2-methylbutyl vinyl benzoate, 2-methylpentyl vinyl benzoate, 2-ethylbutyl vinyl benzoate, 3-methylpentyl vinyl benzoate, 2-methylhexyl vinyl benzoate, 3-methylhexyl vinyl benzoate, triethylcarbyl vinyl benzoate, 1-methyl-1-cyclopentyl vinyl benzoate, 1-ethyl-1-cyclopentyl vinyl benzoate, 1-methyl-1-cyclohexyl vinyl benzoate, 1-ethyl-1-cyclohexyl vinyl benzoate, 1-methylnorbornyl vinyl benzoate, 1-ethylnorbornyl vinyl benzoate, 2-methyl-2-adamantyl vinyl benzoate, 2-ethyl-2-adamantyl vinyl benzoate, 3-hydroxy-1-adamantyl vinyl benzoate, tetrahydrofuranyl vinyl benzoate, tetrahydropyranyl vinyl benzoate, 1-methoxyethyl vinyl benzoate, 1-ethoxyethyl vinyl benzoate, 1-n-propoxyethyl vinyl benzoate, 1-isopropoxyethyl vinyl benzoate, n-butoxyethyl vinyl benzoate, 1-isobutoxyethyl vinyl benzoate, 1-sec-butoxyethyl vinyl benzoate, 1-tert-butoxyethyl vinyl benzoate, 1-tert-amyloxyethyl vinyl benzoate, 1-ethoxy-n-propyl vinyl benzoate, 1-cyclohexyloxyethyl vinyl benzoate, methoxypropyl vinyl benzoate, ethoxypropyl vinyl benzoate, 1-methoxy-1-methyl-ethyl vinyl benzoate, 1-ethoxy-1-methyl-ethyl vinyl benzoate, trimethylsilyl vinyl benzoate, triethylsilyl vinyl benzoate, dimethyl-tert-butylsilyl vinyl benzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinyl benzoate, adamantyl vinyl benzoate, 2-(2-methyl)adamantyl vinyl benzoate, chloroethyl vinyl benzoate, 2-hydroxyethyl vinyl benzoate, 2,2-dimethylhydroxypropyl vinyl benzoate, 5-hydroxybenzyl vinyl benzoate, trimethylolpropane vinyl benzoate, glycidyl vinyl benzoate, benzyl vinyl benzoate, phenyl vinyl benzoate, and naphthyl vinyl benzoate.

Specific examples of styrenes include styrene, benzyl styrene, trifluoromethyl styrene, acetoxy styrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethyl styrene, 4-fluoro-3-trifluoromethyl styrene, and vinyl naphthalene.

Specific examples of allyl compounds include allyl acetate, allyl caproate, allyl caprylate, allyl laurate, allyl palmitate, allyl stearate, allyl benzoate, allyl acetoacetate, allyl lactate, and allyl oxyethanol.

Specific examples of vinyl ethers include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethyleneglycol vinyl ether, dimethylaminoethyl vinyl ether, diethylaminoethyl vinyl ether, butylaminoethyl vinyl ether, benzyl vinyl ether, tetrahydrofurfuryl vinyl ether, vinyl phenyl ether, vinyl tolyl ether, vinyl chlorophenyl ether, vinyl 2,4-dichlorophenyl ether, vinyl naphthyl ether, and vinyl anthranyl ether.

Specific examples of vinyl esters include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl buthoxyacetate, vinyl phenylacetate, vinyl acetoacetate, vinyl lactate, vinyl β-phenylbutyrate, and vinyl cyclohexylcarboxylate.

Among them, (meth)acrylic acid, (meth)acrylate esters, 4-vinylbenzoic acid, 4-vinylbenzoate esters, and styrenes are preferable. In particular, (meth)acrylic acid, tert-butyl(meth)acrylate, 4-vinyl benzoic acid, tert-butyl 4-vinylbenzoate, styrene, benzyl styrene, chlorostyrene, and vinyl naphthalene are preferable.

In the hyperbranched polymer of the present invention, the amount of monomer constituting the core portion is 10 to 90% by mol, preferably 10 to 80% by mol, and more preferably 10 to 60% by mol, relative to the total monomer. When the amount of monomer constituting the core portion is at this range, an appropriate hydrophobicity to a developing solution is imparted, thereby suppressing dissolution of the unexposed part, and thus, is preferable.

The amount of monomer represented by formula (I) is 5 to 100% by mol, preferably 20 to 100% by mol, and more preferably 50 to 100% by mol, relative to the total monomer constituting the core portion of the hyperbranched polymer in the present invention. At this range, the core portion takes a spherical morphology which advantageously suppresses intermolecular entanglement, and thus, is preferable.

When the core portion of the hyperbranched polymer of the present invention is a copolymer of the monomer represented by formula (I) and other polymers, the amount of monomer represented by formula (I) relative to the total monomer constituting the core portion is preferably 10 to 99% by mol, more preferably 20 to 99% by mol, and in particular 30 to 99%. When the monomer represented by formula (I) is included at this amount, the core portion takes a spherical morphology which advantageously suppresses intermolecular entanglement, and thus, is preferable.

When the monomer represented by formula (I) is used at this amount, functions such as substrate adhesiveness and glass transition temperature can be improved while maintaining a spherical morphology in the core portion, and thus, is preferable. The amounts of the monomer represented by formula (I) and of other monomers in the core portion may be controlled by the charge ratio for the polymerization, according to purpose.

### (Shell Portion)

The shell portion of the hyperbranched polymer of the present invention constitutes a polymer molecule terminal of the polymer and has a repeating unit represented by formula (II) and/or a repeating unit represented by formula (III) depicted in Chapter 1. The repeating unit contains the acid-decomposable group decomposable by the action of an organic acid such as acetic acid, maleic acid, and benzoic acid or an inorganic acid such as hydrochloric acid, sulfuric acid, and nitric acid, and more preferably by the action of any one of a photo-inductive acid-generating material, which generates an acid by a photo energy, and a heat or both. It is preferable that the acid-decomposable group become a hydrophilic group by decomposition.

R¹ in formula (II) and R⁴ in formula (III) represent a hydrogen atom or an alkyl group having 1 to 3 carbon atoms. Among them, a hydrogen atom and a methyl group are preferable, and a hydrogen atom is more preferable.

R² in formula (II) represents a hydrogen atom; a linear, a branched, or a cyclic alkyl group having 1 to 30 carbon atoms, preferably 1 to 20 carbon atoms, and more preferably 1 to 10 carbon atoms; or an aryl group having 6 to 30 carbon atoms, preferably 6 to 20 carbon atoms, and more preferably 6 to 10 carbon atoms. Examples of the linear, the branched, or the cyclic alkyl group include a methyl group, an ethyl group, a propyl group, an isopropyl group, a butyl group, an isobutyl group, a tert-butyl group, and a cyclohexyl group. Examples of the aryl group include a phenyl group, a 4-methylphenyl group, and a naphthyl group. Among them, a hydrogen atom, a methyl group, an ethyl group, and a phenyl group are preferable, though a hydrogen atom is particularly preferable.

R³ in formula (II) and R⁵ in formula (III) represent a hydrogen atom; a linear, a branched, or a cyclic alkyl group having 1 to 40 carbon atoms, preferably 1 to 30 carbon atoms, and more preferably 1 to 20 carbon atoms; a trialkyl silyl group (here, the number of carbons in each alkyl group is 1 to 6, preferably 1 to 4); an oxoalkyl group (here, the number of carbons in the alkyl group is 4 to 20, preferably 4 to 10); or the group represented by formula (i) in Chapter 1 (here, R⁶ represents a hydrogen atom; a linear, a branched, or a cyclic alkyl group having 1 to 10 carbon atoms, preferably 1 to 8 carbon atoms, and more preferably 1 to 6 carbon atoms. Each R⁷ and R⁸ independently represents a hydrogen atom; a linear, a branched, or a cyclic alkyl group having 1 to 10 carbon atoms, preferably 1 to 8 carbon atoms, and more preferably 1 to 6 carbon atoms; or may form a ring by bonding with each other). Among them, a linear, a branched, or a cyclic alkyl group having 1 to 40 carbon atoms, preferably 1 to 30 carbon atoms, and more preferably 1 to 20 carbon atoms is preferable. A branched alkyl group having 1 to 20 carbon atoms is more preferable.

In the above-mentioned R³ and R⁵, examples of the linear, the branched, or the cyclic alkyl group include an ethyl group, a propyl group, an isopropyl group, a butyl group, an isobutyl group, a tert-butyl group, a cyclopentyl group, a cyclohexyl group, a cycloheptyl group, a triethylcarbyl group, a 1-ethylnorbornyl group, a 1-methylcyclohexyl group, an adamantyl group, a 2-(2-methyl)adamantyl group, and a tert-amyl group. Among them, a tert-butyl group is particularly preferable.

In the above-mentioned R³ and R⁵, examples of the trialkyl silyl group include the trialkyl group whose each alkyl group has 1 to 6 carbon atoms, such as a trimethyl silyl group, a triethyl silyl group, and a dimethyl tert-butyl silyl group. Examples of the oxoalkyl group include a 3-oxocyclohexyl group.

R⁶ in formula (i) represents a linear, a branched, or a cyclic alkyl group having 1 to 10 carbon atoms. Each R⁷ and R⁸ independently represents a hydrogen atom; a linear, a branched, or a cyclic alkyl group having 1 to 10 carbon atoms, or R⁷ and R⁸ may form a ring by bonding with each other.

Examples of the group represented by formula (i) include a linear or a branched acetal group such as a 1-methoxyethyl group, a 1-ethoxyethyl group, a 1-n-propoxyethyl group, a 1-isopropoxyethyl group, a 1-n-butoxyethyl group, a 1-isobutoxyethyl group, a 1-sec-butoxyethyl group, a 1-tert-butoxyethyl group, a 1-tert-amyloxyethyl group, a 1-ethoxy-n-propyl group, a 1-cyclohexyloxyethyl group, a methoxypropyl group, an ethoxypropyl group, a 1-methoxy-1-methyl-ethyl group, and 1-ethoxy-1-methyl-ethyl group; a cyclic acetal group such as a tetrahydrofuranyl group and a tetrahydropyranyl group. Among them, an ethoxyethyl group, a butoxyethyl group, an ethoxypropyl group, and a tetrahydropyranyl group are particularly preferable.

Monomers giving repeating units represented by formula (II) include, for example, vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δvalerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate. Among these, a copolymer of 4-vinylbenzoic acid and tert-butyl 4-vinylbenzoate is preferable.

Monomers giving repeating units represented by formula (III) include, for example, acrylate, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1-ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, methacrylic acid, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate. Among these, copolymers of acrylate and tert-butyl acrylate are preferable. Here, copolymers of any one of 4-vinylbenzoic acid and acrylic acid or both, and any one of tert-butyl 4-vinylbenzoate and tert-butyl acrylate or both are also preferable.

Monomers other than the monomers giving the repeating unit represented by formula (II) and formula (III) may be used as the monomers constituting the shell portion provided the monomers have a structure containing a radical polymerizable unsaturated bond.

Examples of monomers usable as a comonomer include compounds containing a radical polymerizable unsaturated bond, selected from among styrenes, an allyl compound, vinyl ethers, vinyl esters, and crotonate esters, except for the monomers as described above.

Specific examples of styrenes include styrene, tert-buthoxy styrene, α-methyl-tert-buthoxy styrene, 4-(1-methoxyethoxy)styrene, 4-(1-ethoxyethoxy)styrene, tetrahydropyranyloxy styrene, adamantyloxy styrene, 4-(2-methyl-2-adamantyloxy)styrene, 4-(1-methylcyclohexyloxy)styrene, trimethylsilyloxy styrene, dimethyl-tert-butylsilyloxy styrene, tetrahydropyranyloxy styrene, benzyl styrene, trifluoromethyl styrene, acetoxy styrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethyl styrene, 4-fluoro-3-trifluoromethyl styrene, and vinyl naphthalene.

Specific examples of the allyl esters include allyl acetate, allyl caproate, allyl caprylate, allyl laurate, allyl palmitate, allyl stearate, allyl benzoate, allyl acetoacetate, allyl lactate, and allyl oxyethanol.

Specific examples of the vinyl ethers include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethyleneglycol vinyl ether, dimethylaminoethyl vinyl ether, diethylaminoethyl vinyl ether, butylaminoethyl vinyl ether, benzyl vinyl ether, tetrahydrofurfuryl vinyl ether, vinyl phenyl ether, vinyl tolyl ether, vinyl chlorophenyl ether, vinyl 2,4-dichlorophenyl ether, vinyl naphthyl ether, and vinyl anthranyl ether.

Specific examples of the vinyl esters include vinyl butyrate, vinyl isobutyrate, vinyl trimethyl acetate, vinyl diethylacetate, vinyl valerate, vinyl caproate, vinyl chloroacetate, vinyl dichloroacetate, vinyl methoxyacetate, vinyl buthoxyacetate, vinyl phenyl acetate, vinyl acetoacetate, vinyl lactate, vinyl β-phenyl butyrate, and vinyl cyclohexyl carboxylate.

Specific examples of the crotonate esters include butyl crotonate, hexyl crotonate, glycerin monocrotonate, dimethyl itaconate, diethyl itaconate, dibutyl itaconate, dimethyl maleate, dibutyl fumarate, maleic anhydride, maleimide, acrylonitrile, methacrylonitrile, and maleironitrile. The monomers represented by formula (IV) to formula (XIII) depicted in Chapter 1 and the like may also be included.

Among them, styrenes and crotonate esters, in particular, styrene, benzyl styrene, chlorostyrene, vinyl naphthalene, butyl crotonate, hexyl crotonate, and maleic anhydride are preferable.

In the hyperbranched polymer of the present invention, the monomers giving the repeating unit represented by any one of formula (II) and formula (III) or both are contained in the polymer with the amount of preferably 10 to 90% by mol, more preferably 20 to 90% by mol, and yet more preferably 30 to 90% by mol. In particular, in the shell portion, the amount of the repeating unit represented by any one of formula (II) and formula (III) or both is preferably 50 to 100% by mol, and more preferably 80 to 100% by mol. When the amount is at this range, a light-exposed part is efficiently removed in the developing step by dissolving into a basic solution, and thus, is preferable.

When the shell portion of the hyperbranched polymer of the present invention is a copolymer of monomer giving repeating units represented by formula (II) and/or monomer giving repeating units represented by formula (III) and other monomers, the amount of repeating units represented by formula (II) and/or the amount of repeating units represented by formula (III) relative to the total amount of monomer constituting the shell portion is preferably 30 to 90% by mol, and more preferably 50 to 70% by mol. When the amount is at this range, functions such as the etching resistance, the wetting properties, and the glass transition temperature are improved without damaging efficient dissolution of a light-exposed part into a basic solution, thus, is preferable.

Here, the amount of the repeating units represented by formula (II) and/or the amount of the repeating units represented by formula (III) and other repeating units in the shell portion may be controlled by the mol ratio at the time of introduction into the shell portion according to purpose.

### (Metal Catalyst)

Examples of the catalyst usable in the present invention include a catalyst formed of a transition metal such as a copper, an iron, a ruthenium, and a chromium, combined with a ligand such as pyridines and bipyridines which are unsubstituted or substituted with a group such an alkyl group, an aryl group, an amino group, a halogen group, and an ester group, or alkyl- or aryl-substituted phosphines. Examples include a catalyst such as a copper (I) bipyridyl complex composed of copper chloride and bipyridyl, and an iron triphenyl phosphine complex composed of iron chloride and triphenyl phosphine. Among them, a copper (I) bipyridyl complex is particularly preferable.

The amount of metal catalyst used in the synthesis method of the present invention is preferably 0.1 to 70% by mol, and more preferably 1 to 60% by mol, relative to the total monomer. When the catalyst is used in this amount, the core portion of the hyperbranched polymer having a desirable degree of branching can be obtained.

### (Synthesis of a Resist Polymer Intermediate)

The core-shell hyperbranched polymer having the acid-decomposable group in the shell portion can be synthesized by adding the metal catalyst into a reaction system together with a monomer forming the core portion to form the core portion having a branching structure, followed by adding a monomer forming the acid decomposable group to form the shell portion.

The core portion of the core-shell hyperbranched polymer may be synthesized by a living radical polymerization reaction of raw material monomer in a solvent such as chlorobenzene usually at 0 to 200° C. for 0.1 to 30 hours.

The shell portion of the core-shell hyperbranched polymer may be introduced into the polymer terminal by reacting the core portion of the hyperbranched polymer synthesized as described above with a monomer containing the acid-decomposable group.

### (First Method)

In a first method, after the core portion obtained at the step for synthesizing the core portion of the hyperbranched polymer as described above is separated, an acid-decomposable group represented by formula (II) and/or an acid-decomposable group represented by formula (III) may be introduced, by using, for example, a monomer giving the repeating unit represented by formula (II) and/or the repeating unit represented by formula (III) as the monomer containing the acid-decomposable group.

Additional polymerization of a linear polymerization is performed by living radical polymerization of a double bond of at least one kind of compound that includes monomer giving a repeating unit represented by formula (II) and/or a repeating unit represented by formula (III) utilizing the large number of halogenated carbons present at the afore-mentioned core terminal as the initiating points by using a transition metal complex catalyst similar to that used for the synthesis of the core portion of the core-shell hyperbranched polymer, such as a copper (I) bipyridyl complex as the catalyst. Specifically, the hyperbranched polymer of the present invention may be synthesized by reacting the core portion with at least one kind of compound that includes monomer giving a repeating unit represented by formula (II) and/or monomer giving a repeating unit represented by formula (III), usually at 0 to 200° C. for 0.1 to 30 hours in a solvent such as chlorobenzene.

### (Second Method)

In a second method, the acid-decomposable group represented by any one of formula (II) and formula (III) or both may be introduced, without separating the core portion after the core portion is formed in the step for synthesizing the core portion of the hyperbranched polymer, by using, for example, a monomer giving the repeating unit represented by formula (II) and/or monomer giving the repeating unit represented by formula (III) as the monomer containing the acid-decomposable group. In this case, the metal catalyst added in the step of forming the shell portion may be the same as or different from the metal catalyst used in the step of forming the core portion. The metal catalyst used at the step of forming the core portion may be used after being regenerated. The regeneration may be performed by a method commonly known by those skilled in the art. The removal of metal before the shell-formation and after the core-formation may be performed by the same method as used at Step (B), which will be mentioned later.

Usually, the obtained resist polymer intermediate contains 0.1 to 5% by mass of metals depending on the amount of the metal catalyst used. To maintain a high performance as a semi-conductor, it is necessary to reduce the amount of metal contained in the resist polymer to 100 ppb or less by purification. When a copper (I) bipyridyl complex is used as the metal catalyst, the copper content in the resist polymer intermediate is preferably 50 ppb or less. In the present invention, metal content may be measured by an ICP mass analysis instrument or flameless atomic absorption spectroscopy.

### (Step (B))

### (Pure Water)

Pure water used to wash the resist polymer intermediate obtained at Step (A) is preferably water having a total metal content, at 25° C., 10 ppb or less. It is also preferable to use pure water having a specific resistance, at 25° C., equal to or higher than 10 MΩ·cm. It is also further preferable to use ultrapure water having a specific resistance, at 25° C., equal to or higher than 18 MΩ·cm. To prevent contamination by metal derived from water during the washing treatment, it is preferable to reduce the metal content in the pure water used for washing as low as possible.

Pure water may be produced by a combination of methods such as distillation, adsorption by activated carbon, ion-exchange resin treatment, filtration, and reverse osmosis, specifically, by using an instrument such as, for example, CSR-200 (manufactured by Advantec Toyo Kaisha. Ltd.). For washing, the pure water and, an aqueous solution containing an organic compound having a chelating capacity (such as formic acid, oxalic acid, and acetic acid) and/or an aqueous solution containing an inorganic compound such as hydrochloric acid and sulfuric acid, may be used.

Examples of the organic compound having a chelating capacity include an organic acid such as citric acid, gluconic acid, tartaric acid, and malonic acid, in addition to formic acid, oxalic acid, and acetic acid; an amino carbonate such as nitrilotriacetic acid, ethylenediaminetetraacetic acid, and diethylenetriamine pentaacetic acid; a hydroxyamino carbonate. Among them, organic carboxylic acids are preferable, and oxalic acid and citric acid are more preferable. As the inorganic acid usable in the present invention, hydrochloric acid is preferable. The aqueous solutions of the organic compound having a chelating capacity and the aqueous solution of the inorganic acid are prepared preferably by using the pure water as described above, and the concentration of each aqueous solution is preferably 0.05 to 10% by mass.

When the pure water, an aqueous solution of the organic compound having a chelating capacity, and an aqueous solution of the inorganic acid are used, the aqueous solution of the organic compound having a chelating capacity and the aqueous solution of the inorganic acid may be used as a mixture thereof or separately. It is preferable to use the aqueous acidic solution whose pH is controlled, for example, at 5 or less. When the aqueous acidic solutions are used, a solubility distribution ratio of a metal element into a water layer is increased, thereby enabling to reduce the number of washings remarkably as compared with the washing by using pure water alone, and thus, is preferable.

The temperature of the pure water used in the washing is preferably 5 to 50° C., more preferably 10 to 40° C., and yet more preferably 15 to 30° C. When the pure water is used at these temperature ranges, washing efficiency is increased, and thus, is preferable.

### (Washing Treatment)

The washing treatment to remove metals may be performed by adding the pure water, after insoluble metals are removed by filtration from the reaction solution containing the resist polymer intermediate and the metal catalyst obtained at Step (A), or by the liquid-liquid extraction using the pure water and, the aqueous solution containing the organic compound having a chelating capacity and/or the aqueous solution containing the inorganic acid.

When the pure water and, the aqueous solution containing the organic compound having a chelating capacity and/or the aqueous solution containing the inorganic acid are added, the aqueous solution of the organic compound having a chelating capacity and the aqueous solution of the inorganic acid may be used as a mixture thereof or separately. When the aqueous solutions are used separately, the order of use is not restricted, but it is preferable to use the solution of the inorganic acid later, because it is assumed that the aqueous solution containing the organic compound having a chelating capacity is effective to remove a copper catalyst and multivalent metals, while the aqueous solution containing the inorganic acid is effective to remove monovalent metals derived from experimental equipments and the like. Accordingly, when the aqueous solution containing the organic compound having a chelating capacity and the aqueous solution containing the inorganic acid are used as a mixture for washing, washing only by the aqueous solution of the inorganic acid is preferably performed after washing by the mixture.

The volume ratio of the reaction solvent to the pure water at the time of removal of metals by washing is preferably 1:0.1 to 1:10, and more preferably 1:0.5 to 1:5. In a case where the pure water and, the aqueous solution containing the organic compound having a chelating capacity and/or the aqueous solution containing the inorganic compound are added, if each solution is used separately, it is preferable that the ratio of the reaction solvent to each solvent be at the above-mentioned range. The same is true when the aqueous solution of the organic compound having a chelating capacity and the aqueous solution of the inorganic acid are used as a mixture thereof.

In other words, it is preferably that, not only the ratio of the reaction solvent to the pure water, but also the ratio of the reaction solvent to the aqueous solution containing the organic compound having a chelating capacity, the ratio of the reaction solvent to the aqueous solution containing the inorganic acid, and the ratio of the reaction solvent to the mixture of the aqueous solution of the organic compound having a chelating capacity and the aqueous solution of the inorganic acid be at the above-mentioned range. By washing at this ratio, metals can be removed easily and by a moderate number of washing, and thus, is preferable from an operational view point. The concentration of the resist polymer intermediate dissolved in the reaction solvent is usually about 1 to about 30% by mass relative to the solvent, and it is preferable to control the concentration by adding chlorobenzene or chloroform used at the time of copolymerization, as needed.

The liquid-liquid extraction may be performed as follows: the reaction solvent and the pure water, or the pure water and, the aqueous solution of the organic compound having a chelating capacity and/or the aqueous solution of the inorganic acid are added into the reaction solution preferably at 10 to 50° C. and more preferably at 20 to 40° C., and then the resulting mixture is thoroughly mixed by agitation and the like. Thereafter, the mixture is separated into two layers after standing or centrifugal separation, and then the water layer into which metal ions have migrated is removed by a decantation and the like.

It is desirable to reduce the metal content by repeating the extraction, and as needed, performing the centrifugal separation. The number of the extractions is not particularly restricted, but when the pure water is used independently, the number of extractions is preferably two times or more, and more preferably 2 to 30 times, after a blue color of a copper ion of the metal catalyst has disappeared. When the pure water and, the aqueous solution of the organic compound having a chelating capacity and/or the aqueous solution of the inorganic acid are used, a preferable number of the extraction is 2 to 10 times after a blue color of a copper ion of the metal catalyst has disappeared.

When washing is performed by the inorganic acid after washing by the aqueous solution containing the organic compound having a chelating capacity or by the mixed solution of the aqueous solution of the organic compound having a chelating capacity and the aqueous solution of the inorganic acid, a sufficient number of washings only by the aqueous solution containing the inorganic acid is 1 to 5 times. Thus, the metal content in the hyperbranched polymer can be reduced to 100 ppb or less.

When the washing treatment is performed by the aqueous acidic solution, after the extraction treatment by the aqueous acidic solution, it is preferable to perform the extraction treatment by pure water at least 1 to 2 times and preferably 1 to 5 times to remove the acid. To avoid contamination by metals derived from experimental equipments and the like, it is preferable to use pre-washed experimental equipment particularly when the equipment is used after copper ion is reduced. A method of the pre-washing is not particularly restricted, and for example, may include washing by an aqueous nitric acid.

The solution containing the resist polymer intermediate obtained as described above contains residual monomers, by-product oligomers, ligands, and the like, in addition to the polymer. A pure resist polymer can be obtained by a re-precipitation operation using a poor solvent such as methanol to remove residual monomers and by-product oligomers. Then, the solution containing the resist polymer intermediate is subjected to an operation to remove the solvent by a vacuum distillation and the like to obtain the resist polymer intermediate in a solid state usable for applications following thereafter.

After the catalyst removal is performed as described above, metals can be removed by the following operations: the solution containing the resist polymer intermediate or the resist polymer intermediate in a solid state is dissolved into an organic solvent, and then the pure water, or the pure water and any one of the aqueous solution containing the organic compound having a chelating capacity and/or the aqueous solution containing the inorganic acid are added to the solution, and then the resulting mixture is further subjected to the liquid-liquid extraction or an ion-exchange treatment using an acid-type of an ion-exchange resin or an ion-exchange membrane.

Examples of the organic solvent preferably used when the liquid-liquid extraction is performed include, in addition to chlorobenzene and chloroform used at the time of synthesis of the resist polymer intermediate, acetate esters such as ethyl acetate, n-butyl acetate, and isoamyl acetate; ketones such as methyl ethyl ketone, methyl isobutyl ketone, cyclohexanone, 2-heptane, and 2-pentanone; glycol ether acetates such as ethyleneglycol monoethyl ether acetate, ethyleneglycol monobutyl ether acetate, ethyleneglycol monomethyl ether acetate; and aromatic hydrocarbons such as toluene and xylene. Ethyl acetate and methyl isobutyl ketone are more preferable. These solvents may be used singly or in a combination of equal to or more than two kinds.

The amount of organic solvent is preferably about 1 to about 30% by mass and more preferably about 5 to about 20% by mass as “% by mass” of the resist polymer intermediate relative to the organic solvent, similarly to that mentioned before. The ratio (by volume) of the adding pure water to the organic solvent is preferably 1:0.1 to 1:10 and more preferably 1:0.5 to 1:5, similarly to that mentioned before. The same is true for a case where the pure water and, the aqueous solution of the organic compound having a chelating capacity and/or the aqueous solution of the inorganic acid are used. The number of the extractions is not particularly restricted, but is preferably 1 to 5 times and more preferably 1 to about 3 times. The order of the washing is also the same as mentioned before.

When an acid-type of ion-exchange resin an ion-exchange-membrane is used for the metal removal, it is preferable to use it after the metal impurity content is reduced to about 1 ppm by washing with the pure water. Examples of usable ion-exchange resin include a generally used cationic ion-exchange resin such as a styrene/vinylbenzene cationic ion-exchange resin, for example, Amberlyst IR 15 (manufactured by Rohm and Haas Company). As an ion-exchange membrane, for example, Protego CP (manufactured by Nihon Mykrolis K. K.), which is obtained by graft-polymerizing a polyethylene porous membrane with an ion-exchanging group, may be used.

### (Filtration by Micro Filter)

To remove colloidal metals in particles, it is preferable to perform filtration through a filter, in addition to washing by pure water, preferably after washing by the pure water. A filter with a pore diameter of 1 μm or less is preferably used. Examples include Mykrolis PCM based on an ultra-high molecular weight polyethylene membrane and Whatman's Puradisc based on PTFE (trade mark Teflon). The filtration is performed usually at the flux of 1 mL/minute to 20 mL/second.

With such operations, the amount of metal contained in the resist polymer intermediate can be reduced to 100 ppb or less, in particular when copper chloride is used as the catalyst, the amount may be reduced further to 50 ppb or less for copper, and also to 50 ppb or less for other metals. When the partial decomposition of the acid-decomposable group is performed without sufficient metal removal at this step, the acid group such as a carboxylic acid group formed by the decomposition forms a complex with an impure metal, thereby making the metal removal by the water washing very difficult. However, according to the method of the present invention, these problems can be addressed efficiently.

### (Step (C))

According to the present invention, a hyperbranched polymer having a given ratio of the acid-decomposable group to the acid group can be obtained when the partial decomposition of the acid-decomposable group is performed after metal impurities have been reduced to a great extent after the synthesis of the resist polymer intermediate.

### (Acid Catalyst)

Specific examples of the acid catalyst include hydrochloric acid, sulfuric acid, phosphoric acid, hydrobromic acid, p-toluene sulfonic acid, acetic acid, trifluoroacetic acid, trifluoromethane sulfonic acid, and formic acid. Hydrochloric acid, sulfuric acid, p-toluene sulfonic acid, acetic acid, trifluoroacetic acid, and formic acid are preferable.

### (Decomposition of the Acid-Decomposable Group)

The partial decomposition of the acid-decomposable group by the acid catalyst as described above may be done as follows. The resist polymer intermediate in a solid state is dissolved in an appropriate organic solvent, such as 1,4-dioxane, containing usually 0.001 to 100 equivalent of the acid catalyst relative to the acid-decomposable group, and then the resulting mixture is agitated and heated usually at 50 to 150° C. for 10 minutes to 20 hours.

The optimal ratio of the acid-decomposable group to the acid group in the obtained resist polymer is different depending on composition of the resist composition, but preferably 5 to 80% by mol of the introduced acid-decomposable group in the monomer is de-protected. When the ratio of the acid-decomposable group to the acid group is at this range, a high sensitivity and an efficient dissolution into a basic solution after the light-exposure are realized, and thus, is preferable. The obtained resist polymer in a solid state may also be used, after it is separated from the reaction solvent and dried, in the applications following thereafter.

The degree of branching (Br) of the core portion in the hyperbranched polymer is preferably 0.1 to 0.9, more preferably 0.3 to 0.7, yet more preferably 0.4 to 0.5, and most preferably 0.5. When the degree of branching (Br) of the core portion is at such ranges, an intermolecular entanglement among polymers is small, thereby leading to suppressing surface roughness in the pattern wall, and thus, is preferable.

Here, the degree of branching may be obtained by measuring ¹H-NMR of the product. Namely, the branching degree can be calculated by computing equation (A) mentioned in Chapter 1 by using H1°, the integral ratio of protons in —CH₂Cl appearing at 4.6 ppm, and H2°, the integral ratio of the protons in —CHCl appearing at 4.8 ppm. Here, when the polymerization progresses at both —CH₂Cl and —CHCl thereby enhancing the branching, the value of Br approaches 0.5.

The weight-average molecular weight of the core portion of the hyperbranched polymer of the present invention is preferably 300 to 100,000, also preferably 500 to 80,000, more preferably 1,000 to 60,000, yet more preferably 1,000 to 50,000, and most preferably 1,000 to 30,000. When the molecular weight of the core portion is at such ranges, the core portion takes a spherical morphology thereby securing the solubility into the reaction solvent in the reaction to introduce the acid-decomposable group, and thus, is preferable. In addition, performance of a film-formation is excellent and also dissolution of a light-unexposed part is suppressed advantageously in the hyperbranched polymer having the acid-decomposable group introduced at its core portion having the molecular weight at the above-mentioned range, and thus, is preferable.

Weight-average molecular weight (M) of the hyperbranched polymer of the present invention is preferably 500 to 150,000, more preferably 2,000 to 150,000, yet more preferably 1,000 to 100,000, yet more preferably 2,000 to 60,000, and most preferably 3,000 to 60,000. When the weight-average molecular weight (M) of the hyperbranched polymer is at such ranges, a resist containing the hyperbranched polymer is excellent in a film formation and can maintain its form because the process pattern formed in a lithography step is strong. In addition, it is excellent in terms of dry-etching resistance and surface roughness.

Weight-average molecular weight (Mw) of the core portion may be obtained by a GPC measurement using a tetrahydrofuran solution with a concentration of 0.05% by mass at 40° C. Tetrahydrofuran may be used as a moving phase and styrene as a standard material. Weight-average molecular weight (M) of the hyperbranched polymer in the present invention may be obtained as follows: an introduction ratio (composition ratio) of repeating units in the polymer into which the acid-decomposable group is introduced is obtained by H¹NMR, and based on the weight-average molecular weight (Mw) of the core portion in the hyperbranched polymer, a calculation is made by using the introduction ratio of each composition unit and the molecular weight of each composition unit.

At the decomposition step of the acid-decomposable group, the resist polymer may be contaminated by a trace amount of metal impurities from experimental equipments and the like. Thus, after this step, the washing treatment using the pure water having a total metal content of 10 ppb or less at 25° C., or the washing treatment using the pure water an, the aqueous solution containing the organic compound having a chelating capacity and/or the aqueous solution containing the inorganic acid may be performed.

According to the method of the present invention, metal content in the obtained resist polymer can be reduced to 100 ppb. Reduction of the metal content is preferable because pollution in a plasma treatment and adverse effects to electric properties of a semi-conductor due to metal impurities remaining in a pattern can be prevented. In this regard, the concentration of the copper used as the catalyst is preferably reduced to 50 ppb. Here, the metal content referred to in the present invention indicates the total metal content including, in addition to metals derived from the metal catalyst, metals derived from the pure water used in the washing and from experimental equipment.

In the following, the embodiments of examples in Chapter 3 will be explained. The embodiments of examples in Chapter 3 are not limited to the following specific examples, nor is interpretation of the embodiments to be limited by the following specific examples.

### First Example

### Synthesis of a Resist Polymer Intermediate

Into a three-necked reaction vessel (300 mL volume) equipped with an agitator and a cooling column, under an argon gas atmosphere, 2.3 g of weighed 2,2′-bipyridyl, 0.74 g of copper (I) chloride, and 23 mL of chlorobenzene (reaction solvent) were added. Then, 4.6 g of chloromethyl styrene was added drop-wise for 5 minutes. The resulting mixture was heated at a constant internal temperature of 125° C. and agitated to synthesize the core portion. The total reaction time including the drop-wise addition was 25 minutes. Thereafter, 150 mL of chlorobenzene and 17.1 g of tert-butyl 4-vinylbenzoate were added by syringe, respectively. The resulting mixture was heated at 125° C. and agitated for 4 hours to introduce the acid-decomposable group.

### (Washing Treatment)

The reaction mixture was cooled rapidly, transferred to a reaction vessel (1 L volume), 500 mL of ultrapure water (25° C.) with a specific resistance of 18 MΩ·cm and a metal content of 1 ppb or less at 25° C. produced by GSR-200 (manufactured by Advantec Toyo Kaisha, Ltd.) were added thereto. The mixture was agitated vigorously for 30 minutes, and then allowed to stand for 15 minutes, resulting in a separation of an organic layer containing the polymer intermediate and a water layer. The water layer was removed by decantation, and then a series of the operations from the addition of 500 mL of the pure water to the separation of the water layer was repeated 18 times thereafter. Then, filtration through a microfilter (Optimizer D-300, manufactured by Nihon Mykrolis K. K.) was performed at the flux of 4 mL/minute with an application of pressure.

Then, 400 mL of methanol was added to the layer containing the resist polymer intermediate for re-precipitation, and unreacted monomers and the reaction solvent were removed by removing the supernatant solution. The deposited substance was washed by a mixed solution of tetrahydrofuran and methanol to obtain the washed resist polymer intermediate in a solid state and of a pale yellow color. The metal content was 40 ppb for copper and 23 ppb for sodium. The metal content of the resist polymer intermediate was measured by an ICP mass analysis instrument (P-6000 type MIP-MS, manufactured by Hitachi, Ltd.).

### (Decomposition of Acid-Decomposable Group)

Into a reaction vessel equipped with a reflux column were added 0.6 gram of the washed resist polymer intermediate, 30 mL of 1,4-dioxane, and 0.6 milliliter of aqueous hydrochloric acid, and then the resulting mixture was heated at 90° C. for 65 minutes to decompose a part of the tert-butyl 4-vinylbenzoate group to the 4-vinylbenzoic acid group.

Then, the obtained reaction mixture was poured into 300 mL of the ultrapure water (25° C.) with the specific resistance of 18 MΩ·cm and a metal content of less than 1 ppb at 25° C. produced by GSR-200 (manufactured by Advantec Toyo Kaisha, Ltd.). The resulting solid component was separated and dried to obtain the resist polymer. The yield was 0.44 gram. The mol ratio of the tert-butyl 4-vinylbenzoate part to the 4-vinylbenzoic acid part was measured to be 50:50 by a ¹H-NMR. The metal content in the resist polymer intermediate was measured by ICPMAS (P-6000 type MIP-MS, manufactured by Hitachi, Ltd.). The results are indicated in Table 4.

### (Preparation of Resist Composition)

A propyleneglycol monomethyl acetate (PGMEA) solution containing 4.0% by mass of the obtained resist polymer and 0.16% by mass of triphenyl sulfonium trifluoromethane sulfonate (photo-inductive acid-generating material) was prepared and the solution was filtered through a filter with 0.45 μm pore diameter to obtain a resist composition. The prepared resist composition was spin-coated on a silicon wafer, and then the solvent was evaporated by heat-treatment at 90° C. for one minute to obtain a thin film 100 nm in thickness.

### (Measurement of Sensitivity to Ultraviolet Beam Exposure)

As a light source, an ultraviolet beam emitting instrument of an electric discharge tube type DNA-FIX DF-245 (manufactured by ATTO Corp.) was used. Thin film samples, 100 nm in thickness and formed on silicon wafers, were exposed by emitting a 245 nm wavelength UV beam of a varying energy, from 0 mJ/cm² to 50 mJ/cm², onto a 10 mm×3 mm rectangular portion of the thin film samples. After heat-treatment at 100° C. for 4 minutes, the silicon wafers were development by immersion in an aqueous solution of tetramethyl ammonium hydroxide (TMAH, 2.4% by mass) at 25° C. for 2 minutes. After a water wash and drying, the film thickness was measured by a thin film measurement instrument F20 (manufactured by Filmetrics Japan, Inc.), and the minimum emission energy at which the film thickness became zero (sensitivity) was measured. The results are depicted in Table 4.

### Second Example

### Synthesis of the Resist Polymer Intermediate

Into a reaction vessel (50 mL volume) were added 21 mmol of chloromethyl styrene (monomer for the reaction), 13.1 mmol of 2,2-bipyridyl and 6.6 mmol of copper (I) chloride (catalyst), and 8 mL of chlorobenzene (solvent). After the inside of the reaction vessel was replaced with argon, the resulting mixture was agitated at 115° C. for 30 minutes for the polymerization reaction. To the reaction solution, 50 mL of chloroform was added to dissolve and dilute the polymer, and then the catalyst was removed by the liquid-liquid extraction by adding ultrapure water (25° C.) having a specific resistance of 18 MΩ·cm and a metal content of 1 ppb or less at 25° C. generated by GSR-200 (manufactured by Advantec Toyo Kaisha, Ltd.).

After the filtered solution was concentrated, 200 mL of methanol was added to precipitate the polymer, and then unreacted monomer and the reaction solvent were removed by removing the supernatant solution. Thereafter, the precipitated polymer was dissolved into 20 mL of tetrahydrofuran and then 500 mL of methanol was added. This re-precipitation operation was repeated twice to synthesize the core portion (yield 60%).

Then, into a reaction vessel (50 mL volume), 1 gram of the core portion (a raw material polymer), 33 mmol of tert-butyl acrylate (compound containing the acid-decomposable group), 4.1 mmol of 2,2-bipyridyl and 2.1 mmol of copper (I) chloride (catalyst), and 13 mL of chlorobenzene (solvent) were added. After the inside of the reaction vessel was replaced with argon, the resulting mixture was agitated at 125° C. for 30 minutes for polymerization to obtain a solution containing a resist polymer intermediate having the introduced shell portion.

### (Washing Treatment)

To the reaction solution, 10 mL of chlorobenzene was added, and then the solution was transferred to a vessel (300 mL volume). The ultrapure water (25° C.) having a specific resistance of 18 MΩ·cm and a metal content of 1 ppb or less at 25° C. generated by GSR-200 (manufactured by Advantec Toyo Kaisha, Ltd.) was added, and then the resulting mixture was agitated vigorously for 30 minutes, and thereafter allowed to stand for 15 minutes, resulting in a separation of an organic layer containing the polymer intermediate and a water layer. The water layer was removed by decantation, and then a series of the operations from the addition of 100 mL of the pure water to the separation of the water layer was repeated 14 times thereafter.

Then, 400 mL of methanol was added to the layer containing the resist polymer intermediate for re-precipitation, and a solid component was separated. The precipitated solid was washed by a mixed solution of tetrahydrofuran and methanol to obtain a solid with a pale yellow color. The obtained solid was dissolved into 30 mL of ethyl acetate and the ultrapure water (25° C.) having a specific resistance of 18 MΩ·cm and a metal content of 1 ppb or less at 25° C. generated by GSR-200 (manufactured by Advantec Toyo Kaisha, Ltd.) was added. The resulting mixture was agitated vigorously for 30 minutes, and then allowed to stand for 15 minutes, resulting in a separation of an organic layer containing the polymer intermediate and a water layer. The water layer was removed, and then a series of the operations from the addition of 100 mL of the pure water to the separation of the water layer was repeated 12 more times.

Then, filtration through a microfilter (Optimizer D-300, manufactured by Nihon Mykrolis K. K.) was performed at the flux of 4 mL/minute with an application of pressure. The solvent in the solution was removed under a reduced pressure to obtain the washed resist polymer intermediate with a pale yellow color in a solid state. The metal content was 30 ppb for copper and 27 ppb for sodium.

### (Decomposition of the Acid-Decomposable Group)

The decomposition of the acid-decomposable group was performed according to the method mentioned in the first example. The mol ratio of the tert-butyl acrylate part to the acrylic acid part was measured to be 70:30 by ¹H-NMR. The metal content of the obtained resist polymer were measured. The results are indicated in Table 4.

### (Preparation of Resist Composition and Measurement of Sensitivity to Ultraviolet Beam Exposure)

A resist composition was prepared in a similar manner to that in the first example, and the sensitivity to the exposure experiment with a UV beam (254 nm) was measured. The results are indicated in Table 4.

### Third Example

### Synthesis of a Resist Polymer Intermediate

Into a three-necked reaction vessel (300 mL volume) equipped with an agitator and a cooling column, under an argon gas atmosphere, 2.3 g of weighed 2,2′-bipyridyl, 0.74 g of copper (I) chloride, and 23 mL of chlorobenzene (reaction solvent) were added. Then, 4.6 g of chloromethyl styrene was added drop-wise for 5 minutes. The resulting mixture was heated at a constant internal temperature of 125° C. and agitated to synthesize the core portion. The total reaction time including the drop-wise addition was 40 minutes. Thereafter, 150 mL of chlorobenzene and 17.1 g of tert-butyl 4-vinylbenzoate were added by syringe, respectively. The resulting mixture was heated at 125° C. and agitated for 4 hours to introduce the acid-decomposable group.

### (Washing Treatment)

The reaction mixture was cooled rapidly, transferred to a reaction vessel (1 L volume), 500 mL of ultrapure water (25° C.) with a specific resistance of 18 MΩ·cm and a metal content of 1 ppb or less at 25° C. produced by GSR-200 (manufactured by Advantec Toyo Kaisha, Ltd.) were added thereto. The mixture was agitated vigorously for 30 minutes, and then allowed to stand for 15 minutes, resulting in a separation of an organic layer containing the polymer intermediate and a water layer. The water layer was removed by decantation, and then a series of the operations from the addition of 500 mL of the pure water to the separation of the water layer was repeated 14 times thereafter.

Then, the layer containing the resist polymer intermediate was added by 400 mL of methanol for re-precipitation, and unreacted monomers and the reaction solvent were removed by removing the supernatant solution. The precipitated substance was washed by a mixed solution of tetrahydrofuran and methanol to obtain a purified solid with a pale yellow color. The solid was dissolved into 30 mL of ethyl acetate, and the resulting polymer solution was contacted with an ion-exchange membrane (Protego CP, manufactured by Nihon Mykrolis K. K.) at the flux of 0.5 to 10 mL/minute with applying a pressure.

Subsequently, the filtration through a microfilter (Optimizer D-300, manufactured by Nihon Mykrolis K. K.) was carried out at the flux of 4 mL/minute with an application of pressure. Thereafter, the solvent in the obtained solution was removed under a reduced pressure to obtain the washed resist polymer intermediate with a pale yellow color in a solid state. The metal content was 20 ppb for copper and 18 ppb for sodium.

### (Decomposition of the Acid-Decomposable Group)

Decomposition of the acid-decomposable group was carried out according to the method of the first example, and the obtained solid was dissolved into ethyl acetate to make a solution having a concentration of 10% by mass. To the resulting solution, 3-equivalents volume (relative to ethyl acetate) of the ultrapure water (25° C.) having a specific resistance of 18 MΩ·cm and a metal content of 1 ppb or less at 25° C. produced by GSR-200 (manufactured by Advantec Toyo Kaisha, Ltd.) was added. The solution was agitated vigorously for 30 minutes, and then allowed to stand for 15 minutes, resulting in a separation of an organic layer containing the polymer intermediate and a water layer. The water layer was removed, and then a series of the operations from the addition of the pure water to the separation of the water layer was repeated two more times.

The solvent in the obtained solution was removed under a reduced pressure to obtain the purified resist polymer in a solid state. The mol ratio of the tert-butyl 4-vinylbenzoate part to the 4-vinylbenzoic acid part was measured to be 50:50 by ¹H-NMR. The results of the measurement of metal content in the resist polymer are indicated in Table 4.

### (Preparation of Resist Composition and Measurement of Sensitivity to Ultraviolet Beam Exposure)

A resist composition was prepared in a similar manner to that in the first example, and in exposure experiments, sensitivity to a UV beam (254 nm) was measured. The results are indicated in Table 4.

### First Comparative Example

### Synthesis of a Resist Polymer Intermediate

Into a three-necked reaction vessel (300 mL volume) equipped with an agitator and a cooling column, under an argon gas atmosphere, 2.3 g of weighed 2,2′-bipyridyl, 0.74 g of copper (I) chloride, and 23 mL of chlorobenzene (reaction solvent) were added. Then, 4.6 g of chloromethyl styrene was added drop-wise for 5 minutes. The resulting mixture was heated at a constant internal temperature of 125° C. and agitated to synthesize the core portion. The total reaction time including the drop-wise addition was 40 minutes. Thereafter, 150 mL of chlorobenzene and 17.1 g of tert-butyl 4-vinylbenzoate were added by syringe, respectively. The resulting mixture was heated at 125° C. and agitated for 4 hours to introduce the acid-decomposable group.

### (Washing Treatment)

The reaction mixture was cooled rapidly, transferred to a reaction vessel (1 L volume), 500 mL of ultrapure water (25° C.) with a specific resistance of 18 MΩ·cm and a metal content of 1 ppb or less at 25° C. produced by GSR-200 (manufactured by Advantec Toyo Kaisha, Ltd.) were added thereto. The mixture was agitated vigorously for 30 minutes, and then allowed to stand for 15 minutes, resulting in a separation of an organic layer containing the polymer intermediate and a water layer. The water layer was removed by decantation, and then a series of the operations from the addition of 500 mL of the pure water to the separation of the water layer was repeated 2 times thereafter. The water layer showed slightly a blue color of a copper ion.

Then, the layer containing the resist polymer intermediate was added by 400 mL of methanol for re-precipitation, and unreacted monomers and the reaction solvent were removed by removing the supernatant solution. The precipitated substance was washed by a mixed solution of tetrahydrofuran and methanol to obtain a purified solid with a pale yellow color. The metal content was 400 ppm for copper and 100 ppm for sodium.

### (Decomposition of the Acid-Decomposable Group)

Then, the deprotection was carried out according to the method in the third example to obtain a purified product of a pale yellow color in a solid state. The mol ratio of the tert-butyl 4-vinylbenzoate part to the 4-vinylbenzoic acid part was measured to be 50:50 by ¹H-NMR. The solid was dissolved into 30 mL of ethyl acetate, and the resulting polymer solution was contacted with an ion-exchange membrane (Protego CP, manufactured by Nihon Mykrolis K. K.) at the flux of 0.5 to 10 mL/minute with an application of pressure. The solvent in the obtained solution was removed under a reduced pressure to obtain a purified product in a state of solid with a pale yellow color. The mol ratio of the tert-butyl 4-vinylbenzoate part to the 4-vinylbenzoic acid part was measured to be 30:70 by ¹H-NMR. Then, the metal content of the obtained resist polymer was measured. The results are indicated in Table 4.

### (Preparation of Resist Composition and Measurement of Sensitivity to Ultraviolet Beam Exposure)

A resist composition was prepared in a similar manner to that in the first example, and in exposure experiments, sensitivity to a UV beam (254 nm) was measured. The results are indicated in Table 4.

TABLE 4

| | metal contents (ppb) | | | | sensitivity (mJ/cm²) to |
|---|---|---|---|---|---|
| | Cu | Na | Fe | Ca | ultraviolet light (254 nm) |
| first | 35 | 18 | 15 | 14 | 1 |
| example | | | | | |
| second | 28 | 24 | 18 | 16 | 1 |
| example | | | | | |
| third | 20 | 15 | 15 | 18 | 1 |
| example | | | | | |
| first comparative | 212 | 107 | 59 | 84 | unexposed portion was |
| example | | | | | dissolved |

In the first comparative example, the carboxylic group at the polymer terminal formed a metal chelate, thereby bringing far more amount of metals relative to the ion-exchange capacity of an ion-exchange resin into the polymer, resulting in insufficient removal of metals. In addition, the ion-exchange was performed with a large amount of metals still present, thereby generating a large amount of the acid by the exchange with the metals. As a result, the carboxylate ester was decomposed, resulting in dissolution of even unexposed parts.

### Fourth Example

### Synthesis of a Resist Polymer Intermediate

In a similar manner to that described in the first example, the core portion was synthesized, and then the acid-decomposable group was introduced to synthesize the resist polymer intermediate.

### (Washing Treatment)

The reaction mixture was cooled rapidly, and then the insoluble metal catalyst was removed by filtration. The resulting solution was transferred to a reaction vessel (1 liter volume), 500 mL of a 3% by weight aqueous oxalic acid solution prepared using ultrapure water (25° C.) having a specific resistance of 18 MΩ·cm and a metal content of 1 ppb or less at 25° C. generated by GSR-200 (manufactured by Advantec Toyo Kaisha, Ltd.) was added. The solution was agitated vigorously for 30 minutes, and then allowed to stand for 15 minutes, resulting in a separation of an organic layer containing the polymer intermediate and a water layer. The water layer was removed by a decantation, and then a series of the operations from the addition of 500 mL of the 3% by weight of aqueous oxalic acid solution to the separation of the water layer was repeated three more times.

Then, 500 mL of a 3% by weight of aqueous hydrochloric acid solution prepared using ultrapure water (25° C.) having a specific resistance of 18 MΩ·cm and a metal content of 1 ppb or less at 25° C. generated by GSR-200 (manufactured by Advantec Toyo Kaisha, Ltd.) was added. The resulting mixture was agitated vigorously for 30 minutes, and then allowed to stand for 15 minutes, resulting in separation into an organic layer containing the polymer intermediate and a water layer. The water layer was removed by a decantation, and then a series of the operations from the addition of 500 mL of the 3% by weight of aqueous hydrochloric acid solution to the separation of the water layer was repeated 2 more times.

Then, 500 mL of the ultrapure water (25° C.) having specific resistance of 18 MΩ·cm and the metal content of 1 ppb or less at 25° C. generated by GSR-200 (manufactured by Advantec Toyo Kaisha, Ltd.) was added. The resulting mixture was agitated vigorously for 30 minutes, and then allowed to stand for 15 minutes, resulting in a separation of an organic layer containing the polymer intermediate and a water layer. The water layer was removed by decantation, and then a series of the operations from the addition of 500 mL of the pure water to the separation of the water layer was repeated 4 more times. Thereafter, the filtration was performed by using a microfilter (Optimizer D-300, manufactured by Nihon Mykrolis K. K.) at the flux of 4 mL/minute with an application of pressure.

Then, after 400 mL of methanol was added to the layer containing the resist polymer intermediate for re-precipitation, unreacted monomers and the reaction solvent were removed by removing the supernatant solution. The precipitated product was washed by a mixed solution of tetrahydrofuran and methanol to obtain the washed resist polymer intermediate in a solid state and of a pale yellow color. Each of metals (Na, Cu, Ca, and Fe) contained therein was below the detection limit. Measurements of the metal content of the resist polymer intermediates and the resist polymers in the fourth to the sixth examples were made by a flameless atomic absorption method of an acid decomposition type (manufactured by PerkinElmer Inc.).

### (Decomposition of Acid-Decomposable Group)

The acid-decomposable group was decomposed in a similar manner to that depicted in the first example to obtain a resist polymer. The yield was 0.44 g. The mol ratio of the tert-butyl 4-vinylbenzoate part to the 4-vinylbenzoic acid part was measured to be 50:50 by ¹H-NMR. The metal content (Na, Cu, Ca, and Fe) of the obtained resist polymer was measured, all of which were below the detection limit (20 ppb). The results are indicated in Table 5.

### (Preparation of Resist Compositions and Measurement of Sensitivity to Ultraviolet Beam Exposure)

A resist composition was prepared in a similar manner to that in the first example, and the sensitivity was measured. The results are indicated in Table 5.

### Fifth Example

### Synthesis of Resist Polymer Intermediate

In a similar manner to that described in the second example, the core portion was synthesized, and then the acid-decomposable group was introduced to synthesize the resist polymer intermediate.

### (Washing Treatment)

After the reaction solution was filtered to remove the insoluble metal catalyst, 10 mL of chlorobenzene was added. The resulting solution was transferred to a reaction vessel (300 mL volume), a mixed solution of 50 mL of oxalic acid (3% by weight) and 50 mL of hydrochloric acid (1% by weight) prepared using the ultrapure water (25° C.) having specific resistance of 18 MΩ·cm and a metal content of 1 ppb or less at 25° C. generated by GSR-200 (manufactured by Advantec Toyo Kaisha, Ltd.) was added thereto. The solution was agitated vigorously for 30 minutes, and then allowed to stand for 15 minutes, resulting in a separation of an organic layer containing the polymer intermediate and a water layer. The water layer was removed by decantation, and then a series of the operations from the addition of a mixed solution of 50 mL of oxalic acid (3% by weight) and 50 mL of hydrochloric acid (1% by weight) to the separation of the water layer was repeated two more times.

Then, 100 mL of a 3% by weight of aqueous hydrochloric acid solution prepared using the ultrapure water (25° C.) having a specific resistance of 18 MΩ·cm and a metal content of 1 ppb or less at 25° C. generated by GSR-200 (manufactured by Advantec Toyo Kaisha, Ltd.) was added. The resulting mixture was agitated vigorously for 30 minutes, and then allowed to stand for 15 minutes, resulting in a separation of an organic layer containing the polymer intermediate and a water layer. The water layer was removed by decantation, and then a series of the operations from the addition of 500 mL of a 3% by weight of aqueous hydrochloric acid solution to the separation of the water layer was repeated one more time. Then, 100 mL of the ultrapure water (25° C.) having a specific resistance of 18 MΩ·cm and a metal content of 1 ppb or less at 25° C. generated by GSR-200 (manufactured by Advantec Toyo Kaisha, Ltd.) was added. The resulting mixture was agitated vigorously for 30 minutes, and then allowed to stand for 15 minutes, resulting in a separation of an organic layer containing the polymer intermediate and a water layer. The water layer was removed by decantation, and then a series of the operations from the addition of 100 mL of the pure water to the separation of the water layer was repeated three more times.

Then, after 400 mL of methanol was added to the layer containing the resist polymer intermediate for re-precipitation, and a solid component was separated. The precipitated product was washed by a mixed solution of tetrahydrofuran and methanol to obtain a solid with a pale yellow color. The obtained solid was dissolved in 30 mL of ethyl acetate, and the ultrapure water (25° C.) having a specific resistance of 18 MΩ·cm and a metal content of 1 ppb or less at 25° C. generated by GSR-200 (manufactured by Advantec Toyo Kaisha, Ltd.) was added. The resulting mixture was agitated vigorously for 30 minutes, and then allowed to stand for 15 minutes, resulting in a separation of an organic layer containing the polymer intermediate and a water layer. The water layer was removed, and then a series of the operations from the addition of 100 mL of the pure water to the separation of the water layer was repeated two more times.

Then, filtration through a microfilter (Optimizer D-300, manufactured by Nihon Mykrolis K. K.) was performed at the flux of 4 mL/minute with an application of pressure. The solvent in the solution was removed under a reduced pressure to obtain the washed resist polymer intermediate in a solid state with a pale yellow color. All of the metals (Na, Cu, Ca, and Fe) therein were below the detection limit.

### (Decomposition of Acid-Decomposable Group)

The acid-decomposable group was decomposed in a similar manner to that described in the first example to obtain a resist polymer. The mol ratio of the tert-butyl acrylate part to the acrylic acid part was measured to be 70:30 by ¹H-NMR. Then, the metal contents (Na, Cu, Ca, and Fe) in the obtained resist polymer were measured, all of which were below the detection limit (20 ppb). The results are indicated in Table 5.

### (Preparation of Resist Composition and Measurement of Sensitivity to Ultraviolet Beam Exposure)

A resist composition was prepared in a similar manner to that in the fourth example, and in exposure experiments, sensitivity to a UV beam (254 nm) was measured. The results are indicated in Table 5.

### Sixth Example

### Synthesis of a Resist Polymer Intermediate

In a similar manner to that described in the third example, the core portion was synthesized, and then the acid-decomposable group was introduced to synthesize the resist polymer intermediate.

### (Washing Treatment)

The reaction mixture was cooled rapidly, and then the insoluble metal catalyst was removed by filtration. The resulting solution was transferred to a reaction vessel (1 liter volume), 500 mL of a 3% by weight citric acid aqueous solution prepared using ultrapure water (25° C.) having a specific resistance of 18 MΩ·cm and a metal content of 1 ppb or less at 25° C. generated by GSR-200 (manufactured by Advantec Toyo Kaisha, Ltd.) was added. The solution was agitated vigorously for 30 minutes, and then allowed to stand for 15 minutes, resulting in a separation of an organic layer containing the polymer intermediate and a water layer. The water layer was removed by a decantation, and then a series of the operations from the addition of 500 mL of pure water to the separation of the water layer was repeated three more times.

Then, 500 mL of a 3% by weight of aqueous hydrochloric acid solution prepared using ultrapure water (25° C.) having a specific resistance of 18 MΩ·cm and a metal content of 1 ppb or less at 25° C. generated by GSR-200 (manufactured by Advantec Toyo Kaisha, Ltd.) was added. The resulting mixture was agitated vigorously for 30 minutes, and then allowed to stand for 15 minutes, resulting in separation into an organic layer containing the polymer intermediate and a water layer. The water layer was removed by a decantation, and then a series of the operations from the addition of 500 mL of the 3% by weight of aqueous hydrochloric acid solution to the separation of the water layer was repeated 2 more times.

Then, 500 mL of the ultrapure water (25° C.) having specific resistance of 18 MΩ·cm and the metal content of 1 ppb or less at 25° C. generated by GSR-200 (manufactured by Advantec Toyo Kaisha, Ltd.) was added. The resulting mixture was agitated vigorously for 30 minutes, and then allowed to stand for 15 minutes, resulting in a separation of an organic layer containing the polymer intermediate and a water layer. The water layer was removed by decantation, and then a series of the operations from the addition of 500 mL of the pure water to the separation of the water layer was repeated 4 more times.

Then, to the layer containing the resist polymer intermediate, 400 mL of methanol for re-precipitation was added, and unreacted monomers and the reaction solvent were removed by removing the supernatant solution. The precipitated substance was washed by a mixed solution of tetrahydrofuran and methanol to obtain a purified solid with a pale yellow color. The solid was dissolved in 30 mL of ethyl acetate, and the resulting polymer solution was contacted with an ion-exchange membrane (Protego CP, manufactured by Nihon Mykrolis K. K.) at the flux of 0.5 to 10 mL/minute with an application of pressure.

Subsequently, filtration through a microfilter (Optimizer D-300, manufactured by Nihon Mykrolis K. K.) was carried out at the flux of 4 mL/minute with an application of pressure. Thereafter, the solvent in the obtained solution was removed under a reduced pressure to obtain the washed resist polymer intermediate in a solid state with a pale yellow color. All of the metals (Na, Cu, Ca, and Fe) therein were below the detection limit.

### (Decomposition of the Acid-Decomposable Group)

The acid-decomposable group was decomposed in a similar manner to that described in the fourth example to obtain a resist polymer. The mol ratio of the tert-butyl 4-vinylbenzoate part to the 4-vinylbenzoic acid part was measured to be 50:50 by ¹H-NMR. Then, the metal contents (Na, Cu, Ca, and Fe) in the obtained resist polymer were measured, all of which were below the detection limit (20 ppb). The results are indicated in Table 5.

### (Preparation of Resist Composition and Measurement of Sensitivity to Ultraviolet Beam Exposure)

A resist composition was prepared in a similar manner to that in the fourth example, and the sensitivity to the exposure experiments with an UV beam (254 nm) was measured. The results are indicated in Table 5.

TABLE 5

| | metal contents (ppb) | | | | |
|---|---|---|---|---|---|
| | Cu | Na | Fe | Ca | |
| | detection limit | | | | sensitivity (mJ/cm²) to |
| | 20 | 20 | 20 | 20 | ultraviolet light (254 nm) |
| fourth | ND | ND | ND | ND | 1 |
| example | | | | | |
| fifth | ND | ND | ND | ND | 1 |
| example | | | | | |
| sixth | ND | ND | ND | ND | 1 |
| example | | | | | |

### EFFECT OF INVENTION

According to the present invention, a hyperbranched polymer with a low metal content due to thorough removal of the metal catalyst used in polymerization can be synthesized simply and easily. According to the present invention, a hyperbranched polymer having a given ratio of the acid group and the acid-decomposable group in the shell portion can be synthesized simply and easily. The hyperbranched polymer obtained by the method of the present invention has high sensitivities not only to n UV beam but also to an extreme UV beam. According to the present invention, pollution in plasma treatment of the obtained hyperbranched polymer and any adverse effects on electric properties can be prevented. The hyperbranched polymer obtained by the present invention is excellent in terms of substrate adhesiveness as well.

### <Chapter 4>

In the following, exemplary embodiments of the method of synthesizing the hyperbranched polymer of the present invention will be explained in detail with reference to the attached drawing.

### (Substances Used in Synthesis of Hyperbranched Polymer)

Substances used in the synthesis of the hyperbranched polymer (hereinafter, hyperbranched polymer) synthesized according to the synthesis method of the hyperbranched polymer will be explained. In the synthesis of the hyperbranched polymer, a monomer, a metal catalyst, a polar solvent, and other solvents are used.

### (Monomers)

Monomers used in the synthesis of the hyperbranched polymer will be explained. When synthesizing the core-shell hyperbranched polymer, the monomers used for synthesis of the hyperbranched polymer are roughly divided into monomers for the core portion and monomers for the shell portion.

### (Monomers for Core Portion)

Among monomers used in the synthesis of hyperbranched polymer, monomers for the core portion will be explained first. The core portion of the hyperbranched polymer constitutes a nucleus of the hyperbranched polymer molecule. The core portion of the hyperbranched polymer is formed by polymerizing at least the monomers represented by formula (I) depicted in Chapter 1.

In formula (I), Y represents a linear, a branched, or a cyclic alkylene group having 1 to 10 carbon atoms. The number of carbons in Y is preferably 1 to 8. More preferable number of carbons in Y is 1 to 6. Y in formula (I) may contain a hydroxyl group or a carboxyl group.

Specific examples of Y in formula (I) include a methylene group, an ethylene group, a propylene group, an isopropylene group, a butylene group, an isobutylene group, an amylene group, a hexylene group, and a cyclohexylene group. Furthermore, Y in formula (I) includes a group in which the above-mentioned groups are bonded with each other directly or via —O—, —CO—, and —COO—.

Y in formula (I) is preferably an alkylene group having 1 to 8 carbon atoms among the groups mentioned above. Y in formula (I) is more preferably a linear alkylene group having 1 to 8 carbon atoms among the alkylene groups having 1 to 8 carbon atoms. Examples of the alkylene group more preferable include a methylene group, an ethylene group, an —OCH₂— group, and an —OCH₂CH₂— group. Monomers corresponding to formula (I) include a halogen atom (a halogen group) such as a fluorine atom, a chlorine atom, a bromine atom, and an iodine atom. Specific examples of preferable monomers corresponding to formula (I) include a chlorine atom and a bromine atom among the halogen atoms mentioned above.

Specific examples of the monomer used in the synthesis of the hyperbranched polymer and represented by formula (I) include chloromethyl styrene, bromomethyl styrene, p-(1-chloroethyl)styrene, bromo(4-vinylphenyl)phenylmethane, 1 bromo-1-(4-vinylphenyl)propane-2-one, and 3-bromo-3-(4-vinylphenyl)propanol. More specific examples of the preferable monomer represented by formula (I) among the monomers used for synthesis of the hyperbranched polymer include chloromethyl styrene, bromomethyl styrene, and p-(1-chloroethyl)styrene.

Monomers constituting the core portion of the hyperbranched polymer may include, in addition to the monomers represented by formula (I), other monomers. There is no restriction with regard to other monomers provided the monomer can be subject to radical polymerization, and may be chosen appropriately according to purpose. Examples of other monomers capable of radical polymerization include compounds having a radical polymerizable unsaturated bond such as (meth)acrylic acid, (meth)acrylate esters, vinylbenzoic acid, vinylbenzoate esters, styrenes, an allyl compound, vinyl ethers, vinyl esters, and the like.

Specific examples of (meth)acrylate esters cited as other monomers capable of radical polymerization include tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1 ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1 ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate.

Specific examples of vinyl benzoate esters cited as other monomers capable of radical polymerization include vinyl benzoate, tert-butyl vinyl benzoate, 2-methylbutyl vinyl benzoate, 2-methylpentyl vinyl benzoate, 2-ethylbutyl vinyl benzoate, 3-methylpentyl vinyl benzoate, 2-methylhexyl vinyl benzoate, 3-methylhexyl vinyl benzoate, triethylcarbyl vinyl benzoate, 1-methyl-1-cyclopentyl vinyl benzoate, 1-ethyl-1-cyclopentyl vinyl benzoate, 1-methyl-1-cyclohexyl vinyl benzoate, 1-ethyl-1-cyclohexyl vinyl benzoate, 1-methylnorbornyl vinyl benzoate, 1-ethylnorbornyl vinyl benzoate, 2-methyl-2-adamantyl vinyl benzoate, 2-ethyl-2-adamantyl vinyl benzoate, 3-hydroxy-1-adamantyl vinyl benzoate, tetrahydrofuranyl vinyl benzoate, tetrahydropyranyl vinyl benzoate, 1-methoxyethyl vinyl benzoate, 1-ethoxyethyl vinyl benzoate, 1-n-propoxyethyl vinyl benzoate, 1-isopropoxyethyl vinyl benzoate, n-butoxyethyl vinyl benzoate, 1-isobutoxyethyl vinyl benzoate, 1-sec-butoxyethyl vinyl benzoate, 1-tert-butoxyethyl vinyl benzoate, 1-tert-amyloxyethyl vinyl benzoate, 1-ethoxy-n-propyl vinyl benzoate, 1-cyclohexyloxyethyl vinyl benzoate, methoxypropyl vinyl benzoate, ethoxypropyl vinyl benzoate, 1-methoxy-1-methyl-ethyl vinyl benzoate, 1-ethoxy-1-methyl-ethyl vinyl benzoate, trimethylsilyl vinyl benzoate, triethylsilyl vinyl benzoate, dimethyl-tert-butylsilyl vinyl benzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinyl benzoate, adamantyl vinyl benzoate, 2-(2-methyl)adamantyl vinyl benzoate, chloroethyl vinyl benzoate, 2-hydroxyethyl vinyl benzoate, 2,2-dimethylhydroxypropyl vinyl benzoate, 5-hydroxybenzyl vinyl benzoate, trimethylolpropane vinyl benzoate, glycidyl vinyl benzoate, benzyl vinyl benzoate, phenyl vinyl benzoate, and naphthyl vinyl benzoate.

Specific examples of styrenes cited as other monomers capable of radical polymerization include styrene, benzyl styrene, trifluoromethyl styrene, acetoxy styrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethyl styrene, 4-fluoro-3-trifluoromethyl styrene, and vinyl naphthalene.

Specific examples of allyl compounds cited as other monomers capable of radical polymerization include allyl acetate, allyl caproate, allyl caprylate, allyl laurate, allyl palmitate, allyl stearate, allyl benzoate, allyl acetoacetate, allyl lactate, and allyl oxyethanol.

Specific examples of vinyl ethers cited as other monomers capable of radical polymerization include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethyleneglycol vinyl ether, dimethylaminoethyl vinyl ether, diethylaminoethyl vinyl ether, butylaminoethyl vinyl ether, benzyl vinyl ether, tetrahydrofurfuryl vinyl ether, vinyl phenyl ether, vinyl tolyl ether, vinyl chlorophenyl ether, vinyl 2,4-dichlorophenyl ether, vinyl naphthyl ether, and vinyl anthranyl ether.

Specific examples of vinyl esters cited as other monomers capable of radical polymerization include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl buthoxyacetate, vinyl phenylacetate, vinyl acetoacetate, vinyl lactate, vinyl β-phenylbutyrate, and vinyl cyclohexylcarboxylate.

Among the various kinds of monomer described above, (meth)acrylic acid, (meth)acrylate esters, 4-vinylbenzoic acid, 4-vinylbenzoate esters, and styrenes are preferable as the monomers for the core portion of the hyperbranched polymer. Among the various kinds of monomers afore-mentioned, specific examples of preferable monomers for the core portion of the hyperbranched polymer include (meth)acrylic acid, tert-butyl(meth)acrylate, 4-vinylbenzoic acid, tert-butyl 4-vinylbenzoate, styrene, benzyl styrene, chlorostyrene, and vinyl naphthalene.

In the hyperbranched polymer, the amount of monomer for the core portion at the time of charging is preferably 10 to 90% by mol relative to the total monomer used for the synthesis of the hyperbranched polymer. In the hyperbranched polymer, the amount of monomer for the core portion at the time of charging is more preferably 10 to 80% by mol relative to the total monomer used for the synthesis of the hyperbranched polymer, and yet more preferably 10 to 60% by mol relative to the total monomers used for the synthesis of the hyperbranched polymer.

By controlling the amount of monomer for the core portion in the hyperbranched polymer at the above-mentioned ranges, for example, when the hyperbranched polymer is used as a resist composition containing the hyperbranched polymer, the hyperbranched polymer can be imparted with a suitable hydrophobicity to a developing solution. Thus, for example, when a semi-conductor integrated circuit, a flat panel display, a printed wiring board are subjected to a microfabrication process using a resist composition containing the hyperbranched polymer, dissolution of an unexposed part can be suppressed, and thus, is preferable.

In the hyperbranched polymer, the amount of monomer represented by formula (I) at the time of charging is preferably 5 to 100% by mol relative to the total monomer used for the synthesis of the hyperbranched polymer, and is more preferably 20 to 100% by mol relative to the total monomers used for the synthesis of the hyperbranched polymer.

In the hyperbranched polymer, the amount of monomer for the core portion at the time of charging is yet more preferably 50 to 100% by mol relative to the total monomer used for the synthesis of the hyperbranched polymer. When the amount of monomer represented by formula (I) in the hyperbranched polymer is at the above-mentioned ranges, the core portion takes a spherical morphology, thereby advantageously suppressing intermolecular entanglement, and thus, is preferable.

In a case where the core portion of the hyperbranched polymer is a copolymer of monomer represented by formula (I) and other monomers, the amount of monomer represented by formula (I) relative to the total monomer constituting the core portion at the time of charging is preferably 10 to 99% by mol. In a case where the core portion of the hyperbranched polymer is a copolymer of monomer represented by formula (I) and other monomers, the amount of monomer represented by formula (I) relative to the total monomer constituting the core portion at the time of charging is more preferably 20 to 99% by mol.

In the case where the core portion of the hyperbranched polymer is a copolymer of monomer represented by formula (I) and other monomers, the amount of monomer represented by formula (I) relative to the total monomer constituting the core portion at the time of charging is yet more preferably 30 to 99% by mol. When the amount of monomer represented by formula (I) in the hyperbranched polymer is at the above-mentioned ranges, the core portion takes a spherical morphology, thereby advantageously suppressing intermolecular entanglement, and thus, is preferable.

When the amount of monomer represented by formula (I) in the hyperbranched polymer is at the above-mentioned ranges, functions such as substrate adhesiveness and glass transition temperature are improved while maintaining a spherical morphology in the core portion, and thus, is preferable. The amounts of the monomer represented by formula (I) and of the other monomers in the core portion may be controlled by the charging ratio at the time of polymerization, according to purpose.

### (Monomers for Shell Portion)

Among the monomer used in the synthesis of hyperbranched polymer, monomer for the shell portion will be explained. The shell portion of the hyperbranched polymer constitutes the terminal of the hyperbranched polymer molecule. The shell portion of the hyperbranched polymer is formed of at least repeating units represented by formula (II) or repeating units represented by formula (III) depicted in Chapter 1.

The repeating units represented by formula (II) and formula (III) depicted in Chapter 1 contain an acid-decomposable group which is decomposed by the action of an organic acid such as acetic acid, maleic acid, and benzoic acid, by the action of an inorganic acid such as hydrochloric acid, sulfuric acid, and nitric acid, or preferably by the action of a photo-inductive acid-generating material which generates an acid by a photo energy, with the last being preferable. An acid-decomposable group giving a hydrophilic group by decomposition is preferable.

R¹ in formula (II) and R⁴ in formula (III) represent hydrogen or an alkyl group having 1 to 3 carbon atoms, among which, R¹ in formula (II) and R⁴ in formula (III) are preferably hydrogen and a methyl group. Hydrogen is more preferable as R¹ in formula (II) and R⁴ in formula (III).

R² in formula (II) represents hydrogen, an alkyl group, or an aryl group. The alkyl group in R² in formula (II) is preferably, for example, an alkyl group having 1 to 30 carbon atoms, more preferably an alkyl group having 1 to 20 carbon atoms, and yet more preferably an alkyl group having 1 to 10 carbon atoms. The alkyl group has a linear, a branched, or a cyclic structure. Specific examples of the alkyl group of R² in formula (II) include a methyl group, an ethyl group, a propyl group, an isopropyl group, a butyl group, an isobutyl group, a tert-butyl group, and a cyclohexyl group.

The aryl group of R² in formula (II) preferably has 6 to 30 carbon atoms, more preferably 6 to 20, and yet more preferably 6 to 10. Specific examples of the aryl group of R² in formula (II) include a phenyl group, a 4-methyl phenyl group, and a naphthyl group, among which, includes hydrogen, methyl groups, ethyl groups, phenyl groups, and the like. As one of the most preferable group of R² in formula (II), a hydrogen atom may be mentioned.

R³ in formula (II) and R⁵ in formula (III) represent hydrogen, an alkyl group, a trialkyl silyl group, an oxoalkyl group, or a group represented by formula (i) of Chapter 1. It is preferable that the alkyl group of R³ in formula (II) and R⁵ in formula (III) be an alkyl group having 1 to 40 carbon atoms. More preferably the number of carbons of the alkyl group of R³ in formula (II) and R⁵ in formula (III) is 1 to 30.

Yet more preferably the number of carbons of the alkyl group in R³ in formula (II) and R⁵ in formula (III) is 1 to 20. The alkyl group in R³ in formula (II) and R⁵ in formula (III) may be linear, branched, or cyclic. As R³ in formula (II) and R⁵ in formula (III), a branched alkyl group having 1 to 20 carbon atoms is more preferable.

Preferably the number of carbons of each alkyl group in R³ in formula (II) and R⁵ in formula (III) is 1 to 6, and more preferably 1 to 4. Preferably the number of carbons of the alkyl group of the oxoalkyl group in R³ in formula (II) and R⁵ in formula (III) is 4 to 20, and more preferably 4 to 10.

R⁶ in formula (i) of Chapter 1 represents hydrogen or an alkyl group. The alkyl group of R⁶ in formula (i) is linear, branched, or cyclic. It is preferable that the alkyl group of R⁶ in formula (i) be an alkyl group having 1 to 10 carbon atoms. More preferably the number of carbons of the alkyl group of R⁶ in formula (i) is 1 to 8, and yet more preferably the number is 1 to 6.

R⁷ and R⁸ in formula (i) represent hydrogen or an alkyl group. The hydrogen atom and the alkyl group in R⁷ and R⁸ in formula (i) may be independent of each other or form a ring. The alkyl group in R⁷ and R⁸ in formula (i) has a linear, branched, or cyclic structure. It is preferable that the alkyl group in R⁷ and R⁸ in formula (i) be an alkyl group having 1 to 10 carbon atoms. More preferably the number of carbons of the alkyl group in R⁷ and R⁸ in formula (i) is 1 to 8, and yet more preferably the number is 1 to 6. R⁷ and R⁸ in formula (i) are preferably a branched alkyl group having 1 to 20 carbon atoms.

Examples of the group represented by formula (i) include a linear or a branched acetal group such as a 1-methoxyethyl group, a 1-ethoxyethyl group, a 1-n-propoxyethyl group, a 1-isopropoxyethyl group, a 1-n-butoxyethyl group, a 1-isobutoxyethyl group, a 1-sec-butoxyethyl group, a 1-tert-butoxyethyl group, a 1-tert-amyloxyethyl group, a 1-ethoxy-n-propyl group, a 1-cyclohexyloxyethyl group, a methoxypropyl group, an ethoxypropyl group, a 1-methoxy-1-methyl-ethyl group, and 1-ethoxy-1-methyl-ethyl group; a cyclic acetal group such as a tetrahydrofuranyl group and a tetrahydropyranyl group. Among the above-mentioned groups represented by formula (i), an ethoxyethyl group, a butoxyethyl group, an ethoxypropyl group, and a tetrahydropyranyl group are particularly preferable.

Examples of a linear, a branched, or a cyclic alkyl group in R³ in formula (II) and R⁵ in formula (III) include an ethyl group, a propyl group, an isopropyl group, a butyl group, an isobutyl group, a tert-butyl group, a cyclopentyl group, a cyclohexyl group, a cycloheptyl group, a triethylcarbyl group, a 1-ethylnorbornyl group, 1-methylcyclohexyl group, an adamantyl group, a 2-(2-methyl)adamantyl group, and a tert-amyl group. Among them, a tert-butyl group is particularly preferable.

Examples of the trialkyl silyl group in R³ in formula (II) and R⁵ in formula (III) include a group having 1 to 6 carbon atoms in each alkyl group, such as a trimethyl silyl group, a triethyl silyl group, and a dimethyl-tert-butyl silyl group. Examples of the oxoalkyl group include a 3-oxocyclohexyl group.

Monomers giving repeating units represented by formula (II) include, for example, vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate. Among these, a polymer of 4-vinylbenzoic acid and tert-butyl 4-vinylbenzoate is preferable.

Monomers giving repeating units represented by formula (III) include, for example, acrylate, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1-ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, methacrylic acid, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate. Among these, copolymers of acrylate and tert-butyl acrylate are preferable.

As the polymer for the shell portion, a polymer composed of at least one among 4-vinyl benzoic acid and acrylic acid and at least one among tert-butyl 4-vinyl benzoate and tert-butyl acrylate is also preferable. As the monomers for the shell portion, a monomer other than the monomers giving repeating units represented by formula (II) and formula (III) may also be used provided the monomer has a structure containing a radical polymerizable unsaturated bond.

Examples of monomers usable as a comonomer include compounds containing a radical polymerizable unsaturated bond, selected from among styrenes, an allyl compound, vinyl ethers, vinyl esters, and crotonate esters, except for the monomers as described above.

Specific examples of styrenes other than the styrenes cited as monomers usable as the comonomer constituting the shell portion include styrene, tert-buthoxy styrene, α-methyl-tert-buthoxy styrene, 4-(1-methoxyethoxy)styrene, 4-(1-ethoxyethoxy)styrene, tetrahydropyranyloxy styrene, adamantyloxy styrene, 4-(2-methyl-2-adamantyloxy)styrene, 4-(1-methylcyclohexyloxy)styrene, trimethylsilyloxy styrene, dimethyl-tert-butylsilyloxy styrene, tetrahydropyranyloxy styrene, benzyl styrene, trifluoromethyl styrene, acetoxy styrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethyl styrene, 4-fluoro-3-trifluoromethyl styrene, and vinyl naphthalene.

Specific examples of the allyl esters include allyl acetate, allyl caproate, allyl caprylate, allyl laurate, allyl palmitate, allyl stearate, allyl benzoate, allyl acetoacetate, allyl lactate, and allyl oxyethanol.

Specific examples of the vinyl ethers cited as comonomers usable as a monomer constituting the shell portion include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethyleneglycol vinyl ether, dimethylaminoethyl vinyl ether, diethylaminoethyl vinyl ether, butylaminoethyl vinyl ether, benzyl vinyl ether, tetrahydrofurfuryl vinyl ether, vinyl phenyl ether, vinyl tolyl ether, vinyl chlorophenyl ether, vinyl 2,4-dichlorophenyl ether, vinyl naphthyl ether, and vinyl anthranyl ether.

Specific examples of the vinyl esters cited as comonomers usable as a monomer constituting the shell portion include vinyl butyrate, vinyl isobutyrate, vinyl trimethyl acetate, vinyl diethylacetate, vinyl valerate, vinyl caproate, vinyl chloroacetate, vinyl dichloroacetate, vinyl methoxyacetate, vinyl buthoxyacetate, vinyl phenyl acetate, vinyl acetoacetate, vinyl lactate, vinyl β-phenyl butyrate, and vinyl cyclohexyl carboxylate.

Specific examples of the crotonate esters cited as comonomers usable as a monomer constituting the shell portion include butyl crotonate, hexyl crotonate, glycerin monocrotonate, dimethyl itaconate, diethyl itaconate, dibutyl itaconate, dimethyl maleate, dibutyl fumarate, maleic anhydride, maleimide, acrylonitrile, methacrylonitrile, and maleironitrile.

The monomers represented by formula (IV) to formula (XIII) depicted in Chapter 1 and the like may also be used as comonomers constituting the shell portion.

As comonomers usable as the monomers for the shell portion, styrenes and crotonate esters are preferable among the monomers represented by formula (IV) to formula (XIII). As comonomers usable as the monomers for the shell portion, styrene, benzyl styrene, chlorostyrene, vinyl naphthalene, butyl crotonate, hexyl crotonate, and maleic anhydride are preferable among the monomers represented by formula (IV) to formula (XIII).

In the hyperbranched polymer, at least monomer giving repeating units represented by formula (II) or monomer giving repeating units represented by formula (III) is included. The amount of monomer giving the repeating units above at the time of charging is preferably 10 to 90% by mol relative to the total amount of monomer used for the synthesis of the hyperbranched polymer. The amount of the monomer giving the repeating units as described above at the time of charging is more preferably 20 to 90% by mol relative to the total amount of monomer used for the synthesis of the hyperbranched polymer.

The amount of monomer giving the repeating units above at the time of charging is more preferably 30 to 90% by mol relative to the total amount of monomer used for the synthesis of the hyperbranched polymer. In particular, the amount of monomer giving the repeating units represented by formula (II) and formula (III) in the shell portion at the time of charging is 50 to 100% by mol, and preferably 80 to 100% by mol, relative to the total amount of monomer used for the synthesis of the hyperbranched polymer. When the amount of monomer giving the repeating units above at the time of charging is at the above-mentioned ranges relative to the total monomer used for the synthesis of the hyperbranched polymer, the light-exposed part is removed efficiently by dissolution into a basic solution at the lithography developing step using the resist composition containing the hyperbranched polymer, and thus, is preferable.

In a case where the shell portion of the hyperbranched polymer of the present invention is a copolymer of monomer giving the repeating units represented by formula (II) or monomer giving the repeating units represented by formula (III) and other monomers, the amount of monomer giving repeating units represented by formula (II) and/or the amount of monomer giving repeating units represented by formula (III) relative to the total amount of monomer constituting the shell portion at the time of charging is preferably 30 to 90% by mol and yet more preferably 50 to 70% by mol. When the amount of the monomer giving repeating units represented by formula (II) and/or the amount of the monomer giving repeating units represented by formula (III) relative to the total amount of monomer constituting the shell portion is at the above ranges, functions such as etching resistance, wetting properties, and glass transition temperature are improved without hindering an efficient dissolution of a light-exposed part into a basic solution, and thus, is preferable.

At least the amount of the repeating units represented by formula (II) and/or the amount of the repeating units represented by formula (III), and other repeating units in the shell portion may be controlled by the charging mol ratios at the time of introduction into the shell portion, according to purpose.

### (Metal Catalyst)

Metal catalyst used in the synthesis of the hyperbranched polymer will be explained. In the synthesis of the hyperbranched polymer, a metal catalyst is used. As the metal catalyst, for example, a metal catalyst composed of a ligand and a transition metal compound of, for example, copper, iron, ruthenium, and chromium. examples of the transition metal compound include copper (I) chloride, copper (I) bromide, copper (I) iodide, copper (I) cyanide, copper (I) oxide, copper (I) perchlorate, iron (I) chloride, iron (I) bromide, and iron (I) iodide.

Examples of the ligand include pyridines, bipyridines, polyamines, and phosphines, unsubstituted or substituted with an alkyl group, an aryl group, an amino group, a halogen group, an ester group, and the like. examples of the preferable metal catalyst include a copper (I) bipyridyl complex and a copper (I) pentamethyl diethylene triamine complex, which are composed of copper chloride and respective ligands, and an iron (II) triphenyl phosphine complex and an iron (II) tributyl amine complex, which are composed of iron chloride and respective ligands, or others.

The amount of metal catalyst used for synthesis of the hyperbranched polymer at the time of charge is preferably 0.01 to 70% by mol relative to the total monomer used for synthesis of the hyperbranched polymer. The amount of metal catalyst used for synthesis of the hyperbranched polymer at the time of charge is more preferably 0.1 to 60% by mol relative to the total monomer used for synthesis of the hyperbranched polymer. When the metal catalyst for synthesis of the hyperbranched polymer is used at this amount, reactivity may be improved, thereby enabling to synthesize the hyperbranched polymer having a suitable degree of branching.

When the amount of metal catalyst used for synthesis of the hyperbranched polymer is below the above-mentioned range, there is a possibility that reactivity is markedly reduced, and thus the polymerization becomes sluggish. On the other hand, when the amount of metal catalyst used for synthesis of the hyperbranched polymer is above the range, the polymerization reaction becomes excessively active so that the coupling reaction among radicals at growing terminals tends to occur easily, thereby making control of the polymerization difficult. Further, when the amount of the metal catalyst used for synthesis of the hyperbranched polymer is above the range, the coupling reaction among radicals induces gelation of the reaction system.

The metal catalyst may be made into a coordination compound by mixing a transition metal compound as described above and a ligand in an apparatus. The metal catalyst composed of a transition metal and a ligand may also be added to an apparatus in the form of an active coordination compound. Making a coordination compound by mixing a transition metal compound and a ligand in an apparatus is preferable because a simplified operation can be expected in the synthesis of the hyperbranched polymer.

The method of adding the metal catalyst is not particularly restricted, and the metal catalyst may be added, for example, all at once in advance of the shell polymerization. Further, additional metal catalyst may be added after an initiation of the polymerization according to the degree of an inactivation of the catalyst. For example, when the state of dispersion of a coordination compound forming the metal catalyst in the reaction system is inhomogeneous, a transition metal compound may be added to an apparatus in advance, and then followed by addition of only a ligand.

### (Polar Solvents)

Additives used in the synthesis of the hyperbranched polymer will be explained. In the polymerization of the above-mentioned monomers, among compounds represented by formula (1-1) and compounds represented by formula (1-2) mentioned in Chapter 1, at least one type may be added.

R₁ in formula (1-1) represents hydrogen, an alkyl group having 1 to 10 carbon atoms, an aryl group having 6 to 10 carbon atoms, or an aralkyl group having 7 to 10 carbon atoms. More specifically, R₁ in the formula (1-1) represents a hydrogen, an alkyl group having 1 to 10 carbon atoms, an aryl group having 6 to 10 carbon atoms, or an aralkyl group having 7 to 10 carbon atoms. “A” in formula (1-1) represents a cyano group, a hydroxy group, and a nitro group. examples of the compound represented by formula (1-1) include nitriles, alcohols, and a nitro compound.

Specific examples of nitriles included in compounds represented by formula (1-1) include acetonitrile, propionitrile, butyronitrile, and benzonitrile. Specific examples of alcohols included in compounds represented by formula (1-1) include methanol, ethanol, 1-propanol, 2-propanol, 1-butanol, cyclohexyl alcohol, and benzyl alcohol. Specific examples of nitro compounds included in compounds represented by formula (1-1) include nitromethane, nitroethane, nitropropane, and nitrobenzene. The compound represented by formula (1-1) is not restricted to the compounds mentioned above.

R₂ and R₃ in formula (1-2) represent hydrogen, an alkyl group having 1 to 10 carbon atoms, an aryl group having 6 to 10 carbon atoms, an aralkyl group having 7 to 10 carbon atoms, or a or a or a dialkylamino group having 1 to 10 carbon atoms; B represents a carbonyl group and a sulfonyl group. More specifically, R₂ and R₃ in formula (1-2) represent hydrogen, an alkyl group having 1 to 10 carbon atoms, an aryl group having 6 to 10 carbon atoms, an aralkyl group having 7 to 10 carbon atoms, or a dialkyl amine group having 2 to 10 carbon atoms. R₂ and R₃ in formula (1-2) may be the same or different.

Examples of the compound represented by formula (1-2) include ketones, sulfoxides, and an alkyl formamide compound. Specific examples of the ketones include acetone, 2-butanone, 2-pentanone, 3-pentanone, 2-hexanone, cyclohexanone, 2-methyl cyclohexanone, acetophenone, and 2-methyl acetophenone.

Specific examples of the sulfoxides included in the compounds represented by formula (1-2) include dimethyl sulfoxide and diethyl sulfoxide. Specific examples of the alkyl formamide compound included in the compounds represented by formula (1-2) include N,N-dimethyl formamide, N,N-diethylformamide, and N,N-dibutyl formamide. The compounds represented by formula (1-2) are not restricted to the above-mentioned compounds. Among the compounds represented by formula (1-1) or formula (1-2), nitriles, nitro compounds, ketones, sulfoxides, and alkyl formamide compounds are preferable, while acetonitrile, propionitrile, benzonitrile, nitroethane, nitropropane, dimethyl sulfoxide, acetone, and N,N-dimethyl formamide are more preferable.

In the synthesis of the hyperbranched polymer, compounds represented by formula (1-1) or formula (1-2) may be used independently or in combination of two or more.

In the synthesis of the hyperbranched polymer, compounds represented by formula (1-1) or formula (1-2) may be used independently or in combination of two or more as a solvent.

The amount of the compounds represented by formula (1-1) or (1-2) to be added in the synthesis of the hyperbranched polymer is preferably 2 times to 10000 times by mol ratio relative to the amount of transition metal in the metal catalyst. The amount of the compound represented by formula (1-1) or the amount of the compound represented by (1-2) to be added relative to the amount of a transition metal in the metal catalyst is more preferably 3 times to 7000 times by mol ratio, and yet more preferably 4 times to 5000 times by mol ratio relative to the amount of transition metal in the metal catalyst.

When the added amount of the compound represented by formula (1-1) or of the compound represented by formula (1-2) is too small, the rapid increase in molecular weight may not be controlled sufficiently. On the other hand, when the added amount of the compound represented by formula (1-1) or of the compound represented by formula (1-2) is too large, the reaction rate is slowed, leading to the formation of a large amount of oligomers.

### (Other Solvents)

Other solvents used in the synthesis of the hyperbranched polymer will be explained. It is preferable that the polymerization reaction of the hyperbranched polymer be carried out in the various kinds of solvents given below, though the reaction can occur without a solvent. The other solvents used in the polymerization of the hyperbranched polymer in the presence of the metal catalyst are not particularly restricted, and examples include a hydrocarbon solvent, an ether solvent, a halogenated hydrocarbon solvent, a ketone solvent, an alcohol solvent, a nitrile solvent, an ester solvent, a carbonate solvent, and an amide solvent. Various kinds of solvents for the synthesis of the hyperbranched polymer as described above may be used independently or in a combination of two or more.

Specific examples of the hydrocarbon solvent as the other solvents used for the synthesis of the hyperbranched polymer include benzene and toluene. Specific examples of the ether solvent used for the synthesis of the hyperbranched polymer include diethyl ether, tetrahydrofuran, diphenyl ether, anisole, and dimethoxy benzene.

Specific examples of the halogenated hydrocarbon solvent as the other solvents used for the synthesis of the hyperbranched polymer include methylene chloride, chloroform, and chlorobenzene. Specific examples of the ketone solvent used for the synthesis of the hyperbranched polymer include acetone, methyl ethyl ketone, and methyl isobutyl ketone. Specific examples of the alcohol solvent used for the synthesis of the hyperbranched polymer include methanol, ethanol, propanol, and isopropanol.

Specific examples of the nitrile solvent as the other solvents used for the synthesis of the hyperbranched polymer include acetonitrile, propionitrile, and benzonitrile. Specific examples of the ester solvent used for the synthesis of the hyperbranched polymer include ethyl acetate and butyl acetate. Specific examples of the carbonate solvent used for the synthesis of the hyperbranched polymer include ethylene carbonate and propylene carbonate.

Specific examples of the amide solvent as the other solvents used for the synthesis of the hyperbranched polymer include N,N-dimethylformamide and N,N-dimethylacetamide.

### (Preparation Method of Metal Catalyst)

Preparation method of the metal catalyst used for the synthesis of the hyperbranched polymer will be explained. The metal catalyst used for the synthesis of the hyperbranched polymer is composed of a transition metal and a ligand, and may be made into a coordination compound by mixing a transition metal compound and a ligand in an equipment in the polymerization reaction for the synthesis of the hyperbranched polymer. The metal catalyst may be composed of a transition metal and a ligand and added to an apparatus in the form of an active coordination compound. It is preferable to make a coordination compound by mixing a transition metal compound and a ligand in an apparatus because a simplified synthesis operation can be expected.

To prevent deactivation of the catalyst by oxidation, it is preferable that all substances to be used for the polymerization, namely, metal catalysts, solvents, monomers, and the like be fully deoxygenated by evacuation or blowing-in an inert gas such as nitrogen and argon prior to the polymerization.

### (Method of Adding Metal Catalyst)

A method of adding the metal catalyst used for the synthesis of the hyperbranched polymer will be explained. The method of adding the metal catalyst used for the synthesis of the hyperbranched polymer is not particularly restricted and the metal catalyst may be added, for example, all at once prior to the polymerization. Also, additional metal catalyst may be added after initiation of the polymerization according to the level of inactivation. For example, when the state of dispersion of the coordination compound forming the metal catalyst is inhomogeneous in the entire reaction system, the transition metal compound may be added to an apparatus in advance, and then followed by addition of only the ligand.

Each step for the synthesis of the hyperbranched polymer will be explained in detail.

### (Core Polymerization)

The core polymerization to synthesize the core portion of the hyperbranched polymer will be explained. It is preferable that the core polymerization be carried out in the presence of nitrogen or an inert gas, or under the gas flow thereof, and in the absence of oxygen, to prevent radicals from being affected by oxygen. The core polymerization may be carried out in a batch process or a continuous process.

The core polymerization may be carried out, for example, by adding the monomer dropwise into a reaction vessel. When the amount of the catalyst is small, a high degree of branching in the synthesized core portion may be maintained by controlling the rate of the dropwise addition of the monomer. In other words, by controlling the rate of the dropwise addition of the monomer, the amount of the metal catalyst can be reduced while maintaining a high degree of branching in the synthesized hyperbranched core polymer (macro initiator). To keep a high degree of branching in the formed core portion, the concentration of the monomer added dropwise is preferably 1 to 50% by mass relative to the total reaction mass. More preferably, the concentration of the monomer added dropwise is 2 to 20% by mass relative to the total reaction mass.

The polymerization time is preferably 0.1 to 10 hours depending on the molecular weight of the polymer. The reaction temperature in the core polymerization is preferably 0 to 200° C. More preferably, the reaction temperature for the core polymerization is 50 to 150° C. When the polymerization is carried out at a temperature above a boiling point of a solvent used, for example, a pressure may be applied in an autoclave.

In the core polymerization, it is preferable that the reaction system be distributed uniformly. The reaction system may be made homogeneous, for example, by agitation. As a specific example of an agitation condition in core polymerization, preferably the power necessary for agitation per unit volume is 0.01 kW/m³ or more. In the core polymerization, additional catalyst or a reducing agent to regenerate the catalyst may be added according to the progress of the polymerization and degree of catalyst inactivation.

In the core polymerization, the polymerization is stopped when the molecular weight reaches the point prescribed in the core polymerization. The method of stopping the core polymerization is not particularly restricted, and a method such as inactivating the catalyst, for example, by cooling or by adding an oxidizing agent, a chelating agent, or others may be used.

### (Shell Polymerization)

The shell polymerization to synthesize the shell portion of the hyperbranched polymer will be explained. It is preferable that the shell polymerization be carried out in the presence of nitrogen or an inert gas, or under the gas flow thereof, and in the absence of oxygen, to prevent radicals from being affected by oxygen. In the embodiment, the step of forming the shell portion is realized by the shell polymerization. The shell polymerization may be carried out in a batch process or a continuous process.

The shell polymerization may be carried out subsequently after the core polymerization, or by adding a catalyst again after the metal catalyst and monomer are removed after the core polymerization.

In the shell polymerization by using the formed core portion (core macromer), for example, a metal catalyst is placed in a reaction system prior to initiation of the reaction, and then the core portion and a monomer are added dropwise into the reaction system. Specifically, for example, a metal catalyst is placed inside a reaction vessel in advance, and then the core portion and the monomer are added dropwise into the reaction vessel. Alternatively, for example, monomer for the shell portion described above may be added dropwise into a reaction vessel in which the core portion and the reaction catalyst are placed in advance.

In the shell polymerization, gelation which occurs when the reaction concentration is high may be efficiently prevented by adding the monomer into the formed core portion dropwise. Concentration of the core portion in the shell polymerization is preferably 0.1 to 30% by mass relative to the total amount of the reaction at the time of charge. More preferably, the concentration of the core portion in the shell polymerization is 0.1 to 20% by mass relative to the total amount of the reaction at the time of charge.

Concentration of the monomer for the shell portion in the shell polymerization is preferably 0.5 to 20 mol equivalents relative to the active site of the core macromer at the time of charge. More preferably, the concentration of the monomer for the shell portion in the shell polymerization is 1 to 15 mol equivalents relative to the active site of the core portion. By appropriately controlling the amount of monomer for the shell portion in the shell polymerization, the core/shell ratio in the hyperbranched polymer can be controlled.

The polymerization time for the shell polymerization is preferably 0.1 to 10 hours depending on the molecular weight of the polymer. The reaction temperature of the shell polymerization is preferably 0 to 200° C. More preferably, the reaction temperature for the shell polymerization is 50 to 150° C. When the polymerization is carried out at a temperature above a boiling point of a solvent used, for example, a pressure may be applied in an autoclave.

In the shell polymerization, the reaction system is made homogeneous. For example, the reaction system may be distributed uniformly by agitation. As a specific agitation condition in the shell polymerization, the agitation power requirement per unit volume is preferably, for example, 0.01 kW/m³ or more.

In the shell polymerization, additional catalyst or a reducing agent may be added to regenerate the catalyst according to a progress of the polymerization and the degree of the catalyst inactivation. The shell polymerization is stopped when the molecular weight reaches the point prescribed in the shell polymerization. The method of stopping the shell polymerization is not particularly restricted, and a method such as inactivating the catalyst, for example, by cooling, or by adding an oxidizing agent, a chelating agent, or others may be used.

### (Purification)

Purification of the hyperbranched polymer will be explained. In the purification of the hyperbranched polymer, removal of the metal catalyst, removal of monomers, and removal of trace metal are performed.

### Removal of Metal Catalyst

In the purification processes of the hyperbranched polymer, removal of the metal catalyst is performed after the shell polymerization. Removal of the metal catalyst may be done, for example, by the following (a) to (c) methods independently or in a combination of thereof.

(a) Use various kinds of adsorbents, such as Kyoward manufactured by Kyowa Chemical Industry Co., Ltd.
(b) Remove insoluble matter by filtration and centrifugal separation.
(c) Extract by using a water solution containing an acid and/or a compound having a chelating effect.

Examples of a compound having a chelating effect and used in method (c) include organic acids such as formic acid, acetic acid, oxalic acid, citric acid, gluconic acid, tartaric acid, and malonic acid; an amino carbonate such as nitrilotriacetic acid, ethylenediaminetetraacetic acid, and diethylenetriamine pentaacetic acid; and a hydroxyamino carbonate. Examples of a compound having a chelating effect and used in the method (c) include inorganic acids such as hydrochloric acid and sulfuric acid. Concentration of the aqueous solution containing a compound having a chelating capacity is preferably, for example, 0.05 to 10% by mass, and may differ depending on a chelating capacity of the substance.

### (Monomer Removal)

Removal of the monomers may be performed after the metal catalyst is removed or after the metal catalyst and subsequently, trace metals are removed. In the removal of monomers, unreacted monomers among the monomers added dropwise at the core polymerization and the shell polymerization at step S102 are removed. Unreacted monomers may be removed, for example, by the following (d) to (e) methods independently or in a combination thereof.

(d) Precipitate polymer by adding a poor solvent to a reaction substance dissolved in a good solvent.
(e) Wash polymer using a mixed solvent of a good solvent and a poor solvent.

In (d) to (e) above, examples of a good solvent include a halogenated hydrocarbon, a nitro compound, a nitrile, an ether, a ketone, an ester, a carbonate ester, and a mixture thereof. Specific examples include tetrahydrofuran, chlorobenzene, and chloroform. Examples of the poor solvent include methanol, ethanol, 1-propanol, 2-propanol, water, and a mixture thereof. Here, the method of removing unreacted monomers is not restricted particularly to the methods described above.

### (Removal of Trace Metal)

Removal of trace metal will be explained. Removal of trace metal is performed after removal of the metal catalyst as described above to reduce trace metal remaining in the polymer. Reduction of trace metal remaining in the reaction system, in which the hyperbranched polymer having the shell portion formed by the shell polymerization is present, may be done, for example, by the following (f) to (g) methods independently or in a combination thereof.

(f) Extract by a liquid-liquid extraction using an aqueous solution containing an organic compound having a chelating capacity, an aqueous solution of an inorganic acid, and pure water.
(g) Use an adsorbent and an ion-exchange resin.

Examples of the organic solvent preferably used for the liquid-liquid extraction in method (f) include a halogenated hydrocarbon such as chlorobenzene and chloroform; acetate esters such as ethyl acetate, n-butyl acetate, and isoamyl acetate; ketones such as methyl ethyl ketone, methyl isobutyl ketone, cyclohexanone, 2-heptane, and 2-pentanone; glycol ether acetates such as ethyleneglycol monoethyl ether acetate, ethyleneglycol monobutyl ether acetate, ethyleneglycol monomethyl ether acetate; and aromatic hydrocarbons such as toluene and xylene.

Examples of the organic solvent more preferably used for the liquid-liquid extraction in method (f) include chloroform, methyl isobutyl ketone, and ethyl acetate. These solvents may be used independently or in a combination of two or more. In the liquid-liquid extraction according to (f), a “% by mass” of the hyperbranched polymer after the purification in (f) is preferably about 1 to about 30% by mass relative to the organic solvent. More preferable “% by mass” of the resist polymer intermediate relative to the organic solvent is about 5 to about 20% by mass.

Examples of an organic compound having an chelating capacity used in the liquid-liquid extraction method (f) include an organic acid such as formic acid, acetic acid, oxalic acid, citric acid, gluconic acid, tartaric acid, and malonic acid; an amino carbonate such as nitrilotriacetic acid, ethylenediaminetetraacetic acid, and diethylenetriamine pentaacetic acid; and a hydroxyamino carbonate. Examples of the inorganic acid used in the liquid-liquid extraction method (f) include hydrochloric acid and sulfuric acid.

In the liquid-liquid extraction according to method (f), concentrations of the organic compound having a chelating capacity and the inorganic acid in the aqueous solution are preferably, for example, 0.05 to 10% by mass. Here, concentration of the organic compound having a chelating capacity in the liquid-liquid extraction in (f) is different depending on a chelating capacity of the compound. Concentration of the inorganic acid is different depending on its acid strength.

In the method of removing trace metal, when an aqueous solution containing an organic compound having a chelating capacity and an aqueous solution containing an inorganic acid are used, a mixture of the aqueous solution containing the organic compound having a chelating capacity and the aqueous solution containing the inorganic acid may be used, or the aqueous solution containing the organic compound having a chelating capacity and the aqueous solution containing the inorganic acid may be used separately. When the aqueous solution containing the organic compound having a chelating capacity and the aqueous solution containing the inorganic acid are used separately, the aqueous solution containing the organic compound having a chelating capacity or the aqueous solution containing the inorganic acid may be used first.

In removing trace metals, when the aqueous solution containing the organic compound having a chelating capacity and the aqueous solution containing the inorganic acid are used separately, it is more preferable to use the aqueous solution containing the inorganic acid at later stage because the aqueous solution containing the organic compound having a chelating capacity is effective in removing copper catalyst and multivalent metal, and the aqueous solution containing the inorganic acid is effective in removing monovalent metal derived from experimental equipment and the like.

Accordingly, when the aqueous solution containing the organic compound having a chelating capacity and the aqueous solution containing the inorganic acid are used as a mixture, it is also preferable to wash the shell portion by an aqueous solution containing only the inorganic acid at a later stage. The number of extractions is not particularly restricted, but preferably is 2 to 5 times, for example. To avoid contamination by metals derived from experimental equipment and the like, it is preferable to use pre-washed experimental equipment particularly when used in a reduced copper ion state. The method of pre-washing is not particularly restricted, and for example, may be washing by an aqueous nitric acid.

The number of washings solely by the aqueous solution containing the inorganic acid is preferably 1 to 5 times. When the washing solely by the aqueous solution containing the inorganic acid is performed 1 to 5 times, monovalent metal can be removed sufficiently. Further, to remove residual acid components, it is preferable to perform the extraction treatment by pure water last to remove the acid completely. The number of washings by pure water is preferably 1 to 5 times. When the washing by pure water is performed 1 to 5 times, residual acid can be removed sufficiently.

In the removal of trace metals, respective volume ratios of the reaction solvent containing the purified hyperbranched polymer (hereinafter, “reaction solvent”) to the aqueous solution containing the organic compound having a chelating capacity, to the aqueous solution containing the inorganic acid, and to pure water are each preferably 1:0.1 to 1:10 by volume. More preferably the volume ratios are 1:0.5 to 1:5 by volume. When the washing is performed using the solvent at such ratios, metal can be easily removed by a moderate number of washings. Thus, operations can be simplified and easy, thereby leading to efficient synthesis of the core-shell hyperbranched polymer, and thus, is preferable. It is preferable that the concentration by mass of a resist polymer intermediate dissolved in the reaction solvent be usually approximately 1 to 30% by mass relative to the solvent.

The liquid-liquid extraction treatment in method (f) is performed, for example, by separating the mixed solvent composed of the reaction solvent and the aqueous solution containing the organic compound having a chelating capacity, the aqueous solution containing the inorganic acid, and pure water (hereinafter, simply “mixed solvent”) into two layers, and then removing a water layer containing migrated metal ions by decantation.

Separation of the mixed solvent into two layers may be performed, for example, by the following method; the aqueous solution containing the organic compound having a chelating capacity, the aqueous solution containing the inorganic acid, and pure water are added into the reaction solvent, are mixed thoroughly by agitation, and allowed to stand thereafter. Separation of the mixed solvent into two layers may be performed by centrifugal separation, for example. The liquid-liquid extraction treatment in method (f) is preferably performed, for example, at a temperature of 10 to 50° C. and more preferably at 20 to 40° C.

In the synthesis of the core-shell hyperbranched polymer, partial decomposition of an acid-decomposable group may be carried out, as needed, after trace metal are removed. In the partial decomposition of the acid-decomposable group, for example, a part of the acid-decomposable group is decomposed (the acid-decomposable group is directed) to an acid group by using the acid catalyst mentioned above. The liquid-liquid extraction treatment in method (f) is performed at a temperature of 20 to 40° C., preferably.

### (Deprotection)

Deprotection of the hyperbranched polymer will be explained. In the deprotection, a partial decomposition of the acid-decomposable group may be performed, as needed, after trace metal as described above is removed. In the partial decomposition of the acid-decomposable group, for example, a part of the acid-decomposable group is decomposed to the acid group by using the acid catalyst as described above. In the embodiment, the process of forming the acid group is realized here.

In the decomposition of part of an acid-decomposable group by the acid catalyst (partial decomposition of the acid-decomposable group) to the acid group, usually acid catalyst of 0.001 to 100 equivalents to the acid-decomposable group in the core-shell hyperbranched polymer obtained after the removal of metal is used. Examples of the acid catalyst include hydrochloric acid, sulfuric acid, phosphoric acid, hydrobromic acid, p-toluene sulfonic acid, acetic acid, trifluoroacetic acid, trifluoromethane sulfonic acid, and formic acid.

An organic solvent used in the reaction of the partial decomposition of the acid-decomposable group is preferably an organic solvent that can dissolve the hyperbranched polymer obtained after trace metals are removed, and also is miscible with water. Specifically, in view of availability and ease of handling, the organic solvent used in the reaction of the partial decomposition of the acid-decomposable group is preferably selected from among 1,4-dioxane, tetrahydrofuran, acetone, methyl ethyl ketone, diethyl ketone, and a mixture thereof.

The amount of organic solvent used in the reaction of the partial decomposition of the acid-decomposable group is not particularly restricted provided that the hyperbranched polymer, obtained after removal of trace metal, and the acid catalyst are dissolved, but is preferably 5 to 500 times by mass as much the hyperbranched polymer obtained after removal of trace metal.

More preferably, the amount of the organic solvent used in the reaction of the partial decomposition of the acid-decomposable group by using the acid catalyst is 8 to 200 times by mass as much the hyperbranched polymer obtained after removal of trace metal. The reaction to partially decompose the acid-decomposable group may be performed by heating at 50 to 150° C. and for 10 minutes to 20 hours with agitation.

Concerning the ratio of the acid-decomposable group to the acid group in the hyperbranched polymer obtained after the deprotection, preferably 0.1 to 80% by mol of the monomer having the introduced acid-decomposable group is de-protected to the acid group. When the ratio of the acid-decomposable group to the acid group is at the above-mentioned range, high sensitivity and efficient dissolution into a basic solution after light-exposure are realized, and thus, is preferable.

When the core-shell hyperbranched polymer obtained after the deprotection is used for a resist composition of a photo resist and the like, the optimal ratio of the acid-decomposable group to the acid group in the hyperbranched polymer varies according to the composition of the resist composition. The ratio of the acid-decomposable group to the acid group may be controlled by appropriately choosing the amount of the acid catalyst, the temperature, and the reaction time.

After the partial decomposition reaction of the acid-decomposable group, a solution containing the hyperbranched polymer having a formed acid group obtained after the partial decomposition of the acid-decomposable group (hereinafter, “reaction solution”) is mixed with the ultrapure water to precipitate the hyperbranched polymer obtained after the partial decomposition of the acid-decomposable group. Then, the solution containing the precipitated hyperbranched polymer is subjected to centrifugal separation, filtration, decantation, and the like to separate the hyperbranched polymer formed after the partial decomposition reaction of the acid-decomposable group. Thereafter, the hyperbranched polymer precipitated is dissolved again into an organic solvent, and then the liquid-liquid extraction is performed using the solution containing the precipitated hyperbranched polymer dissolved therein and ultrapure water to remove residual acid catalyst.

The organic solvent used in the liquid-liquid extraction as mentioned before is preferably an organic solvent which can dissolve the precipitated hyperbranched polymer, and in addition, is poorly miscible or not miscible with water. There is no particular restriction in the organic solvent provide the organic solvent has the properties as described above, and examples of the organic solvent usable in the liquid-liquid extraction include methyl isobutyl ketone and ethyl acetate.

The solubility of the precipitated hyperbranched polymer in the solvent used in the liquid-liquid extraction varies depending on the ratio of the acid-decomposable group to the acid group in the hyperbranched polymer. Accordingly, a concentration of the precipitated hyperbranched polymer in the organic solvent used in the liquid-liquid extraction is not particularly restricted, but for example 1 to 40% by mass is preferable.

The amount of ultrapure water used in the liquid-liquid extraction relative to the organic solvent is preferably at the range of ultrapure water/organic solvent=0.1/1 to 1/0.1 by a volume ratio. When a part of the acid-decomposable group is decomposed to the acid group by using the acid catalyst, it is preferable that the ultrapure water for the liquid-liquid extraction be used with the volume ratio of ultrapure water/organic solvent=0.5/1 to 1/0.5 at the above-mentioned range, because the amount of a waste effluent can be reduced at this range.

It is preferable that the liquid-liquid extraction be repeated at 10 to 50° C. until the pH of the water layer becomes neutral. The number of the extractions is determined depending on the concentration of the acid used, but is preferably 1 to 10 times to suppress an increase in the amount of the waste effluent accompanying an increase in the scale of the synthesis of the hyperbranched polymer for industrialization. After extraction by the liquid-liquid extraction, the organic solvent used in the liquid-liquid extraction is distilled out, and then the residue is dried. Thus, the hyperbranched polymer of a desired structure can be obtained.

### (Filtration)

A solution after the liquid-liquid extraction is filtered. The filtration is done using a filter with a pore diameter of 0.1 μm or less. To prevent a slowed filtration rate due to clogging, a filter with a pore diameter of 0.01 to 0.1 μm is preferably used. However, the pore diameter is not restricted to the above-mentioned values, and for example, pore diameters of 0.2 μm and of 0.5 μm may be used. For the filtration, for example, a filter made of an ultra-high density polyethylene with a specific gravity of 0.91 or higher is used.

### (Molecular Structure)

A molecular structure of the core-shell hyperbranched polymer will be explained. The degree of branching (Br) of the core portion of the core-shell hyperbranched polymer is preferably 0.3 to 0.5. More preferably the degree of branching (Br) is 0.4 to 0.5. When the degree of branching (Br) of the core portion of the core-shell hyperbranched polymer is at the above range, a resist composition containing the core-shell hyperbranched polymer synthesized by using the hyperbranched core polymer has a low intermolecular entanglement among the polymers and thereby suppresses surface roughness in the pattern wall, and thus, is preferable.

Here, the degree of branching (Br) of the core portion in the core-shell hyperbranched polymer may be obtained by measuring a ¹H-NMR of the product. Namely, the degree of branching can be calculated by computing equation (A) in Chapter 1 by using H1°, an integral ratio of protons in —CH₂Cl appearing at 4.6 ppm, and H2°, an integral ratio of the protons in —CHCl appearing at 4.8 ppm. When polymerization progresses at both —CH₂Cl and —CHCl, thereby enhancing the branching, the degree of branching (Br) approaches 0.5.

The weight-average molecular weight (Mw) of the core portion in the core-shell hyperbranched polymer is preferably 300 to 8,000, also preferably 500 to 6,000, and most preferably 1,000 to 4,000. When the molecular weight of the core portion is at such ranges, the core portion takes a spherical morphology, thereby, ensuring solubility into the reaction solvent in the reaction to introduce the acid-decomposable group, and thus, is preferable. In addition, performance of a film-formation is excellent, and dissolution of a light-unexposed part is prevented advantageously in the hyperbranched polymer whose core portion having the molecular weight at the above range is introduced by the acid-decomposable group, and thus, is preferable.

The degree of multi-dispersion (Mw/Mn) of the core portion in the core-shell hyperbranched polymer is preferably 1 to 3, and more preferably 1 to 2.5. At such ranges, there is no risk of adverse effects such as insolubilization after light exposure, and thus, is preferable.

The weight-average molecular weight (M) of the core-shell hyperbranched polymer is preferably 500 to 21,000, more preferably 2,000 to 21,000, and most preferably 3,000 to 21,000. When the weight-average molecular weight (M) of the hyperbranched polymer is at such ranges, a resist composition containing the hyperbranched polymer is excellent in a film formation and can maintain its form because the process pattern formed in a lithography step is strong. In addition, it is excellent in terms of dry-etching resistance and surface roughness.

The weight-average molecular weight (Mw) of the core portion in the core-shell hyperbranched polymer may be obtained, for example, by a GPC measurement using a tetrahydrofuran solution (0.5% by mass) at 40° C. Tetrahydrofuran may be used as a moving phase, styrene as a standard material.

The weight-average molecular weight (M) of the core-shell hyperbranched polymer may be obtained as follows: an introduction ratio (composition ratio) of each repeating unit in the polymer into which the acid-decomposable group is introduced is obtained by ¹H-NMR, and then, based on the weight-average molecular weight (Mw) of the core portion in the core-shell hyperbranched polymer, M is obtained by a calculation by using the introduction ratio of each composition unit and the molecular weight of each composition unit.

### (Application of the Hyperbranched Polymer)

Application of the polymer is not particularly restricted, and may be used for, for example, a polymer for a photo resist, a resin for ink-jet processing such as a color filter and a biochip, a crosslinking agent in a powder paint, a substrate for a solid electrolyte, and a pour-point depressant for a BDF.

For example, when the hyperbranched polymer is applied to a polymer of a photo resist, an excellent polymer for a photo resist having a small concavity and convexity of the pattern wall and a high solubility in a basic solution after a light-exposure, namely a high light-sensitivity, may be obtained by introducing the acid-decomposable group, as the shell portion at the terminals of the core portion of the hyperbranched polymer, into the terminal of the hyperbranched polymer. In such an application, for example, tert-butyl acrylate may be polymerized to give the shell portion of the core-shell hyperbranched polymer by an Atom Transfer Radical Polymerization.

The resist composition may support an electron beam, a deep ultraviolet beam (DUV), and an extreme ultraviolet beam (EUV), which require a surface smoothness at a nanometer level, thereby enabling formation of a fine pattern for manufacturing a semi-conductor integrated circuit. Thus, a resist composition containing the hyperbranched polymer synthesized according to the manufacturing method of the present invention can be suitably used in various fields which use a semi-conductor integrated circuit produced by using a light source irradiating a short wavelength light.

Further, in a semi-conductor integrated circuit produced by using a resist composition containing the hyperbranched polymer of the embodiment, when the semi-conductor integrated circuit is exposed to light, is heated, dissolved in a basic developing solution, and then washed by water-washing and the like during fabrication, substantially no undissolved residues remain on exposed surfaces, thereby enabling formation of a nearly vertical edge. This, a fine semi-conductor integrated circuit having stable performance and supporting an electron beam, a deep ultraviolet beam (DUV), and an extreme ultraviolet beam (EUV) can be obtained.

### (Resist Composition)

A resist composition using the hyperbranched polymer will be explained. The blending amount of the core-shell hyperbranched polymer (resist polymer) in a resist composition using the hyperbranched polymer (hereinafter, simply “resist composition”) is preferably 4 to 40% by mass and more preferably 4 to 20% by mass relative to a total amount of the resist composition.

The resist composition contains the core-shell hyperbranched polymer above and a photo-inductive acid-generating material. The resist composition may further contain, as needed, an acid-diffusion suppressor (an acid scavenger), a surfactant, other components, a solvent, and the like.

There is no particular restriction in terms of photo-inductive acid-generating material contained in the resist composition provided acid is generated upon exposure to UV light, an X-ray beam, an electron beam, and the like, and may be selected appropriately from among commonly known photo-inductive acid-generating materials according to purpose. Specific examples of the photo-inductive acid-generating material include onium salt, sulfonium salt, a halogen-containing triazine compound, a sulfone compound, a sulfonate compound, an aromatic sulfonate compound, and an N-hydroxyimide sulfonate compound.

Examples of onium salt included in the photo-inductive acid-generating material include a diaryl iodonium salt, a triaryl selenonium salt, and a triaryl sulfonium salt. Examples of diaryl iodonium salt include diphenyl iodonium trifluoromethane sulfonate, 4-methoxyphenyl phenyl iodonium hexafluoroantimonate, 4-methoxyphenyl phenyl iodonium trifluoromethane sulfonate, bis(4-tert-butylphenyl)iodonium tetrafluoroborate, bis(4-tert-butylphenyl)iodonium hexafluorophosphate, bis(4-tert-butylphenyl)iodonium hexafluoroantimonate, and bis(4-tert-butylphenyl)iodonium trifluoromethane sulfonate.

Specific examples of triaryl selenonium salt included in onium salt include triphenyl selenonium hexafluorophosphoric salt, triphenyl selenonium tetrafluoroborate salt, and triphenyl selenonium hexafluoroantimonate salt. Examples of triaryl sulfonium salt included in onium salt include triphenyl sulfonium hexafluorophosphoric salt, triphenyl sulfonium hexafluoroantimonate salt, diphenyl-4-thiophenoxyphenyl sulfonium hexafluoroantimonate salt, and diphenyl-4-thiophenoxyphenyl sulfonium pentafluorohydroxy antimonate salt.

Examples of sulfonium salt included in the photo-inductive acid-generating material include triphenyl sulfonium hexafluorophosphate, triphenyl sulfonium hexafluoroantimonate, triphenyl sulfonium trifluoromethane sulfonate, 4-methoxyphenyl diphenyl sulfonium hexafluoroantimonate, 4-methoxyphenyl diphenyl sulfonium trifluoromethane sulfonate, p-tolyldiphenyl sulfonium trifluoromethane sulfonate, 2,4,6-trimethylphenyl diphenyl sulfonium trifluoromethane sulfonate, 4-tert-butylphenyl diphenyl sulfonium trifluoromethane sulfonate, 4-phenylthiophenyl diphenyl sulfonium hexafluorophosphate, 4 phenylthiophenyl diphenyl sulfonium hexafluoroantimonate, 1-(2-naphthoylmethyl)thioranium hexafluoroantimonate, 1-(2-naphthoylmethyl)thioranium trifluoroantimonate, 4-hydroxy-1-naphthyl dimethyl sulfonium hexafluoroantimonate, and 4-hydroxy-1-naphthyl dimethyl sulfonium trifluoromethane sulfonate.

Specific examples of a halogen-containing triazine compound included in the photo-inductive acid-generating material include 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2-(4-chlorophenyl)-4,6-bis(trichloromethyl)-1,3,5-triazine, 2-(4-methoxyphenyl)-4,6-bis(trichloromethyl)-1,3,5-triazine, 2-(4-methoxy-1-naphthyl)-4,6-bis(trichloromethyl)-1,3,5-triazine, 2-(benzo[d][1,3]dioxolane-5-yl)-4,6-bis(trichloromethyl)-1,3,5-triazine, 2-(4-methoxystyryl)-4,6-bis(trichloromethyl)-1,3,5-triazine, 2-(3,4,5-trimethoxystyryl)-4,6-bis(trichloromethyl)-1,3,5-triazine, 2-(3,4-dimethoxystyryl)-4,6-bis(trichloromethyl)-1,3,5-triazine, 2-(2,4-dimethoxystyryl)-4,6-bis(trichloromethyl)-1,3,5-triazine, 2-(2-methoxystyryl)-4,6-bis(trichloromethyl)-1,3,5-triazine, 2-(4-butoxystyryl)-4,6-bis(trichloromethyl)-1,3,5-triazine, and 2-(4-benzyloxystyryl)-4,6-bis(trichloromethyl)-1,3,5-triazine.

Specific examples of the sulfone compound included in the photo-inductive acid-generating material include diphenyl disulfone, di-p-tolyl disulfone, bis(phenylsulfonyl)diazomethane, bis(4-chlorophenylsulfonyl)diazomethane, bis(p-tolylsulfonyl)diazomethane, bis(4-tert-butylphenylsulfonyl)diazomethane, bis(2,4-xylylsulfonyl)diazomethane, bis(cyclohexylsulfonyl)diazomethane, (benzoyl)(phenylsulfonyl)diazomethane, and phenylsulfonyl acetophenone.

Specific examples of the aromatic sulfonate compound included in the photo-inductive acid-generating material include α-benzoylbenzyl p-toluene sulfonate (common name: benzoin tosylate), β-benzoyl-β-hydroxyphenetyl p-toluene sulfonate (common name: α-methylol benzoin tosylate), 1,2,3-benzenetriyl trismethane sulfonate, 2,6-dinitrobenzyl p-toluene sulfonate, 2-nitrobenzyl p-toluene sulfonate, and 4-nitrobenzyl p-toluene sulfonate.

Specific examples of the N-hydroxyimide sulfonate compound included in the photo-inductive acid-generating material include N-(phenylsulfonyloxy)succinimide, N-(trifluoromethylsulfonyloxy)succinimide, N-(p-chlorophenylsulfonyloxy)succinimide, N-(cyclohexylsulfonyloxy)succinimide, N-(1-naphthylsulfonyloxy)succinimide, N-(benzylsulfonyloxy)succinimide, N-(10-camphorsulfonyloxy)succinimide, N-(trifluoromethylsulfonyloxy)phthalimide, N-(trifluoromethylsulfonyloxy)-5-norbornene-2,3-dicarboxylmide, N-(trifluoromethylsulfonyloxy)naphthalimide, and N-(10-camphorsulfonyloxy)naphthalimide.

Among various kinds of the photo-inductive acid-generating material as described above, sulfonium salt is preferable, in particular, triphenyl sulfonium trifluoromethane sulfonate; and sulfone compounds, in particular, bis(4-tert-butylphenylsulfonyl)diazomethane and bis(cyclohexylsulfonyl)diazomethane.

The photo-inductive acid-generating material may be used independently or in a combination of two or more. There is no particular restriction in the blending ratio of the photo-inductive acid-generating material, and the blending ratio may be appropriately determined according to purpose, though it is preferably 1 to 30 parts by mass relative to 100 parts by mass of the hyperbranched polymer of the present invention. More preferably, the blending ratio of the photo-inductive acid-generating material is 0.1 to 10 parts by mass.

There is no particular restriction in the acid-diffusion suppressor contained in the resist composition provided the acid-diffusion suppressor is a component having functions to control the diffusion of acid generated from the photo-inductive acid-generating material in a resist film and to suppress undesired chemical reactions in non-exposed regions. The acid-diffusion suppressor contained in the resist composition may be appropriately selected from various kinds of commonly known acid-diffusion suppressors according to purpose.

Examples of acid-diffusion suppressors contained in the resist composition include a compound having one nitrogen atom in a single molecule, a compound having two nitrogen atoms in a single molecule, a polyamino compound and a polymer thereof having three nitrogen atoms or more in a single molecule, an amide-containing compound, an urea compound, and a nitrogen-containing heterocyclic compound.

Examples of nitrogen compounds having one nitrogen atom in a single molecule cited as an acid-diffusion suppressor include a mono(cyclo)alkyl amine, a di(cyclo)alkyl amine, a tri(cyclo)alkyl amine, and an aromatic amine. Specific examples of mono(cyclo)alkyl amine include n-hexyl amine, n-heptyl amine, n-octyl amine, n-nonyl amine, n-decyl amine, and cyclohexyl amine.

Examples of di(cyclo)alkyl amine included in nitrogen compounds having one nitrogen atom in a single molecule include di-n-butyl amine, di-n-pentyl amine, di-n-hexyl amine, di-n-heptyl amine, di-n-octyl amine, di-n-nonyl amine, di-n-decyl amine, and cyclohexyl methyl amine.

Examples of tri(cyclo)alkyl amine included in nitrogen compounds having one nitrogen atom in a single molecule include triethyl amine, tri-n-propyl amine, tri-n-butyl amine, tri-n-pentyl amine, tri-n-hexyl amine, tri-n-heptyl amine, tri-n-octyl amine, tri-n-nonyl amine, tri-n-decyl amine, cyclohexyl dimethyl amine, methyl dicyclohexyl amine, and tricyclohexyl amine.

Examples of aromatic amine included in nitrogen compounds having one nitrogen atom in a single molecule include aniline, N-methyl aniline, N,N-dimethyl aniline, 2 methyl aniline, 3-methyl aniline, 4-methyl aniline, 4-nitroaniline, diphenyl amine, triphenyl amine, and naphthyl amine.

Examples of nitrogen compounds having two nitrogen atoms in a single molecule cited as an acid-diffusion suppressor include ethylenediamine, N,N,N′,N′-tetramethyl ethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, and bis(2-diethylaminoethyl)ether.

Examples of polyamino compounds and polymers thereof having three nitrogen atoms or more in a single molecule and cited as an acid-diffusion suppressor include poly(ethylene imine), poly(allyl amine), and a polymer of N-(2-dimethylaminoethyl)acrylamide.

Examples of amide-containing compounds cited as an acid-diffusion suppressor include N-tert-buthoxycarbonyl di-n-octylamine, N-tert-buthoxycarbonyl di-n-nonylamine, N-tert-buthoxycarbonyl di-n-decylamine, N-tert-buthoxycarbonyl dicyclohexylamine, N-tert-buthoxycarbonyl-1-adamantylamine, N-tert-buthoxycarbonyl-N-methyl-1-adamantylamine, N,N-di-tert-buthoxycarbonyl-1-adamantylamine, N,N-di-tert-buthoxycarbonyl-N-methyl-1-adamantylamine, N-tert-buthoxycarbonyl-4,4-diaminodiphenylmethane, N,N′-di-tert-buthoxycarbonyl hexamethylenediamine, N,N,N′,N′-tetra-tert-buthoxycarbonyl hexamethylenediamine, N,N′-di-tert-buthoxycarbonyl-1,7-diaminoheptane, N,N′-di-tert-buthoxycarbonyl-1,8-diaminooctane, N,N′-di-tert-buthoxycarbonyl-1,9-diaminononane, N,N-di-tert-buthoxycarbonyl-1,10-diaminodecane, N,N-di-tert-buthoxycarbonyl-1,12-diaminododecane, N,N-di-tert-buthoxycarbonyl-4,4′-diaminodiphenylmethane, N-tert-buthoxycarbonyl benzimidazole, N-tert-buthoxycarbonyl-2-methyl benzimidazole, N-tert-buthoxycarbonyl-2-phenyl benzimidazole, formamide, N-methyl formamide, N,N-dimethyl formamide, acetamide, N-methyl acetamide, N,N-dimethyl acetamide, propionamide, benzamide, pyrrolidone, and N-methylpyrrolidone.

Specific examples of urea compounds cited as an acid-diffusion suppressor include urea, methyl urea, 1,1-dimethyl urea, 1,3-dimethyl urea, 1,1,3,3-tetramethyl urea, 1,3-diphenyl urea, and tri-n-butyl thiourea.

Specific examples of nitrogen-containing heterocyclic compounds cited as an acid-diffusion suppressor include imidazole, 4-methyl imidazole, 4-methyl-2-phenyl imidazole, benzimidazole, 2-phenyl benzimidazole, pyridine, 2-methyl pyridine, 4-methylpyridine, 2-ethyl pyridine, 4-ethyl pyridine, 2-phenyl pyridine, 4-phenyl pyridine, 2-methyl-4-phenyl pyridine, nicotine, nicotinic acid, nicotinic acid amide, quinoline, 4-hydroxy quinoline, 8-oxy quinoline, acridine, piperadine, 1-(2-hydroxyethyl)piperadine, pyrazine, pyrazole, pyridazine, quinozalin, purine, pyrrolidine, piperidine, 3-piperidino-1,2-propanediol, morpholine, 4-methyl morpholine, 1,4-dimethyl piperadine, and 1,4-diazabicyclo[2.2.2]octane.

The acid-diffusion suppressor as described above may be used singly or in a combination of two or more. There is no particular restriction in the amount of the acid-diffusion suppressor blended, and the amount may be appropriately chosen according to purpose. The amount is preferably 0.1 to 1000 parts by mass and more preferably 0.5 to 10 parts by mass relative to 100 parts by mass of the photo-inductive acid-generating material as described above.

Examples of surfactant contained in the resist composition include a polyoxyethylene alkyl ether, a polyoxyethylene alkyl aryl ether, a sorbitan fatty acid ester, a nonionic surfactant of a polyoxyethylene sorbitan fatty acid ester, a fluoro-surfactant, and a silicon-surfactant. There is no particular restriction in the surfactant contained in the resist composition provided the surfactant is a component exhibiting improved functions in coating properties, striation, developing properties, and the like, and may be appropriately selected from commonly known surfactants according to purpose.

Specific examples of polyoxyethylene alkyl ethers cited as a surfactant contained in the resist composition include polyoxyethylene lauryl ether, polyoxyethylene stearyl ether, polyoxyethylene cetyl ether, and polyoxyethylene oleyl ether. Specific examples of polyoxyethylene alkyl aryl ethers cited as the surfactant contained in the resist composition include polyoxyethylene octylphenol ether and polyoxyethylene nonylphenol ether.

Specific examples of sorbitan fatty acid esters cited as the surfactant contained in the resist composition include sorbitan monolaurate, sorbitan monopalmitate, sorbitan monostearate, sorbitan monooleate, sorbitan trioleate, and sorbitan tristearate. Specific examples of the nonionic surfactant of the polyoxyethylene sorbitan fatty acid ester cited as the surfactant contained in the resist composition include polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate.

Specific examples of the fluoro-surfactant cited as the surfactant contained in the resist composition include EFTOP EF301, EF303, and EF352 (manufactured by Shin Akita Kasei Co., Ltd.), MEGAFAC F171, F173, F176, F189, and R08 (manufactured by DIC Corp.), Fluorade FC430 and FC431 (manufactured by Sumitomo 3M Ltd.), and Asahi Guard AG710, Surflon S-382, SC101, SX102, SC103, SC104, SC105, and SC106 (manufactured by Asahi Glass Co., Ltd.).

Specific examples of silicon-surfactants cited as the surfactant contained in the resist composition include organosiloxane polymer KP341 (manufactured by Shin-Etsu Chemical Co., Ltd.). Various kinds of the surfactant cited above may be used independently or in a combination of two or more. The blending amount of the various kinds of surfactant is preferably, for example, 0.0001 to 5 parts by mass relative to 100 parts by mass of the hyperbranched polymer formed by the synthesis method of the present invention.

More preferably, the blending amount of the various kinds of the surfactant is 0.0002 to 2 parts by mass relative to 100 parts by mass of the hyperbranched polymer formed by the synthesis method of the present invention. There is no particular restriction in the blending amount of the various kinds of surfactant and the amount may be appropriately chosen according to purpose.

Examples of other components contained in the resist composition include a sensitizer, a dissolution-control material, an additive having an acid-dissociating group, a resin that is dissolvable in a basic solution, a dye, a pigment, an adhesive adjuvant, a defoamer, a stabilizer, and an anti-halation agent. Specific examples of sensitizers cited as other components contained in the resist composition include acetophenones, benzophenones, naphthalenes, biacetyl, eosin, rose bengal, pyrenes, anthracenes, and phenothiazines.

There is no particular restriction in the sensitizer provided the sensitizer absorbs the energy of radioactive ray and transmits the energy to the photo-inductive acid-generating material, thereby increasing the amount of acid generated and effecting an apparent sensitivity of the resist composition. The sensitizers may be used independently or in a combination of two or more.

Specific examples of dissolution-control materials cited as other components contained in the resist composition include a polyketone and a polyspiroketal. There is no particular restriction in the dissolution-control material cited as other components contained in the resist composition provided the material appropriately controls the dissolution contrast and the dissolution rate when the resist is formed. The dissolution-control materials cited as other components contained in the resist composition may be used independently or in a combination of two or more.

Specific examples of additives having the acid-dissociation group cited and as other components contained in the resist composition include tert-butyl 1-adamantanecarboxylate, tert-buthoxycarbonylmethyl 1-adamantanecarboxylate, di-tert-butyl 1,3-adamantanedicarboxylate, tert-butyl 1-adamantaneacetate, tert-buthoxycarbonylmethyl 1-adamantaneacetate, di-tert-butyl 1,3-adamantanediacetate, tert-butyl deoxycholate, tert-buthoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, mevalonolactone deoxycholate, tert-butyl lithocholate, tert-buthoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate. The various kinds of additive having an acid-dissociating group as described above may be used independently or in a combination of two or more. There is no particular restriction in the various kinds of additive having an acid-dissociating group provided the additive further improves the dry-etching resistance, pattern formation, adhesion with a substrate, and the like.

Specific examples of resin dissolvable in a basic solution cited as other components contained in the resist composition include poly(4-hydroxystyrene), partially hydrogenated poly(4-hydroxystyrene), poly(3-hydroxystyrene), 4-hydroxystyrene/3-hydroxystyrene polymer, 4-hydroxystyrene/styrene polymer, novolak resin, poly(vinyl alcohol), and poly(acrylic acid).

The weight-average molecular weight (Mw) of the resin that is dissolvable in a basic solution is usually 1,000 to 1,000,000, and preferably 2,000 to 100,000. The resin dissolvable in a basic solution may be used independently or in a combination of two or more. There is no particular restriction in the resin dissolvable in a basic solution cited as other components contained in the resist composition provided the resin improves the solubility of the resin composition of the present invention into a basic solution.

The dye or the pigment cited as other components contained in the resist composition visualizes a latent image in the exposed part. By visualizing a latent image in the exposed part, the effect of a halation during exposure to a light may be reduced. The adhesive adjuvant cited as other components contained in the resist composition may improve adhesion between the resist composition and a substrate.

Specific examples of solvents cited as other components contained in the resist composition include a ketone, a cyclic ketone, a propyleneglycol monoalkyl ether acetate, an alkyl 2-hydroxypropionate, an alkyl 3-alkoxypropionate, and other solvents. There is no particular restriction in the solvent cited as other components contained in the resist composition provided the solvent can dissolve the other components and the like contained in the resist composition, and the solvent may be appropriately selected from solvents safely usable.

Specific examples of ketones cited as other components contained in the resist composition include methyl isobutyl ketone, methyl ethyl ketone, 2-butanone, 2-pentanone, 3-methyl-2-butanone, 2-hexanone, 4-methyl-2-pentanone, 3-methyl-2-pentanone, 3,3-dimethyl-2-butanone, 2-heptanone, and 2-octanone.

Specific examples of the cyclic ketone contained in the solvent cited as other components contained in the resist composition include cyclohexanone, cyclopentanone, 3-methyl cyclopentanone, 2-methyl cyclohexanone, 2,6-dimethyl cyclohexanone, and isophorone.

Specific examples of the propyleneglycol monoalkyl ether acetate included in the solvent cited as other components contained in the resist composition include propyleneglycol monomethyl ether acetate, propyleneglycol monoethyl ether acetate, propyleneglycol mono-n-propyl ether acetate, propyleneglycol mono-i-propyl ether acetate, propyleneglycol mono-n-butyl ether acetate, propyleneglycol mono-i-butyl ether acetate, propyleneglycol mono-sec-butyl ether acetate, and propyleneglycol mono-tert-butyl ether acetate.

Specific examples of the alkyl 2-hydroxypropionate included in the solvent cited as other components contained in the resist composition include methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate, and tert-butyl 2-hydroxypropionate.

Specific examples of the alkyl 3-alkoxypropionate included in the solvent cited as other components contained in the resist composition include methyl 3-methoxypropionate, ethyl 3-methoxypropionate, methyl 3-ethoxypropionate, and ethyl 3-ethoxypropionate.

Examples of the other solvents contained in the solvent cited as other components contained in the resist composition include n-propyl alcohol, i-propyl alcohol, n-butyl alcohol, tert-butyl alcohol, cyclohexanol, ethyleneglycol monomethyl ether, ethyleneglycol monoethyl ether, ethyleneglycol mono-n-propyl ether, ethyleneglycol mono-n-butyl ether, diethyleneglycol dimethyl ether, diethyleneglycol diethyl ether, diethyleneglycol di-n-propyl ether, diethyleneglycol di-n-butyl ether, ethyleneglycol monomethyl ether acetate, ethyleneglycol monoethyl ether acetate, ethyleneglycol mono-n-propyl ether acetate, propyleneglycol, propyleneglycol monomethyl ether, propyleneglycol monoethyl ether, propyleneglycol mono-n-propyl ether, ethyl 2-hydroxy-2-methylpropionate, ethyl ethoxyacetate, ethyl hydroxyacetate, methyl 2-hydroxy-3-methyl lactate, 3-methoxybutyl acetate, 3-methyl-3-methoxybutyl acetate, 3-methyl-3-methoxybutyl propionate, 3-methyl-3-methoxybutyl butyrate, ethyl acetate, n-propyl acetate, n-butyl acetate, methyl acetoacetate, ethyl acetoacetate, methyl pilvate, ethyl pilvate, N-methyl pyrrolidone, N,N-dimethyl formamide, N,N-dimethyl acetamide, benzyl ethyl ether, di-n-hexyl ether, ethyleneglycol monomethyl ether, diethyleneglycol monoethyl ether, γ-butyrolactone, toluene, xylene, caproic acid, caprylic acid, octane, decane, 1-octanol, 1-nonanol, benzyl alcohol, benzyl acetate, ethyl benzoate, diethyl oxalate, diethyl maleate, ethylene carbonate, and propylene carbonate. These solvents may be used singly or in a combination of equal to or more than two kinds.

As described above, according to the method of synthesizing the hyperbranched polymer in the embodiment, a rapid increase in the molecular weight is suppressed by using a polar solvent, and thus the hyperbranched polymer of a desired molecular weight and degree of branching can be obtained. In addition, an increase in the molecular weight associated with the progress of polymerization of the hyperbranched polymer over time can be suppressed. Thus, a method of synthesizing the hyperbranched polymer with improved durable stability of the resolution performance of the hyperbranched polymer usable for a resist composition can be provided.

According to the method of synthesizing the hyperbranched polymer in the embodiment, an increase in the molecular weight associated with the progress of polymerization of the hyperbranched polymer having the shell portion with the introduced acid-decomposable group over time can be suppressed. Thus, a method of synthesizing the hyperbranched polymer with an improved durable stability of the resolution performance of the hyperbranched polymer usable for a resist composition may be provided.

According to the method of synthesizing the hyperbranched polymer in the embodiment, by removing the acid catalyst used in the introduction of the acid-decomposable group by using the ultrapure water, an increase in the molecular weight associated with the progress of polymerization of the hyperbranched polymer over time can be suppressed. Thus, a method of synthesizing the hyperbranched polymer with an improved durable stability of the resolution performance of the hyperbranched polymer usable for a resist composition can be provided.

The resist composition containing the hyperbranched polymer of the embodiment may be treated for the patterning treatment by development after exposure to a light in pattern. The resist composition may support with an electron beam, a deep ultraviolet beam (DUV), and an extreme ultraviolet beam (EUV), which require a surface smoothness at a nanometer level, thereby enabling to form a fine pattern for manufacturing a semi-conductor integrated circuit. Thus, the resist composition containing the core-shell hyperbranched polymer formed by the synthesis method of the present invention may be suitably used in various fields using a semi-conductor integrated circuit produced by using a light source irradiating a short wavelength light.

In the semi-conductor integrated circuit produced using the resist composition containing the core-shell hyperbranched polymer formed by the synthesis method of the present invention, when it is exposed to light, heated, dissolved in a basic developing solution, and then washed with water and the like during production, substantially no undissolved residues remain on an light-exposed part, and thus, a nearly vertical edge can be obtained.

In the following, the embodiments of the present invention as described in Chapter 4 will be clarified concretely by the following examples. However, the following examples shall in no way limit the interpretation of the present invention.

### (Weight-Average Molecular Weight (Mw))

The weight-average molecular weight (Mw) of the core portion in the hyperbranched polymer of an example will be explained. The weight-average molecular weight (Mw) of the core portion in the hyperbranched polymer of the example was obtained by a GPC (Gel Permeation Chromatography) measurement using a tetrahydrofuran solution (0.5% by mass) at 40° C., a GPC HLC-8020 type instrument and two TSKgel HXL-M columns (manufactured by Tosoh Corporation) connected in series. In the GPC measurement, tetrahydrofuran was used as a moving phase and styrene was used as a standard material.

### (Degree of Branching (Br))

The degree of branching (Br) of the core portion in the hyperbranched polymer in examples will be explained. The degree of branching (Br) was obtained by measuring ¹H-NMR of the product. Namely, the degree of branching (Br) of the core portion in the hyperbranched polymer in examples was calculated by computing equation (A) by using H1°, an integral ratio of protons in —CH₂Cl appearing at 4.6 ppm, and H2°, an integral ratio of the protons in —CHCl appearing at 4.8 ppm. Here, when the polymerization progresses at both —CH₂Cl and —CHCl thereby enhancing the branching, the degree of branching (Br) approaches 0.5.

### (Core/Shell Ratio)

The core/shell ratio of the hyperbranched polymer in examples will be explained. The core/shell ratio was obtained by measuring ¹H-NMR of the product. Namely, the core/shell ratio of the hyperbranched polymer in examples was calculated by using the integral ratio of protons appearing at 1.4 to 1.6 ppm assignable to the tert-butyl group and the integral ratio of the protons appearing at near 7.2 ppm assignable to the aromatic group.

### (Analysis of Trace Metal)

Measurements of metal content in the core-shell hyperbranched polymer were made by an ICP mass analysis instrument (P-6000 type MIP-MS, manufactured by Hitachi Ltd.) or a flameless atomic absorption method (manufactured by PerkinElmer Inc.).

### (Ultrapure Water)

Ultrapure water used to synthesize the hyperbranched polymer in examples will be explained. The ultrapure water, containing 1 ppb or less of metals at 25° C. and having a specific resistance of 18 MΩ·cm, used to synthesize the core-shell hyperbranched polymer in examples is made by using GSR-200 equipment (manufactured by Advantec Toyo Kaisha, Ltd.).

Synthesis of the hyperbranched core polymer in examples was carried out as follows (in a temperature-controlled room at 25° C.) with reference to the synthesis method described by Krzysztof Matyjaszewski, Macromolecules, 29, 1079 (1996) and by Jean M. J. Frecht, J. Poly. Sci., 36, 955 (1998).

### First Example

### Method for Synthesizing Core-Shell Hyperbranched Polymer

### (Synthesis of Core Portion of Hyperbranched Polymer)

A synthesis of the core portion of the hyperbranched polymer in Experiment 1 will be explained. The core portion of the hyperbranched polymer (hereinafter, “hyperbranched core polymer”) in Experiment 1 was synthesized by the following method. Firstly, 18.3 g of 2,2′-bipyridyl, 5.8 g of copper (I) chloride, 441 mL of chlorobenzene, and 49 mL of acetonitrile were charged into a four-necked flask (1 liter volume), which was then assembled with a dropping funnel containing 90.0 g of weighed chloromethyl styrene, a cooling column, and an agitator. The inside the reaction equipment thus assembled was entirely degassed and replaced with an argon gas. After the argon-replacement, the above-mentioned mixture was heated at 115° C., and then chloromethyl styrene was added dropwise into the reaction vessel for one hour. After the dropwise addition, the heating with agitation was continued for 3 hours. The reaction time including the dropwise addition of chloromethyl styrene into the reaction vessel was 4 hours.

After the reaction by heating with agitation, the reaction system after the reaction was filtered to remove insoluble matters. After the filtration, 500 mL of an aqueous oxalic acid solution (3% by mass) prepared using ultrapure water was added to the filtered solution. After the resulting mixture was agitated for 20 minutes, a water layer that resulted after the agitation was removed. The copper of the reaction catalyst was removed by repeating a series of the following operations four times: to the solution after removal of the water layer, an aqueous oxalic acid solution (3% by mass) prepared using ultrapure water was added; the resulting mixture was agitated; and then the water layer was removed from the solution after the agitation.

To the solution resulting after removal of the copper, 700 mL of methanol was added to re-precipitate a solid component. The solid component obtained by re-precipitation was washed with 500 mL of a mixed solvent of THF (tetrahydrofuran)/methanol=2/8 (by volume). After the washing, the solvent was removed by decantation from the solution. The operation to wash the solid component obtained by re-precipitation with 500 mL of a mixed solvent of THF:methanol=2:8 was repeated two times.

Thereafter, it was dried under a reduced pressure of 0.1 Pa at 25° C. for 2 hours. As a result, 64.8 g of the hyperbranched core polymer of the first example was obtained as the purified product. The yield of the obtained hyperbranched core polymer was 72%. The weight-average molecular weight (Mw) and the degree of branching (Br) of the obtained hyperbranched core polymer were 2000 and 0.50, respectively.

### (Synthesis of the Shell Portion of the Hyperbranched Polymer)

The synthesis of the shell portion of the hyperbranched polymer of the first example will be explained. In the synthesis of the shell portion of the hyperbranched polymer of the first example, 10 g of the hyperbranched core polymer of the first example described above, 5.1 g of 2,2′-bipyridyl, and 1.6 g of copper (I) chloride were added to a four-necked reaction vessel (1 liter volume) equipped with an agitator and a cooling column, and then the entire system including the reaction vessel was fully degassed under vacuum. Under an argon gas atmosphere, 250 mL of chlorobenzene (reaction solvent) was added, followed by the addition of 48 mL of tert-butyl acrylate by syringe. The resulting mixture was heated at 120° C. with agitation for 5 hours.

After the polymerization, undissolved matter was removed by filtration, and then 300 mL of an aqueous oxalic acid solution (3% by mass) prepared using ultrapure water was added to the filtered solution. The resulting solution was agitated for 20 minutes, and then a water layer was removed from the solution after the agitation. The copper of the reaction catalyst was removed by repeating a series of the following operations four times: to the solution obtained after removal of the water layer, the aqueous oxalic acid solution (3% by mass) prepared using ultrapure water was added; the resulting mixture was agitated; and then the water layer was removed from the solution after the agitation.

### (Purification)

Purification in the first example will be explained. In the purification in the first example, from the solution of a pale yellow color obtained after the copper was removed, the solvents therein were removed by evaporation, and then 700 mL of methanol was added to the resulting solution to re-precipitate a solid component. A series of the operations, in which the solid component obtained by re-precipitation was dissolved into 50 mL of THF and re-precipitated again by adding 500 mL of methanol, was repeated two times, and then the solid component was dried under a reduced pressure of 0.1 Pa at 25° C. for 3 hours.

As a result, 17.1 g of the solid core-shell hyperbranched polymer with a pale yellow color was obtained as the purified product. The yield of the obtained solid with a pale yellow color was 76%. The mol ratio of the obtained core-shell hyperbranched polymer was calculated by ¹H-NMR. As a result, the core/shell ratio of the core-shell hyperbranched polymer was 40/60.

### (Removal of Trace Metal)

Removal of trace metal in the experiment will be explained. In the removal of trace metal, 6 g of the core-shell hyperbranched polymer having the shell portion as described above dissolved in chloroform was mixed with 100 g of an aqueous oxalic acid solution (3% by mass) prepared using ultrapure water. The resulting solution was agitated vigorously for 30 minutes. After the agitation, an organic layer was extracted from the solution after the agitation. The organic layer was again mixed with 100 g of the aqueous oxalic acid solution (3% by mass) prepared using ultrapure water, and then agitated vigorously for 30 minutes. After the agitation, the organic layer was extracted from the solution after the agitation.

The operation to vigorously agitate the mixture of the organic layer extracted and the aqueous oxalic acid solution (3% by mass) prepared using ultrapure water was repeated five times in total. To the solution after agitation, 100 g of hydrochloric acid (3% by mass) was added, and the resulting mixture was agitated vigorously for 30 minutes, and thereafter the organic layer was extracted from the solution after the agitation.

Subsequently, a series of following operations was repeated three times: the organic layer extracted was mixed with 100 g of the ultrapure water, the resulting mixture was agitated vigorously for 30 minutes, and then the organic layer was extracted from the solution after the agitation. The solvents in the finally obtained organic layer were removed by evaporation, and a residue was dried under a reduced pressure of 0.1 Pa at 25° C. for 3 hours. The metal contents in the solid component obtained after removal of the solvents were analyzed as mentioned previously. As a result, the content of copper, sodium, iron, and aluminum in the solid component was 10 ppb or less.

### (Deprotection)

Deprotection in the first example will be explained. In the deprotection in the first example, 0.6 g of the weighed solid component obtained after removal of the organic solvents was added into a reaction vessel equipped with a reflux column. After 30 mL of dioxane and 0.6 mL of hydrochloric acid (30%) were added, the resulting mixture was heated with agitation at 90° C. for 60 minutes. The crude reaction matter obtained by heating with agitation was poured into 300 mL of the ultrapure water to re-precipitate a solid component.

Thereafter, the solution of the re-precipitated solid dissolved in 30 mL dioxane was poured into 300 mL of the ultrapure water to re-precipitate the solid component again.

### (Filtration)

A solution of the re-precipitated solid component dissolved in 100 mL of tetrahydrofuran was filtered through a filter with a pore diameter of 0.02 μm made of an ultra-high density polyethylene (Optimizer D-300, manufactured by Nihon Mykrolis K. K.) at the flux of 4 mL/min under an applied pressure. The organic solvent in the filtrated solution was removed by evaporation under vacuum, and the obtained solid component was dried under a reduced pressure of 0.1 Pa at 25° C. for 3 hours to obtain the core-shell hyperbranched polymer of first example. The yield of the core-shell hyperbranched polymer of first example was 0.4 gram (66%). The mol ratio of the acid-decomposable group to the acid group was 78/22.

### Second Example

### Method for Synthesizing Core-Shell Hyperbranched Polymer

### (Synthesis of Core Portion of Hyperbranched Polymer)

A synthesis of the core portion of the hyperbranched polymer in Experiment 1 will be explained. The core portion of the hyperbranched polymer (hereinafter, “hyperbranched core polymer”) in Experiment 1 was synthesized by the following method. Firstly, 11.8 g of 2,2′-bipyridyl, 3.5 g of copper (I) chloride, and 345 mL of benzonitrile were charged into a four-necked flask (1 liter volume), which was then assembled with a dropping funnel containing 54.2 g of weighed chloromethyl styrene, a cooling column, and an agitator. The inside the reaction equipment thus assembled was entirely degassed and replaced with an argon gas. After the argon-replacement, the above-mentioned mixture was heated at 125° C., and then chloromethyl styrene was added dropwise into the reaction vessel for 30 minutes. After the dropwise addition, the heating with agitation was continued for 3.5 hours. The reaction time including the dropwise addition of chloromethyl styrene into the reaction vessel was 4 hours.

After the reaction, the reaction solution was filtered through a filter paper having a retaining particle size of 1 μm. Then, the filtered solution was poured into a pre-mixed solution of 844 g of methanol and 211 g of the ultrapure water to re-precipitate poly(chloromethyl styrene).

After 29 g of the polymer obtained by the re-precipitation was dissolved in 100 g of benzonitrile, to the resulting solution, a mixed solution of 200 g of methanol and 50 g of the ultrapure water was added. After centrifugal separation, the solvents were removed by decantation to recover the polymer. This recovery operation was repeated three times to obtain a precipitated polymer.

After the decantation, the precipitated product was dried under a reduce pressure to obtain 14.0 g of poly(chloromethyl styrene). The yield was 26%. The weight-average molecular weight (Mw) of the polymer obtained by GPC measurement (polystyrene equivalent) was 1140, and the degree of branching (Br) obtained by the ¹H-NMR measurement was 0.51.

### (Synthesis of Shell Portion of Hyperbranched Polymer)

The synthesis of the shell portion of the hyperbranched polymer of the second example will be explained. The shell portion of the hyperbranched polymer of the second example was synthesized by the following method by using the core portion of the hyperbranched polymer described above (hereinafter, “hyperbranched core polymer”). Into a four-necked reaction vessel (volume of 500 mL) containing 1.6 g of copper (I) chloride, 5.1 g of 2,2′-bipyridyl, and 10.0 g of the hyperbranched core polymer, 248 mL of monochlorobenzene and 48 mL of tert-butyl acrylate were charged by syringe, respectively, under an argon atmosphere. Subsequently, the mixture in the reaction vessel was heated with agitation at 125° C. for 5 hours.

### (Purification)

Purification in the second example will be explained. After termination of the polymerization reaction carried out by heating with agitation as described above, the reaction system after the polymerization reaction was filtered to remove undissolved matter. Subsequently, to 308 g of the filtered solution obtained by the filtration, 615 g of a mixed aqueous acid solution containing 3% by mass of oxalic acid and 1% by mass of hydrochloric acid prepared using ultrapure water was added. After the resulting solution was agitated for 20 minutes, the water layer was removed from the reaction system. Thereafter, the copper of the reaction catalyst was removed by repeating a series of the following operations four times: to the polymer solution obtained after removal of the water layer, the above-mentioned aqueous solution containing oxalic acid and hydrochloric acid was added; the resulting solution was agitated; and then the water layer was removed from the solution after the agitation.

A pale yellow color solution obtained after the removal of copper was concentrated under a reduced pressure of 15 mmHg at 40° C. to obtain 62.5 g of a concentrated solution. Into the resulting concentrated solution were added 219 g of methanol and then 31 g of the ultrapure water to precipitate a solid component. After the solid component obtained by precipitation was dissolved into 20 g of THF, to the resulting solution, 200 g of methanol was added and then 29 g of the ultrapure water was added to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 23.8 g. The mol ratio of the copolymer (the core-shell hyperbranched polymer having the formed shell portion) was calculated from ¹H-NMR. The core/shell mol ratio of the core-shell hyperbranched polymer having the formed shell portion was 30/70.

### (Filtration)

A solution of the obtained dried hyperbranched polymer dissolved in 100 mL of tetrahydrofuran was filtered through a filter with a pore diameter of 0.02 μm made of an ultra-high density polyethylene (Optimizer D-300, manufactured by Nihon Mykrolis K. K.) at the flux of 4 mL/min under an applied pressure. The organic solvent in the filtered solution was removed by evaporation under vacuum, and the obtained solid component was dried under a reduced pressure of 0.1 Pa at 25° C. for 3 hours to obtain the core-shell hyperbranched polymer of the second example. The yield of the core-shell hyperbranched polymer of the second example was 21.4 g.

### Third Example

### Synthesis of the Core-Shell Hyperbranched Polymer

The core-shell hyperbranched polymer in the third example will be explained. The core-shell hyperbranched polymer in the third example was synthesized by de-protecting the core-shell hyperbranched polymer before the filtration treatment in the second example.

### (Deprotection)

Deprotection in the third example will be explained. In the deprotection in the third example, firstly 2.0 g of the copolymer (the core-shell hyperbranched polymer before the deprotection in the second example) was weighed into a reaction vessel equipped with a reflux condenser, and 18.0 g of 1,4-dioxane and 0.2 g of sulfuric acid (50% by mass) were added into it. Thereafter, the entire reaction system including the reaction vessel equipped with a reflux condenser was heated to the reflux temperature, under which condition the system was refluxed with agitation for 60 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added and then the solution was agitated vigorously at room temperature for 30 minutes. After the water layer was separated, 50 g of the ultrapure water was again added, the resulting mixture was agitated vigorously at room temperature for 30 minutes, and then the water layer was separated. A series of the operations, involving addition of 50 g of the ultrapure water, the vigorous agitation of the mixture at room temperature for 30 minutes, and the separation of the water layer thereafter, was repeated two more times. The methyl isobutyl ketone solution was evaporated under reduced pressure to remove the solvent, and then the residue was dried at 40° C. under reduced pressure to obtain 1.6 g of the polymer.

### (Filtration)

A solution of the obtained dried hyperbranched polymer dissolved in 100 mL of tetrahydrofuran was filtered through a filter having a pore diameter of 0.02 μm made of an ultra-high density polyethylene (Optimizer D-300, manufactured by Nihon Mykrolis K. K.) at the flux of 4 mL/min under an applied pressure. The organic solvent in the filtered solution was removed by evaporation under vacuum, and the obtained solid component was dried under a reduced pressure of 0.1 Pa at 25° C. for 3 hours to obtain the core-shell hyperbranched polymer of the third example. The yield of the core-shell hyperbranched polymer of the third example was 1.5 g. The mol ratio of the acid-decomposable group to the acid group was 78/22.

### Fourth Example

### Synthesis of Core-Shell Hyperbranched Polymer

### (Synthesis of Shell Portion of Hyperbranched Polymer)

The synthesis of the core-shell hyperbranched polymer of a fourth example will be explained. The core-shell hyperbranched polymer of the fourth example was synthesized by the following method by using the core portion of the hyperbranched polymer of the second example as described above (hereinafter, “hyperbranched core polymer”). Into a four-necked reaction vessel (volume of 500 mL) containing 1.6 g of copper (I) chloride, 5.1 g of 2,2′-bipyridyl, and 10.0 g of the hyperbranched core polymer of second example, 248 mL of monochlorobenzene and 81 mL of tert-butyl acrylate were charged by syringe under an argon atmosphere. Subsequently, the mixture in the reaction vessel was heated with agitation at 125° C. for 5 hours.

### (Purification)

Purification in the fourth example will be explained. After termination of the polymerization reaction carried out by heating with agitation as described above, the reaction system after the polymerization reaction was filtered to remove undissolved matter. Subsequently, to 340 g of the filtered solution obtained by the filtration, 680 g of a mixed aqueous acid solution containing 3% by mass of oxalic acid and 1% by mass of hydrochloric acid prepared using ultrapure water was added. After the resulting solution was agitated for 20 minutes, the water layer was removed from the reaction system. Thereafter, the copper of the reaction catalyst was removed by repeating a series of the following operations four times: to the polymer solution obtained after removal of the water layer, the above-mentioned aqueous solution containing oxalic acid and hydrochloric acid was added; the resulting solution was agitated; and then the water layer was removed from the solution after the agitation.

A pale yellow color solution obtained after the removal of copper was concentrated under a reduced pressure of 15 mmHg at 40° C. to obtain 88.0 g of a concentrated solution. Into the resulting concentrated solution were added 308 g of methanol and then 44 g of the ultrapure water to precipitate a solid component. After the solid component obtained by precipitation was dissolved into 44 g of THF, to the resulting solution, 440 g of methanol was added and then 63 g of the ultrapure water was added to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 33.6 g. The mol ratio of the copolymer (the core-shell hyperbranched polymer having the formed shell portion) was calculated from ¹H-NMR. The core/shell mol ratio of the core-shell hyperbranched polymer having the formed shell portion was 19/81.

### (Deprotection)

Deprotection in the fourth example will be explained. In the deprotection in the fourth example, firstly 2.0 g of the copolymer (the core-shell hyperbranched polymer before the deprotection in the fourth example) was weighed into a reaction vessel equipped with a reflux condenser, and 18.0 g of 1,4-dioxane and 0.2 g of sulfuric acid (50% by mass) were added into it. Thereafter, the entire reaction system including the reaction vessel equipped with a reflux condenser was heated to the reflux temperature, under which condition the system was refluxed with agitation for 30 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added and then the solution was agitated vigorously at room temperature for 30 minutes. After the water layer was separated, 50 g of the ultrapure water was again added, the resulting mixture was agitated vigorously at room temperature for 30 minutes, and then the water layer was separated. A series of the operations, involving addition of 50 g of the ultrapure water, the vigorous agitation of the mixture at room temperature for 30 minutes, and the separation of the water layer thereafter, was repeated two more times. The methyl isobutyl ketone solution was evaporated under reduced pressure to remove the solvent, and then the residue was dried at 40° C. under reduced pressure to obtain 1.6 g of the polymer.

### (Filtration)

A solution of the obtained dried hyperbranched polymer dissolved in 100 mL of tetrahydrofuran was filtered through a filter having a pore diameter of 0.02 μm made of an ultra-high density polyethylene (Optimizer D-300, manufactured by Nihon Mykrolis K. K.) at the flux of 4 mL/min under an applied pressure. The organic solvent in the filtered solution was removed by evaporation under vacuum, and the obtained solid component was dried under a reduced pressure of 0.1 Pa at 25° C. for 3 hours to obtain the core-shell hyperbranched polymer of the fourth example. The yield of the core-shell hyperbranched polymer of the fourth example was 1.5 g. The mol ratio of the acid-decomposable group to the acid group was 92/8.

### Fifth Example

### Synthesis of Core-Shell Hyperbranched Polymer

### (Synthesis of Shell Portion of Hyperbranched Polymer)

The synthesis of the core-shell hyperbranched polymer of a fifth example will be explained. The core-shell hyperbranched polymer of the fifth example was synthesized by the following method by using the core portion of the hyperbranched polymer of the second example as described above (hereinafter, “hyperbranched core polymer”). Into a four-necked reaction vessel (volume of 1000 mL) containing 1.6 g of copper (I) chloride, 5.1 g of 2,2′-bipyridyl, and 10.0 g of the hyperbranched core polymer of the fourth example, 248 mL of monochlorobenzene and 187 mL of tert-butyl acrylate were charged by syringe under an argon atmosphere. Subsequently, the mixture in the reaction vessel was heated with agitation at 125° C. for 5 hours.

### (Purification)

Purification in the fifth example will be explained. After termination of the polymerization reaction carried out by heating with agitation as described above, the reaction system after the polymerization reaction was filtered to remove undissolved matter. Subsequently, to 440 g of the filtered solution obtained by the filtration, 880 g of a mixed aqueous acid solution containing 3% by mass of oxalic acid and 1% by mass of hydrochloric acid prepared using ultrapure water was added. After the resulting solution was agitated for 20 minutes, the water layer was removed from the reaction system. Thereafter, the copper of the reaction catalyst was removed by repeating a series of the following operations four times: to the polymer solution obtained after removal of the water layer, the above-mentioned aqueous solution containing oxalic acid and hydrochloric acid was added; the resulting solution was agitated; and then the water layer was removed from the solution after the agitation.

A pale yellow color solution obtained after the removal of copper was concentrated under a reduced pressure of 15 mmHg at 40° C. to obtain 175 g of a concentrated solution. Into the resulting concentrated solution were added 613 g of methanol and then 88 g of the ultrapure water to precipitate a solid component. After the solid component obtained by precipitation was dissolved into 85 g of THF, to the resulting solution, 850 g of methanol was added and then 121 g of the ultrapure water was added to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 65.9 g. The mol ratio of the copolymer (the core-shell hyperbranched polymer having the formed shell portion) was calculated from ¹H-NMR. The core/shell mol ratio of the core-shell hyperbranched polymer having the formed shell portion was 10/90.

### (Deprotection)

Deprotection in the fifth example will be explained. In the deprotection in the fifth example, firstly 2.0 g of the copolymer (the core-shell hyperbranched polymer before the deprotection in the fourth example) was weighed into a reaction vessel equipped with a reflux condenser, and 18.0 g of 1,4-dioxane and 0.2 g of sulfuric acid (50% by mass) were added into it. Thereafter, the entire reaction system including the reaction vessel equipped with a reflux condenser was heated to the reflux temperature, under which condition the system was refluxed with agitation for 15 minutes. Thereafter, a crude reaction matter obtained after the reflux with agitation was poured into 180 mL of the ultrapure water to precipitate a solid component. After the solid component obtained by re-precipitation was dissolved into 50 g of methyl isobutyl ketone, to the resulting solution, 50 g of the ultrapure water was added and then the solution was agitated vigorously at room temperature for 30 minutes. After the water layer was separated, 50 g of the ultrapure water was again added, the resulting mixture was agitated vigorously at room temperature for 30 minutes, and then the water layer was separated. A series of the operations, involving addition of 50 g of the ultrapure water, the vigorous agitation of the mixture at room temperature for 30 minutes, and the separation of the water layer thereafter, was repeated two more times. The methyl isobutyl ketone solution was evaporated under reduced pressure to remove the solvent, and then the residue was dried at 40° C. under reduced pressure to obtain 1.7 g of the polymer.

### (Filtration)

A solution of the obtained dried hyperbranched polymer dissolved in 100 mL of tetrahydrofuran was filtered through a filter having a pore diameter of 0.02 μm made of an ultra-high density polyethylene (Optimizer D-300, manufactured by Nihon Mykrolis K. K.) at the flux of 4 mL/min under an applied pressure. The organic solvent in the filtered solution was removed by evaporation under vacuum, and the obtained solid component was dried under a reduced pressure of 0.1 Pa at 25° C. for 3 hours to obtain the core-shell hyperbranched polymer of the fourth example. The yield of the core-shell hyperbranched polymer of the fifth example was 1.5 g. The mol ratio of the acid-decomposable group to the acid group was 95/5.

### Sixth Example

### Synthesis of Core-Shell Hyperbranched Polymer

### (Synthesis of Shell Portion of Hyperbranched Polymer)

The synthesis of the core-shell hyperbranched polymer of a sixth example will be explained. The core-shell hyperbranched polymer of the sixth example was synthesized by the following method by using the core portion of the hyperbranched polymer of the second example as described above (hereinafter, “hyperbranched core polymer”). Into a four-necked reaction vessel (volume of 500 mL) containing 1.6 g of copper (I) chloride, 5.1 g of 2,2′-bipyridyl, and 10.0 g of the hyperbranched core polymer of the fourth example, 248 mL of monochlorobenzene and 14 mL of tert-butyl acrylate were charged by syringe under an argon atmosphere. Subsequently, the mixture in the reaction vessel was heated with agitation at 125° C. for 5 hours.

### (Purification)

Purification in the sixth example will be explained. After termination of the polymerization reaction carried out by heating with agitation as described above, the reaction system after the polymerization reaction was filtered to remove undissolved matter. Subsequently, to 285 g of the filtered solution obtained by the filtration, 570 g of a mixed aqueous acid solution containing 3% by mass of oxalic acid and 1% by mass of hydrochloric acid prepared using ultrapure water was added. After the resulting solution was agitated for 20 minutes, the water layer was removed from the reaction system. Thereafter, the copper of the reaction catalyst was removed by repeating a series of the following operations four times: to the polymer solution obtained after removal of the water layer, the above-mentioned aqueous solution containing oxalic acid and hydrochloric acid was added; the resulting solution was agitated; and then the water layer was removed from the solution after the agitation.

A pale yellow color solution obtained after the removal of copper was concentrated under a reduced pressure of 15 mmHg at 40° C. to obtain 32 g of a concentrated solution. Into the resulting concentrated solution were added 112 g of methanol and then 16 g of the ultrapure water to precipitate a solid component. After the solid component obtained by precipitation was dissolved into 16 g of THF, to the resulting solution, 160 g of methanol was added and then 23 g of the ultrapure water was added to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 12.1 g. The mol ratio of the copolymer (the core-shell hyperbranched polymer having the formed shell portion) was calculated from ¹H-NMR. The core/shell mol ratio of the core-shell hyperbranched polymer having the formed shell portion was 61/39.

### (Deprotection)

Deprotection in the sixth example will be explained. In the deprotection in the sixth example, firstly 2.0 g of the copolymer (the core-shell hyperbranched polymer before the deprotection in the sixth example) was weighed into a reaction vessel equipped with a reflux condenser, and 18.0 g of 1,4-dioxane and 0.2 g of sulfuric acid (50% by mass) were added into it. Thereafter, the entire reaction system including the reaction vessel equipped with a reflux condenser was heated to the reflux temperature, under which condition the system was refluxed with agitation for 150 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added and then the solution was agitated vigorously at room temperature for 30 minutes. After the water layer was separated, 50 g of the ultrapure water was again added, the resulting mixture was agitated vigorously at room temperature for 30 minutes, and then the water layer was separated. A series of the operations, involving addition of 50 g of the ultrapure water, the vigorous agitation of the mixture at room temperature for 30 minutes, and the separation of the water layer thereafter, was repeated two more times. The methyl isobutyl ketone solution was evaporated under reduced pressure to remove the solvent, and then the residue was dried at 40° C. under reduced pressure to obtain 1.4 g of the polymer.

### (Filtration)

A solution of the obtained dried hyperbranched polymer dissolved in 100 mL of tetrahydrofuran was filtered through a filter having a pore diameter of 0.02 μm made of an ultra-high density polyethylene (Optimizer D-300, manufactured by Nihon Mykrolis K. K.) at the flux of 4 mL/min under an applied pressure. The organic solvent in the filtered solution was removed by evaporation under vacuum, and the obtained solid component was dried under a reduced pressure of 0.1 Pa at 25° C. for 3 hours to obtain the core-shell hyperbranched polymer of the fourth example. The yield of the core-shell hyperbranched polymer of the sixth example was 1.3 g. The mol ratio of the acid-decomposable group to the acid group was 49/51.

### First Reference Example

### Synthesis of Tert-Butyl 4-Vinylbenzoate

The synthesis was carried out with reference to Synthesis, 833-834 (1982). Into a reaction vessel (1 liter volume) equipped with a dropping funnel were added, under an argon atmosphere, 91 g of 4-vinyl benzoic acid, 99.5 g of 1,1′-carbodimidazole, 2.4 g of 4-tert-butyl pyrocathecol, and 500 g of dehydrated dimethyl formamide, and the resulting solution was agitated for one hour at a constant temperature of 30° C. Thereafter, 93 g of 1,8-diazabicyclo[5.4.0]-7-undecene and 91 g of dehydrated 2-methyl-2-propanol were added, and then the resulting mixture was agitated for 4 hours. After the reaction, 300 mL of diethyl ether and an aqueous potassium carbonate solution (10%) were added, and then an objective substance was extracted to an ether layer. Thereafter, the diethyl ether layer was dried under reduced pressure to obtain tert-butyl 4-vinylbenzoate having a pale yellow color. It was confirmed by ¹H-NMR that the objective substance was obtained. The yield was 88%.

### Seventh Example

### Synthesis of Core-Shell Hyperbranched Polymer

### (Synthesis of Shell Portion of Hyperbranched Polymer)

The synthesis of the core-shell hyperbranched polymer of a seventh example will be explained. The core-shell hyperbranched polymer of the seventh example was synthesized by the following method by using the core portion of the hyperbranched polymer of the second example as described above (hereinafter, “hyperbranched core polymer”). Into a four-necked reaction vessel (volume of 1000 mL) containing 0.8 g of copper (I) chloride, 2.6 g of 2,2′-bipyridyl, and 5.0 g of the hyperbranched core polymer of the fourth example, 421 mL of monochlorobenzene and 46.8 g of tert-butyl 4-vinylbenzoate were charged by syringe under an argon atmosphere. Subsequently, the mixture in the reaction vessel was heated with agitation at 125° C. for 3.5 hours.

### (Purification)

Purification in the seventh example will be explained. After termination of the polymerization reaction carried out by heating with agitation as described above, the reaction system after the polymerization reaction was filtered to remove undissolved matter. Subsequently, to 490 g of the filtered solution obtained by the filtration, 980 g of a mixed aqueous acid solution containing 3% by mass of oxalic acid and 1% by mass of hydrochloric acid prepared using ultrapure water was added. After the resulting solution was agitated for 20 minutes, the water layer was removed from the reaction system. Thereafter, the copper of the reaction catalyst was removed by repeating a series of the following operations four times: to the polymer solution obtained after removal of the water layer, the above-mentioned aqueous solution containing oxalic acid and hydrochloric acid was added; the resulting solution was agitated; and then the water layer was removed from the solution after the agitation.

A pale yellow color solution obtained after the removal of copper was concentrated under a reduced pressure of 15 mmHg at 40° C. to obtain 41 g of a concentrated solution. Into the resulting concentrated solution were added 144 g of methanol and then 21 g of the ultrapure water to precipitate a solid component. After the solid component obtained by precipitation was dissolved into 21 g of THF, to the resulting solution, 210 g of methanol was added and then 30 g of the ultrapure water was added to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 15.9 g. The mol ratio of the copolymer (the core-shell hyperbranched polymer having the formed shell portion) was calculated from ¹H-NMR. The core/shell mol ratio of the core-shell hyperbranched polymer having the formed shell portion was 29/71.

### (Deprotection)

Deprotection in the seventh example will be explained. In the deprotection in the seventh example, firstly 2.0 g of the copolymer (the core-shell hyperbranched polymer before the deprotection in the seventh example) was weighed into a reaction vessel equipped with a reflux condenser, and 18.0 g of 1,4-dioxane and 0.2 g of sulfuric acid (50% by mass) were added into it. Thereafter, the entire reaction system including the reaction vessel equipped with a reflux condenser was heated to the reflux temperature, under which condition the system was refluxed with agitation for 180 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added and then the solution was agitated vigorously at room temperature for 30 minutes. After the water layer was separated, 50 g of the ultrapure water was again added, the resulting mixture was agitated vigorously at room temperature for 30 minutes, and then the water layer was separated. A series of the operations, involving addition of 50 g of the ultrapure water, the vigorous agitation of the mixture at room temperature for 30 minutes, and the separation of the water layer thereafter, was repeated two more times. The methyl isobutyl ketone solution was evaporated under reduced pressure to remove the solvent, and then the residue was dried at 40° C. under reduced pressure to obtain 1.7 g of the polymer.

### (Filtration)

A solution of the obtained dried hyperbranched polymer dissolved in 100 mL of tetrahydrofuran was filtered through a filter having a pore diameter of 0.02 μm made of an ultra-high density polyethylene (Optimizer D-300, manufactured by Nihon Mykrolis K. K.) at the flux of 4 mL/min under an applied pressure. The organic solvent in the filtered solution was removed by evaporation under vacuum, and the obtained solid component was dried under a reduced pressure of 0.1 Pa at 25° C. for 3 hours to obtain the core-shell hyperbranched polymer of the fourth example. The yield of the core-shell hyperbranched polymer of the seventh example was 1.5 g. The mol ratio of the acid-decomposable group to the acid group was 38/62.

### Eighth Example

### Synthesis of Core-Shell Hyperbranched Polymer

### (Synthesis of Shell Portion of Hyperbranched Polymer)

The synthesis of the core-shell hyperbranched polymer of a eighth example will be explained. The core-shell hyperbranched polymer of the eighth example was synthesized by the following method by using the core portion of the hyperbranched polymer of the second example as described above (hereinafter, “hyperbranched core polymer”). Into a four-necked reaction vessel (volume of 1000 mL) containing 1.6 g of copper (I) chloride, 5.1 g of 2,2′-bipyridyl, and 5.0 g of the hyperbranched core polymer of the fourth example, 421 mL of monochlorobenzene and 46.8 g of tert-butyl 4-vinylbenzoate were charged by syringe under an argon atmosphere. Subsequently, the mixture in the reaction vessel was heated with agitation at 125° C. for 3 hours.

### (Purification)

Purification in the eighth example will be explained. After termination of the polymerization reaction carried out by heating with agitation as described above, the reaction system after the polymerization reaction was filtered to remove undissolved matter. Subsequently, to 490 g of the filtered solution obtained by the filtration, 980 g of a mixed aqueous acid solution containing 3% by mass of oxalic acid and 1% by mass of hydrochloric acid prepared using ultrapure water was added. After the resulting solution was agitated for 20 minutes, the water layer was removed from the reaction system. Thereafter, the copper of the reaction catalyst was removed by repeating a series of the following operations four times: to the polymer solution obtained after removal of the water layer, the above-mentioned aqueous solution containing oxalic acid and hydrochloric acid was added; the resulting solution was agitated; and then the water layer was removed from the solution after the agitation.

A pale yellow color solution obtained after the removal of copper was concentrated under a reduced pressure of 15 mmHg at 40° C. to obtain 64 g of a concentrated solution. Into the resulting concentrated solution were added 224 g of methanol and then 32 g of the ultrapure water to precipitate a solid component. After the solid component obtained by precipitation was dissolved into 32 g of THF, to the resulting solution, 320 g of methanol was added and then 46 g of the ultrapure water was added to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 24.5 g. The mol ratio of the copolymer (the core-shell hyperbranched polymer having the formed shell portion) was calculated from ¹H-NMR. The core/shell mol ratio of the core-shell hyperbranched polymer having the formed shell portion was 20/80.

### (Deprotection)

Deprotection in the eighth example will be explained. In the deprotection in the eighth example, firstly 2.0 g of the copolymer (the core-shell hyperbranched polymer before the deprotection in the eighth example) was weighed into a reaction vessel equipped with a reflux condenser, and 18.0 g of 1,4-dioxane and 0.2 g of sulfuric acid (50% by mass) were added into it. Thereafter, the entire reaction system including the reaction vessel equipped with a reflux condenser was heated to the reflux temperature, under which condition the system was refluxed with agitation for 90 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added and then the solution was agitated vigorously at room temperature for 30 minutes. After the water layer was separated, 50 g of the ultrapure water was again added, the resulting mixture was agitated vigorously at room temperature for 30 minutes, and then the water layer was separated. A series of the operations, involving addition of 50 g of the ultrapure water, the vigorous agitation of the mixture at room temperature for 30 minutes, and the separation of the water layer thereafter, was repeated two more times. The methyl isobutyl ketone solution was evaporated under reduced pressure to remove the solvent, and then the residue was dried at 40° C. under reduced pressure to obtain 1.7 g of the polymer.

### (Filtration)

A solution of the obtained dried hyperbranched polymer dissolved in 100 mL of tetrahydrofuran was filtered through a filter having a pore diameter of 0.02 μm made of an ultra-high density polyethylene (Optimizer D-300, manufactured by Nihon Mykrolis K. K.) at the flux of 4 mL/min under an applied pressure. The organic solvent in the filtered solution was removed by evaporation under vacuum, and the obtained solid component was dried under a reduced pressure of 0.1 Pa at 25° C. for 3 hours to obtain the core-shell hyperbranched polymer of the fourth example. The yield of the core-shell hyperbranched polymer of the eighth example was 1.5 g. The mol ratio of the acid-decomposable group to the acid group was 38/62.

### Ninth Example

### Synthesis of Core-Shell Hyperbranched Polymer

### (Synthesis of Shell Portion of Hyperbranched Polymer)

The synthesis of the core-shell hyperbranched polymer of a ninth example will be explained. The core-shell hyperbranched polymer of the ninth example was synthesized by the following method by using the core portion of the hyperbranched polymer of the second example as described above (hereinafter, “hyperbranched core polymer”). Into a four-necked reaction vessel (volume of 1000 mL) containing 1.6 g of copper (I) chloride, 5.1 g of 2,2′-bipyridyl, and 5.0 g of the hyperbranched core polymer of the tenth example, 530 mL of monochlorobenzene and 60.2 g of tert-butyl 4-vinylbenzoate were charged by syringe under an argon atmosphere. Subsequently, the mixture in the reaction vessel was heated with agitation at 125° C. for 4 hours.

### (Purification)

Purification in the ninth example will be explained. After termination of the polymerization reaction carried out by heating with agitation as described above, the reaction system after the polymerization reaction was filtered to remove undissolved matter. Subsequently, to 620 g of the filtered solution obtained by the filtration, 1240 g of a mixed aqueous acid solution containing 3% by mass of oxalic acid and 1% by mass of hydrochloric acid prepared using ultrapure water was added. After the resulting solution was agitated for 20 minutes, the water layer was removed from the reaction system. Thereafter, the copper of the reaction catalyst was removed by repeating a series of the following operations four times: to the polymer solution obtained after removal of the water layer, the above-mentioned aqueous solution containing oxalic acid and hydrochloric acid was added; the resulting solution was agitated; and then the water layer was removed from the solution after the agitation.

A pale yellow color solution obtained after the removal of copper was concentrated under a reduced pressure of 15 mmHg at 40° C. to obtain 130 g of a concentrated solution. Into the resulting concentrated solution were added 455 g of methanol and then 65 g of the ultrapure water to precipitate a solid component. After the solid component obtained by precipitation was dissolved into 65 g of THF, to the resulting solution, 650 g of methanol was added and then 93 g of the ultrapure water was added to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 50.2 g. The mol ratio of the copolymer (the core-shell hyperbranched polymer having the formed shell portion) was calculated from ¹H-NMR. The core/shell mol ratio of the core-shell hyperbranched polymer having the formed shell portion was 9/91.

### (Deprotection)

Deprotection in the ninth example will be explained. In the deprotection in the ninth example, firstly 2.0 g of the copolymer (the core-shell hyperbranched polymer before the deprotection in the ninth example) was weighed into a reaction vessel equipped with a reflux condenser, and 18.0 g of 1,4-dioxane and 0.2 g of sulfuric acid (50% by mass) were added into it. Thereafter, the entire reaction system including the reaction vessel equipped with a reflux condenser was heated to the reflux temperature, under which condition the system was refluxed with agitation for 30 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added and then the solution was agitated vigorously at room temperature for 30 minutes. After the water layer was separated, 50 g of the ultrapure water was again added, the resulting mixture was agitated vigorously at room temperature for 30 minutes, and then the water layer was separated. A series of the operations, involving addition of 50 g of the ultrapure water, the vigorous agitation of the mixture at room temperature for 30 minutes, and the separation of the water layer thereafter, was repeated two more times. The methyl isobutyl ketone solution was evaporated under reduced pressure to remove the solvent, and then the residue was dried at 40° C. under reduced pressure to obtain 1.7 g of the polymer.

### (Filtration)

A solution of the obtained dried hyperbranched polymer dissolved in 100 mL of tetrahydrofuran was filtered through a filter having a pore diameter of 0.02 μm made of an ultra-high density polyethylene (Optimizer D-300, manufactured by Nihon Mykrolis K. K.) at the flux of 4 mL/min under an applied pressure. The organic solvent in the filtered solution was removed by evaporation under vacuum, and the obtained solid component was dried under a reduced pressure of 0.1 Pa at 25° C. for 3 hours to obtain the core-shell hyperbranched polymer of the fourth example. The yield of the core-shell hyperbranched polymer of the ninth example was 1.5 g. The mol ratio of the acid-decomposable group to the acid group was 92/8.

### Tenth Example

### Synthesis of Core-Shell Hyperbranched Polymer

### (Synthesis of Shell Portion of Hyperbranched Polymer)

The synthesis of the core-shell hyperbranched polymer of a tenth example will be explained. The core-shell hyperbranched polymer of the tenth example was synthesized by the following method by using the core portion of the hyperbranched polymer of the second example as described above (hereinafter, “hyperbranched core polymer”). Into a four-necked reaction vessel (volume of 1000 mL) containing 0.8 g of copper (I) chloride, 2.6 g of 2,2′-bipyridyl, and 5.0 g of the hyperbranched core polymer of the fourth example, 106 mL of monochlorobenzene and 8.0 g of tert-butyl 4-vinylbenzoate were charged by syringe under an argon atmosphere. Subsequently, the mixture in the reaction vessel was heated with agitation at 125° C. for 1 hour.

### (Purification)

Purification in the tenth example will be explained. After termination of the polymerization reaction carried out by heating with agitation as described above, the reaction system after the polymerization reaction was filtered to remove undissolved matter. Subsequently, to 127 g of the filtered solution obtained by the filtration, 254 g of a mixed aqueous acid solution containing 3% by mass of oxalic acid and 1% by mass of hydrochloric acid prepared using ultrapure water was added. After the resulting solution was agitated for 20 minutes, the water layer was removed from the reaction system. Thereafter, the copper of the reaction catalyst was removed by repeating a series of the following operations four times: to the polymer solution obtained after removal of the water layer, the above-mentioned aqueous solution containing oxalic acid and hydrochloric acid was added; the resulting solution was agitated; and then the water layer was removed from the solution after the agitation.

A pale yellow color solution obtained after the removal of copper was concentrated under a reduced pressure of 15 mmHg at 40° C. to obtain 19 g of a concentrated solution. Into the resulting concentrated solution were added 67 g of methanol and then 10 g of the ultrapure water to precipitate a solid component. After the solid component obtained by precipitation was dissolved into 10 g of THF, to the resulting solution, 100 g of methanol was added and then 14 g of the ultrapure water was added to re-precipitate the solid component.

The solid component recovered by centrifugal separation after the re-precipitation as described above was dried at 40° C. and 0.1 mmHg for 2 hours to obtain a purified solid with a pale yellow color. The yield of the core-shell hyperbranched polymer having the formed shell portion was 7.3 g. The mol ratio of the copolymer (the core-shell hyperbranched polymer having the formed shell portion) was calculated from ¹H-NMR. The core/shell mol ratio of the core-shell hyperbranched polymer having the formed shell portion was 60/40.

### (Deprotection)

Deprotection in the tenth example will be explained. In the deprotection in the tenth example, firstly 2.0 g of the copolymer (the core-shell hyperbranched polymer before the deprotection in the tenth example) was weighed into a reaction vessel equipped with a reflux condenser, and 18.0 g of 1,4-dioxane and 0.2 g of sulfuric acid (50% by mass) were added into it. Thereafter, the entire reaction system including the reaction vessel equipped with a reflux condenser was heated to the reflux temperature, under which condition the system was refluxed with agitation for 240 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added and then the solution was agitated vigorously at room temperature for 30 minutes. After the water layer was separated, 50 g of the ultrapure water was again added, the resulting mixture was agitated vigorously at room temperature for 30 minutes, and then the water layer was separated. A series of the operations, involving addition of 50 g of the ultrapure water, the vigorous agitation of the mixture at room temperature for 30 minutes, and the separation of the water layer thereafter, was repeated two more times. The methyl isobutyl ketone solution was evaporated under reduced pressure to remove the solvent, and then the residue was dried at 40° C. under reduced pressure to obtain 1.4 g of the polymer.

### (Filtration)

A solution of the obtained dried hyperbranched polymer dissolved in 100 mL of tetrahydrofuran was filtered through a filter having a pore diameter of 0.02 μm made of an ultra-high density polyethylene (Optimizer D-300, manufactured by Nihon Mykrolis K. K.) at the flux of 4 mL/min under an applied pressure. The organic solvent in the filtered solution was removed by evaporation under vacuum, and the obtained solid component was dried under a reduced pressure of 0.1 Pa at 25° C. for 3 hours to obtain the core-shell hyperbranched polymer of the fourth example. The yield of the core-shell hyperbranched polymer of the tenth example was 1.3 g. The mol ratio of the acid-decomposable group to the acid group was 22/78.

### —Preparation of Resist Compositions—

Resist compositions in the first to the tenth examples will be explained. The resist compositions in the first to the tenth examples contain 4.8% by mass of the core-shell hyperbranched polymers synthesized by the above-mentioned methods, 10% by mass of triphenyl sulfonium bisnonaflate as the photo-inductive acid-generating material, trioctylamine as a quencher (8% by mol relative to the photo-inductive acid-generating material), and propylene glycol monomethyl acetate (residual part).

### —Storage Conditions of Resist Compositions—

The resist compositions in the first to the tenth examples as described above were kept respectively in storage rooms maintained at 23° C. and 5° C. each in respective light-blocking glass vials.

### First Comparative Example

### Synthesis of Core-Shell Hyperbranched Polymer

The hyperbranched polymer of the first comparative example will be explained. In the hyperbranched polymer of the first comparative example, the hyperbranched polymer was synthesized in a similar manner to that of the first example except that filtration was not carried out as compared with the synthesis method for the core-shell hyperbranched polymer explained in the first example. The core/shell mol ratio of the core-shell hyperbranched polymer of the first comparative example was 40/60. The mol ratio of the acid-decomposable group to the acid group was 78/22.

### Second Comparative Example

### Synthesis of Core-Shell Hyperbranched Polymer

The hyperbranched polymer of the second comparative example will be explained. In the hyperbranched polymer of the second comparative example, the hyperbranched polymer was synthesized in a similar manner to that of the second example except that filtration was not carried out as compared with the synthesis method for the core-shell hyperbranched polymer explained in the second example. The core/shell mol ratio of the core-shell hyperbranched polymer of the second comparative example was 30/70.

### Third Comparative Example

### Synthesis of Core-Shell Hyperbranched Polymer

The hyperbranched polymer of the third comparative example will be explained. In the hyperbranched polymer of the third comparative example, the hyperbranched polymer was synthesized in a similar manner to that of the third example except that filtration was not carried out as compared with the synthesis method for the core-shell hyperbranched polymer explained in the third example. The core/shell mol ratio of the core-shell hyperbranched polymer of the third comparative example was 30/70. The mol ratio of the acid-decomposable group to the acid group was 78/22.

### Fourth Comparative Example

### Synthesis of Core-Shell Hyperbranched Polymer

The hyperbranched polymer of the fourth comparative example will be explained. In the hyperbranched polymer of the fourth comparative example, the hyperbranched polymer was synthesized in a similar manner to that of the seventh example except that filtration was not carried out as compared with the synthesis method for the core-shell hyperbranched polymer explained in the seventh example. The core/shell mol ratio of the core-shell hyperbranched polymer of the fourth comparative example was 30/70. The mol ratio of the acid-decomposable group to the acid group was 38/62.

### —Preparation of Resist Compositions—

The resist compositions of the first to the fourth comparative examples were prepared in a similar manner to that in the resist compositions of the first to the tenth examples as described above.

### —Storage Conditions of Resist Compositions—

Storage conditions for the resist compositions in the first to the fourth comparative examples were the same as those in the first to the tenth examples.

### —Evaluation of Resist Resolution—

Evaluation of the resist resolution will be explained. In evaluation of the resist resolution, a resist composition was spin-coated on a silicon wafer and had a 100-nanometer thickness. The spin-coating was performed at 1900 rpm and for 1 minute. The electron-beam printing instrument used was CABLE 9000 (manufactured by Crestec Inc.). The applied electric voltage was 50 KeV. Conditions in the exposure process were as following: PB: 140° C. for 1 minute; PEB: 115° C. for 3 minutes; Development: Immersion in an aqueous tetramethylammonium hydroxide (2.38% by mass) at 23° C. for 2 minutes; Rinse: Immersion in the ultrapure water for 1 minute.

The degree of resolution was confirmed by the storage time until the resolution with the resolution degree, L/S=30 nm, was observed by using FE-SEM S4800 (manufactured by Hitachi High-Technologies Corp.). The results of the resist compositions of the first to the fourth comparative examples and the first to the tenth examples are indicated in Table 6.

TABLE 6

| | |
|---|---|
| storage temperature | storage period for |
| (degrees C.) | obtaining L/=30 nm |

| | | | |
|---|---|---|---|
| first comparative | 5 | 6 | months |
| example | 23 | 6 | months |
| second comparative | 5 | 6 | months |
| example | 23 | 6 | months |
| third comparative | 5 | 6 | months |
| example | 23 | 6 | months |
| fourth comparative | 5 | 6 | months |
| example | 23 | 6 | months |
| first example | 5 | 1 | year |
| | 23 | 1 | year |
| second example | 5 | 1 | year |
| | 23 | 1 | year |
| third example | 5 | 1 | year |
| | 23 | 1 | year |
| fourth example | 5 | 1 | year |
| | 23 | 1 | year |
| fifth example | 5 | 1 | year |
| | 23 | 1 | year |
| sixth example | 5 | 1 | year |
| | 23 | 1 | year |
| seventh example | 5 | 1 | year |
| | 23 | 1 | year |
| eighth example | 5 | 1 | year |
| | 23 | 1 | year |
| ninth example | 5 | 1 | year |
| | 23 | 1 | year |
| tenth example | 5 | 1 | year |
| | 23 | 1 | year |

### <Chapter 5>

The core-shell hyperbranched polymer of the embodiments relating to the present invention in Chapter 5 has a structure containing the core portion of the hyperbranched core polymer as the macro initiator and the shell portion covering the core portion.

The hyperbranched core polymer is synthesized by the atom transfer radical polymerization (ATRP) method, one kind of living radical polymerization method. Examples of the monomer used for synthesis of the hyperbranched core polymer include at least a monomer represented by formula (I).

In formula (I), Y represents a linear, a branched, or a cyclic alkylene group having 1 to 10 carbon atoms. The number of carbons in Y is preferably 1 to 8. More preferable number of carbons in Y is 1 to 6. Y in formula (I) may contain a hydroxyl group or a carboxyl group.

Specific examples of Y in formula (I) include a methylene group, an ethylene group, a propylene group, an isopropylene group, a butylene group, an isobutylene group, an amylene group, a hexylene group, and a cyclohexylene group. Furthermore, Y in formula (I) includes a group in which the above-mentioned groups are bonded with each other directly or via —O—, —CO—, and —COO—.

Y in formula (I) is preferably an alkylene group having 1 to 8 carbon atoms among the groups mentioned above. Y in formula (I) is more preferably a linear alkylene group having 1 to 8 carbon atoms among the alkylene groups having 1 to 8 carbon atoms. examples of the alkylene group more preferable include a methylene group, an ethylene group, an —OCH₂— group, and an —OCH₂CH₂— group. Z in formula (I) represents a halogen atom (a halogen group) such as a fluorine atom, a chlorine atom, a bromine atom, and an iodine atom. Specific examples of preferable Z in formula (I) include a chlorine atom and a bromine atom among the halogen atoms mentioned above.

Specific examples of the monomer represented by formula (I) include chloromethyl styrene, bromomethyl styrene, p-(1-chloroethyl)styrene, bromo(4-vinylphenyl)phenylmethane, 1-bromo-1-(4-vinylphenyl)propane-2-one, and 3-bromo-3-(4-vinylphenyl)propanol. More specific examples of the preferable monomer represented by formula (I) among the monomers used for synthesis of the hyperbranched polymer include chloromethyl styrene, bromomethyl styrene, and p-(1-chloroethyl)styrene.

Monomers constituting the core portion of the hyperbranched polymer of the present invention may include, in addition to the monomers represented by formula (I), other monomers. There is no restriction with regard to other monomers provided the monomer can be subject to radical polymerization, and may be chosen appropriately according to purpose. Examples of other monomers capable of radical polymerization include compounds having a radical polymerizable unsaturated bond such as (meth)acrylic acid, (meth)acrylate esters, vinylbenzoic acid, vinylbenzoate esters, styrenes, an allyl compound, vinyl ethers, vinyl esters, and the like.

Specific examples of (meth)acrylate esters cited as other monomers capable of radical polymerization include tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1 ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate.

Specific examples of vinyl benzoate esters cited as other monomers capable of radical polymerization include vinyl benzoate, tert-butyl vinyl benzoate, 2-methylbutyl vinyl benzoate, 2-methylpentyl vinyl benzoate, 2-ethylbutyl vinyl benzoate, 3-methylpentyl vinyl benzoate, 2-methylhexyl vinyl benzoate, 3-methylhexyl vinyl benzoate, triethylcarbyl vinyl benzoate, 1-methyl-1-cyclopentyl vinyl benzoate, 1-ethyl-1-cyclopentyl vinyl benzoate, 1-methyl-1-cyclohexyl vinyl benzoate, 1-ethyl-1-cyclohexyl vinyl benzoate, 1-methylnorbornyl vinyl benzoate, 1-ethylnorbornyl vinyl benzoate, 2-methyl-2-adamantyl vinyl benzoate, 2-ethyl-2-adamantyl vinyl benzoate, 3-hydroxy-1-adamantyl vinyl benzoate, tetrahydrofuranyl vinyl benzoate, tetrahydropyranyl vinyl benzoate, 1-methoxyethyl vinyl benzoate, 1-ethoxyethyl vinyl benzoate, 1-n-propoxyethyl vinyl benzoate, 1-isopropoxyethyl vinyl benzoate, n-butoxyethyl vinyl benzoate, 1-isobutoxyethyl vinyl benzoate, 1-sec-butoxyethyl vinyl benzoate, 1-tert-butoxyethyl vinyl benzoate, 1-tert-amyloxyethyl vinyl benzoate, 1-ethoxy-n-propyl vinyl benzoate, 1-cyclohexyloxyethyl vinyl benzoate, methoxypropyl vinyl benzoate, ethoxypropyl vinyl benzoate, 1-methoxy-1-methyl-ethyl vinyl benzoate, 1-ethoxy-1-methyl-ethyl vinyl benzoate, trimethylsilyl vinyl benzoate, triethylsilyl vinyl benzoate, dimethyl-tert-butylsilyl vinyl benzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinyl benzoate, adamantyl vinyl benzoate, 2-(2-methyl)adamantyl vinyl benzoate, chloroethyl vinyl benzoate, 2-hydroxyethyl vinyl benzoate, 2,2-dimethylhydroxypropyl vinyl benzoate, 5-hydroxybenzyl vinyl benzoate, trimethylolpropane vinyl benzoate, glycidyl vinyl benzoate, benzyl vinyl benzoate, phenyl vinyl benzoate, and naphthyl vinyl benzoate.

Specific examples of styrenes cited as other monomers capable of radical polymerization include styrene, benzyl styrene, trifluoromethyl styrene, acetoxy styrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethyl styrene, 4-fluoro-3-trifluoromethyl styrene, and vinyl naphthalene.

Specific examples of allyl compounds cited as other monomers capable of radical polymerization include allyl acetate, allyl caproate, allyl caprylate, allyl laurate, allyl palmitate, allyl stearate, allyl benzoate, allyl acetoacetate, allyl lactate, and allyl oxyethanol.

Specific examples of vinyl ethers cited as other monomers capable of radical polymerization include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethyleneglycol vinyl ether, dimethylaminoethyl vinyl ether, diethylaminoethyl vinyl ether, butylaminoethyl vinyl ether, benzyl vinyl ether, tetrahydrofurfuryl vinyl ether, vinyl phenyl ether, vinyl tolyl ether, vinyl chlorophenyl ether, vinyl 2,4-dichlorophenyl ether, vinyl naphthyl ether, and vinyl anthranyl ether.

Specific examples of vinyl esters cited as other monomers capable of radical polymerization include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl buthoxyacetate, vinyl phenylacetate, vinyl acetoacetate, vinyl lactate, vinyl β-phenylbutyrate, and vinyl cyclohexylcarboxylate.

Specific examples of a preferable monomer constituting the hyperbranched core polymer include (meth)acrylic acid, tert-butyl(meth)acrylate, 4-vinyl benzoic acid, tert-butyl 4-vinylbenzoate, styrene, benzyl styrene, chlorostyrene, and vinyl naphthalene.

The amount of the monomer constituting the hyperbranched core polymer relative to total monomers used in the synthesis of the hyperbranched polymer is preferably 10 to 90% by mol, more preferably 10 to 80% by mol, and yet more preferably 10 to 60% by mol.

By controlling the amount of monomer constituting the hyperbranched core polymer at the above ranges, for example, when the core-shell hyperbranched polymer is used in a resist composition, a hyperbranched polymer with a suitable hydrophobicity to a developing solution can be provided. Thus, for example, when a microfabrication process for a semi-conductor integrated circuit, a flat panel display, a printed wiring board uses a resist composition containing the hyperbranched polymer, dissolution of an unexposed part may be suppressed, and thus, is preferable.

The amount of the monomer represented by formula (I) relative to total monomers used in the synthesis of the hyperbranched core polymer is preferably 5 to 100% by mol, more preferably 20 to 100% by mol, and yet more preferably 50 to 100% by mol. When the amount of the monomer represented by formula (I) in the hyperbranched core polymer is at the above ranges, the hyperbranched core polymer takes a spherical morphology, which is advantageous in suppressing the intermolecular entanglement, and thus, is preferable.

When the hyperbranched core polymer is a copolymer of a monomer represented by formula (I) and other monomers, the amount of the monomer represented by formula (I) relative to total monomers constituting the hyperbranched core polymer is preferably 10 to 99% by mol, more preferably 20 to 99% by mol, and yet more preferably 30 to 99% by mol. When the amount of the monomer represented by formula (I) in the hyperbranched core polymer is at the above ranges, the hyperbranched core polymer takes a spherical morphology, thereby advantageously suppressing the intermolecular entanglement and improving functions such as the substrate adhesiveness and the glass transition temperature, and thus, is preferable. The amount of the monomer represented by formula (I) and the other monomers in the core portion may be controlled by the charging ratio at the time of polymerization according to the purpose.

In the synthesis of the hyperbranched core polymer, a metal catalyst is used. As the metal catalyst, for example, a metal catalyst composed of a ligand and a transition metal compound of, for example, copper, iron, ruthenium, and chromium. examples of the transition metal compound include copper (I) chloride, copper (I) bromide, copper (I) iodide, copper (I) cyanide, copper (I) oxide, copper (I) perchlorate, iron (I) chloride, iron (I) bromide, and iron (I) iodide.

Examples of the ligand include pyridines, bipyridines, polyamines, and phosphines, unsubstituted or substituted with an alkyl group, an aryl group, an amino group, a halogen group, an ester group, and the like. examples of the preferable metal catalyst include a copper (I) bipyridyl complex and a copper (I) pentamethyl diethylene triamine complex, which are composed of copper chloride and respective ligands, and an iron (II) triphenyl phosphine complex and an iron (II) tributyl amine complex, which are composed of iron chloride and respective ligands, or others. As the ligand, the ligands described in Chem. Rev., 2001, 101, 3689—may be used as well.

The amount of the metal catalyst relative to that of total monomers used for synthesis of the hyperbranched core polymer is preferably 0.01 to 70% by mol, and more preferably 0.1 to 60% by mol. When the catalyst is used at this amount, reactivity can be improved, thereby enabling synthesis of a hyperbranched core polymer having a suitable degree of branching.

When the amount of the metal catalyst used is below the range, reactivity may be markedly reduced, thereby leading to a risk of the polymerization becoming sluggish. On the other hand, when the amount of the metal catalyst used is above the range, the polymerization reaction becomes excessively active and the coupling reaction among radicals at growing terminals tends to occur easily, thereby making control of the polymerization difficult. Further, when the amount of the metal catalyst used is above the range, the coupling reaction among radicals induces gelation of the reaction system.

The metal catalyst may be made into a coordination compound by mixing a transition metal compound and a ligand in an apparatus. The metal catalyst composed of a transition metal compound and a ligand may be added to the apparatus in the form of an active coordination compound. Making a coordination compound by mixing a transition metal compound and a ligand in the apparatus is preferable because of operations in the synthesis of the hyperbranched polymer can be simplified.

A method of adding the metal catalyst is not particularly restricted and the metal catalyst may be added, for example, all at once prior to the polymerization of the hyperbranched core polymer. Further, additional metal catalyst may be added after initiation of the polymerization depending on the level of inactivation of the catalyst. For example, when distribution of a coordination compound forming the metal catalyst in the reaction system is not uniform, the transition metal compound may be added to the apparatus in advance, followed by addition of only a ligand afterwards.

The polymerization reaction for synthesis of the hyperbranched core polymer is carried out preferably in a solvent, though the reaction can occur in the absence of a solvent. The solvent used in the polymerization of the hyperbranched core polymer is not particularly restricted. examples of the solvent include a hydrocarbon solvent such as benzene and toluene; an ether solvent such as diethyl ether, tetrahydrofuran, diphenyl ether, anisole, and dimethoxy benzene; a halogenated hydrocarbon solvent such as methylene chloride, chloroform, and chlorobenzene; a ketone solvent such as acetone, methyl ethyl ketone, and methyl isobutyl ketone; an alcohol solvent such as methanol, ethanol, propanol, and isopropanol; a nitrile solvent such as acetonitrile, propionitrile, and benzonitrile; an ester solvent such as ethyl acetate and butyl acetate; a carbonate solvent such as ethylene carbonate and propylene carbonate; and an amide solvent such as N,N-dimethylformamide and N,N-dimethylacetamide. These may be used independently or in a combination of two or more kinds.

In the synthesis of the hyperbranched core polymer, it is preferable that the core polymerization be carried out in the presence of nitrogen, an inert gas, or under the flow thereof, and in the absence of oxygen to prevent oxygen from affecting the radicals. The core polymerization may be carried out in a batch process or a continuous process.

In the synthesis of the hyperbranched polymer, the synthesis may be done by adding monomer to a polymerization reactor after the metal catalyst is introduced in advance. Here, the amount of monomer added later to the metal catalyst per one charge is less than the total amount of the monomer to be added to the metal catalyst.

For example, the monomer is added according to a method such as a continuous method in which the monomer is mixed with the metal catalyst by a dropwise addition during a prescribed period, or a portion-wise method in which the total monomer to be mixed with the metal catalyst is divided into multiple portions where each portion of a given amount is added at given intervals. Thus, the amount of the monomer per one charge added later to the metal catalyst is less than the total monomer to be added into the metal catalyst.

The monomer also may be added to the metal catalyst, for example, by continuously charging the monomer into the metal catalyst for a prescribed period. In this case, the amount of the monomer mixed with the metal catalyst per unit time is less than the total amount of the monomers to be mixed with the metal catalyst.

When the monomer is mixed into the reaction system by the continuous method, the time for the dropwise addition of the monomer is preferably, for example, 5 to 300 minutes. More preferably, the time for the dropwise addition of the monomer is 15 to 240 minutes, and yet more preferably, 30 to 180 minutes.

When the monomer is mixed with the metal catalyst in the portion-wise method, one portion of the monomer is mixed, and then the next portion of the monomer is mixed after a prescribed interval. The interval may be at least the time required for the mixed monomer to perform one polymerization, the time required for the mixed monomer to be dispersed to homogeneously or to be dissolved in the entire reaction system, or the time required for the fluctuated temperature of the reaction system caused by the addition of the monomer to be stabilized.

If the time of the dropwise addition of the monomer into the metal catalyst is too short, there is a possibility that a rapid increase of the molecular weight is not controlled sufficiently. If the time of the dropwise addition of the monomer into the reaction system is too long, the total polymerization time from the start of the synthesis of the hyperbranched polymer to the end becomes long, thereby increasing the cost for synthesizing the hyperbranched polymer, and thus, is not preferable.

In the core polymerization, polymerization may be performed by using an additive. In the core polymerization, among compounds represented by formula (1-1) and compounds represented by formula (1-2) depicted in Chapter 1, at least one type may be added.

R₁ in formula (1-1) represents hydrogen, an alkyl group having 1 to 10 carbon atoms, an aryl group having 6 to 10 carbon atoms, or an aralkyl group having 7 to 10 carbon atoms. “A” in formula (1-1) represents a cyano group, a hydroxy group, and a nitro group. Examples of the compound represented by formula (1-1) include nitriles, alcohols, and a nitro compound.

Specific examples of nitriles included in compounds represented by formula (1-1) include acetonitrile, propionitrile, butyronitrile, and benzonitrile. Specific examples of alcohols included in compounds represented by formula (1-1) include methanol, ethanol, 1-propanol, 2-propanol, 1-butanol, cyclohexyl alcohol, and benzyl alcohol. Specific examples of nitro compounds included in compounds represented by formula (1-1) include nitromethane, nitroethane, nitropropane, and nitrobenzene. The compound represented by formula (1-1) is not restricted to the compounds mentioned above.

R₂ and R₃ in formula (1-2) represent hydrogen, an alkyl group having 1 to 10 carbon atoms, an aryl group having 6 to 10 carbon atoms, an aralkyl group having 7 to 10 carbon atoms, or a or a dialkyl amide group having 1 to 10 carbon atoms; B represents a carbonyl group and a sulfonyl group. More specifically, R₂ and R₃ in formula (1-2) represent hydrogen, an alkyl group having 1 to 10 carbon atoms, an aryl group having 6 to 10 carbon atoms, an aralkyl group having 7 to 10 carbon atoms, or a dialkyl amine group having 2 to 10 carbon atoms. R₂ and R₃ in formula (1-2) may be the same or different.

Examples of the compound represented by formula (1-2) include ketones, sulfoxides, and an alkyl formamide compound. Specific examples of the ketones include acetone, 2-butanone, 2-pentanone, 3-pentanone, 2-hexanone, cyclohexanone, 2-methyl cyclohexanone, acetophenone, and 2-methyl acetophenone.

Specific examples of the sulfoxides included in the compounds represented by formula (1-2) include dimethyl sulfoxide and diethyl sulfoxide. Specific examples of the alkyl formamide compound included in the compounds represented by formula (1-2) include N,N-dimethyl formamide, N,N-diethylformamide, and N,N-dibutyl formamide. The compounds represented by formula (1-2) are not restricted to the above-mentioned compounds. Among the compounds represented by formula (1-1) or formula (1-2), nitriles, nitro compounds, ketones, sulfoxides, and alkyl formamide compounds are preferable, while acetonitrile, propionitrile, benzonitrile, nitroethane, nitropropane, dimethyl sulfoxide, acetone, and N,N-dimethyl formamide are more preferable.

In the synthesis of the hyperbranched polymer, compounds represented by formula (1-1) or formula (1-2) may be used independently or in combination of two or more.

In the synthesis of the hyperbranched core polymer, compounds represented by formula (1-1) or formula (1-2) may be used independently or in combination of two or more as a solvent.

The amount of the compounds represented by formula (1-1) or (1-2) to be added in the synthesis of the hyperbranched polymer is preferably 2 times to 10000 times by mol ratio relative to the amount of transition metal in the metal catalyst. The amount of the compound represented by formula (1-1) or the amount of the compound represented by (1-2) to be added relative to the amount of a transition metal in the metal catalyst is more preferably 3 times to 7000 times by mol ratio, and yet more preferably 4 times to 5000 times by mol ratio relative to the amount of transition metal in the metal catalyst.

When the added amount of the compound represented by formula (1-1) or of the compound represented by formula (1-2) is too small, the rapid increase in molecular weight may not be controlled sufficiently. On the other hand, when the added amount of the compound represented by formula (1-1) or of the compound represented by formula (1-2) is too large, the reaction rate is slowed, leading to the formation of a large amount of oligomers.

The core polymerization may be carried out, for example, by adding a monomer dropwise into a reaction vessel. When the amount of the metal catalyst is small, by controlling a rate of the dropwise addition of the monomer, a high degree of branching in a synthesized macro initiator can be maintained. In other words, the amount of the metal catalyst can be reduced while maintaining a high degree of branching in the synthesized hyperbranched core polymer (macro initiator) by controlling the rate of the dropwise addition of the monomer. To maintain a high degree of branching in the hyperbranched core polymer, the concentration of the monomer added dropwise is preferably 1 to 50% by mass and more preferably 2 to 20% by mass relative to the total amount of the reaction.

The polymerization time is preferably 0.1 to 10 hours depending on the molecular weight of the polymer. Reaction temperature in the core polymerization is preferably 0 to 200° C. More preferable reaction temperature in the core polymerization is 50 to 150° C. When the polymerization is carried out at a temperature above the boiling point of the solvent used, for example, the pressure may be increased in an autoclave.

In the core polymerization, it is preferable for the reaction system to be distributed uniformly. The reaction system is distributed uniformly, for example, by agitating the reaction system. As a specific example of an agitation condition for core polymerization, preferably the power necessary for agitation per unit volume is set as 0.01 kW/m³ or more. In the core polymerization, additional catalyst or a reducing agent to regenerate the catalyst may be added according to the progress of the polymerization and degree of catalyst inactivation.

In the synthesis of the hyperbranched polymer, the core polymerization reaction is stopped at the point when the set molecular weight is attained. A method of stopping the core polymerization is not particularly limited, and a method such as inactivating the catalyst, for example, by cooling or by adding an oxidizing agent, a chelating agent, etc. may be used.

The core-shell hyperbranched polymer according to an embodiment has a shell portion which constitutes the terminal of the hyperbranched core polymer molecule synthesized as described above. The shell portion of the hyperbranched polymer has at least a repeating unit represented by formula (II) or a repeating unit represented by formula (III) in Chapter 1.

The repeating unit represented by formula (II) and the repeating unit represented by formula (III) in Chapter 1 contains an acid-decomposable group which is decomposed by an organic acid such as acetic acid, maleic acid, and benzoic acid, and an inorganic acid such as hydrochloric acid, sulfuric acid, and nitric acid, or preferably by a photo-inductive acid-generating material which generates an acid by optical energy. An acid-decomposable group giving a hydrophilic group by decomposition is preferable.

R¹ in formula (II) and R⁴ in formula (III) represent hydrogen or an alkyl group having 1 to 3 carbon atoms, among which, R¹ in formula (II) and R⁴ in formula (III) are preferably hydrogen and a methyl group. Hydrogen is more preferable as R¹ in formula (II) and R⁴ in formula (III).

R² in formula (II) represents hydrogen, an alkyl group, or an aryl group. The alkyl group in R² in formula (II) is preferably, for example, an alkyl group having 1 to 30 carbon atoms, more preferably an alkyl group having 1 to 20 carbon atoms, and yet more preferably an alkyl group having 1 to 10 carbon atoms. The alkyl group has a linear, a branched, or a cyclic structure. Specific examples of the alkyl group of R² in formula (II) include a methyl group, an ethyl group, a propyl group, an isopropyl group, a butyl group, an isobutyl group, a tert-butyl group, and a cyclohexyl group.

The aryl group of R² in formula (II) preferably has 6 to 30 carbon atoms, more preferably 6 to 20, and yet more preferably 6 to 10. Specific examples of the aryl group of R² in formula (II) include a phenyl group, a 4-methyl phenyl group, and a naphthyl group, among which, includes hydrogen, methyl groups, ethyl groups, phenyl groups, and the like. As one of the most preferable group of R² in formula (II), a hydrogen atom may be mentioned.

R³ in formula (II) and R⁵ in formula (III) represent hydrogen, an alkyl group, a trialkyl silyl group, an oxoalkyl group, or a group represented by the following formula (i). It is preferable that the alkyl group of R³ in formula (II) and R⁵ in formula (III) be an alkyl group having 1 to 40 carbon atoms. More preferably the number of carbons of the alkyl group of R³ in formula (II) and R⁵ in formula (III) is 1 to 30.

Yet more preferably the number of carbons of the alkyl group in R³ in formula (II) and R⁵ in formula (III) is 1 to 20. The alkyl group in R³ in formula (II) and R⁵ in formula (III) may be linear, branched, or cyclic. R³ in formula (II) and R⁵ in formula (III) are more preferably a branched alkyl group having 1 to 20 carbon atoms.

Preferably the number of carbons of each alkyl group in R³ in formula (II) and R⁵ in formula (III) is 1 to 6, and more preferably 1 to 4. Preferably the number of carbons of the alkyl group of the oxoalkyl group in R³ in formula (II) and R⁵ in formula (III) is 4 to 20, and more preferably 4 to 10.

R⁶ in formula (i) represents hydrogen or an alkyl group. The alkyl group of R⁶ in formula (i) is linear, branched, or cyclic. It is preferable that the alkyl group of R⁶ in formula (i) be an alkyl group having 1 to 10 carbon atoms. More preferably the number of carbons of the alkyl group of R⁶ in formula (i) is 1 to 8, and yet more preferably the number is 1 to 6.

R⁷ and R⁸ in formula (i) represent hydrogen or an alkyl group. The hydrogen atom and the alkyl group in R⁷ and R⁸ in formula (i) may be independent of each other or form a ring. The alkyl group in R⁷ and R⁸ in formula (i) has a linear, branched, or cyclic structure. It is preferable that the alkyl group in R⁷ and R⁸ in formula (i) be an alkyl group having 1 to 10 carbon atoms. More preferably the number of carbons of the alkyl group in R⁷ and R⁸ in formula (i) is 1 to 8, and yet more preferably the number is 1 to 6. R⁷ and R⁸ in formula (i) are preferably a branched alkyl group having 1 to 20 carbon atoms.

Examples of the group represented by formula (i) include a linear or a branched acetal group such as a 1-methoxyethyl group, a 1-ethoxyethyl group, a 1-n-propoxyethyl group, a 1-isopropoxyethyl group, a 1-n-butoxyethyl group, a 1-isobutoxyethyl group, a 1-sec-butoxyethyl group, a 1-tert-butoxyethyl group, a 1-tert-amyloxyethyl group, a 1-ethoxy-n-propyl group, a 1-cyclohexyloxyethyl group, a methoxypropyl group, an ethoxypropyl group, a 1-methoxy-1-methyl-ethyl group, and 1-ethoxy-1-methyl-ethyl group; a cyclic acetal group such as a tetrahydrofuranyl group and a tetrahydropyranyl group. Among the above-mentioned groups represented by formula (i), an ethoxyethyl group, a butoxyethyl group, an ethoxypropyl group, and a tetrahydropyranyl group are particularly preferable.

Examples of a linear, a branched, or a cyclic alkyl group in R³ in formula (II) and R⁵ in formula (III) include an ethyl group, a propyl group, an isopropyl group, a butyl group, an isobutyl group, a tert-butyl group, a cyclopentyl group, a cyclohexyl group, a cycloheptyl group, a triethylcarbyl group, a 1-ethylnorbornyl group, 1-methylcyclohexyl group, an adamantyl group, a 2-(2-methyl)adamantyl group, and a tert-amyl group. Among them, a tert-butyl group is particularly preferable.

Examples of the trialkyl silyl group in R³ in formula (II) and R⁵ in formula (III) include a group having 1 to 6 carbon atoms in each alkyl group, such as a trimethyl silyl group, a triethyl silyl group, and a dimethyl tert-butyl silyl group. Example of the oxoalkyl group includes a 3-oxocyclohexyl group.

Monomers giving repeating units represented by formula (II) include, for example, vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate. Among these, 4-vinylbenzoic acid and tert-butyl 4-vinylbenzoate is preferable.

Monomers giving repeating units represented by formula (III) include, for example, acrylate, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1-ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, methacrylic acid, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate. Among these, acrylate and tert-butyl acrylate are preferable.

As the monomer constituting the shell portion, a monomer other than the monomers giving repeating units represented by formula (II) and formula (III) may also be used provided the monomer has a structure containing a radical polymerizable unsaturated bond.

Examples of comonomers usable for the polymerization include a compound containing a radical polymerizable unsaturated bond selected from styrenes other than the styrenes mentioned above, an allyl compound, vinyl ethers, vinyl esters, and crotonate esters.

Specific examples of styrenes other than the styrenes cited as monomers usable as the monomer constituting the shell portion include styrene, tert-buthoxy styrene, α-methyl-tert-buthoxy styrene, 4-(1-methoxyethoxy)styrene, 4-(1-ethoxyethoxy)styrene, tetrahydropyranyloxy styrene, adamantyloxy styrene, 4-(2-methyl-2-adamantyloxy)styrene, 4-(1-methylcyclohexyloxy)styrene, trimethylsilyloxy styrene, dimethyl-tert-butylsilyloxy styrene, tetrahydropyranyloxy styrene, benzyl styrene, trifluoromethyl styrene, acetoxy styrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethyl styrene, 4-fluoro-3-trifluoromethyl styrene, and vinyl naphthalene.

Specific examples of allyl compounds cited as comonomers usable as monomers constituting the shell portion include allyl acetate, allyl caproate, allyl caprylate, allyl laurate, allyl palmitate, allyl stearate, allyl benzoate, allyl acetoacetate, allyl lactate, and allyl oxyethanol.

Specific examples of vinyl ethers cited as comonomers usable as monomers constituting the shell portion include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethyleneglycol vinyl ether, dimethylaminoethyl vinyl ether, diethylaminoethyl vinyl ether, butylaminoethyl vinyl ether, benzyl vinyl ether, tetrahydrofurfuryl vinyl ether, vinyl phenyl ether, vinyl tolyl ether, vinyl chlorophenyl ether, vinyl 2,4-dichlorophenyl ether, vinyl naphthyl ether, and vinyl anthranyl ether.

Specific examples of vinyl esters cited as comonomers usable as monomers constituting the shell portion include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl buthoxyacetate, vinyl phenylacetate, vinyl acetoacetate, vinyl lactate, vinyl β-phenylbutyrate, and vinyl cyclohexylcarboxylate.

Specific examples of the crotonate esters cited as comonomers usable as the monomers constituting the shell portion include butyl crotonate, hexyl crotonate, glycerine monocrotonate, dimethyl itaconate, diethyl itaconate, dibutyl itaconate, dimethyl maleate, dibutyl fumarate, maleic anhydride, maleimide, acrylonitrile, methacrylonitrile, and maleironitrile.

Specific examples of monomers usable as monomers constituting the shell portion also include monomers represented by formula (IV) to formula (VIII) in Chapter 1.

Among comonomers usable as monomers constituting the shell portion, styrenes and crotonate esters are preferable. Among comonomers usable as monomers constituting the shell portion, styrene, benzyl styrene, chlorostyrene, vinyl naphthalene, butyl crotonate, hexyl crotonate, and maleic anhydride are preferable.

In the hyperbranched polymer, at least monomer giving a repeating unit represented by formula (II) or monomer giving a repeating unit represented by formula (III) is included. The amount of monomer giving the repeating units above is preferably 10 to 90% by mol relative to the total charge amount of monomer used for synthesizing the hyperbranched polymer at the time of charge. The amount of monomer giving the repeating units as described above is more preferably 20 to 90% by mol relative to the total charge amount of monomer used for synthesizing the hyperbranched polymer at the time of charge.

The amount of monomer giving the repeating units as described above is yet more preferably 30 to 90% by mol relative to the total charge amount of monomer used for synthesizing the hyperbranched polymer at the time of charge. In particular, it is preferable that the repeating unit represented by formula (II) or the repeating unit represented by formula (III) be 50 to 100% by mol, and more preferably 80 to 100% by mol at the time of charge relative to the total charge amount of monomer used for synthesis of the hyperbranched polymer. When the charge amount of monomer giving the repeating unit as described above relative to the total charge amount of monomer used for synthesizing the hyperbranched polymer is at this range, a light-exposed part in the developing step in a lithography using a resist composition containing the hyperbranched polymer is efficiently removed by dissolution into a basic solution, and thus is preferable.

When the shell portion of the core-shell hyperbranched polymer is a polymer of monomer giving a repeating unit represented by formula (II) or monomer giving a repeating unit represented by formula (III) and other monomers, the amount of monomer giving the repeating unit represented by formula (II) and/or the amount of monomer giving the repeating unit represented by to formula (III) is preferably 30 to 90% by mol relative to the total monomer constituting the shell portion, and more preferably 50 to 70% by mol.

When monomer giving a repeating unit represented by formula (II) and/or monomer giving a repeating unit represented by formula (III) is at the above ranges relative to the total amount of monomer constituting the shell portion, functions such as etching resistance, wetting properties, and glass transition temperature are improved without hindering efficient dissolution of a light-exposed part in a basic solution, and thus, is preferable. Here, at least the amount of a repeating unit represented by formula (II) or the amount of the repeating unit represented by formula (III), and other repeating units in the shell portion may be controlled by the mol ratio at the time of introduction into the shell portion according to purpose.

It is preferable that a polymerization of the shell portion in the hyperbranched core polymer (shell polymerization) be carried out in the presence of nitrogen, an inert gas, or under the flow thereof, and in the absence of oxygen to prevent radicals from being affected by oxygen. The shell polymerization may be carried out in a batch process or a continuous process. The shell polymerization may be carried out consecutively following the core polymerization, or by adding a catalyst again after the metal catalyst and monomer are removed after the core polymerization. Further, the shell polymerization may be carried out after drying the hyperbranched core polymer synthesized by the core polymerization.

The shell polymerization is carried out in the presence of a metal catalyst. In the shell polymerization, a metal catalyst similar to those used in the core polymerization may be used. In the shell polymerization, for example, a metal catalyst is placed in a reaction system of the shell polymerization prior to initiation of the shell polymerization, and then the hyperbranched core polymer synthesized by the core polymerization (macro initiator, or core macromer) and a monomer constituting the shell portion are added dropwise. To be specific, for example, a metal catalyst is placed in advance inside a reaction vessel, into which the hyperbranched core polymer and the monomer are added dropwise. Specifically, for example, a monomer constituting the shell portion as described above may be added dropwise into a reaction vessel containing the hyperbranched core polymer in advance. It is preferable that a monomer, a metal catalyst, and a solvent used in the shell polymerization be fully deoxygenated (degassed) in advance as in the case of the core polymerization.

In the polymerization of the shell, a metal catalyst is used. As the metal catalyst, for example, a metal catalyst composed of a ligand and a transition metal compound of, for example, copper, iron, ruthenium, and chromium. examples of the transition metal compound include copper (I) chloride, copper (I) bromide, copper (I) iodide, copper (I) cyanide, copper (I) oxide, copper (I) perchlorate, iron (I) chloride, iron (I) bromide, and iron (I) iodide.

Examples of the ligand include pyridines, bipyridines, polyamines, and phosphines, unsubstituted or substituted with an alkyl group, an aryl group, an amino group, a halogen group, an ester group, and the like. Examples of the preferable metal catalyst include a copper (I) bipyridyl complex and a copper (I) pentamethyl diethylene triamine complex, which are composed of copper chloride and respective ligands, and an iron (II) triphenyl phosphine complex and an iron (II) tributyl amine complex, which are composed of iron chloride and respective ligands, or others.

The amount of the metal catalyst relative to active reaction sites of the hyperbranched core polymer used in the polymerization of the shell is preferably 0.01 to 70% by mol, and more preferably 0.1 to 60% by mol. When the catalyst is used at this amount, reactivity can be improved, thereby enabling synthesis of a core-shell hyperbranched polymer having a suitable degree of branching.

When the amount of metal catalyst used is below the range, reactivity may be markedly reduced, thereby leading to a risk of the polymerization becoming sluggish. On the other hand, when the amount of metal catalyst used is above the range, the polymerization reaction becomes excessively active and the coupling reaction among radicals at growing terminals tends to occur easily, thereby making control of the polymerization difficult. Further, when the amount of metal catalyst used is above the range, the coupling reaction among radicals induces gelation of the reaction system.

The metal catalyst may be made into a coordination compound by mixing a transition metal compound and a ligand in an apparatus. The metal catalyst composed of a transition metal compound and a ligand may be added to the apparatus in the form of an active coordination compound. Making a coordination compound by mixing a transition metal compound and a ligand in the apparatus is preferable because of operations in the synthesis of the hyperbranched polymer can be simplified.

A method of adding the metal catalyst is not particularly restricted and the metal catalyst may be added, for example, all at once prior to the polymerization of the shell. Further, additional metal catalyst may be added after initiation of the polymerization depending on the level of inactivation of the catalyst. For example, when distribution of a coordination compound forming the metal catalyst in the reaction system is not uniform, the transition metal compound may be added to the apparatus in advance, followed by addition of only a ligand afterwards.

The shell polymerization reaction in the presence of the metal catalyst is carried out preferably in a solvent, though the reaction can occur in the absence of a solvent. The solvent used in the shell polymerization reaction in the presence of the metal catalyst is not particularly restricted. examples of the solvent include a hydrocarbon solvent such as benzene and toluene; an ether solvent such as diethyl ether, tetrahydrofuran, diphenyl ether, anisole, and dimethoxy benzene; a halogenated hydrocarbon solvent such as methylene chloride, chloroform, and chlorobenzene; a ketone solvent such as acetone, methyl ethyl ketone, and methyl isobutyl ketone; an alcohol solvent such as methanol, ethanol, propanol, and isopropanol; a nitrile solvent such as acetonitrile, propionitrile, and benzonitrile; an ester solvent such as ethyl acetate and butyl acetate; a carbonate solvent such as ethylene carbonate and propylene carbonate; and an amide solvent such as N,N-dimethylformamide and N,N-dimethylacetamide. These may be used independently or in a combination of two or more kinds.

In the shell polymerization, it is preferable that the shell polymerization be carried out in the presence of nitrogen, an inert gas, or under the gas flow thereof, and in the absence of oxygen to prevent the effects of oxygen on radicals. The shell polymerization may be carried out in a batch process or a continuous process.

In the shell polymerization, polymerization may be performed using an additive. In the shell polymerization, among compounds represented by formula (1-1) and compounds represented by formula (1-2) depicted in Chapter 1, at least one type may be added.

R₁ in formula (1-1) represents hydrogen, an alkyl group having 1 to 10 carbon atoms, an aryl group having 6 to 10 carbon atoms, or an aralkyl group having 7 to 10 carbon atoms. “A” in formula (1-1) represents a cyano group, a hydroxy group, and a nitro group. Examples of the compound represented by formula (1-1) include nitriles, alcohols, and a nitro compound.

Specific examples of the nitriles included in the compounds represented by formula (1-1) include acetonitrile, propionitrile, butyronitrile, and benzonitrile. Specific examples of the alcohols included in the compounds represented by formula (1-1) include methanol, ethanol, 1-propanol, 2-propanol, 1-buthanol, dicyclohexyl alcohol, and benzyl alcohol. Specific examples of the nitro compound included in the compounds represented by formula (1-1) include nitromethane, nitroethane, nitropropane, and nitrobenzene. The compounds represented by formula (1-1) are not restricted to the above-mentioned compounds.

R₂ and R₃ in formula (1-2) represent hydrogen, an alkyl group having 1 to 10 carbon atoms, an aryl group having 6 to 10 carbon atoms, an aralkyl group having 7 to 10 carbon atoms, or a dialkyl amide group having 1 to 10 carbon atoms. B represents a carbonyl group and a sulfonyl group. R₂ and R₃ in formula (1-2) may be the same or different.

Examples of the compound represented by formula (1-2) include ketones, sulfoxides, and an alkyl formamide compound. Specific examples of the ketones include acetone, 2-butanone, 2-pentanone, 3-pentanone, 2-hexanone, cyclohexanone, 2-methyl cyclohexanone, acetophenone, and 2-methyl acetophenone.

Specific examples of the sulfoxides included in the compounds represented by formula (1-2) include dimethyl sulfoxide and diethyl sulfoxide. Specific examples of the alkyl formamide compound included in the compounds represented by formula (1-2) include N,N-dimethyl formamide, N,N-diethylformamide, and N,N-dibutyl formamide. The compounds represented by formula (1-2) are not restricted to the above-mentioned compounds. Among the compounds represented by formula (1-1) or formula (1-2), nitriles, a nitro compound, ketones, sulfoxides, and an alkyl formamide compound are preferable, while acetonitrile, propionitrile, benzonitrile, nitroethane, nitropropane, dimethyl sulfoxide, acetone, and N,N-dimethyl formamide are more preferable.

In the shell polymerization, compounds represented by formula (1-1) or formula (1-2) may be used singly or in a combination of two or more.

In the shell polymerization, compounds represented by formula (1-1) or formula (1-2) may be used singly or in a combination of two or more as a solvent.

The amount of the compounds represented by formula (1-1) or formula (1-2) to be added in the shell polymerization is preferably 2 times to 10000 times by mol ratio relative to the amount of transition metal in the metal catalyst. The amount of the compounds represented by formula (1-1) or formula (1-2) to be added is more preferably 3 times to 7000 times by mol ratio, and yet more preferably 4 times to 5000 times in mol ratio relative to the amount of transition metal in the metal catalyst.

If the added amount of the compounds represented by formula (1-1) or formula (1-2) is too small, a rapid increase of the molecular weight may not be sufficiently controlled. On the other hand, if the added amount of the compounds represented by formula (1-1) or formula (1-2) is too large, the reaction rate may be slowed, leading to a longer reaction time.

By carrying out the shell polymerization in the way as described above, gelation can be efficiently prevented regardless of concentration of the hyperbranched core polymer. The concentration of the hyperbranched core polymer in the shell polymerization is preferably 0.1 to 30% by mass and more preferably 1 to 20% by mass at the time of charge relative to a total amount of the reaction including the hyperbranched core polymer and monomer.

Concentration of the monomer in the shell polymerization is preferably 0.5 to 20 mol equivalents relative to the active site of the hyperbranched core polymer. More preferably, the concentration of the monomer in the shell polymerization is 1 to 15 mol equivalents relative to the active site of the hyperbranched core polymer. By appropriately controlling the amount of the monomer relative to the active site of the hyperbranched core polymer, the core/shell ratio can be controlled.

The polymerization time in the shell polymerization is preferably 0.1 to 30 hours, more preferably 0.1 to 10 hours, and in particular 1 to 10 hours, depending on a molecular weight of the polymer. Reaction temperature of the shell polymerization is preferably 0 to 200° C. More preferably, the reaction temperature of the shell polymerization is 50 to 150° C. When the polymerization is carried out at a temperature above a boiling point of a solvent used, for example, pressure may be applied in an autoclave.

In the shell polymerization, the reaction system is distributed uniformly. For example, the reaction system is distributed uniformly by agitating the reaction system. As a specific agitation condition in the shell polymerization, the power required for agitation per unit volume is preferably, for example, 0.01 kW/m³ or more.

In the shell polymerization, additional catalyst or a reducing agent to regenerate the catalyst may be added according to the progress of the polymerization and degree of catalyst inactivation. The shell polymerization is stopped when the molecular weight reaches the point prescribed in the shell polymerization. A method of stopping the shell polymerization is not particularly restricted, and such a method as inactivating the catalyst, for example, by cooling or by adding an oxidizing agent, a chelating agent, or others may be used.

In the synthesis of the core-shell hyperbranched polymer, removal of the metal catalyst, removal of monomers, and removal of trace metal are performed after the shell polymerization. The metal catalyst is removed after the shell polymerization is over. Removal of the metal catalyst may be done, for example, by the following (a) to (c) methods singly or in a combination thereof.

(a) Use various kinds of adsorbents, such as Kyoward manufactured by Kyowa Chemical Industry Co., Ltd.
(b) Remove insoluble matters by filtration and centrifugal separation.
(c) Extract by an aqueous solution containing any one of an acid and a substance having a chelating effect or both.

Examples of the acid used in the method (c) include p-toluene sulfonic acid, acetic acid, trifluoroacetic acid, trifluoromethane sulfonic acid, formic acid, hydrochloric acid, and sulfuric acid. Examples of the substance having a chelating effect include an organic acid such as oxalic acid, citric acid, gluconic acid, tartaric acid, and malonic acid; an amino carbonate such as nitrilotriacetic acid, ethylenediaminetetraacetic acid, and diethylenetriamine pentaacetic acid; and a hydroxyamino carbonate. Concentration of the acid in an aqueous solution is preferably 0.03 to 20% by mass, though different depending on the kind of the acid. Concentration of the substance having a chelating capacity in an aqueous solution is preferably, for example, 0.05 to 10% by mass, though different depending on the chelating capacity of the substance. Each of the acids and the substances having a chelating capacity may be used singly or in a combination thereof.

Removal of the monomers may be done after having removed the metal catalyst or after having removed trace metal (sometimes referred to as “metal washing” in the present description) which is preceded by the removal of the metal catalyst. In the removal of monomers, unreacted monomers of the monomers added dropwise in the core polymerization and the shell polymerization are removed. Removal of unreacted monomers may be done, for example, by the following (d) to (e) methods singly or in a combination thereof.

(d) Precipitate a polymer by adding a poor solvent to a reaction matter dissolved in a good solvent.
(e) Wash a polymer by a mixed solvent of a good solvent and a poor solvent.

In the above (d) to (e), examples of the good solvent include a hydrocarbon, a halogenated hydrocarbon, a nitro compound, a nitrile, an ether, a ketone, an ester, a carbonate, and a mixture thereof. Specific examples include tetrahydrofuran, toluene, xylene, chlorobenzene, and chloroform. Examples of the poor solvent include methanol, ethanol, 1-propanol, 2-propanol, water, and a mixture thereof.

After monomers are removed as described above, drying is performed. Drying may also be performed after removal of trace metal which is preceded by removal of monomers. In the embodiment, the drying step is realized here. The drying method is not particularly restricted and may include such drying methods as vacuum drying and spray drying. In the drying, the temperature of the environment (hereinafter, “drying temperature”) in which the core-shell hyperbranched polymer obtained after removal of monomers and the core-shell hyperbranched polymer are present is preferably 10 to 70° C. In the drying process, the drying temperature is more preferably 15 to 40° C.

In the drying process, it is preferable to evacuate the environment in which the hyperbranched polymer obtained after removal of monomers is present. The degree of the vacuum in the drying process is preferably 20 Pa ore less. The drying time is preferably 1 to 20 hours, and more preferably 1 to 12 hours. Here, the degree of the vacuum and a drying time are not restricted to the above-mentioned values, and are chosen in such a manner as to maintain the drying temperature appropriately.

In the synthesis of the core-shell hyperbranched polymer, trace metal remaining in the polymer is removed after removal of the metal catalyst and removal of monomers as described above. Removal of trace metal may be done, for example, by the following (f) to (g) methods singly or in a combination thereof.

(f) Extract by a liquid-liquid extraction using any one of an aqueous solution containing an organic compound having a chelating capacity, an aqueous solution of an acid, and pure water or all.
(g) Use an adsorbent and an ion-exchange resin.

Examples of the organic solvent preferably used for the liquid-liquid extraction in the method (f) include a halogenated hydrocarbon such as chlorobenzene and chloroform; acetate esters such as ethyl acetate, n-butyl acetate, and isoamyl acetate; ketones such as methyl ethyl ketone, methyl isobutyl ketone, cyclohexanone, 2-heptane, and 2-pentanone; glycol ether acetates such as ethyleneglycol monoethyl ether acetate, ethyleneglycol monobutyl ether acetate, ethyleneglycol monomethyl ether acetate; and aromatic hydrocarbons such as toluene and xylene.

Examples of the organic solvent more preferably used for the liquid-liquid extraction in the method (f) include chloroform, methyl isobutyl ketone, and ethyl acetate. These solvents may be used singly or in a combination two or more. In the liquid-liquid extraction of the method (f), the amount of the core-shell hyperbranched polymer relative to the organic solvent is preferably about 1 to about 30% by mass. More preferably, the amount of the core-shell hyperbranched polymer relative to the organic solvent is about 5 to about 20% by mass.

Examples of the organic compound having an chelating capacity used in the method (f) of the liquid-liquid extraction include an organic acid such as oxalic acid, citric acid, gluconic acid, tartaric acid, and malonic acid; an amino carbonate such as nitrilotriacetic acid, ethylenediaminetetraacetic acid, and diethylenetriamine pentaacetic acid; and a hydroxyamino carbonate. Examples of the acid used in the method (f) of the liquid-liquid extraction include formic acid, acetic acid, phosphoric acid, hydrochloric acid, and sulfuric acid.

In the liquid-liquid extraction using the method (f), a concentration of the organic compound having a chelating capacity and the acid in the aqueous solution is preferably, for example, 0.05 to 10% by mass.

In the method of removing trace metal, when an aqueous solution containing an organic compound having a chelating capacity is used, a mixture of the aqueous solution containing the organic compound having a chelating capacity and the aqueous solution containing the acid may be used, or the aqueous solution containing the organic compound having a chelating capacity and the aqueous solution containing the acid may be used separately. When the aqueous solution containing the organic compound having a chelating capacity and the aqueous solution containing the inorganic acid are used separately, any of the aqueous solution containing the organic compound having a chelating capacity and the aqueous solution containing the inorganic acid may be used first.

In removing trace metal, when the aqueous solution containing the organic compound having a chelating capacity and the aqueous solution containing the acid are used separately, it is more preferable to use the aqueous solution containing the acid later. This is because the aqueous solution containing the organic compound having a chelating capacity is effective to remove a copper catalyst and multivalent metal, and the aqueous solution containing the acid is effective to remove monovalent metal derived from experimental equipment and the like.

The number of the extractions is not particularly restricted, but preferably 2 to 5 times, for example. To avoid contamination by metals derived from experimental equipment, it is preferable to use pre-washed experimental equipment particularly when they are used in the state of a reduced copper ion. A method for the pre-washing is not particularly restricted, and for example, may include washing by an aqueous nitric acid.

The number of washings solely by the aqueous solution containing the acid is preferably 1 to 5 times. When the washing solely by the aqueous acidic solution is performed 1 to 5 times, monovalent metal can be removed sufficiently. Further, to remove residual acid components, it is preferable to perform the extraction treatment by pure water last to remove the acid completely. The number of washings by pure water is preferably 1 to 5 times. When the washing by pure water is performed 1 to 5 times, residual acid can be removed sufficiently.

In the removal of trace metal, each ratio of the solution containing the core-shell hyperbranched polymer to the aqueous solution containing the organic compound having a chelating capacity, to an aqueous solution containing the acid, and to pure water is preferably 1:0.1 to 1:10 by volume. More preferably, the ratio of the above is 1:0.5 to 1:5 by volume. When the washing is done by using the solvent with such ratios, metals can be easily removed by a moderate number of washings. Thus, operations can be made easy and simple, and thus, is preferable in view of an efficient synthesis of the hyperbranched polymer. Usually, the concentration by mass of a resist polymer intermediate dissolved in the reaction solvent is preferably about 1 to about 30% by mass relative to the solvent.

The liquid-liquid extraction treatment in the method (f) is done, for example, by separating the mixed solvent composed of the reaction solvent and the aqueous solution containing the organic compound having a chelating capacity, the aqueous solution containing the inorganic acid, or a pure water (hereinafter, simply “mixed solvent”) into two layers, and then removing a water layer containing migrated metal ions by a decantation and the like.

Separation of the mixed solvent into two layers may be done, for example, by the following method: into the reaction solvent are added the aqueous solution containing the organic compound having a chelating capacity, the aqueous solution containing the inorganic acid, or pure water, and all are mixed thoroughly by agitation and the like, and subsequently, are allowed to stand. Also, separation of the mixed solvent into two layers may be done by centrifugal separation, for example.

The liquid-liquid extraction treatment in the method (f) is preferably done, for example, at a temperature of 10 to 50° C. The liquid-liquid extraction treatment in the method (f) is more preferably done at 20 to 40° C.

In the synthesis of the core-shell hyperbranched polymer, the deprotection is carried out after metals are removed. In the deprotection, a part of the acid-decomposable group is decomposed (the acid-decomposable group is directed) to the acid group by using the acid catalyst. In the decomposition of a part of the acid-decomposable group to the acid group, usually the acid catalyst of 0.001 to 0.1 equivalent to the acid-decomposable group in the core-shell hyperbranched polymer is used. In the decomposition of a part of the acid-decomposable group to the acid group, a substance, which is dissolved into an organic solvent homogeneously together with the hyperbranched polymer obtained after removal of trace metal as described above and the hyperbranched polymer, is used as the acid catalyst.

Specific examples of the acid catalyst preferably used for the deprotection include hydrochloric acid, sulfuric acid, phosphoric acid, p-toluene sulfonic acid, acetic acid, trifluoroacetic acid, and trifluoromethane sulfonic acid. Among various kinds of acids as described above, hydrochloric acid and sulfuric acid are more preferable because of good reactivity. Sulfuric acid is more preferable because there is no risk of evaporation by heating with reflux, and in addition, it is homogeneously miscible, regardless of temperature, with a solvent into which the hyperbranched polymer obtained after removal of trace metal and the hyperbranched polymer are dissolvable.

An organic solvent used in the deprotection is preferably the one which can dissolve the hyperbranched polymer and the acid catalyst, and also is miscible with water regardless of temperature. In view of availability and ease handling, the organic solvent used in the deprotection is more preferably one selected among 1,4-dioxane, tetrahydrofuran, methyl ethyl ketone, methyl isobutyl ketone, diethyl ketone, and a mixture thereof. Among various kinds of organic solvents as described above, as the organic solvent used in the deprotection, dioxane is preferable because in it a reflux at high temperature, for example, a temperature above 90° C., is possible and in addition it is highly miscible with water.

In the synthesis of the hyperbranched polymer, a high temperature reflux is indispensable to realize the effect of the acid to the maximum extent thereby enabling to perform the acidic decomposition efficiently. The water-miscibility of the organic solvent used in the synthesis of the core-shell hyperbranched polymer is an indispensable element when the re-precipitation operation is performed by adding excess water into the organic solvent after the acidic decomposition.

The amount of the organic solvent used in the deprotection is not particularly restricted as far as the core-shell hyperbranched polymer obtained after removal of the metals as described above and the acid catalyst are dissolved therein, though the amount is preferably, for example, 3 to 50 times by mass and more preferable 5 to 20 times by mass relative to the polymer.

When the amount of the organic solvent relative to the core-shell hyperbranched polymer obtained after the metal removal is below the above-mentioned range, the viscosity of the reaction system is increased, resulting in poor handling. When the amount of the organic solvent relative to the core-shell hyperbranched polymer obtained after the metal removal is above the range, it tends to increase the synthesis cost, and thus, is not preferable in view of increased cost.

Concentration of the core-shell hyperbranched polymer obtained after removal of the metal in the organic solvent used in the deprotection is preferably as high as possible with the conditions that the concentration is below the saturated dissolution concentration of the core-shell hyperbranched polymer at room temperature (25° C.) and the agitation is not affected by a remarkable increase in the viscosity when heated for the reaction. The temperature for the deprotection is preferably 50 to 150° C., and more preferably 70 to 110° C. The time for the deprotection is preferably 10 minutes to 20 hours, and more preferably 10 minutes to 3 hours.

Concerning the ratio of the acid-decomposable group to the acid group in the core-shell hyperbranched polymer obtained after deprotection, preferably 5 to 80% by mol of the monomer having the acid-decomposable group introduced into the core-shell hyperbranched polymer is de-protected to the acid group. When the ratio of the acid-decomposable group to the acid group is at this range, a high sensitivity and an efficient dissolution into a basic solution after the light exposure are realized, thus, is preferable.

The ratio of the acid-decomposable group to the acid group in the core-shell hyperbranched polymer obtained after deprotection is not restricted particularly to the range described above. The optimum value is dependent on the composition ratio of a resist composition when the core-shell hyperbranched polymer is used for a resist composition. The ratio of the acid-decomposable group to the acid group in the core-shell hyperbranched polymer after deprotection may be controlled by controlling the reaction time.

The ratio of the acid-decomposable group to the acid group in the hyperbranched polymer obtained after de-composition may be controlled by appropriately controlling the amount of the acid catalyst used in deprotection, and the temperature and the reaction time of the deprotection. The easiest control may be done by the reaction time.

After deprotection, a solution containing the core-shell hyperbranched polymer after deprotection is mixed with ultrapure water to precipitate the core-shell hyperbranched polymer obtained after the deprotection. Then, the polymer is separated by methods such as centrifugal separation, filtration, and decantation. To remove residual acid catalyst, it is preferable to wash the polymer by contact with an organic solvent, and when necessary, with water.

Drying as described above may be done prior to the shell polymerization, at the time when the polymer is obtained by the core polymerization (hyperbranched core polymer). By doing the drying between the core polymerization and the shell polymerization, the polymer (hyperbranched core polymer) in a state of suppressed gelation may be provided to the shell polymerization. Thus, the gelation in the shell polymerization can be suppressed surely.

Drying as described above may also be done after partial decomposition of the acid-decomposable group. Thus, the gelation of the core-shell hyperbranched polymer in which the shell portion composed of the acid decomposable group and the acid group is attached to the hyperbranched polymer described above may be suppressed more surely.

### (Molecular Structure)

A molecular structure of the core-shell hyperbranched polymer will be explained. The degree of branching (Br) of the core portion in the core-shell hyperbranched polymer is preferably 0.3 to 0.5, and more preferably 0.4 to 0.5. When the degree of branching (Br) of the core portion in the core-shell hyperbranched polymer is at the above-mentioned range, an intermolecular entanglement among the polymers is small, thereby suppressing a surface roughness in the pattern wall, and thus, is preferable.

The degree of branching (Br) of the hyperbranched core polymer in the core-shell hyperbranched polymer may be obtained by measuring ¹H-NMR of the product. Namely, it can be calculated by computing equation (A) as mentioned in the embodiment in Chapter 1 by using H1°, the integral ratio of protons in —CH₂Cl appearing at 4.6 ppm, and H2°, the integral ratio of the protons in —CHCl appearing at 4.8 ppm. When the polymerization progresses at both —CH₂Cl and —CHCl thereby enhancing the branching, the degree of branching (Br) approaches to 0.5.

The weight-average molecular weight (Mw) of the hyperbranched core polymer is preferably 300 to 8,000, more preferably 500 to 6,000, and most preferably 1,000 to 4,000. When the weight-average molecular weight of the hyperbranched core polymer is at such ranges, solubility into the reaction solvent is secured in the reaction to introduce the acid-decomposable group, and thus, is preferable. In addition, performance of a film-formation is excellent and dissolution of an unexposed part is prevented from occurring advantageously in the core-shell hyperbranched polymer whose acid-decomposable group is partially decomposed (acid-decomposable group is introduced) after the acid-decomposable group is introduced into the hyperbranched core polymer having the molecular weight at the above-mentioned range, and thus, is preferable.

The degree of multi-dispersion (Mw/Mn) of the hyperbranched core polymer is preferably 1 to 3, and more preferably 1 to 2.5. In the case where the degree of multi-dispersion (Mw/Mn) of the hyperbranched core polymer is at this range, when the core-shell hyperbranched polymer synthesized by using the hyperbranched core polymer is used as a resist composition, there is no risk of adverse effects such as insolubilization of the core-shell hyperbranched polymer after a light exposure, and thus, is preferable.

Weight-average molecular weight (M) of the core-shell hyperbranched polymer is preferably 500 to 21,000, more preferably 2,000 to 21,000, and most preferably 3,000 to 21,000. When the weight-average molecular weight (M) of the core-shell hyperbranched polymer is at this range, a resist containing the hyperbranched polymer is excellent in a film formation and can maintain its form because the process pattern formed in a lithography step is strong. In addition, a resist composition containing the core-shell hyperbranched polymer as described above is excellent in the dry-etching resistance and the surface roughness.

The weight-average molecular weight (Mw) of the hyperbranched core polymer may be obtained by a GPC measurement using a 0.5% by mass solution of tetrahydrofuran at 40° C. Tetrahydrofuran may be used as a moving phase and styrene as a standard material.

The weight-average molecular weight (M) of the core-shell hyperbranched polymer is obtained as following; an introduction ratio (composition ratio) of each repeating unit in the polymer into which the acid-decomposable group is introduced is obtained by ¹H-NMR, and, based on the weight-average molecular weight (Mw) of the core portion in the core-shell hyperbranched polymer, a calculation is made by using the introduction ratio of each composition unit and the molecular weight of each composition unit.

The core-shell hyperbranched polymer synthesized described above is used for a resist composition, for example. In the resist composition using the core-shell hyperbranched polymer (hereinafter, simply “resist composition”), a compounding amount of the core-shell hyperbranched polymer is preferably 4 to 40 weight %, more preferably 4 to 20 weight % relative to total amount of the resist composition.

The resist composition contains the core-shell hyperbranched polymer above and a photo-inductive acid-generating material. The resist composition may further contain, as needed, an acid-diffusion suppressor (an acid scavenger), a surfactant, other components, a solvent, and the like.

There is no particular restriction in terms of photo-inductive acid-generating material contained in the resist composition provided acid is generated upon exposure to UV light, an X-ray beam, an electron beam, and the like, and may be selected appropriately from among commonly known photo-inductive acid-generating materials according to purpose. Specific examples of the photo-inductive acid-generating material include onium salt, sulfonium salt, a halogen-containing triazine compound, a sulfone compound, a sulfonate compound, an aromatic sulfonate compound, and an N-hydroxyimide sulfonate compound.

Examples of onium salt included in the photo-inductive acid-generating material include a diaryl iodonium salt, a triaryl selenonium salt, and a triaryl sulfonium salt. Examples of diaryl iodonium salt include diphenyl iodonium trifluoromethane sulfonate, 4-methoxyphenyl phenyl iodonium hexafluoroantimonate, 4-methoxyphenyl phenyl iodonium trifluoromethane sulfonate, bis(4-tert-butylphenyl)iodonium tetrafluoroborate, bis(4-tert-butylphenyl)iodonium hexafluorophosphate, bis(4-tert-butylphenyl)iodonium hexafluoroantimonate, and bis(4-tert-butylphenyl)iodonium trifluoromethane sulfonate.

Specific examples of triaryl selenonium salt included in onium salt include triphenyl selenonium hexafluorophosphoric salt, triphenyl selenonium tetrafluoroborate salt, and triphenyl selenonium hexafluoroantimonate salt. Examples of triaryl sulfonium salt included in onium salt include triphenyl sulfonium hexafluorophosphoric salt, triphenyl sulfonium hexafluoroantimonate salt, diphenyl-4-thiophenoxyphenyl sulfonium hexafluoroantimonate salt, and diphenyl-4-thiophenoxyphenyl sulfonium pentafluorohydroxy antimonate salt.

Examples of sulfonium salt included in the photo-inductive acid-generating material include triphenyl sulfonium hexafluorophosphate, triphenyl sulfonium hexafluoroantimonate, triphenyl sulfonium trifluoromethane sulfonate, 4-methoxyphenyl diphenyl sulfonium hexafluoroantimonate, 4-methoxyphenyl diphenyl sulfonium trifluoromethane sulfonate, p-tolyldiphenyl sulfonium trifluoromethane sulfonate, 2,4,6-trimethylphenyl diphenyl sulfonium trifluoromethane sulfonate, 4-tert-butylphenyl diphenyl sulfonium trifluoromethane sulfonate, 4-phenylthiophenyl diphenyl sulfonium hexafluorophosphate, 4 phenylthiophenyl diphenyl sulfonium hexafluoroantimonate, 1-(2-naphthoylmethyl)thioranium hexafluoroantimonate, 1-(2-naphthoylmethyl)thioranium trifluoroantimonate, 4-hydroxy-1-naphthyl dimethyl sulfonium hexafluoroantimonate, and 4-hydroxy-1-naphthyl dimethyl sulfonium trifluoromethane sulfonate.

Specific examples of a halogen-containing triazine compound included in the photo-inductive acid-generating material include 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2-(4-chlorophenyl)-4,6-bis(trichloromethyl)-1,3,5-triazine, 2-(4-methoxyphenyl)-4,6-bis(trichloromethyl)-1,3,5-triazine, 2-(4-methoxy-1-naphthyl)-4,6-bis(trichloromethyl)-1,3,5-triazine, 2-(benzo[d][1,3]dioxolane-5-yl)-4,6-bis(trichloromethyl)-1,3,5-triazine, 2-(4-methoxystyryl)-4,6-bis(trichloromethyl)-1,3,5-triazine, 2-(3,4,5-trimethoxystyryl)-4,6-bis(trichloromethyl)-1,3,5-triazine, 2-(3,4-dimethoxystyryl)-4,6-bis(trichloromethyl)-1,3,5-triazine, 2-(2,4-dimethoxystyryl)-4,6-bis(trichloromethyl)-1,3,5-triazine, 2-(2-methoxystyryl)-4,6-bis(trichloromethyl)-1,3,5-triazine, 2-(4-butoxystyryl)-4,6-bis(trichloromethyl)-1,3,5-triazine, and 2-(4-benzyloxystyryl)-4,6-bis(trichloromethyl)-1,3,5-triazine.

Specific examples of the sulfone compound included in the photo-inductive acid-generating material include diphenyl disulfone, di-p-tolyl disulfone, bis(phenylsulfonyl)diazomethane, bis(4-chlorophenylsulfonyl)diazomethane, bis(p-tolylsulfonyl)diazomethane, bis(4-tert-butylphenylsulfonyl)diazomethane, bis(2,4-xylylsulfonyl)diazomethane, bis(cyclohexylsulfonyl)diazomethane, (benzoyl)(phenylsulfonyl)diazomethane, and phenylsulfonyl acetophenone.

Specific examples of the aromatic sulfonate compound included in the photo-inductive acid-generating material include α-benzoylbenzyl p-toluene sulfonate (common name: benzoin tosylate), β-benzoyl-β-hydroxyphenetyl p-toluene sulfonate (common name: α-methylol benzoin tosylate), 1,2,3-benzenetriyl trismethane sulfonate, 2,6-dinitrobenzyl p-toluene sulfonate, 2-nitrobenzyl p-toluene sulfonate, and 4-nitrobenzyl p-toluene sulfonate.

Specific examples of the N-hydroxyimide sulfonate compound included in the photo-inductive acid-generating material include N-(phenylsulfonyloxy)succinimide, N-(trifluoromethylsulfonyloxy)succinimide, N-(p-chlorophenylsulfonyloxy)succinimide, N-(cyclohexylsulfonyloxy)succinimide, N-(1-naphthylsulfonyloxy)succinimide, N-(benzylsulfonyloxy)succinimide, N-(10-camphorsulfonyloxy)succinimide, N-(trifluoromethylsulfonyloxy)phthalimide, N-(trifluoromethylsulfonyloxy)-5-norbornene-2,3-dicarboxylmide, N-(trifluoromethylsulfonyloxy)naphthalimide, and N-(10-camphorsulfonyloxy)naphthalimide.

Among various kinds of the photo-inductive acid-generating material as described above, sulfonium salt is preferable, in particular, triphenyl sulfonium trifluoromethane sulfonate; and sulfone compounds, in particular, bis(4-tert-butylphenylsulfonyl)diazomethane and bis(cyclohexylsulfonyl)diazomethane.

The photo-inductive acid-generating material may be used independently or in a combination of two or more. There is no particular restriction in the blending ratio of the photo-inductive acid-generating material, and the blending ratio may be appropriately determined according to purpose, though it is preferably 1 to 30 parts by weight relative to 100 parts by weight of the hyperbranched polymer. More preferably, the blending ratio of the photo-inductive acid-generating material is 0.1 to 10 parts by weight.

There is no particular restriction in the acid-diffusion suppressor contained in the resist composition provided the acid-diffusion suppressor is a component having functions to control the diffusion of acid generated from the photo-inductive acid-generating material in a resist film and to suppress undesired chemical reactions in non-exposed regions. The acid-diffusion suppressor contained in the resist composition may be appropriately selected from various kinds of commonly known acid-diffusion suppressors according to purpose.

Examples of acid-diffusion suppressors contained in the resist composition include a compound having one nitrogen atom in a single molecule, a compound having two nitrogen atoms in a single molecule, a polyamino compound and a polymer thereof having three nitrogen atoms or more in a single molecule, an amide-containing compound, an urea compound, and a nitrogen-containing heterocyclic compound.

Examples of compounds having one nitrogen atom in a single molecule cited as an acid-diffusion suppressor include a mono(cyclo)alkyl amine, a di(cyclo)alkyl amine, a tri(cyclo)alkyl amine, and an aromatic amine. Specific examples of mono(cyclo)alkyl amine include n-hexyl amine, n-heptyl amine, n-octyl amine, n-nonyl amine, n-decyl amine, and cyclohexyl amine.

Examples of di(cyclo)alkyl amine included in compounds having one nitrogen atom in a single molecule include di-n-butyl amine, di-n-pentyl amine, di-n-hexyl amine, di-n-heptyl amine, di-n-octyl amine, di-n-nonyl amine, di-n-decyl amine, and cyclohexyl methyl amine.

Examples of tri(cyclo)alkyl amine included in compounds having one nitrogen atom in a single molecule include triethyl amine, tri-n-propyl amine, tri-n-butyl amine, tri-n-pentyl amine, tri-n-hexyl amine, tri-n-heptyl amine, tri-n-octyl amine, tri-n-nonyl amine, tri-n-decyl amine, cyclohexyl dimethyl amine, methyl dicyclohexyl amine, and tricyclohexyl amine.

Examples of aromatic amine included in compounds having one nitrogen atom in a single molecule include aniline, N-methyl aniline, N,N-dimethyl aniline, 2-methyl aniline, 3-methyl aniline, 4-methyl aniline, 4-nitroaniline, diphenyl amine, triphenyl amine, and naphthyl amine.

Examples of compounds having two nitrogen atoms in a single molecule cited as an acid-diffusion suppressor include ethylenediamine, N,N,N′,N′-tetramethyl ethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, and bis(2-diethylaminoethyl)ether.

Examples of polyamino compounds and polymers thereof having three nitrogen atoms or more in a single molecule and cited as an acid-diffusion suppressor include poly(ethylene imine), poly(allyl amine), and a polymer of N-(2-dimethylaminoethyl)acrylamide.

Examples of amide-containing compounds cited as an acid-diffusion suppressor include N-tert-buthoxycarbonyl di-n-octylamine, N-tert-buthoxycarbonyl di-n-nonylamine, N-tert-buthoxycarbonyl di-n-decylamine, N-tert-buthoxycarbonyl dicyclohexylamine, N-tert-buthoxycarbonyl-1-adamantylamine, N-tert-buthoxycarbonyl-N-methyl-1-adamantylamine, N,N-di-tert-buthoxycarbonyl-1-adamantylamine, N,N-di-tert-buthoxycarbonyl-N-methyl-1-adamantylamine, N-tert-buthoxycarbonyl-4,4-diaminodiphenylmethane, N,N′-di-tert-buthoxycarbonyl hexamethylenediamine, N,N,N′,N′-tetra-tert-buthoxycarbonyl hexamethylenediamine, N,N′-di-tert-buthoxycarbonyl-1,7-diaminoheptane, N,N′-di-tert-buthoxycarbonyl-1,8-diaminooctane, N,N′-di-tert-buthoxycarbonyl-1,9-diaminononane, N,N-di-tert-buthoxycarbonyl-1,10-diaminodecane, N,N-di-tert-buthoxycarbonyl-1,12-diaminododecane, N,N-di-tert-buthoxycarbonyl-4,4′-diaminodiphenylmethane, N-tert-buthoxycarbonyl benzimidazole, N-tert-buthoxycarbonyl-2-methyl benzimidazole, N-tert-buthoxycarbonyl-2-phenyl benzimidazole, formamide, N-methyl formamide, N,N-dimethyl formamide, acetamide, N-methyl acetamide, N,N-dimethyl acetamide, propionamide, benzamide, pyrrolidone, and N-methylpyrrolidone.

Specific examples of urea compounds cited as an acid-diffusion suppressor include urea, methyl urea, 1,1-dimethyl urea, 1,3-dimethyl urea, 1,1,3,3-tetramethyl urea, 1,3-diphenyl urea, and tri-n-butyl thiourea.

Specific examples of nitrogen-containing heterocyclic compounds cited as an acid-diffusion suppressor include imidazole, 4-methyl imidazole, 4-methyl-2-phenyl imidazole, benzimidazole, 2-phenyl benzimidazole, pyridine, 2-methyl pyridine, 4-methylpyridine, 2-ethyl pyridine, 4-ethyl pyridine, 2-phenyl pyridine, 4-phenyl pyridine, 2-methyl-4-phenyl pyridine, nicotine, nicotinic acid, nicotinic acid amide, quinoline, 4-hydroxy quinoline, 8-oxy quinoline, acridine, piperadine, 1-(2-hydroxyethyl)piperadine, pyrazine, pyrazole, pyridazine, quinozalin, purine, pyrrolidine, piperidine, 3-piperidino-1,2-propanediol, morpholine, 4-methyl morpholine, 1,4-dimethyl piperadine, and 1,4-diazabicyclo[2.2.2]octane.

The acid-diffusion suppressor may be used independently or in a combination of two or more. The blending amount of the acid-diffusion suppressor is preferably 0.1 to 1000 parts by weight relative to 100 parts by weight of the photo-inductive acid-generating material. More preferable blending amount of the acid-diffusion suppressor is 0.5 to 10 parts by weight relative to 100 parts by weight of the photo-inductive acid-generating material. Here, there is no particular restriction in the blending amount of the acid-diffusion suppressor and the amount may be appropriately chosen according to purpose.

Examples of surfactant contained in the resist composition include a polyoxyethylene alkyl ether, a polyoxyethylene alkyl aryl ether, a sorbitan fatty acid ester, a nonionic surfactant of a polyoxyethylene sorbitan fatty acid ester, a fluoro-surfactant, and a silicon-surfactant. There is no particular restriction in the surfactant contained in the resist composition provided the surfactant is a component exhibiting improved functions in coating properties, striation, developing properties, and the like, and may be appropriately selected from commonly known surfactants according to purpose.

Specific examples of polyoxyethylene alkyl ethers cited as a surfactant contained in the resist composition include polyoxyethylene lauryl ether, polyoxyethylene stearyl ether, polyoxyethylene cetyl ether, and polyoxyethylene oleyl ether. Specific examples of polyoxyethylene alkyl aryl ethers cited as the surfactant contained in the resist composition include polyoxyethylene octylphenol ether and polyoxyethylene nonylphenol ether.

Specific examples of sorbitan fatty acid esters cited as the surfactant contained in the resist composition include sorbitan monolaurate, sorbitan monopalmitate, sorbitan monostearate, sorbitan monooleate, sorbitan trioleate, and sorbitan tristearate. Specific examples of the nonionic surfactant of the polyoxyethylene sorbitan fatty acid ester cited as the surfactant contained in the resist composition include polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate.

Specific examples of the fluoro-surfactant cited as the surfactant contained in the resist composition include EFTOP EF301, EF303, and EF352 (manufactured by Shin Akita Kasei Co., Ltd.), MEGAFAC F171, F173, F176, F189, and R08 (manufactured by DIC Corp.), Fluorade FC430 and FC431 (manufactured by Sumitomo 3M Ltd.), and Asahi Guard AG710, Surflon S-382, SC101, SX102, SC103, SC104, SC105, and SC106 (manufactured by Asahi Glass Co., Ltd.).

Specific examples of silicon-surfactants cited as the surfactant contained in the resist composition include organosiloxane polymer KP341 (manufactured by Shin-Etsu Chemical Co., Ltd.). Various kinds of the surfactant cited above may be used independently or in a combination of two or more.

The blending amount of the various kinds of surfactant is preferably, for example, 0.0001 to 5 parts by weight relative to 100 parts by weight of the hyperbranched polymer. More preferably, the blending amount of the various kinds of the surfactant is 0.0002 to 2 parts by mass relative to 100 parts by mass of the hyperbranched polymer formed by the synthesis method of the present invention. There is no particular restriction in the blending amount of the various kinds of surfactant and the amount may be appropriately chosen according to purpose.

Examples of other components contained in the resist composition include a sensitizer, a dissolution-control material, an additive having an acid-dissociating group, a resin that is dissolvable in a basic solution, a dye, a pigment, an adhesive adjuvant, a defoamer, a stabilizer, and an anti-halation agent. Specific examples of sensitizers cited as other components contained in the resist composition include acetophenones, benzophenones, naphthalenes, biacetyl, eosin, rose bengal, pyrenes, anthracenes, and phenothiazines.

There is no particular restriction in the sensitizer provided the sensitizer absorbs the energy of radioactive ray and transmits the energy to the photo-inductive acid-generating material, thereby increasing the amount of acid generated and effecting an apparent sensitivity of the resist composition. The sensitizers may be used independently or in a combination of two or more.

Specific examples of dissolution-control materials cited as other components contained in the resist composition include a polyketone and a polyspiroketal. There is no particular restriction in the dissolution-control material cited as other components contained in the resist composition provided the material appropriately controls the dissolution contrast and the dissolution rate when the resist is formed. The dissolution-control materials cited as other components contained in the resist composition may be used independently or in a combination of two or more.

Specific examples of additives having the acid-dissociation group cited and as other components contained in the resist composition include tert-butyl 1-adamantanecarboxylate, tert-buthoxycarbonylmethyl 1-adamantanecarboxylate, di-tert-butyl 1,3-adamantanedicarboxylate, tert-butyl 1-adamantaneacetate, tert-buthoxycarbonylmethyl 1-adamantaneacetate, di-tert-butyl 1,3-adamantanediacetate, tert-butyl deoxycholate, tert-buthoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, mevalonolactone deoxycholate, tert-butyl lithocholate, tert-buthoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate. The various kinds of additive having an acid-dissociating group as described above may be used independently or in a combination of two or more. There is no particular restriction in the various kinds of additive having an acid-dissociating group provided the additive further improves the dry-etching resistance, pattern formation, adhesion with a substrate, and the like.

Specific examples of resin dissolvable in a basic solution cited as other components contained in the resist composition include poly(4-hydroxystyrene), partially hydrogenated poly(4-hydroxystyrene), poly(3-hydroxystyrene), 4-hydroxystyrene/3-hydroxystyrene copolymer, 4-hydroxystyrene/styrene copolymer, novolak resin, poly(vinyl alcohol), and poly(acrylic acid). The weight-average molecular weight (Mw) of the resin that is dissolvable in a basic solution is usually 1,000 to 1,000,000, and preferably 2,000 to 100,000.

The resin dissolvable in a basic solution may be used independently or in a combination of two or more. There is no particular restriction in the resin dissolvable in a basic solution cited as other components contained in the resist composition provided the resin improves the solubility of the resin composition of the present invention into a basic solution.

The dye or the pigment cited as other components contained in the resist composition visualizes a latent image in the exposed part. By visualizing a latent image in the exposed part, the effect of a halation during exposure to a light may be reduced. The adhesive adjuvant cited as other components contained in the resist composition may improve adhesion between the resist composition and a substrate.

Specific examples of solvents cited as other components contained in the resist composition include a ketone, a cyclic ketone, a propyleneglycol monoalkyl ether acetate, an alkyl 2-hydroxypropionate, an alkyl 3-alkoxypropionate, and other solvents. There is no particular restriction in the solvent cited as other components contained in the resist composition provided the solvent can dissolve the other components and the like contained in the resist composition, and the solvent may be appropriately selected from solvents safely usable.

Specific examples of ketones cited as other components contained in the resist composition include methyl isobutyl ketone, methyl ethyl ketone, 2-butanone, 2-pentanone, 3-methyl-2-butanone, 2-hexanone, 4-methyl-2-pentanone, 3-methyl-2-pentanone, 3,3-dimethyl-2-butanone, 2-heptanone, and 2-octanone.

Specific examples of the cyclic ketone contained in the solvent cited as other components contained in the resist composition include cyclohexanone, cyclopentanone, 3-methyl cyclopentanone, 2-methyl cyclohexanone, 2,6-dimethyl cyclohexanone, and isophorone.

Specific examples of the propyleneglycol monoalkyl ether acetate included in the solvent cited as other components contained in the resist composition include propyleneglycol monomethyl ether acetate, propyleneglycol monoethyl ether acetate, propyleneglycol mono-n-propyl ether acetate, propyleneglycol mono-i-propyl ether acetate, propyleneglycol mono-n-butyl ether acetate, propyleneglycol mono-i-butyl ether acetate, propyleneglycol mono-sec-butyl ether acetate, and propyleneglycol mono-tert-butyl ether acetate.

Specific examples of the alkyl 2-hydroxypropionate included in the solvent cited as other components contained in the resist composition include methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate, and tert-butyl 2-hydroxypropionate.

Specific examples of the alkyl 3-alkoxypropionate included in the solvent cited as other components contained in the resist composition include methyl 3-methoxypropionate, ethyl 3-methoxypropionate, methyl 3-ethoxypropionate, and ethyl 3-ethoxypropionate.

Examples of the other solvents contained in the solvent cited as other components contained in the resist composition include n-propyl alcohol, i-propyl alcohol, n-butyl alcohol, tert-butyl alcohol, cyclohexanol, ethyleneglycol monomethyl ether, ethyleneglycol monoethyl ether, ethyleneglycol mono-n-propyl ether, ethyleneglycol mono-n-butyl ether, diethyleneglycol dimethyl ether, diethyleneglycol diethyl ether, diethyleneglycol di-n-propyl ether, diethyleneglycol di-n-butyl ether, ethyleneglycol monomethyl ether acetate, ethyleneglycol monoethyl ether acetate, ethyleneglycol mono-n-propyl ether acetate, propyleneglycol, propyleneglycol monomethyl ether, propyleneglycol monoethyl ether, propyleneglycol mono-n-propyl ether, ethyl 2-hydroxy-2-methylpropionate, ethyl ethoxyacetate, ethyl hydroxyacetate, methyl 2-hydroxy-3-methyl lactate, 3-methoxybutyl acetate, 3-methyl-3-methoxybutyl acetate, 3-methyl-3-methoxybutyl propionate, 3-methyl-3-methoxybutyl butyrate, ethyl acetate, n-propyl acetate, n-butyl acetate, methyl acetoacetate, ethyl acetoacetate, methyl pilvate, ethyl pilvate, N-methyl pyrrolidone, N,N-dimethyl formamide, N,N-dimethyl acetamide, benzyl ethyl ether, di-n-hexyl ether, ethyleneglycol monomethyl ether, diethyleneglycol monoethyl ether, 7-butyrolactone, toluene, xylene, caproic acid, caprylic acid, octane, decane, 1-octanol, 1-nonanol, benzyl alcohol, benzyl acetate, ethyl benzoate, diethyl oxalate, diethyl maleate, ethylene carbonate, and propylene carbonate. These solvents may be used singly or in a combination of equal to or more than two kinds.

The resist composition containing the core-shell hyperbranched polymer synthesized according to the method above may be treated for the patterning treatment by development after exposure to a light in a patterned form. The above resist composition may support an electron beam, a deep ultraviolet beam (DUV), and an extreme ultraviolet beam (EUV), which require a surface smoothness of a nanometer level, thereby enabling formation of a fine pattern for manufacturing a semi-conductor integrated circuit. Thus, the resist composition containing the core-shell hyperbranched polymer formed by the synthesis method above can be used suitably in various fields using a semi-conductor integrated circuit produced by using a light source irradiating a short wavelength light.

In the semi-conductor integrated circuit produced by using the resist composition above containing the core-shell hyperbranched polymer of the embodiment, when the semi-conductor integrated circuit is exposed to light, is heated, dissolved in a basic developing solution, and then washed by water and the like during production, substantially no undissolved residues remained on an exposed part, and thus, a nearly vertical edge can be obtained.

As explained above, according to the synthesis method of the core-shell hyperbranched polymer of the embodiment, the core-shell hyperbranched polymer may be synthesized stably and in large quantities without causing a gelation.

According to the core-shell hyperbranched polymer of the embodiments, a resist composition containing the core-shell hyperbranched polymer having stable performance without gelation can be produced in large quantities.

In the following, the present invention and the embodiments relating to the present invention in Chapter 5 as described above will be explained more concretely by the following examples. However, interpretation of the present invention and the embodiments relating to the present invention is not limitedly by the following examples.

### (Weight-Average Molecular Weight (Mw))

The weight-average molecular weight (Mw) of the core portion in the hyperbranched polymer of an example of the embodiments of Chapter 5 will be explained. The weight-average molecular weight (Mw) of the core portion in the core-shell hyperbranched polymer of the example was obtained by a GPC (Gel Permeation Chromatography) measurement using a tetrahydrofuran solution (0.5% by mass) at 40° C., a GPC HLC-8020 type instrument and two TSKgel HXL-M columns (manufactured by Tosoh Corporation) connected in series. In the GPC measurement, tetrahydrofuran was used as a moving phase and styrene was used as a standard material.

### (Degree of Branching (Br) of Hyperbranched Core Polymer)

The degree of branching (Br) of the hyperbranched core polymer in examples will be explained. The degree of branching (Br) was obtained by measuring ¹H-NMR of the product. Namely, the degree of branching (Br) of the hyperbranched core polymer in examples was calculated by computing equation (A) by using H1°, an integral ratio of protons in —CH₂Cl appearing at 4.6 ppm, and H2°, an integral ratio of the protons in —CHCl appearing at 4.8 ppm. Here, when the polymerization progresses at both —CH₂Cl and —CHCl thereby enhancing the branching, the degree of branching (Br) approaches 0.5.

### (Core/Shell Ratio)

The core/shell ratio of the core-shell hyperbranched polymer in examples will be explained. The core/shell ratio was obtained by measuring ¹H-NMR of the product. Namely, the core/shell ratio of the core-shell hyperbranched polymer in examples was calculated by using the integral ratio of protons appearing at 1.4 to 1.6 ppm assignable to the tert-butyl group and the integral ratio of the protons appearing at near 7.2 ppm assignable to the aromatic group.

### (Analysis of Trace Metal)

Measurements of metal content in the core-shell hyperbranched polymer were made by an ICP mass analysis instrument (P-6000 type MIP-MS, manufactured by Hitachi Ltd.) or a flameless atomic absorption method (manufactured by PerkinElmer Inc.).

### (Ultrapure Water)

The ultrapure water used in examples will be explained. The ultrapure water used in examples is produced by using a GSR-200 equipment (manufactured by Advantec Toyo Kaisha, Ltd.). The metal content of the ultrapure water at 25° C. was 1 ppb or less and the specific resistance was 18 MΩ·cm.

Synthesis of the hyperbranched core polymer in examples was carried out as follows (in a temperature-controlled room at 25° C.) with reference to the synthesis method described by Krzysztof Matyjaszewski, Macromolecules, 29, 1079 (1996) and by Jean M. J. Frecht, J. Poly. Sci., 36, 955 (1998).

### First Example

### Core-Shell Hyperbranched Polymer Synthesizing Method

The synthesis of the core portion of the hyperbranched polymer (herein, hyperbranched core polymer) of a first example will be described. The hyperbranched core polymer of the first example was synthesized according to the following method. Firstly, 18.3 g of 2,2′-bipyridyl, 5.8 g of copper (I) chloride, 441 mL of chlorobenzene, and 49 mL of acetonitrile were charged into a four-necked flask (1 liter volume), which was then assembled with a dropping funnel containing 90.0 g of weighed chloromethyl styrene, a cooling column, and an agitator. The inside the reaction equipment thus assembled was entirely degassed and replaced with an argon gas. After the argon-replacement, the above-mentioned mixture was heated at 115° C., and then chloromethyl styrene was added dropwise into the reaction vessel for one hour. After the dropwise addition, the heating with agitation was continued for 3 hours. The reaction time including the dropwise addition of chloromethyl styrene into the reaction vessel was 4 hours.

After the reaction by heating with agitation, the reaction system after the reaction was filtered to remove insoluble matters. After the filtration, 500 mL of an aqueous oxalic acid solution (3% by mass) prepared using ultrapure water was added to the filtered solution. After the resulting mixture was agitated for 20 minutes, a water layer that resulted after the agitation was removed. The copper of the reaction catalyst was removed by repeating a series of the following operations four times: to the solution after removal of the water layer, an aqueous oxalic acid solution (3% by mass) prepared using ultrapure water was added; the resulting mixture was agitated; and then the water layer was removed from the solution after the agitation.

To the solution resulting after removal of the copper, 700 mL of methanol was added to re-precipitate a solid component. The solid component obtained by re-precipitation was washed with 500 mL of a mixed solvent of THF (tetrahydrofuran)/methanol=2/8 (by volume). After the washing, the solvent was removed by decantation from the solution. The operation to wash the solid component obtained by re-precipitation with 500 mL of a mixed solvent of THF:methanol=2:8 was repeated two times.

Thereafter, it was dried under a reduced pressure of 0.1 Pa at 25° C. for 2 hours. As a result, 64.8 g of the hyperbranched core polymer of the first example was obtained as the purified product. The yield of the obtained hyperbranched core polymer was 72%. The weight-average molecular weight (Mw) and the degree of branching (Br) of the obtained hyperbranched core polymer were 2000 and 0.50, respectively.

### (Synthesis of the Shell Portion of the Core-Shell Hyperbranched Polymer)

The synthesis of the shell portion of the core-shell hyperbranched polymer of the first example will be explained. In the synthesis of the shell portion of the core-shell hyperbranched polymer of the first example, 10 g of the core-shell hyperbranched core polymer of the first example described above, 5.1 g of 2,2′-bipyridyl, and 1.6 g of copper (I) chloride were added to a four-necked reaction vessel (1 liter volume) equipped with an agitator and a cooling column, and then the entire system including the reaction vessel was fully degassed under vacuum. Under an argon gas atmosphere, 250 mL of chlorobenzene (reaction solvent) was added, followed by the addition of 48 mL of tert-butyl acrylate by syringe. The resulting mixture was heated at 120° C. with agitation for 5 hours.

After the polymerization, undissolved matter was removed by filtration, and then 300 mL of an aqueous oxalic acid solution (3% by mass) prepared using ultrapure water was added to the filtered solution. The resulting solution was agitated for 20 minutes, and then a water layer was removed from the solution after the agitation. The copper of the reaction catalyst was removed by repeating a series of the following operations four times: to the solution obtained after removal of the water layer, the aqueous oxalic acid solution (3% by mass) prepared using ultrapure water was added; the resulting mixture was agitated; and then the water layer was removed from the solution after the agitation.

In the purification in the first example, from the solution of a pale yellow color obtained after the copper was removed, the solvents therein were removed by evaporation, and then 700 mL of methanol was added to the resulting solution to re-precipitate a solid component. A series of the operations, in which the solid component obtained by re-precipitation was dissolved into 50 mL of THF and re-precipitated again by adding 500 mL of methanol, was repeated two times, and then the solid component was dried under a reduced pressure of 0.1 Pa at 25° C. for 3 hours.

As a result, 17.1 g of the solid core-shell hyperbranched polymer with a pale yellow color was obtained as the purified product. The yield of the obtained solid with a pale yellow color was 76%. The mol ratio of the obtained core-shell hyperbranched polymer was calculated by ¹H-NMR. As a result, the core/shell ratio of the core-shell hyperbranched polymer was 40/60.

### (Removal of Trace Metal)

Removal of trace metal in the first example will be explained. In the removal of trace metal, 6 g of the core-shell hyperbranched polymer having the shell portion as described above dissolved in chloroform was mixed with 100 g of an aqueous oxalic acid solution (3% by mass) prepared using ultrapure water. The resulting solution was agitated vigorously for 30 minutes. After the agitation, an organic layer was extracted from the solution after the agitation. The organic layer was again mixed with 100 g of the aqueous oxalic acid solution (3% by mass) prepared using ultrapure water, and then agitated vigorously for 30 minutes. After the agitation, the organic layer was extracted from the solution after the agitation.

The operation to vigorously agitate the mixture of the organic layer extracted and the aqueous oxalic acid solution (3% by mass) prepared using ultrapure water was repeated five times in total. To the solution after agitation, 100 g of hydrochloric acid (3% by mass) was added, and the resulting mixture was agitated vigorously for 30 minutes, and thereafter the organic layer was extracted from the solution after the agitation.

Subsequently, a series of following operations was repeated three times: the organic layer extracted was mixed with 100 g of the ultrapure water, the resulting mixture was agitated vigorously for 30 minutes, and then the organic layer was extracted from the solution after the agitation. The solvents in the finally obtained organic layer were removed by evaporation, and a residue was dried under a reduced pressure of 0.1 Pa at 25° C. for 3 hours. The metal contents in the solid component obtained after removal of the solvents were analyzed as mentioned previously. As a result, the combined copper, sodium, iron, and aluminum content in the solid component was 10 ppb or less.

### (Deprotection)

Deprotection in the first example will be explained. In the deprotection in the first example, 0.6 g of the weighed solid component obtained after removal of the organic solvents was added into a reaction vessel equipped with a reflux column. After 30 mL of dioxane and 0.6 mL of hydrochloric acid (30%) were added, the resulting mixture was heated with agitation at 90° C. for 60 minutes. The crude reaction matter obtained by heating with agitation was poured into 300 mL of the ultrapure water to re-precipitate a solid component and the solvent was removed by decantation.

Then, a solution of the re-precipitated solid component dissolved in 30 mL of dioxane was poured into 300 mL of the ultrapure water to re-precipitate the solid component again. The solid component obtained by the re-precipitation was recovered and dried under a reduced pressure of 0.1 Pa at 25° C. for 3 hours to obtain the core-shell hyperbranched polymer of first example. The yield of the core-shell hyperbranched polymer of first example was 0.4 gram (66%). The mol ratio of the acid-decomposable group to the acid group was 78/22.

### Second Example

### Synthesis of the Core Portion of the Core-Shell Hyperbranched Polymer

A synthesis of the core portion of the hyperbranched polymer (hereinafter, “hyperbranched core polymer”) of the second example will be explained. The hyperbranched core polymer of the second example was synthesized as follows. Firstly, 54.6 g of tributylamine and 18.7 g of iron (II) chloride were weighed into a four-necked flask (1 liter volume) equipped with an agitator and a cooling column. The entire reaction system including the reaction vessel was fully degassed by evacuation, and 430 mL of chlorobenzene (reaction solvent) was added thereto under an argon gas atmosphere. Then, 90.0 g of chloromethyl styrene was added dropwise for 5 minutes, and the resulting mixture was agitated and heated maintaining the inside temperature constantly at 125° C. The reaction time including the dropwise addition was 27 minutes.

After the reaction by heating with agitation, to the reaction system after the reaction, 500 mL of an aqueous oxalic acid solution (3% by mass) prepared using ultrapure water was added. After the resulting mixture was agitated for 20 minutes, a water layer was removed from the solution. The iron of the reaction catalyst was removed by repeating a series of the following operations four times: to the solution obtained after removal of the water layer, the aqueous oxalic acid solution (3% by mass) prepared using ultrapure water was added; the resulting mixture was agitated; and then the water layer was removed from the solution after the agitation.

To the solution resulting after removal of the iron, 700 mL of methanol was added to re-precipitate a solid component. The solid component obtained by re-precipitation was washed with 1200 mL of a mixed solvent of THF:methanol=2:8. After washing, the solvent in the solution after washing was removed by decantation.

Thereafter, the polymer was washed by adding 500 mL of a mixed solvent of THF:methanol=2:8 into the solid component obtained after removal of the solvent. After washing, the solvent in the solution after washing was removed by decantation. The solution after removal of the solvent was dried under a reduced pressure of 0.1 Pa at 25° C. for 3 hours.

As a result, 72 g of the hyperbranched core polymer of the second example was obtained as the purified product. The yield of the obtained hyperbranched core polymer was 80%. The weight-average molecular weight (Mw) of the obtained hyperbranched core polymer was 2000 and the degree of branching (Br) was 0.50.

### (Synthesis of Shell Portion of Core-Shell Hyperbranched Polymer)

The synthesis of the shell portion of the hyperbranched polymer of the second example will be explained. In the synthesis of the shell portion of the core-shell hyperbranched polymer of the second example, 10 g of the hyperbranched core polymer of the second example described above, 6.1 g of tributylamine, and 2.1 g of iron (II) chloride were weighed into a four-necked reaction vessel (1 liter volume) equipped with an agitator and a cooling column, and then the entire reaction system including the reaction vessel was fully degassed under vacuum. Under an argon gas atmosphere, 260 mL of chlorobenzene (reaction solvent) was added, followed by an addition of 48 mL of tert-butyl acrylate by syringe. The resulting mixture was heated at 120° C. and agitated for 5 hours.

After the polymerization reaction by heating and agitation, to the reaction system after the polymerization reaction, an aqueous oxalic acid solution (3% by mass) was added. After the resulting mixture was agitated for 20 minutes, a water layer was removed from the solution after the agitation. The iron of the reaction catalyst was removed by repeating a series of the following operations four times: to the solution obtained after removal of the water layer, the aqueous oxalic acid solution (3% by mass) prepared using ultrapure water was added; the resulting mixture was agitated; and then the water layer was removed from the solution after the agitation.

To the solution resulting after removal of the iron, 700 mL of methanol was added to re-precipitate a solid component. Then, to the solid component obtained by re-precipitation, 500 mL of methanol was added for re-precipitation, and the operation was repeated two times. Thereafter, the drying was performed under a reduced pressure of 0.1 Pa at 25° C. for 3 hours.

As a result, 22 g of the solid core-shell hyperbranched polymer with a pale yellow color was obtained as the purified product. The yield of the obtained solid with a pale yellow color was 74%. The mol ratio of the obtained core-shell hyperbranched polymer was calculated by ¹H-NMR. As a result, the core/shell ratio of the core-shell hyperbranched polymer was 30/70.

### (Removal of Trace Metal)

Removal of trace metal in the second example will be explained. In the removal of trace metal, 6 g of the core-shell hyperbranched polymer having the shell portion as described above dissolved in chloroform was mixed with 50 g of the aqueous oxalic acid solution (3% by mass) and 50 g of the aqueous hydrochloric acid (1% by mass) prepared using ultrapure water were added together. The resulting solution was agitated vigorously for 30 minutes. After the agitation, an organic layer was extracted from the solution after the agitation. The organic layer was again mixed with 100 g of the aqueous oxalic acid solution (3% by mass) prepared using ultrapure water, and then agitated vigorously for 30 minutes. After the agitation, the organic layer was extracted from the solution after the agitation.

The operation to vigorously agitate the mixture of the organic layer extracted and the aqueous oxalic acid solution (3% by mass) prepared using ultrapure water was repeated five times in total. To the solution after agitation, 100 g of hydrochloric acid (3% by mass) was added, and the resulting mixture was agitated vigorously for 30 minutes, and thereafter the organic layer was extracted from the solution.

Subsequently, a series of following operations was repeated three times: the organic layer extracted was mixed with 100 g of the ultrapure water, the resulting mixture was agitated vigorously for 30 minutes, and then the organic layer was extracted from the solution after the agitation. The solvents in the finally obtained organic layer were removed by evaporation, and a residue was dried under a reduced pressure of 0.1 Pa at 25° C. for 3 hours. The metal contents in the solid component obtained after removal of the solvents were analyzed. As a result, the combined copper, sodium, iron, and aluminum in the solid component content was 10 ppb or less.

### (Deprotection)

Deprotection in the second example will be explained. In the deprotection in the second example, 0.6 g of the weighed solid component obtained after removal of the organic solvents was added into a reaction vessel equipped with a reflux column. After 30 mL of dioxane and 0.6 mL of hydrochloric acid (30%) were added, the resulting mixture was heated with agitation at 90° C. for 60 minutes. The crude reaction matter obtained by heating with agitation was poured into 300 mL of the ultrapure water to re-precipitate a solid component and the solvent was removed by decantation.

Then, a solution containing the re-precipitated solid component dissolved into 30 mL of dioxane was poured into 300 mL of the ultrapure water to re-precipitate the solid component again. The solid component obtained by the re-precipitation was recovered and dried under a reduced pressure of 0.1 Pa at 25° C. for 3 hours to obtain the core-shell hyperbranched polymer of the second example. The yield of the core-shell hyperbranched polymer of second example was 0.4 gram (66%). The mol ratio of the acid-decomposable group to the acid group was 80/20.

### Third Example

### Synthesis of Core Portion of Core-Shell Hyperbranched Polymer

A synthesis of the core portion of the core-shell hyperbranched polymer (hereinafter, “hyperbranched core polymer”) in the third example will be explained. The core portion of the hyperbranched core polymer in the third example was synthesized by the following method. Firstly, 11.8 g of 2,2′-bipyridyl, 3.5 g of copper (I) chloride, and 345 mL of benzonitrile were charged into a four-necked flask (1 liter volume), which was then assembled with a dropping funnel containing 54.2 g of weighed chloromethyl styrene, a cooling column, and an agitator. Inside the reaction equipment thus assembled was entirely degassed and replaced with an argon gas. After the argon-replacement, the resulting mixture was heated at 125° C., and then chloromethyl styrene was added dropwise into the reaction vessel for 30 minutes. After the dropwise addition, the heating with agitation was continued for 3.5 hours. The reaction time including the dropwise addition of chloromethyl styrene into the reaction vessel was 4 hours.

After the reaction, the reaction solution was filtered through a filter paper having a retaining particle size of 1 μm. Then, the filtered solution was poured into a pre-mixed solution of 844 g of methanol and 211 g of the ultrapure water to re-precipitate poly(chloromethyl styrene).

After 29 g of the polymer obtained by the re-precipitation was dissolved into 100 g of benzonitrile, to the resulting solution, a mixed solution of 200 g of methanol and 50 g of the ultrapure water was added. After centrifugal separation, the solvent was removed by decantation to recover the polymer. This recovery operation was repeated three times to obtain a precipitated polymer.

After decantation, the precipitated product was dried under reduce pressure at 25° C. to obtain 14.0 g of poly(chloromethyl styrene). The yield was 26%. The weight-average molecular weight (Mw) of the polymer obtained by GPC measurement (polystyrene equivalent) was 1140, and the degree of branching (Br) obtained by the ¹H-NMR measurement was 0.51.

### (Synthesis of Shell Portion of Core-Shell Hyperbranched Polymer)

The synthesis of the shell portion of the core-shell hyperbranched polymer of the third example will be explained. The shell portion of the core-shell hyperbranched polymer of the third example was synthesized by the following method. Into a four-necked reaction vessel (volume of 500 mL) containing 1.6 g of copper (I) chloride, 5.1 g of 2,2′-bipyridyl, and 10.0 g of the hyperbranched core polymer, 248 mL of monochlorobenzene and 48 mL of tert-butyl acrylate were charged by syringe under an argon atmosphere. Subsequently, the mixture in the reaction vessel was heated with agitation at 125° C. for 5 hours.

After termination of the polymerization reaction carried out by heating and agitation as described above, the reaction system resulting after the termination of the polymerization reaction was filtered to remove undissolved matter. Subsequently, to 308 g of the filtered solution obtained by the filtration, 615 g of a mixture solution of acids containing 3% by mass of oxalic acid and 1% by mass of hydrochloric acid prepared using ultrapure water was added. After the resulting solution was agitated for 20 minutes, the water layer was removed from the reaction system obtained after the agitation. Then, a series of the following operations was repeated four times to remove the copper of the reaction catalyst: to the polymer solution obtained after removal of the water layer, the above-mentioned mixture solution of acids containing oxalic acid and hydrochloric acid was added; the resulting solution was agitated; and then the water layer was removed from the solution obtained after the agitation.

A pale yellow color solution obtained after removal of the copper was concentrated under a reduced pressure of 15 mmHg at 40° C. to obtain 62.5 g of a concentrated solution. To the resulting concentrated solution, 219 g of methanol and then 31 g of the ultrapure water were added to precipitate a solid component. After the solid component obtained by precipitation was dissolved into 20 g of THF, to the resulting solution, 200 g of methanol and then 29 g of the ultrapure water was added to re-precipitate the solid component.

The solid component recovered by centrifugal separation after the re-precipitation operation as described above was dried at 40° C. and 0.1 mmHg for 2 hours to obtain a purified solid with a pale yellow color. The yield of the core-shell hyperbranched polymer having the formed shell portion was 23.8 g. The mol fraction of the copolymer (the core-shell hyperbranched polymer having the formed shell portion) was calculated from ¹H-NMR. The core/shell mol ratio of the core-shell hyperbranched polymer having the formed shell portion was 30/70.

### Fourth Example

The core-shell hyperbranched polymer of the fourth example will be explained. The core-shell hyperbranched polymer of the fourth example was synthesized by de-protecting the core-shell hyperbranched polymer of the third example.

### (Deprotection)

Deprotection in the fourth example will be explained. In the deprotection in the fourth example, firstly 2.0 g of the copolymer (the core-shell hyperbranched polymer in the third example) was weighed into a reaction vessel equipped with a reflux condenser, and 18.0 g of 1,4-dioxane and 0.2 g of sulfuric acid (50% by mass) were added thereto. Thereafter, the entire reaction system including the reaction vessel equipped with the reflux condenser was heated to the reflux temperature, under which condition the system was refluxed with agitation for 60 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added, and then the resulting mixture was agitated vigorously at room temperature for 30 minutes. After the water layer was separated, again 50 g of the ultrapure water was added, the mixture was agitated vigorously at room temperature for 30 minutes, and then the water layer was separated. A series of the operations involving the addition of 50 g of the ultrapure water, the vigorous agitation of the mixture at room temperature for 30 minutes, and the separation of the water layer thereafter was repeated an additional two times. The methyl isobutyl ketone solution was evaporated under reduced pressure to remove the solvent, and then the residue was dried at 40° C. under reduced pressure to obtain 1.6 g of the polymer. The mol ratio of the acid-decomposable group to the acid group was 78/22.

### Fifth Example

The core-shell hyperbranched polymer in the fifth example will be explained. In the core-shell hyperbranched polymer in the fifth example, the shell portion was synthesized by using the core portion of the core-shell hyperbranched polymer in the third example (hereinafter, “hyperbranched core polymer).

### (Synthesis of Shell Portion of Core-Shell Hyperbranched Polymer)

The synthesis of the shell portion of the core-shell hyperbranched polymer of the fifth example will be explained. The shell portion of the core-shell hyperbranched polymer of the fifth example was synthesized by the following method. Into a four-necked reaction vessel (volume of 500 mL) containing 1.6 g of copper (I) chloride, 5.1 g of 2,2′-bipyridyl, and 10.0 g of the hyperbranched core polymer of the third example, 248 mL of monochlorobenzene and 81 mL of tert-butyl acrylate were charged by syringe under an argon atmosphere. Subsequently, the mixture in the reaction vessel was heated with agitation at 125° C. for 5 hours.

After termination of the polymerization reaction carried out by heating and agitation as described above, the reaction system resulting after the termination of the polymerization reaction was filtered to remove undissolved matter. Subsequently, to 340 g of the filtered solution obtained by the filtration, 680 g of a mixture solution of acids containing 3% by mass of oxalic acid and 1% by mass of hydrochloric acid prepared using ultrapure water was added. After the resulting solution was agitated for 20 minutes, the water layer was removed from the reaction system obtained after the agitation. Then, a series of the following operations was repeated four times to remove the copper of the reaction catalyst: to the polymer solution obtained after removal of the water layer, the above-mentioned mixture solution of acids containing oxalic acid and hydrochloric acid was added; the resulting solution was agitated; and then the water layer was removed from the solution obtained after the agitation.

A pale yellow color solution obtained after removal of the copper was concentrated under a reduced pressure of 15 mmHg at 40° C. to obtain 88.0 g of a concentrated solution. To the resulting concentrated solution, 308 g of methanol and then 44 g of the ultrapure water were added to precipitate a solid component. After the solid component obtained by precipitation was dissolved into 44 g of THF, to the resulting solution, 440 g of methanol and then 63 g of the ultrapure water was added to re-precipitate the solid component.

The solid component recovered by centrifugal separation after the re-precipitation operation as described above was dried at 40° C. and 0.1 mmHg for 2 hours to obtain a purified solid with a pale yellow color. The yield of the core-shell hyperbranched polymer having the formed shell portion was 33.6 g. The mol fraction of the copolymer (the core-shell hyperbranched polymer having the formed shell portion) was calculated from ¹H-NMR. The core/shell mol ratio of the core-shell hyperbranched polymer having the formed shell portion was 19/81.

### (Deprotection)

Deprotection in the fifth example will be explained. In the deprotection in the fifth example, firstly 2.0 g of the copolymer (the core-shell hyperbranched polymer in the fifth example) was weighed into a reaction vessel equipped with a reflux condenser, and 18.0 g of 1,4-dioxane and 0.2 g of sulfuric acid (50% by mass) were added thereto. Thereafter, the entire reaction system including the reaction vessel equipped with the reflux condenser was heated to the reflux temperature, under which condition the system was refluxed with agitation for 30 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added, and then the resulting mixture was agitated vigorously at room temperature for 30 minutes. After the water layer was separated, again 50 g of the ultrapure water was added, the mixture was agitated vigorously at room temperature for 30 minutes, and then the water layer was separated. A series of the operations involving the addition of 50 g of the ultrapure water, the vigorous agitation of the mixture at room temperature for 30 minutes, and the separation of the water layer thereafter was repeated an additional two times. The methyl isobutyl ketone solution was evaporated under reduced pressure to remove the solvent, and then the residue was dried at 40° C. under reduced pressure to obtain 1.6 g of the polymer. The mol ratio of the acid-decomposable group to the acid group was 92/8.

### Sixth Example

The core-shell hyperbranched polymer in the sixth example will be explained. In the core-shell hyperbranched polymer in the sixth example, the shell portion was synthesized by using the core portion of the core-shell hyperbranched polymer in the third example (hereinafter, “hyperbranched core polymer).

### (Synthesis of Shell Portion of Core-Shell Hyperbranched Polymer)

The synthesis of the shell portion of the core-shell hyperbranched polymer of the sixth example will be explained. The shell portion of the core-shell hyperbranched polymer of the sixth example was synthesized by the following method. Into a four-necked reaction vessel (volume of 1000 mL) containing 1.6 g of copper (I) chloride, 5.1 g of 2,2′-bipyridyl, and 10.0 g of the hyperbranched core polymer of the third example, 248 mL of monochlorobenzene and 187 mL of tert-butyl acrylate were charged by syringe under an argon atmosphere. Subsequently, the mixture in the reaction vessel was heated with agitation at 125° C. for 5 hours.

After termination of the polymerization reaction carried out by heating and agitation as described above, the reaction system resulting after the termination of the polymerization reaction was filtered to remove undissolved matter. Subsequently, to 440 g of the filtered solution obtained by the filtration, 880 g of a mixture solution of acids containing 3% by mass of oxalic acid and 1% by mass of hydrochloric acid prepared using ultrapure water was added. After the resulting solution was agitated for 20 minutes, the water layer was removed from the reaction system obtained after the agitation. Then, a series of the following operations was repeated four times to remove the copper of the reaction catalyst: to the polymer solution obtained after removal of the water layer, the above-mentioned mixture solution of acids containing oxalic acid and hydrochloric acid was added; the resulting solution was agitated; and then the water layer was removed from the solution obtained after the agitation.

A pale yellow color solution obtained after removal of the copper was concentrated under a reduced pressure of 15 mmHg at 40° C. to obtain 175 g of a concentrated solution. To the resulting concentrated solution, 613 g of methanol and then 88 g of the ultrapure water were added to precipitate a solid component. After the solid component obtained by precipitation was dissolved into 85 g of THF, to the resulting solution, 850 g of methanol and then 121 g of the ultrapure water was added to re-precipitate the solid component.

The solid component recovered by centrifugal separation after the re-precipitation operation as described above was dried at 40° C. and 0.1 mmHg for 2 hours to obtain a purified solid with a pale yellow color. The yield of the core-shell hyperbranched polymer having the formed shell portion was 65.9 g. The mol fraction of the copolymer (the core-shell hyperbranched polymer having the formed shell portion) was calculated from ¹H-NMR. The core/shell mol ratio of the core-shell hyperbranched polymer having the formed shell portion was 10/90.

### (Deprotection)

Deprotection in the sixth example will be explained. In the deprotection in the sixth example, firstly 2.0 g of the copolymer (the core-shell hyperbranched polymer in the sixth example) was weighed into a reaction vessel equipped with a reflux condenser, and 18.0 g of 1,4-dioxane and 0.2 g of sulfuric acid (50% by mass) were added thereto. Thereafter, the entire reaction system including the reaction vessel equipped with the reflux condenser was heated to the reflux temperature, under which condition the system was refluxed with agitation for 15 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added, and then the resulting mixture was agitated vigorously at room temperature for 30 minutes. After the water layer was separated, again 50 g of the ultrapure water was added, the mixture was agitated vigorously at room temperature for 30 minutes, and then the water layer was separated. A series of the operations involving the addition of 50 g of the ultrapure water, the vigorous agitation of the mixture at room temperature for 30 minutes, and the separation of the water layer thereafter was repeated an additional two times. The methyl isobutyl ketone solution was evaporated under reduced pressure to remove the solvent, and then the residue was dried at 40° C. under reduced pressure to obtain 1.7 g of the polymer. The mol ratio of the acid-decomposable group to the acid group was 95/5.

### Seventh Example

The core-shell hyperbranched polymer in the seventh example will be explained. In the core-shell hyperbranched polymer in the seventh example, the shell portion was synthesized by using the core portion of the core-shell hyperbranched polymer in the third example (hereinafter, “hyperbranched core polymer).

### (Synthesis of Shell Portion of Core-Shell Hyperbranched Polymer)

The synthesis of the shell portion of the core-shell hyperbranched polymer of the seventh example will be explained. The shell portion of the core-shell hyperbranched polymer of the seventh example was synthesized by the following method. Into a four-necked reaction vessel (volume of 500 mL) containing 1.6 g of copper (I) chloride, 5.1 g of 2,2′-bipyridyl, and 10.0 g of the hyperbranched core polymer of the third example, 248 mL of monochlorobenzene and 14 mL of tert-butyl acrylate were charged by syringe under an argon atmosphere. Subsequently, the mixture in the reaction vessel was heated with agitation at 125° C. for 5 hours.

After termination of the polymerization reaction carried out by heating and agitation as described above, the reaction system resulting after the termination of the polymerization reaction was filtered to remove undissolved matter. Subsequently, to 285 g of the filtered solution obtained by the filtration, 570 g of a mixture solution of acids containing 3% by mass of oxalic acid and 1% by mass of hydrochloric acid prepared using ultrapure water was added. After the resulting solution was agitated for 20 minutes, the water layer was removed from the reaction system obtained after the agitation. Then, a series of the following operations was repeated four times to remove the copper of the reaction catalyst: to the polymer solution obtained after removal of the water layer, the above-mentioned mixture solution of acids containing oxalic acid and hydrochloric acid was added; the resulting solution was agitated; and then the water layer was removed from the solution obtained after the agitation.

A pale yellow color solution obtained after removal of the copper was concentrated under a reduced pressure of 15 mmHg at 40° C. to obtain 32 g of a concentrated solution. To the resulting concentrated solution, 112 g of methanol and then 16 g of the ultrapure water were added to precipitate a solid component. After the solid component obtained by precipitation was dissolved into 16 g of THF, to the resulting solution, 160 g of methanol and then 23 g of the ultrapure water was added to re-precipitate the solid component.

The solid component recovered by centrifugal separation after the re-precipitation operation as described above was dried at 40° C. and 0.1 mmHg for 2 hours to obtain a purified solid with a pale yellow color. The yield of the core-shell hyperbranched polymer having the formed shell portion was 12.1 g. The mol fraction of the copolymer (the core-shell hyperbranched polymer having the formed shell portion) was calculated from ¹H-NMR. The core/shell mol ratio of the core-shell hyperbranched polymer having the formed shell portion was 61/39.

### (Deprotection)

Deprotection in the seventh example will be explained. In the deprotection in the seventh example, firstly 2.0 g of the copolymer (the core-shell hyperbranched polymer in the seventh example) was weighed into a reaction vessel equipped with a reflux condenser, and 18.0 g of 1,4-dioxane and 0.2 g of sulfuric acid (50% by mass) were added thereto. Thereafter, the entire reaction system including the reaction vessel equipped with the reflux condenser was heated to the reflux temperature, under which condition the system was refluxed with agitation for 150 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added, and then the resulting mixture was agitated vigorously at room temperature for 30 minutes. After the water layer was separated, again 50 g of the ultrapure water was added, the mixture was agitated vigorously at room temperature for 30 minutes, and then the water layer was separated. A series of the operations involving the addition of 50 g of the ultrapure water, the vigorous agitation of the mixture at room temperature for 30 minutes, and the separation of the water layer thereafter was repeated an additional two times. The methyl isobutyl ketone solution was evaporated under reduced pressure to remove the solvent, and then the residue was dried at 40° C. under reduced pressure to obtain 1.4 g of the polymer. The mol ratio of the acid-decomposable group to the acid group was 49/51.

### First Reference Example

### Synthesis of 4-Vinylbenzoic Acid Tert-Butyl Ester

Synthesis of 4-vinylbenzoic acid tert-butyl ester in the first reference example will be explained. In the first reference example, 4-vinylbenzoic acid tert-butyl ester was synthesized with reference to Synthesis, 833-834 (1982).

In the synthesis of 4-vinylbenzoic acid tert-butyl ester of the first reference example, 91 g of 4-vinyl benzoic acid, 99.5 g of 1,1′-carbodimidazole, 2.4 g of 4-tert-butyl pyrocathecol, and 500 g of dehydrated dimethyl formamide were added into a reaction vessel (1 liter volume) equipped with a dropping funnel under an argon atmosphere, and the resulting mixture was agitated for one hour with keeping the entire reaction system including inside the reaction vessel at the constant temperature of 30° C. After the agitation, 93 g of 1,8-diazabicyclo[5.4.0]-7-undecene and 91 g of dehydrated 2-methyl-2-propanol were added to the reaction system obtained after the agitation, and then the resulting mixture was agitated for 4 hours.

After the reaction by agitation, 300 mL of diethyl ether and an aqueous potassium carbonate solution (10%) were added to the reaction system after the reaction, and then an objective substance, 4-vinylbenzoic acid tert-butyl ester, was extracted into the ether layer. After the extraction, the diethyl ether layer obtained by the extraction was dried under a reduced pressure to obtain a liquid with a pale yellow color. It was confirmed by ¹H-NMR that the objective substance, 4-vinylbenzoic acid tert-butyl ester, was obtained. The yield of 4-vinylbenzoic acid tert-butyl ester in the first reference example was 88%.

### Eighth Example

### Synthesis of Core Portion of Core-Shell Hyperbranched Polymer

A synthesis of the core portion of the core-shell hyperbranched polymer (hereinafter, “hyperbranched core polymer”) of the eighth example will be explained. In the synthesis of the hyperbranched core polymer of the eighth example, 25.5 g of pentamethyldiethylene triamine and 14.6 g of copper (I) chloride were weighed into a four-necked flask (1 liter volume) equipped with an agitator and a cooling column. The entire reaction system including the reaction vessel was fully degassed by evacuation, and 460 mL of chlorobenzene (reaction solvent) was added under an argon gas atmosphere. Then, 90.0 g of chloromethyl styrene was added dropwise for 5 minutes, and the resulting mixture was heated maintaining the entire reaction system including inside the reaction vessel at the constant temperature of 125° C. with agitation. The reaction time including the dropwise addition was 27 minutes.

After the reaction by heating with agitation, the reaction system after the reaction was filtered to remove undissolved matters. After the filtration, 500 mL of an aqueous oxalic acid solution (3% by mass) prepared using ultrapure water was added to the filtered solution after the filtration. After the resulting mixture was agitated for 20 minutes, a water layer was removed from the solution after the agitation. The copper of the reaction catalyst was removed by repeating a series of the following operations four times: to the solution after removal of the water layer, the aqueous oxalic acid solution (3% by mass) prepared using ultrapure water was added; the resulting mixture was agitated; and then the water layer was removed from the solution after the agitation.

To the solution resulted after removal of the copper, 700 mL of methanol was added to re-precipitate a solid component. The solid component obtained by re-precipitation was washed by adding 1200 mL of a mixed solvent of THF:methanol=2/8. After washing, the solvent was removed by decantation from the solution. Then, the operation to wash the solid component obtained by re-precipitation with 500 mL of a mixed solvent of THF:methanol=2:8 was repeated two times.

Thereafter, drying was performed under a reduced pressure of 0.1 Pa at 25° C. for 2 hours. As a result, the hyperbranched core polymer of the eighth example was obtained as the purified product. The yield of the obtained hyperbranched core polymer was 72%. The weight-average molecular weight (Mw) and the degree of branching (Br) of the obtained hyperbranched core polymer were 2000 and 0.50, respectively.

### (Synthesis of Shell Portion of Core-Shell Hyperbranched Polymer)

A synthesis of the shell portion of the hyperbranched polymer of the eighth example will be explained. In the synthesis of the shell portion of the hyperbranched polymer of the eighth example, 10 g of the hyperbranched core polymer of the eighth example, 2.8 g of pentamethyldiethylene triamine, and 1.6 g of copper (I) chloride were weighed into a four-necked flask (1 liter volume) equipped with an agitator and a cooling column. The entire reaction system including the reaction vessel was fully degassed by evacuation, and 400 mL of chlorobenzene (reaction solvent) was added under an argon gas atmosphere. Then, 40 g of 4-vinylbenzoic acid tert-butyl ester synthesized in the first reference example was charged by syringe. The resulting mixture was heated with agitation at 120° C. for 3 hours.

After the polymerization reaction by heating and agitation, the reaction system after the polymerization reaction was filtered to remove undissolved matter. After the filtration, an aqueous oxalic acid solution (3% by mass) was added to the filtered solution. After the resulting mixture was agitated for 20 minutes, a water layer was removed from the solution. The copper of the reaction catalyst was removed by repeating a series of the following operations four times: to the solution obtained after removal of the water layer, the aqueous oxalic acid solution (3% by mass) prepared using ultrapure water was added; the resulting mixture was agitated; and then the water layer was removed from the solution after the agitation.

Then, 700 mL of methanol was added to the solution after the copper was removed to re-precipitate a solid component. The solid component obtained by re-precipitation was dissolved into 50 mL of THF and re-precipitated again by adding 500 mL of methanol. This operation was repeated two times, and then the solid component was dried under a reduced pressure of 0.1 Pa at 25° C. for 3 hours.

As a result, 20 g of the solid core-shell hyperbranched polymer with a pale yellow color was obtained as the purified product. The yield of the obtained solid with a pale yellow color was 48%. The mol ratio of the obtained core-shell hyperbranched polymer was calculated by ¹H-NMR. As a result, the core/shell ratio of the core-shell hyperbranched polymer was 30/70.

### (Removal of Trace Metal)

Removal of trace metal in the eighth example will be explained. In the removal of trace metal, 6 g of the core-shell hyperbranched polymer having the shell portion as described above dissolved in chloroform was mixed with 50 g of the aqueous oxalic acid solution (3% by mass) and 50 g of the aqueous hydrochloric acid (1% by mass) prepared using ultrapure water were added together. The resulting solution was agitated vigorously for 30 minutes. After the agitation, an organic layer was extracted from the solution after the agitation. The organic layer was again mixed with 100 g of the aqueous oxalic acid solution (3% by mass) prepared using ultrapure water, and then agitated vigorously for 30 minutes. After the agitation, the organic layer was extracted from the solution after the agitation.

Then, a series of the following operations was repeated 5 times in total: 50 g of the aqueous oxalic acid solution (3% by mass) and 50 g of the aqueous hydrochloric acid (1% by mass) respectively prepared using ultrapure water were added to the extracted organic layer together, and then the resulting mixture was agitated vigorously. To the solution after agitation, 100 g of hydrochloric acid (3% by mass) was added, and the resulting mixture was agitated vigorously for 30 minutes, and thereafter the organic layer was extracted from the solution.

Subsequently, a series of following operations was repeated three times: the organic layer extracted was mixed with 100 g of the ultrapure water, the resulting mixture was agitated vigorously for 30 minutes, and then the organic layer was extracted from the solution after the agitation. The solvents in the finally obtained organic layer were removed by evaporation as described above, and a residue was dried under a reduced pressure of 0.1 Pa at 25° C. for 3 hours. The metal content in the solid component obtained after removal of the solvents were analyzed. As a result, the combined copper, sodium, iron, and aluminum content in the solid component was 10 ppb or less.

### (Deprotection)

Deprotection in the eighth example will be explained. Into a reaction vessel equipped with a reflux condenser containing 2.0 g of the copolymer, 98.0 g of dioxane and 3.5 g of sulfuric acid (30% by mass) were added. The resulting mixture was refluxed at 95° C. for 60 minutes, and then the crude reaction matter was poured into 980 mL of the ultrapure water to obtain a re-precipitated solid component. After the solid component was dissolved into 80 mL of dioxane, to the resulting solution, 800 mL of the ultrapure water was added for re-precipitation again, thereby removing the acid catalyst. The solid component was recovered and dried under a reduced pressure of 0.1 Pa at 25° C. for 3 hours to obtain a polymer. The yield of the obtained polymer was 1.6 g (Yield 82%). The mol ratio of the acid-decomposable group to the acid group was 75/25.

### Ninth Example

The core-shell hyperbranched polymer in the ninth example will be explained. In the core-shell hyperbranched polymer in the ninth example, the shell portion was synthesized by using the core portion of the core-shell hyperbranched polymer in the third example (hereinafter, “hyperbranched core polymer).

### (Synthesis of Shell Portion of Core-Shell Hyperbranched Polymer)

The synthesis of the shell portion of the core-shell hyperbranched polymer of the ninth example will be explained. The shell portion of the core-shell hyperbranched polymer of the ninth example was synthesized by the following method. Into a four-necked reaction vessel (volume of 1000 mL) containing 0.8 g of copper (I) chloride, 2.6 g of 2,2′-bipyridyl, and 5.0 g of the hyperbranched core polymer of the third example, 421 mL of monochlorobenzene and 46.8 g of tert-butyl 4-vinylbenzoate were charged by syringe under an argon atmosphere. Subsequently, the mixture in the reaction vessel was heated with agitation at 125° C. for 3.5 hours.

After termination of the polymerization reaction carried out by heating and agitation as described above, the reaction system resulting after the termination of the polymerization reaction was filtered to remove undissolved matter. Subsequently, to 490 g of the filtered solution obtained by the filtration, 980 g of a mixture solution of acids containing 3% by mass of oxalic acid and 1% by mass of hydrochloric acid prepared using ultrapure water was added. After the resulting solution was agitated for 20 minutes, the water layer was removed from the reaction system obtained after the agitation. Then, a series of the following operations was repeated four times to remove the copper of the reaction catalyst: to the polymer solution obtained after removal of the water layer, the above-mentioned mixture solution of acids containing oxalic acid and hydrochloric acid was added; the resulting solution was agitated; and then the water layer was removed from the solution obtained after the agitation.

A pale yellow color solution obtained after removal of the copper was concentrated under a reduced pressure of 15 mmHg at 40° C. to obtain 41 g of a concentrated solution. To the resulting concentrated solution, 144 g of methanol and then 21 g of the ultrapure water were added to precipitate a solid component. After the solid component obtained by precipitation was dissolved into 21 g of THF, to the resulting solution, 210 g of methanol and then 30 g of the ultrapure water was added to re-precipitate the solid component.

The solid component recovered by centrifugal separation after the re-precipitation operation as described above was dried at 40° C. and 0.1 mmHg for 2 hours to obtain a purified solid with a pale yellow color. The yield of the core-shell hyperbranched polymer having the formed shell portion was 15.9 g. The mol fraction of the copolymer (the core-shell hyperbranched polymer having the formed shell portion) was calculated from ¹H-NMR. The core/shell mol ratio of the core-shell hyperbranched polymer having the formed shell portion was 29/71.

### (Deprotection)

Deprotection in the ninth example will be explained. In the deprotection in the ninth example, firstly 2.0 g of the copolymer (the core-shell hyperbranched polymer in the ninth example) was weighed into a reaction vessel equipped with a reflux condenser, and 18.0 g of 1,4-dioxane and 0.2 g of sulfuric acid (50% by mass) were added thereto. Thereafter, the entire reaction system including the reaction vessel equipped with the reflux condenser was heated to the reflux temperature, under which condition the system was refluxed with agitation for 180 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added, and then the resulting mixture was agitated vigorously at room temperature for 30 minutes. After the water layer was separated, again 50 g of the ultrapure water was added, the mixture was agitated vigorously at room temperature for 30 minutes, and then the water layer was separated. A series of the operations involving the addition of 50 g of the ultrapure water, the vigorous agitation of the mixture at room temperature for 30 minutes, and the separation of the water layer thereafter was repeated an additional two times. The methyl isobutyl ketone solution was evaporated under reduced pressure to remove the solvent, and then the residue was dried at 40° C. under reduced pressure to obtain 1.7 g of the polymer. The mol ratio of the acid-decomposable group to the acid group was 38/62.

### Tenth Example

The core-shell hyperbranched polymer in the tenth example will be explained. In the core-shell hyperbranched polymer in the tenth example, the shell portion was synthesized by using the core portion of the core-shell hyperbranched polymer in the third example (hereinafter, “hyperbranched core polymer).

### (Synthesis of Shell Portion of Core-Shell Hyperbranched Polymer)

The synthesis of the shell portion of the core-shell hyperbranched polymer of the tenth example will be explained. The shell portion of the core-shell hyperbranched polymer of the tenth example was synthesized by the following method. Into a four-necked reaction vessel (volume of 1000 mL) containing 1.6 g of copper (I) chloride, 5.1 g of 2,2′-bipyridyl, and 5.0 g of the hyperbranched core polymer of the third example, 421 mL of monochlorobenzene and 46.8 g of tert-butyl 4-vinylbenzoate were charged by syringe under an argon atmosphere. Subsequently, the mixture in the reaction vessel was heated with agitation at 125° C. for 3 hours.

After termination of the polymerization reaction carried out by heating and agitation as described above, the reaction system resulting after the termination of the polymerization reaction was filtered to remove undissolved matter. Subsequently, to 490 g of the filtered solution obtained by the filtration, 980 g of a mixture solution of acids containing 3% by mass of oxalic acid and 1% by mass of hydrochloric acid prepared using ultrapure water was added. After the resulting solution was agitated for 20 minutes, the water layer was removed from the reaction system obtained after the agitation. Then, a series of the following operations was repeated four times to remove the copper of the reaction catalyst: to the polymer solution obtained after removal of the water layer, the above-mentioned mixture solution of acids containing oxalic acid and hydrochloric acid was added; the resulting solution was agitated; and then the water layer was removed from the solution obtained after the agitation.

A pale yellow color solution obtained after removal of the copper was concentrated under a reduced pressure of 15 mmHg at 40° C. to obtain 64 g of a concentrated solution. To the resulting concentrated solution, 224 g of methanol and then 32 g of the ultrapure water were added to precipitate a solid component. After the solid component obtained by precipitation was dissolved into 32 g of THF, to the resulting solution, 320 g of methanol and then 46 g of the ultrapure water was added to re-precipitate the solid component.

The solid component recovered by centrifugal separation after the re-precipitation operation as described above was dried at 40° C. and 0.1 mmHg for 2 hours to obtain a purified solid with a pale yellow color. The yield of the core-shell hyperbranched polymer having the formed shell portion was 24.5 g. The mol fraction of the copolymer (the core-shell hyperbranched polymer having the formed shell portion) was calculated from ¹H-NMR. The core/shell mol ratio of the core-shell hyperbranched polymer having the formed shell portion was 20/80.

### (Deprotection)

Deprotection in the tenth example will be explained. In the deprotection in the tenth example, firstly 2.0 g of the copolymer (the core-shell hyperbranched polymer in the tenth example) was weighed into a reaction vessel equipped with a reflux condenser, and 18.0 g of 1,4-dioxane and 0.2 g of sulfuric acid (50% by mass) were added thereto. Thereafter, the entire reaction system including the reaction vessel equipped with the reflux condenser was heated to the reflux temperature, under which condition the system was refluxed with agitation for 90 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added, and then the resulting mixture was agitated vigorously at room temperature for 30 minutes. After the water layer was separated, again 50 g of the ultrapure water was added, the mixture was agitated vigorously at room temperature for 30 minutes, and then the water layer was separated. A series of the operations involving the addition of 50 g of the ultrapure water, the vigorous agitation of the mixture at room temperature for 30 minutes, and the separation of the water layer thereafter was repeated an additional two times. The methyl isobutyl ketone solution was evaporated under reduced pressure to remove the solvent, and then the residue was dried at 40° C. under reduced pressure to obtain 1.7 g of the polymer. The mol ratio of the acid-decomposable group to the acid group was 71/29.

### Eleventh Example

The core-shell hyperbranched polymer in the eleventh example will be explained. In the core-shell hyperbranched polymer in the eleventh example, the shell portion was synthesized by using the core portion of the core-shell hyperbranched polymer in the third example (hereinafter, “hyperbranched core polymer).

### (Synthesis of Shell Portion of Core-Shell Hyperbranched Polymer)

The synthesis of the shell portion of the core-shell hyperbranched polymer of the eleventh example will be explained. The shell portion of the core-shell hyperbranched polymer of the eleventh example was synthesized by the following method. Into a four-necked reaction vessel (volume of 1000 mL) containing 1.6 g of copper (I) chloride, 5.1 g of 2,2′-bipyridyl, and 5.0 g of the hyperbranched core polymer of the third example, 530 mL of monochlorobenzene and 60.2 g of tert-butyl 4-vinylbenzoate were charged by syringe under an argon atmosphere. Subsequently, the mixture in the reaction vessel was heated with agitation at 125° C. for 4 hours.

After termination of the polymerization reaction carried out by heating and agitation as described above, the reaction system resulting after the termination of the polymerization reaction was filtered to remove undissolved matter. Subsequently, to 620 g of the filtered solution obtained by the filtration, 1240 g of a mixture solution of acids containing 3% by mass of oxalic acid and 1% by mass of hydrochloric acid prepared using ultrapure water was added. After the resulting solution was agitated for 20 minutes, the water layer was removed from the reaction system obtained after the agitation. Then, a series of the following operations was repeated four times to remove the copper of the reaction catalyst: to the polymer solution obtained after removal of the water layer, the above-mentioned mixture solution of acids containing oxalic acid and hydrochloric acid was added; the resulting solution was agitated; and then the water layer was removed from the solution obtained after the agitation.

A pale yellow color solution obtained after removal of the copper was concentrated under a reduced pressure of 15 mmHg at 40° C. to obtain 130 g of a concentrated solution. To the resulting concentrated solution, 455 g of methanol and then 65 g of the ultrapure water were added to precipitate a solid component. After the solid component obtained by precipitation was dissolved into 65 g of THF, to the resulting solution, 650 g of methanol and then 93 g of the ultrapure water was added to re-precipitate the solid component.

The solid component recovered by centrifugal separation after the re-precipitation operation as described above was dried at 40° C. and 0.1 mmHg for 2 hours to obtain a purified solid with a pale yellow color. The yield of the core-shell hyperbranched polymer having the formed shell portion was 50.2 g. The mol fraction of the copolymer (the core-shell hyperbranched polymer having the formed shell portion) was calculated from ¹H-NMR. The core/shell mol ratio of the core-shell hyperbranched polymer having the formed shell portion was 9/91.

### (Deprotection)

Deprotection in the eleventh example will be explained. In the deprotection in the eleventh example, firstly 2.0 g of the copolymer (the core-shell hyperbranched polymer in the eleventh example) was weighed into a reaction vessel equipped with a reflux condenser, and 18.0 g of 1,4-dioxane and 0.2 g of sulfuric acid (50% by mass) were added thereto. Thereafter, the entire reaction system including the reaction vessel equipped with the reflux condenser was heated to the reflux temperature, under which condition the system was refluxed with agitation for 30 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added, and then the resulting mixture was agitated vigorously at room temperature for 30 minutes. After the water layer was separated, again 50 g of the ultrapure water was added, the mixture was agitated vigorously at room temperature for 30 minutes, and then the water layer was separated. A series of the operations involving the addition of 50 g of the ultrapure water, the vigorous agitation of the mixture at room temperature for 30 minutes, and the separation of the water layer thereafter was repeated an additional two times. The methyl isobutyl ketone solution was evaporated under reduced pressure to remove the solvent, and then the residue was dried at 40° C. under reduced pressure to obtain 1.7 g of the polymer. The mol ratio of the acid-decomposable group to the acid group was 92/8.

### Twelfth Example

The core-shell hyperbranched polymer in the twelfth example will be explained. In the core-shell hyperbranched polymer in the twelfth example, the shell portion was synthesized by using the core portion of the core-shell hyperbranched polymer in the third example (hereinafter, “hyperbranched core polymer).

### (Synthesis of Shell Portion of Core-Shell Hyperbranched Polymer)

The synthesis of the shell portion of the core-shell hyperbranched polymer of the twelfth example will be explained. The shell portion of the core-shell hyperbranched polymer of the twelfth example was synthesized by the following method. Into a four-necked reaction vessel (volume of 300 mL) containing 0.8 g of copper (I) chloride, 2.6 g of 2,2′-bipyridyl, and 5.0 g of the hyperbranched core polymer of the third example, 106 mL of monochlorobenzene and 8.0 g of tert-butyl 4-vinylbenzoate were charged by syringe under an argon atmosphere. Subsequently, the mixture in the reaction vessel was heated with agitation at 125° C. for 1 hour.

After termination of the polymerization reaction carried out by heating and agitation as described above, the reaction system resulting after the termination of the polymerization reaction was filtered to remove undissolved matter. Subsequently, to 127 g of the filtered solution obtained by the filtration, 254 g of a mixture solution of acids containing 3% by mass of oxalic acid and 1% by mass of hydrochloric acid prepared using ultrapure water was added. After the resulting solution was agitated for 20 minutes, the water layer was removed from the reaction system obtained after the agitation. Then, a series of the following operations was repeated four times to remove the copper of the reaction catalyst: to the polymer solution obtained after removal of the water layer, the above-mentioned mixture solution of acids containing oxalic acid and hydrochloric acid was added; the resulting solution was agitated; and then the water layer was removed from the solution obtained after the agitation.

A pale yellow color solution obtained after removal of the copper was concentrated under a reduced pressure of 15 mmHg at 40° C. to obtain 19 g of a concentrated solution. To the resulting concentrated solution, 67 g of methanol and then 10 g of the ultrapure water were added to precipitate a solid component. After the solid component obtained by precipitation was dissolved into 10 g of THF, to the resulting solution, 100 g of methanol and then 14 g of the ultrapure water was added to re-precipitate the solid component.

The solid component recovered by centrifugal separation after the re-precipitation operation as described above was dried at 40° C. and 0.1 mmHg for 2 hours to obtain a purified solid with a pale yellow color. The yield of the core-shell hyperbranched polymer having the formed shell portion was 7.3 g. The mol fraction of the copolymer (the core-shell hyperbranched polymer having the formed shell portion) was calculated from ¹H-NMR. The core/shell mol ratio of the core-shell hyperbranched polymer having the formed shell portion was 60/40.

### (Deprotection)

Deprotection in the twelfth example will be explained. In the deprotection in the twelfth example, firstly 2.0 g of the copolymer (the core-shell hyperbranched polymer in the twelfth example) was weighed into a reaction vessel equipped with a reflux condenser, and 18.0 g of 1,4-dioxane and 0.2 g of sulfuric acid (50% by mass) were added thereto. Thereafter, the entire reaction system including the reaction vessel equipped with the reflux condenser was heated to the reflux temperature, under which condition the system was refluxed with agitation for 240 minutes. Thereafter, a crude reaction matter obtained after the reflux with agitation was poured into 180 mL of the ultrapure water to precipitate a solid component.

After the solid component obtained by re-precipitation was dissolved into 50 g of methyl isobutyl ketone, to the resulting solution, 50 g of the ultrapure water was added, and then the resulting mixture was agitated vigorously at room temperature for 30 minutes. After the water layer was separated, again 50 g of the ultrapure water was added, the mixture was agitated vigorously at room temperature for 30 minutes, and then the water layer was separated. A series of the operations involving the addition of 50 g of the ultrapure water, the vigorous agitation of the mixture at room temperature for 30 minutes, and the separation of the water layer thereafter was repeated an additional two times. The methyl isobutyl ketone solution was evaporated under reduced pressure to remove the solvent, and then the residue was dried at 40° C. under reduced pressure to obtain 1.4 g of the polymer. The mol ratio of the acid-decomposable group to the acid group was 22/78.

### First Comparative Example

### Synthesis of the Core Portion of the Core-Shell Hyperbranched Polymer

A synthesis of the core portion of the core-shell hyperbranched polymer (hereinafter, “hyperbranched core polymer”) in the first comparative example will be explained. The hyperbranched core polymer in the first comparative example was synthesized by the following method. Firstly, 18.3 g of 2,2′-bipyridyl, 5.8 g of copper (I) chloride, 441 mL of chlorobenzene, and 49 mL of acetonitrile were charged into a four-necked flask (1 liter volume), which was then assembled with a dropping funnel containing 90.0 g of weighed chloromethyl styrene, a cooling column, and an agitator. The inside of the reaction equipment thus assembled was entirely degassed, and thereafter replaced with an argon gas. After the argon-replacement, the above-mentioned mixture was heated at 115° C., and then chloromethyl styrene was added dropwise into the reaction vessel for one hour. After the dropwise addition, the heating with agitation was continued for 3 hours. The reaction time including the dropwise addition of chloromethyl styrene into the reaction vessel was 4 hours.

After the reaction by heating and agitation, the reaction system after the reaction was filtered to remove insoluble matter. After the filtration, 500 mL of an aqueous oxalic acid solution (3% by mass) prepared using ultrapure water was added into the filtered solution. After the resulting mixture was agitated for 20 minutes, a water layer was removed from the solution. The copper of the reaction catalyst was removed by repeating a series of the following operations four times: to the solution obtained after removal of the water layer, the aqueous oxalic acid solution (3% by mass) prepared using ultrapure water was added; the resulting mixture was agitated; and then the water layer was removed from the solution after the agitation.

To the solution obtained after removal of the copper, 700 mL of methanol was added to re-precipitate a solid component. The solid component obtained by re-precipitation was washed by adding 500 mL of a mixed solvent of THF:methanol=2/8. The operation to remove the solvent after the washing by decantation was repeated two times. Thereafter, the drying was done under a reduced pressure of 0.1 Pa at 100° C. for 2 hours. As a result, the reaction system became a gel so that purification of the washed solid component could not be performed.

### Second Comparative Example

### Synthesis of Core Portion of Core-Shell Hyperbranched Polymer

A synthesis of the core portion of the core-shell hyperbranched polymer in the second comparative example will be explained. The core portion of the core-shell hyperbranched polymer in the second comparative example was synthesized by the following method. Firstly, 11.8 g of 2,2′-bipyridyl, 3.5 g of copper (I) chloride, and 345 mL of benzonitrile were charged into a four-necked flask (1 liter volume), which was then assembled with a dropping funnel containing 54.2 g of weighed chloromethyl styrene, a cooling column, and an agitator. The inside of the reaction equipment thus assembled was entirely degassed and replaced with an argon gas. After the argon-replacement, the above-mentioned mixture was heated at 125° C., and then chloromethyl styrene was added dropwise into the reaction vessel for 30 minutes. After the dropwise addition, the heating with agitation was continued for 3.5 hours. The reaction time including the dropwise addition of chloromethyl styrene into the reaction vessel was 4 hours.

After the reaction, the reaction solution was filtered through a filter paper having a retaining particle size of 1 μm. Then, the filtered solution was poured into a pre-mixed solution of 844 g of methanol and 211 g of the ultrapure water to re-precipitate poly(chloromethyl styrene).

After 29 g of the polymer obtained by the re-precipitation was dissolved into 100 g of benzonitrile, to the resulting solution, a mixed solution of 200 g of methanol and 50 g of the ultrapure water was added. After centrifugal separation, the solvents were removed by decantation to recover the polymer. This recovery operation was repeated three times to obtain a precipitated polymer.

After decantation, the precipitated matter was dried under a reduced pressure of 0.1 Pa at 100° C. for 2 hours. As a result, the reaction system became a gel so that purification of the washed solid component could not be performed.

### (Preparation of Resist Compositions)

The resist compositions of examples will be explained. In the first to the twelfth examples, each of the resist compositions of the first to the twelfth examples was prepared as follows: a propyleneglycol monomethyl acetate (PEGMEA) solution containing 4.0% by mass of each of the core-shell hyperbranched polymers obtained in the first to the twelfth examples and 0.16% by mass of triphenyl sulfonium trifluoromethane sulfonate (photo-inductive acid-generating material) was prepared and then filtered through a filter having 0.45 μm pore diameter.

Each of thus prepared resist compositions was spin-coated on a silicon wafer, and then the resin composition spin-coated on a silicon wafer was heat-treated at 90° C. for one minute to evaporate the solvent. As a result, a thin film having a 100-nanometer thickness was formed on the silicon wafer.

### (Measurement of Sensitivity to Ultraviolet Beam Exposure)

Sensitivity of the resist compositions of the first to the twelfth examples to ultraviolet beam exposure will be explained. Sensitivity of the resist compositions of the first to the twelfth examples to ultraviolet beam exposure was measured in the following way. In the measurement, an ultraviolet beam emitting instrument of an electric discharge tube type DF-245 DNA-FIX (manufactured by ATTO Corp.) was used as the light source.

By using the light source described above, a 245 nm wavelength UV beam was emitted to expose a 10 mm×3 mm rectangular portion of each thin film formed on silicon wafers and having a 100-nanometer thickness. During exposure, the energy of the light was varied from 0 mJ/cm² to 50 mJ/cm². After the light exposure, the silicon wafer was heat treated at 100° C. for 4 minutes and developed by immersion in an aqueous solution of tetramethyl ammonium hydroxide (TMAH, 2.4% by mass) at 25° C. for 2 minutes. After the development, each silicon wafer was washed with water and dried, and the film thickness was measured to obtain the emission energy at which the film thickness after the development became zero (sensitivity). The film thickness was measured by a thin film measurement instrument F20 (manufactured by Filmetrics Japan, Inc.). The results are indicated in Table 7.

TABLE 7

| | sensitivity |
|---|---|
| | (mJ/cm²) |
| first example | 1 |
| second example | 1 |
| third example | 3 |
| fourth example | 1 |
| fifth example | 1 |
| sixth example | 1 |
| seventh example | 1 |
| eighth example | 1 |
| ninth example | 3 |
| tenth example | 1 |
| eleventh example | 1 |
| twelfth example | 1 |

1. A hyperbranched polymer synthesizing method employing living radical polymerization of a monomer in the presence of a metal catalyst, the hyperbranched polymer synthesizing method comprising:
forming a shell portion by introducing an acid-decomposable group to a core portion formed of a hyperbranched polymer synthesized by living radical polymerization;
forming an acid group by partially decomposing the acid-decomposable group in the shell portion by an acid catalyst;
precipitating a core-shell hyperbranched polymer contained in a first solution and having the acid group, by mixing the first solution with ultrapure water; and
extracting, from a mixed solution into an organic solvent by a liquid-liquid extraction, the core-shell hyperbranched polymer having the acid group, wherein the mixed solution contains a second solution containing the core-shell hyperbranched polymer precipitated at the precipitating and dissolved into the organic solvent, and the ultrapure water of an amount yielding a prescribed ratio of the ultrapure water relative to the organic solvent in the second solution.

2. The hyperbranched polymer synthesizing method according to claim 1, wherein at the extracting by liquid-liquid extraction, the prescribed ratio of the ultrapure water:the organic solvent ranges from 0.1:1 to 1:0.1 by volume.

3. The hyperbranched polymer synthesizing method claim 1, wherein the organic solvent has properties of dissolving and separating the core-shell hyperbranched polymer from water.

4. The hyperbranched polymer synthesizing method of synthesizing a hyperbranched polymer by polymerizing a monomer capable of living radical polymerization in the presence of a metal catalyst according to claim 1, further comprising:
generating a precipitate by mixing a mixed solvent consisting of two or more solvents and having a solubility parameter of 10.5 or more with a reaction solution containing a hyperbranched polymer synthesized by living radical polymerization.

5. The hyperbranched polymer synthesizing method according to claim 4, wherein at the generating of a precipitate, the precipitate is generated by mixing 0.2 to 10 parts by volume of the solvent relative to the reaction solution.

6. The hyperbranched polymer synthesizing method according to claim 4, further comprising:
generating a core-shell hyperbranched polymer having a shell portion formed by introducing an acid-degradable group into a core portion that is the precipitate generated at the generating of a precipitate; and
forming an acid group by an acid catalyst to degrade a portion of the acid-degradable group constituting the shell portion of the core-shell hyperbranched polymer generated at the generating of a core-shell hyperbranched polymer.

7. The hyperbranched polymer synthesizing method of synthesizing a core-shell hyperbranched polymer having an acid group and an acid-degradable group in a shell portion according to claim 1, further comprising:
obtaining the core-shell hyperbranched polymer by synthesizing a core portion by polymerizing a monomer capable of living radical polymerization in the presence of a metal catalyst and to the core portion, introducing an acid-degradable group to form the shell portion;
obtaining a hyperbranched polymer having a metal content 100 ppb or less by washing the hyperbranched polymer having the acid-degradable group in the shell portion with pure water; and
forming the acid group by subsequently degrading, by an acid catalyst, a portion of the acid-degradable group constituting the shell portion.

8. The hyperbranched polymer synthesizing method according to claim 7, wherein a total metal content of the pure water is 10 ppb or less at 25 degrees C.

9. The hyperbranched polymer synthesizing method according to claim 7, wherein at the obtaining of a hyperbranched polymer, filtration with a microfilter is performed in addition to the washing with the pure water.

10. The hyperbranched polymer synthesizing method of synthesizing a core-shell hyperbranched polymer having an acid group and an acid-degradable group in a shell portion according to claim 1, further comprising:
obtaining the core-shell hyperbranched polymer by synthesizing a core portion by polymerizing a monomer capable of living radical polymerization in the presence of a metal catalyst and to the core portion, introducing an acid-degradable group to form the shell portion;
obtaining a hyperbranched polymer having a metal content 100 ppb or less by washing the hyperbranched polymer having the acid-degradable group in the shell portion with pure water and an aqueous solution of an organic compound having chelating ability and/or an aqueous solution of an inorganic acid; and
forming the acid group by subsequently degrading, by an acid catalyst, a portion of the acid-degradable group constituting the shell portion.

11. The hyperbranched polymer synthesizing method according to claim 10, wherein a total metal content of the pure water is 10 ppb or less at 25 degrees C.

12. The hyperbranched polymer synthesizing method according to claim 10, wherein at the obtaining of a hyperbranched polymer, filtration with a microfilter is performed in addition to the washing with the pure water.

13. The hyperbranched polymer synthesizing method according to claim 10, wherein
the organic compound having chelating ability used at the obtaining of a hyperbranched polymer is an organic carboxylic acid selected from among formic acid, oxalic acid, acetic acid, citric acid, gluconic acid, tartaric acid, and malonic acid, and
the inorganic acid is hydrochloric acid or sulfuric acid.

14. The hyperbranched polymer synthesizing method according to claim 1, further comprising:
polymerizing by causing living radical polymerization of a monomer in the presence of a metal catalyst;
refining by using a reprecipitating method to collect a polymer polymerized at the polymerizing, from a reaction solution containing the polymer; and
filtering, through a filter having a pore diameter of 0.1 μm or less, the polymer refined at the refining.

15. The hyperbranched polymer synthesizing method according to claim 14, wherein
the polymer polymerized at the polymerizing is a core-shell hyperbranched polymer containing an acid-degradable group in a shell portion.

16. The hyperbranched polymer synthesizing method of synthesizing a hyperbranched polymer through living radical polymerization of a monomer in the presence of a metal catalyst according to claim 1, further comprising:
removing the metal catalyst in a reaction system where the hyperbranched polymer has been synthesized by the living radical polymerization; and
drying, at 10 to 70 degrees C., a solvent in the reaction system to remove the solvent after the removing of the metal catalyst.

17. The hyperbranched polymer synthesizing method according to claim 16,
wherein at the drying, pressure of the reaction system is reduced to a pressure lower than atmospheric pressure to achieve a vacuum state.

18. A hyperbranched polymer synthesized according to the hyperbranched polymer synthesizing method according to claim 1.

19. A resist composition containing the hyperbranched polymer according to claim 18.

20. A semiconductor integrated circuit having a pattern formed with the resist composition according to claim 19.

21. A semiconductor integrated circuit fabrication method comprising forming a pattern using the resist composition according to claim 19.

22. (canceled)
